(19) United States
(12) Patent Application Publication
(10) Pub. No.: US 2024/0118617 A1
(43) Pub. Date: Apr. 11, 2024

(54) Polymer, Resist Composition, And Patterning Process

(71) Applicant: SHIN-ETSU CHEMICAL CO., LTD., Tokyo (JP)

(72) Inventors: Masahiro FUKUSHIMA, Joetsu-shi (JP); Takahiro SUZUKI, Joetsu-shi (JP); Masayoshi SAGEHASHI, Joetsu-shi (JP); Koji HASEGAWA, Joetsu-shi (JP)

(73) Assignee: SHIN-ETSU CHEMICAL CO., LTD., Tokyo (JP)

(21) Appl. No.: 18/450,670

(22) Filed: Aug. 16, 2023

(30) Foreign Application Priority Data
Sep. 12, 2022 (JP) 2022-144800

(51) Int. Cl. G03F 7/039; C08F 112/14; C08F 112/32; G03F 7/038; G03F 7/20; G03F 7/32

(52) U.S. Cl. CPC G03F 7/0397; C08F 112/24; C08F 112/32; G03F 7/0382; G03F 7/2002; G03F 7/322; C08F 2800/10

(57) ABSTRACT

A polymer (P) to generate an acid by light exposure and to change in solubility in a developer with an action of the acid, the polymer containing: a repeating unit represented by the following formula (A-1); a repeating unit represented by any one or more selected from the following formulae (B-1), (B-2), (B-3), and (B-4) to generate an acid by light exposure; and a repeating unit represented by the following formula (a-1) or (a-2) other than the repeating unit represented by the formula (A-1). This provides a polymer to be contained in a resist composition that is excellent in etching resistance and that makes it possible to form a pattern with high sensitivity, high resolution, high contrast, and small LWR and CDU when using, in particular, an electron beam or an extreme ultraviolet ray (EUV) having a wavelength of 13.5 nm; a resist composition containing the polymer; and a patterning process using the resist composition.

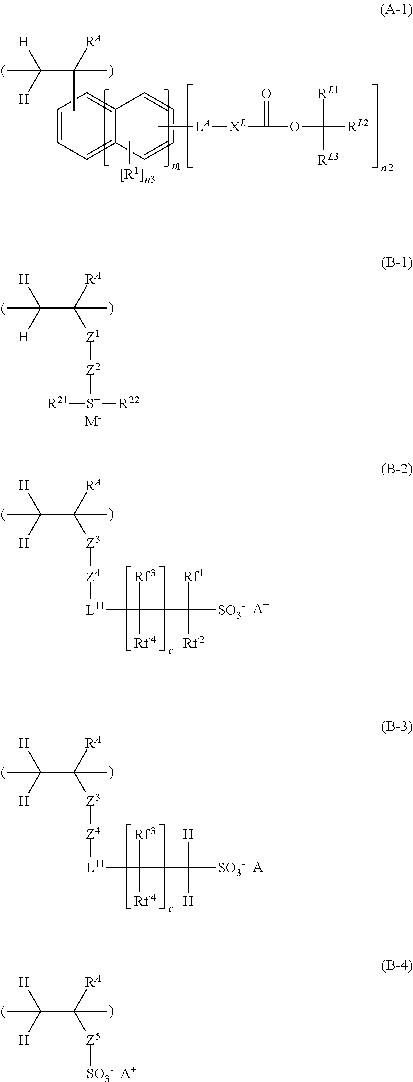

### TECHNICAL FIELD

The present invention relates to: a polymer; a resist composition; and a patterning process using the resist composition.

### BACKGROUND ART

In recent years, finer pattern formation has been required accompanying higher integration of integrated circuits. In processing a pattern with 0.2 μm or smaller, a chemically amplified resist, which uses an acid as a catalyst, is generally used. In this case, a high-energy beam such as ultraviolet ray, far ultraviolet ray, and electron beam (EB) is used as an exposure light source. In particular, electron beam lithography, which is used as an ultrafine processing technology, is also essential as a method for processing a photomask blank used in producing a photomask for semiconductor manufacturing.

Although polymers having many aromatic skeletons having an acidic side chain, for example polyhydroxystyrene, have been suitably used as a resist material for KrF excimer laser, such polymers greatly absorb light having a wavelength of near 200 nm, and thereby have not been used as the resist material for ArF excimer laser. However, such a polymer is an important material as a resist composition for EB lithography and a resist composition for extreme ultraviolet (EUV) lithography, which are effective technologies for forming a pattern smaller than the process limit of the ArF excimer laser, in terms of achievement of high etching resistance.

Mainly used as a base polymer of a positive resist composition for EB lithography or resist composition for EUV lithography is a material in which an acid generated from a photo-acid generator by irradiation with a high-energy beam catalyzes deprotection of an acid-decomposable protective group masking an acidic functional group in a phenol side chain contained in the base polymer to allow the base polymer to be dissolved in an alkaline developing liquid. As the acid-decomposable protective group, a tertiary alkyl group, a tert-butoxycarbonyl group, an acetal group, etc. have been mainly used. When a protective group, such as an acetal group, that requires a relatively low activation energy for deprotection is used, there is an advantage that a highly sensitive resist film can be obtained. However, if inhibition of diffusion of the generated acid is insufficient, the deprotection reaction also proceeds in an unexposed part in the resist film, leading to a problem of degradation of line edge roughness (LER) and decrease in in-plane uniformity (CDU) of the pattern.

As the miniaturization progresses, image blurs due to acid diffusion become a problem. To ensure resolution for fine patterns, there is a proposal that it is important to not only improve dissolution contrast as previously reported, but also control acid diffusion. Nevertheless, since chemically amplified resist materials enhance the sensitivity and contrast through acid diffusion, an attempt to minimize acid diffusion by reducing the temperature and/or time of post-exposure bake (PEB) results in significant reductions of sensitivity and contrast. Since the distance of acid diffusion is closely correlated to the type of acid-labile group, it is desired to develop an acid-labile group capable of undergoing deprotection reaction within a very short distance of acid diffusion.

It is pointed out that an ArF resist material containing a methacrylic acid or the like whose carboxy group is substituted with an acid-labile group swells in an alkaline developer. On the other hand, a KrF resist material containing hydroxystyrene or the like whose phenol group is substituted with an acid-labile group little swells. However, the hydroxystyrene allows for substantial acid diffusion, leaving concern about a decline of resolution. There is also proposal of structural units in which a carboxy group in a styrenecarboxylate is substituted with an acid-labile group (Patent Documents 1 to 3). However, there is still room for improvement, and there is desire for the development of a resist in which there is little acid diffusion and which hardly swells in an alkaline developer.

Regulation of the resist sensitivity and pattern profile has been variously improved by selection and combination of the materials used for the resist composition, the process conditions, etc. One such improvement involves the acid diffusion problem that considerably affects the resolution of the chemically amplified resist composition. Since this acid diffusion problem considerably affects the sensitivity and the resolution, many investigations have been made.

To suppress the diffusion of acid, investigations are made on polymers having a photo-acid generator copolymerized in the constitutional unit of a base polymer. In particular, an anion-bound polymer having an anion moiety of an ionic photo-acid generator copolymerized with a main chain of a base polymer is effective for suppressing the diffusion of the generated acid, and much study is carried out (Patent Documents 4 to 6).

In addition to the formation of fine patterns, the etching resistance of resist patterns is also important. Indene copolymers described in Patent Document 7 and acenaphthylene copolymers described in Patent Document 8 are expected to have improved etching resistance due to a high carbon density and a robust main chain structure based on cycloolefin structure. In addition, in response to demands for further miniaturization, it is desired to develop a resist material in which acid diffusion is controlled, various lithography properties are excellent, and the etching resistance of a resist pattern is also excellent.

### CITATION LIST

### Patent Literature

Patent Document 1: JP 6237763 B
Patent Document 2: JP 6694451 B
Patent Document 3: JP 7055070 B
Patent Document 4: JP 5954253 B
Patent Document 5: JP 6702264 B
Patent Document 6: JP 2018-013687 A
Patent Document 7: JP 3865048 B
Patent Document 8: JP 2006-169302 A

### SUMMARY OF INVENTION

### Technical Problem

As a chemically amplified resist composition that uses an acid as a catalyst, it is desired to develop a resist composition that realizes higher sensitivity and higher resolution in the formation of fine patterns, improves the line width roughness (LWR) of line patterns and the CDU of hole patterns, and is also excellent in etching resistance.

The present invention has been made in view of the above-described circumstances. An object of the present invention is to provide: a polymer to be contained in a resist composition that is excellent in etching resistance and that makes it possible to form a pattern with high sensitivity, high resolution, high contrast, and small LWR and CDU when using a high-energy beam, in particular, an electron beam or an extreme ultraviolet ray (EUV) having a wavelength of 13.5 nm; a resist composition containing the polymer; and a patterning process using the resist composition.

### Solution to Problem

To achieve the object, the present invention provides a polymer (P) to generate an acid by light exposure and to change in solubility in a developer with an action of the acid, the polymer comprising:
a repeating unit represented by the following formula (A-1);
a repeating unit represented by any one or more selected from the following formulae (B-1), (B-2), (B-3), and (B-4) to generate an acid by light exposure; and
a repeating unit represented by the following formula (a-1) or (a-2) other than the repeating unit represented by the formula (A-1),

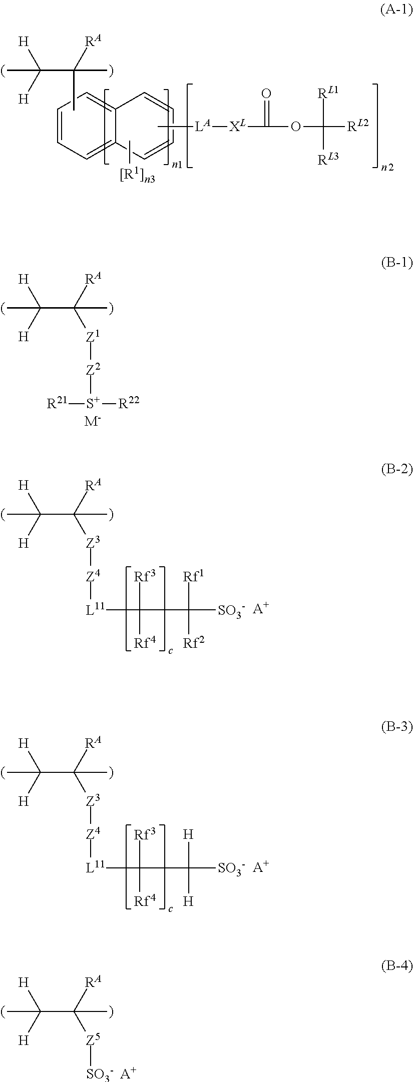

wherein in the formula (A-1), R^{A} represents a hydrogen atom, a fluorine atom, a methyl group, or a trifluoromethyl group, R^{L1}, R^{L2}, and R^{L3} each independently represent a hydrocarbyl group having 1 to 30 carbon atoms, any two of R^{L1}, R^{L2}, and R^{L3} optionally being bonded to each other to form a ring and when R^{L1}, R^{L2}, and R^{L3} are not bonded to each other to form a ring, at least one of R^{L1}, R^{L2}, and R^{L3} has one of a multiple bond, an aliphatic ring, and an aromatic ring structure, L^{A} represents a single bond, an ether bond, an ester bond, a sulfonic acid ester bond, a carbonate bond, or a carbamate bond, X^{L} represents a single bond or a hydrocarbylene group having 1 to 40 carbon atoms and optionally having a heteroatom, R¹ represents a halogen atom or a hydrocarbyl group having 1 to 20 carbon atoms and optionally having a heteroatom, n1 represents an integer of 0 or 1, n2 represents an integer of 1 or 2, n3 represents an integer of 0 to 6, provided that when n1 is 0, 1≤n2+n3≤5 and when n1 is 1, 1≤n2+n3≤7, in the formulae (B-1) to (B-4), R^{A} is as defined above, Z¹ represents a single bond or a phenylene group, Z² represents —C(═O)—O—Z²¹—, —C(═O)—NH—Z²¹—, or —O—Z²¹—, Z²¹ represents an aliphatic hydrocarbylene group having 1 to 6 carbon atoms, a phenylene group, or a divalent group obtained by combining these groups, Z²¹ optionally having a carbonyl group, an ester bond, an ether bond, or a hydroxy group, Z³ represents a single bond, a phenylene group, a naphthylene group, or (main chain) —C(═O)—O—Z³¹—, Z³¹ represents an aliphatic hydrocarbylene group having 1 to 10 carbon atoms, or a phenylene group or a naphthylene group optionally having a hydroxy group, an ether bond, an ester bond, or a lactone ring, Z⁴ represents a single bond or —Z⁴¹—C(═O)—O—, Z⁴¹ represents a hydrocarbylene group having 1 to 20 carbon atoms and optionally having a heteroatom, Z⁵ represents a single bond, a methylene group, an ethylene group, a phenylene group, a fluorinated phenylene group, a phenylene group substituted with a trifluoromethyl group, —C(═O)—O—Z⁵¹—, —C(═O)—NH—Z⁵¹—, or —O—Z⁵¹—, Z⁵¹ represents an aliphatic hydrocarbylene group having 1 to 6 carbon atoms, a phenylene group, a fluorinated phenylene group, or a phenylene group substituted with a trifluoromethyl group, Z⁵¹ optionally having a carbonyl group, an ester bond, an ether bond, or a hydroxy group, R²¹ and R²² each independently represent a hydrocarbyl group having 1 to 20 carbon atoms and optionally having a heteroatom, R²¹ and R²² are optionally bonded to each other to form a ring together with a sulfur atom to which R²¹ and R²² are bonded, L¹¹ represents a single bond, an ether bond, an ester bond, a carbonyl group, a sulfonic acid ester bond, a carbonate bond, or a carbamate bond, Rf¹ and Rf² each independently represent a fluorine atom or a fluorinated alkyl group having 1 to 6 carbon atoms, Rf³ and Rf⁴ each independently represent a hydrogen atom, a fluorine atom, or a fluorinated alkyl group having 1 to 6 carbon atoms, M⁻ represents a non-nucleophilic counterion, A⁺ represents an onium cation, and “c” represents an integer of 0 to 3,

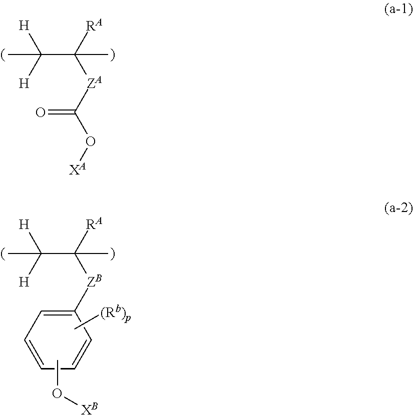

wherein R^{A} is as defined above, Z^{A} represents a single bond, a phenylene group, a naphthylene group, or (main chain) —C(═O)—O—Z^{A1}—, Z^{A1} represents a linear, branched, or cyclic alkanediyl group having 1 to 10 carbon atoms, or a phenylene group or a naphthylene group optionally having a hydroxy group, an ether bond, an ester bond, or a lactone ring, Z^{B} represents a single bond or (main chain) —C(═O)—O—, R^{b} represents a linear, branched, or cyclic hydrocarbyl group having 1 to 20 carbon atoms and optionally having a heteroatom, “p” represents an integer of 0 to 4, and X^{A} and X^{B} each independently represent an acid-labile group.

Such a polymer is a polymer to be contained in a resist composition that is excellent in etching resistance and that makes it possible to form a pattern with high sensitivity, high resolution, high contrast, and small LWR and CDU when using a high-energy beam, in particular, an electron beam or an extreme ultraviolet ray (EUV) having a wavelength of 13.5 nm.

Furthermore, in the present invention, the repeating unit represented by the formula (A-1) is preferably a repeating unit represented by the following formula (A-2),

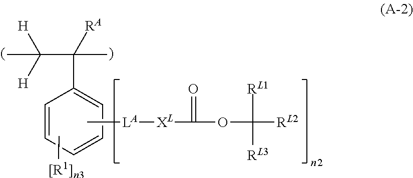

wherein R^{A}, R^{L1}, R^{L2}, R^{L3}, R¹, L^{A}, X^{L}, n2, and n3 are as defined above.

In the present invention, it is preferable to use such a repeating unit.

In this event, the repeating unit represented by the formula (A-2) is preferably a repeating unit represented by the following formula (A-3),

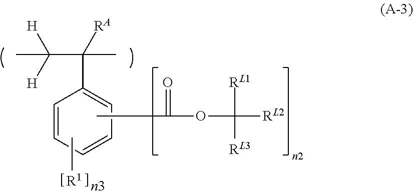

wherein R^{A}, R^{L1}, R^{L2}, R^{L3}, R¹, n2, and n3 are as defined above.

In the present invention, it is further preferable to use such a repeating unit.

Furthermore, in the present invention, the repeating unit represented by the formulae (B-2), (B-3), and (B-4) to generate an acid by light exposure preferably contains an onium cation represented by the following formula (cation-1) or (cation-2) as the onium cation A⁺,

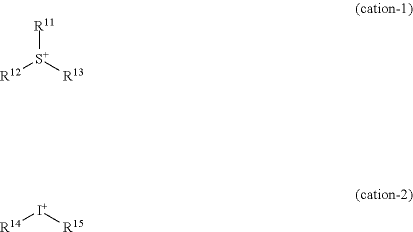

wherein R¹¹, R¹², and R¹³ each independently represent a linear, branched, or cyclic hydrocarbyl group having 1 to 30 carbon atoms and optionally having a heteroatom, any two of R¹¹, R¹², and R¹³ are optionally bonded to each other to form a ring together with a sulfur atom in the formula, and R¹⁴ and R¹⁵ each independently represent a linear, branched, or cyclic hydrocarbyl group having 1 to 30 carbon atoms and optionally having a heteroatom.

In the present invention, it is preferable to use such an onium cation.

The present invention preferably further comprises a repeating unit represented by the following formula (C-1) in the polymer (P),

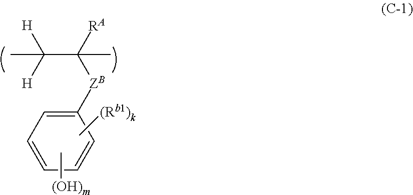

wherein R^{A} and Z^{B} are as defined above, R^{b1} represents a halogen atom, a cyano group, or a hydrocarbyl group having 1 to 20 carbon atoms, hydrocarbyloxy group having 1 to 20 carbon atoms, hydrocarbylcarbonyl group having 2 to 20 carbon atoms, hydrocarbylcarbonyloxy group having 2 to 20 carbon atoms, or hydrocarbyloxycarbonyl group having 2 to 20 carbon atoms optionally having a heteroatom, “m” represents an integer of 1 to 4, “k” represents an integer of 0 to 3, and “m+k” represents an integer of 1 to 4.

The present invention preferably has such a repeating unit.

The present invention preferably further comprises a repeating unit represented by the following formula (D-1) in the polymer (P),

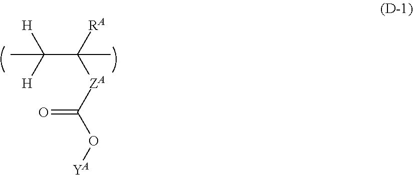

wherein R^{A} and Z^{A} are as defined above, Y^{A} represents a hydrogen atom or a polar group having at least one structure selected from a hydroxy group, a cyano group, a carbonyl group, a carboxy group, an ether bond, an ester bond, a sulfonic acid ester bond, a carbonate bond, a lactone ring, a sultone ring, and a carboxylic anhydride.

The present invention further preferably has such a repeating unit.

In addition, the present invention provides a resist composition comprising the above-described polymer.

Such a resist composition is excellent in etching resistance and makes it possible to form a pattern with high sensitivity, high resolution, high contrast, and small LWR and CDU when a high-energy beam is used, in particular, an electron beam or an extreme ultraviolet ray (EUV) having a wavelength of 13.5 nm.

In this event, the inventive resist composition preferably further comprises an organic solvent.

Such a resist composition has excellent handleability, and is preferable.

In this event, the inventive resist composition preferably further comprises a photo-acid generator other than a structural unit of the polymer (P) to generate an acid by light exposure.

Such a resist composition has excellent resolution and there is no risk of a problem of foreign matter arising after the development of the resist film or when removing the resist film. Therefore, such a resist composition is preferable.

In this event, the inventive resist composition preferably further comprises a quencher.

Such a resist composition has excellent resolution and there is no risk of sensitivity being degraded considerably, and is preferable.

In this event, the inventive resist composition preferably further comprises:
a surfactant insoluble or hardly soluble in water and soluble in an alkaline developer; and/or
a surfactant insoluble or hardly soluble in water and an alkaline developer.

Such a resist composition has a sufficiently improved receding contact angle between the surface of the resist film and water and the dissolution rate of the resist film surface in the developer is low, so that the height of the formed fine pattern can be maintained sufficiently. Therefore, such a resist composition is preferable.

The present invention also provides a patterning process comprising the steps of:
forming a resist film on a substrate by using the above-described resist composition;
exposing the resist film to a high-energy beam; and
developing the exposed resist film by using a developer.

Such a patterning process makes it possible to form a pattern with high sensitivity, high resolution, high contrast, and small LWR and CDU when a high-energy beam is used, in particular, an electron beam or an extreme ultraviolet ray (EUV) having a wavelength of 13.5 nm.

In this event, an i-line beam, a KrF excimer laser beam, an ArF excimer laser beam, an electron beam, or an extreme ultraviolet ray having a wavelength of 3 to 15 nm is preferably used as the high-energy beam.

According to such a patterning process, the pattern can be formed favorably.

In this event, an aqueous alkaline solution is preferably used as the developer to obtain a positive pattern, where an exposed portion is dissolved and an unexposed portion is not dissolved.

According to such a patterning process, a positive pattern can be obtained.

In this event, an organic solvent is preferably used as the developer to obtain a negative pattern, where an unexposed portion is dissolved and an exposed portion is not dissolved.

According to such a patterning process, a negative pattern can be obtained.

### Advantageous Effects of Invention

As described above, when the inventive polymer or a resist composition containing the polymer is used, it is possible to construct a resist pattern having high sensitivity, little LWR, little CDU, high contrast, excellent resolution, and a wide process margin, and it is also possible to form a pattern having excellent etching resistance.

### DESCRIPTION OF EMBODIMENTS

As described above, it has been desired to develop a polymer to be contained in a resist composition that is excellent in etching resistance and that makes it possible to form a pattern with high sensitivity, high resolution, high contrast, and small LWR and CDU particularly when using an electron beam or an extreme ultraviolet ray (EUV) having a wavelength of 13.5 nm.

To achieve the object, the present inventors have studied earnestly and found a resist composition containing a polymer that contains: a repeating unit having an acid-labile group and having a vinyl aromatic unit as a polymerizable group; and a particular repeating unit that generates an acid by exposure to light. The present inventors have found out that by using such a resist composition, it is possible to form a pattern having high sensitivity, high contrast, excellent resolution, excellent LWR of line patterns, excellent CDU of hole patterns, and a wide process margin, and that the resist composition is also excellent in etching resistance, so that the resist composition is extremely effective for fine pattern formation. Thus, the present invention has been completed.

That is, the present invention is a polymer (P) to generate an acid by light exposure and to change in solubility in a developer with an action of the acid, the polymer comprising:
a repeating unit represented by the following formula (A-1);
a repeating unit represented by any one or more selected from the following formulae (B-1), (B-2), (B-3), and (B-4) to generate an acid by light exposure; and
a repeating unit represented by the following formula (a-1) or (a-2) other than the repeating unit represented by the formula (A-1),

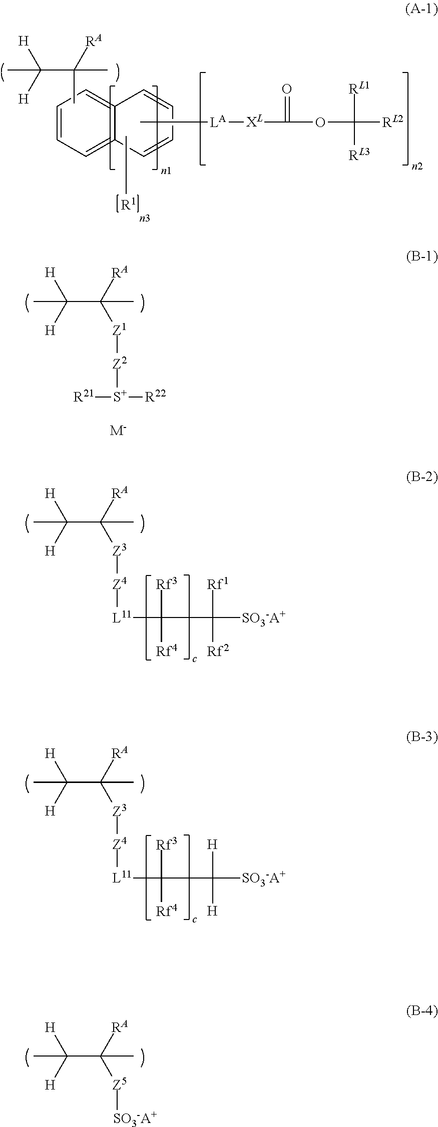

wherein in the formula (A-1), R^{A} represents a hydrogen atom, a fluorine atom, a methyl group, or a trifluoromethyl group, R^{L1}, R^{L2}, and R^{L3} each independently represent a hydrocarbyl group having 1 to 30 carbon atoms, any two of R^{L1}, R^{L2}, and R^{L3} optionally being bonded to each other to form a ring and when R^{L1}, R^{L2}, and R^{L3} are not bonded to each other to form a ring, at least one of R^{L1}, R^{L2}, and R^{L3} has one of a multiple bond, an aliphatic ring, and an aromatic ring structure, L^{A} represents a single bond, an ether bond, an ester bond, a sulfonic acid ester bond, a carbonate bond, or a carbamate bond, X^{L} represents a single bond or a hydrocarbylene group having 1 to 40 carbon atoms and optionally having a heteroatom, R¹ represents a halogen atom or a hydrocarbyl group having 1 to 20 carbon atoms and optionally having a heteroatom, n1 represents an integer of 0 or 1, n2 represents an integer of 1 or 2, n3 represents an integer of 0 to 6, provided that when n1 is 0, 1≤n2+n3≤5 and when n1 is 1, 1≤n2+n3≤7, in the formulae (B-1) to (B-4), R^{A} is as defined above, Z¹ represents a single bond or a phenylene group, Z² represents —C(═O)—O—Z²¹—, —C(═O)—NH—Z²¹—, or —O—Z²¹—, Z²¹ represents an aliphatic hydrocarbylene group having 1 to 6 carbon atoms, a phenylene group, or a divalent group obtained by combining these groups, Z²¹ optionally having a carbonyl group, an ester bond, an ether bond, or a hydroxy group, Z³ represents a single bond, a phenylene group, a naphthylene group, or (main chain) —C(═O)—O—Z³¹—, Z³¹ represents an aliphatic hydrocarbylene group having 1 to 10 carbon atoms, or a phenylene group or a naphthylene group optionally having a hydroxy group, an ether bond, an ester bond, or a lactone ring, Z⁴ represents a single bond or —Z⁴¹—C(═O)—O—, Z⁴¹ represents a hydrocarbylene group having 1 to 20 carbon atoms and optionally having a heteroatom, Z⁵ represents a single bond, a methylene group, an ethylene group, a phenylene group, a fluorinated phenylene group, a phenylene group substituted with a trifluoromethyl group, —C(═O)—O—Z⁵¹—, —C(═O)—NH—Z⁵¹—, or —O—Z⁵¹—, Z⁵¹ represents an aliphatic hydrocarbylene group having 1 to 6 carbon atoms, a phenylene group, a fluorinated phenylene group, or a phenylene group substituted with a trifluoromethyl group, Z⁵¹ optionally having a carbonyl group, an ester bond, an ether bond, or a hydroxy group, R²¹ and R²² each independently represent a hydrocarbyl group having 1 to 20 carbon atoms and optionally having a heteroatom, R²¹ and R²² are optionally bonded to each other to form a ring together with a sulfur atom to which R²¹ and R²² are bonded, L¹¹ represents a single bond, an ether bond, an ester bond, a carbonyl group, a sulfonic acid ester bond, a carbonate bond, or a carbamate bond, Rf¹ and Rf² each independently represent a fluorine atom or a fluorinated alkyl group having 1 to 6 carbon atoms, Rf³ and Rf⁴ each independently represent a hydrogen atom, a fluorine atom, or a fluorinated alkyl group having 1 to 6 carbon atoms, M⁻ represents a non-nucleophilic counterion, A⁺ represents an onium cation, and “c” represents an integer of 0 to 3,

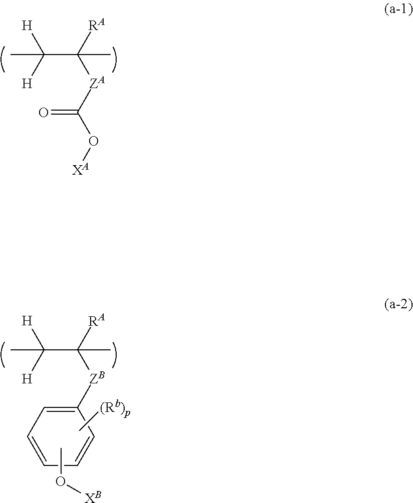

wherein R^{A} is as defined above, Z^{A} represents a single bond, a phenylene group, a naphthylene group, or (main chain) —C(═O)—O—Z^{A1}—, Z^{A1} represents a linear, branched, or cyclic alkanediyl group having 1 to 10 carbon atoms, or a phenylene group or a naphthylene group optionally having a hydroxy group, an ether bond, an ester bond, or a lactone ring, Z^{B} represents a single bond or (main chain) —C(═O)—O—, R^{b} represents a linear, branched, or cyclic hydrocarbyl group having 1 to 20 carbon atoms and optionally having a heteroatom, “p” represents an integer of 0 to 4, and X^{A} and X^{B} each independently represent an acid-labile group.

Hereinafter, the present invention will be described in detail. However, the present invention is not limited thereto.

### [Polymer (P)]

The inventive polymer (P) contains: a repeating unit having an acid-labile group and having a vinyl aromatic unit as a polymerizable group; a repeating unit that generates an acid when exposed to light; and a particular repeating unit other than the repeating unit having an acid-labile group and containing a vinyl aromatic unit as a polymerizable group.

### [Repeating Unit Having Acid-Labile Group and Containing Vinyl Aromatic Unit as Polymerizable Group (Repeating Unit A)]

The inventive polymer (P) contains a repeating unit (hereinafter, also referred to as a repeating unit A) having an acid-labile group and containing a vinyl aromatic unit as a polymerizable group. The repeating unit A is represented by the following formula (A-1).

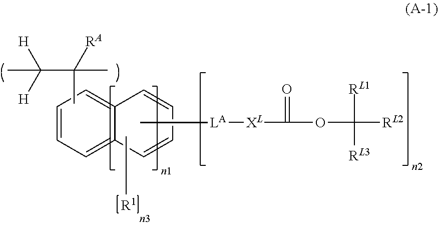

In the formula (A-1), R^{A} represents a hydrogen atom, a fluorine atom, a methyl group, or a trifluoromethyl group. R^{L1}, R^{L2}, and R^{L3} each independently represent a hydrocarbyl group having 1 to 30 carbon atoms, any two of R^{L1}, R^{L2}, and R^{L3} optionally being bonded to each other to form a ring. When R^{L1}, R^{L2}, and R^{L3} are not bonded to each other to form a ring, at least one of R^{L1}, R^{L2}, and R^{L3} has one of a multiple bond, an aliphatic ring, and an aromatic ring structure. L^{A} represents a single bond, an ether bond, an ester bond, a sulfonic acid ester bond, a carbonate bond, or a carbamate bond. X^{L} represents a single bond or a hydrocarbylene group having 1 to 40 carbon atoms and optionally having a heteroatom. R¹ represents a halogen atom or a hydrocarbyl group having 1 to 20 carbon atoms and optionally having a heteroatom. n1 represents an integer of 0 or 1. n2 represents an integer of 1 or 2. n3 represents an integer of 0 to 6, provided that when n1 is 0, 1≤n2+n3≤5 and when n1 is 1, 1≤n2+n3≤7.

In the formula (A-1), each R^{A} independently represents a hydrogen atom, a fluorine atom, a methyl group, or a trifluoromethyl group. In particular, R^{A} is preferably a hydrogen atom or a methyl group, and is further preferably a hydrogen atom.

In the formula (A-1), R^{L1}, R^{L2}, and R^{L3} each independently represent a hydrocarbyl group having 1 to 30 carbon atoms, preferably 1 to 10 carbon atoms, any two of R^{L1}, R^{L2}, and R^{L3} optionally being bonded to each other to form a ring. When R^{L1}, R^{L2}, and R^{L3} are not bonded to each other to form a ring, at least one of R^{L1}, R^{L2}, and R^{L3} has one of a multiple bond, an aliphatic ring, and an aromatic ring structure. When R^{L1}, R^{L2}, and R^{L3} are not bonded to each other to form a ring, it is preferable for at least one of R^{L1}, R^{L2}, and R^{L3} to have a structure having 2 to 30 carbon atoms and including a multiple bond, an alicyclic structure having 3 to 30 carbon atoms, or an aromatic ring structure having 6 to 30 carbon atoms. In addition, the —CH₂— contained in the hydrocarbyl group or heterocyclic group may be substituted with —O— or —S—.

The structure formed with R^{L1}, R^{L2}, and R^{L3} constitutes the acid-labile group, and specific examples include the following, but are not limited thereto. “*” represents a bond with an adjacent oxygen atom.

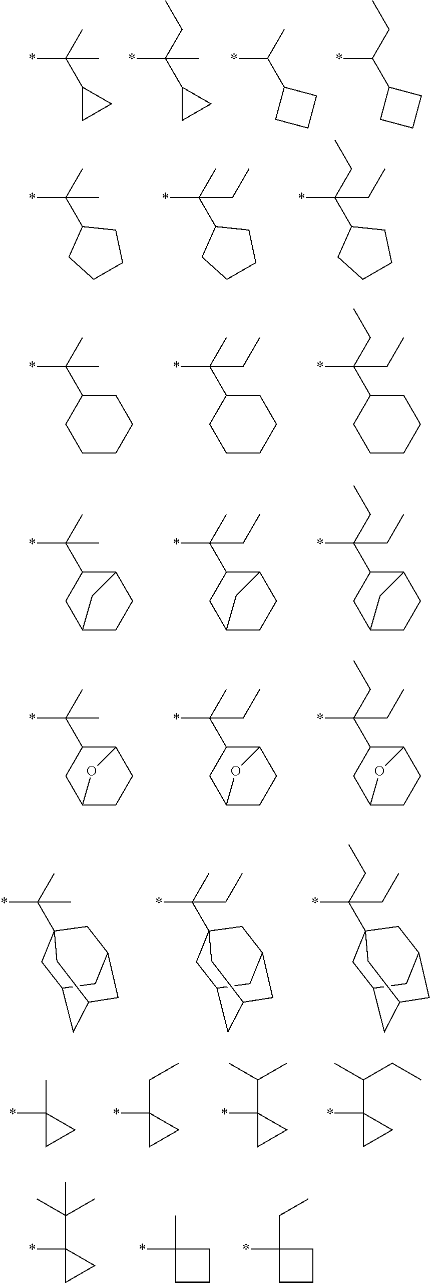

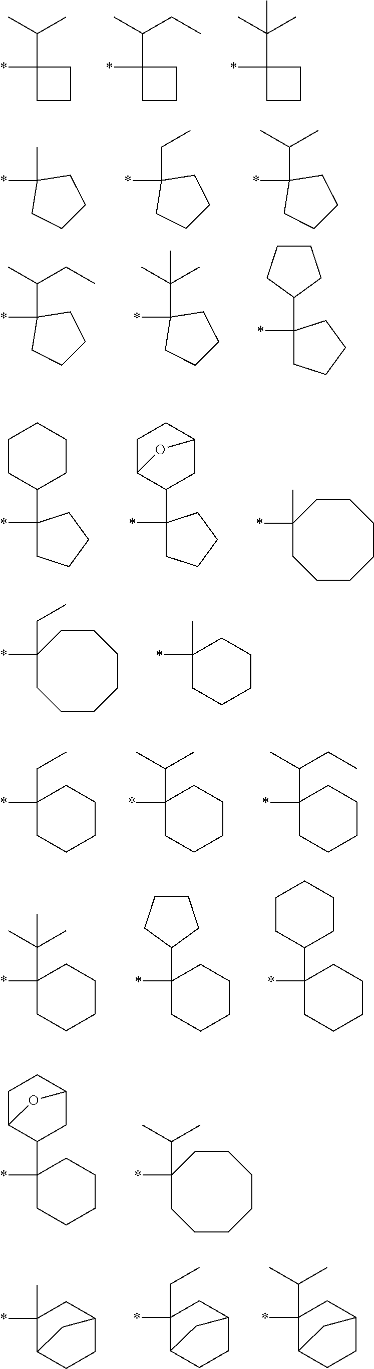

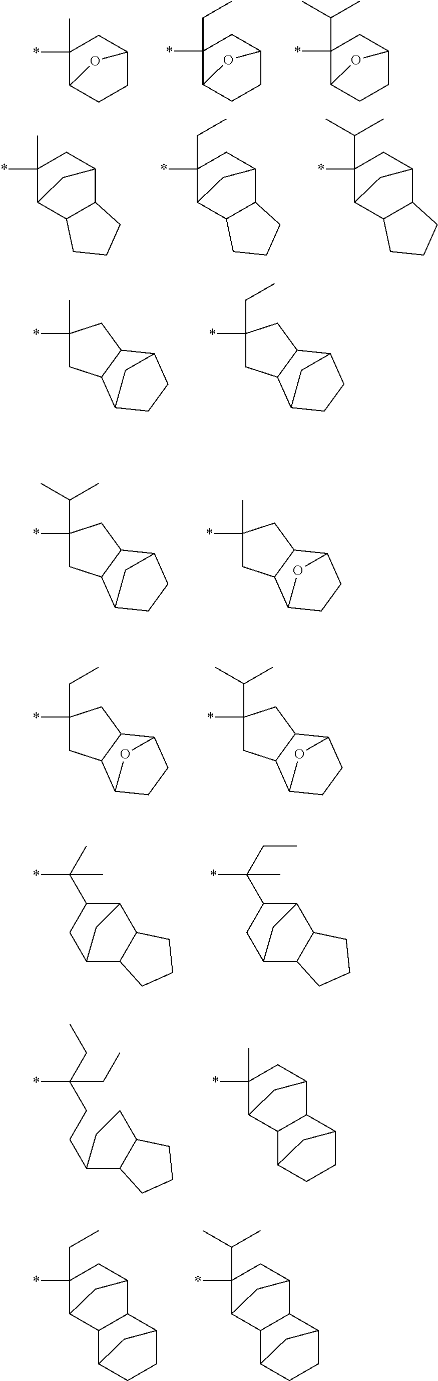

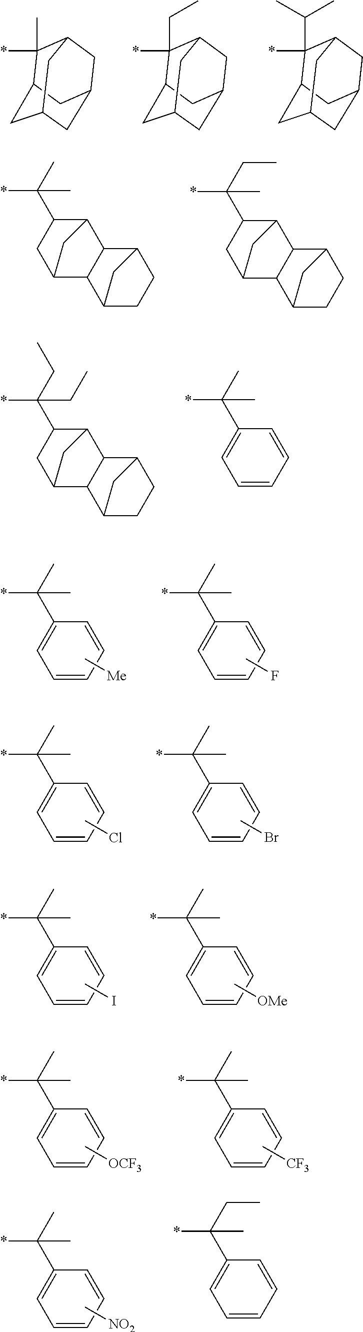

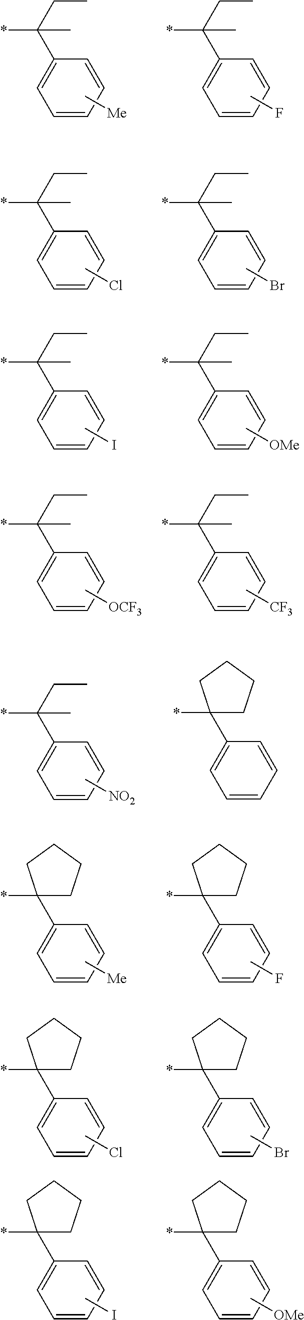

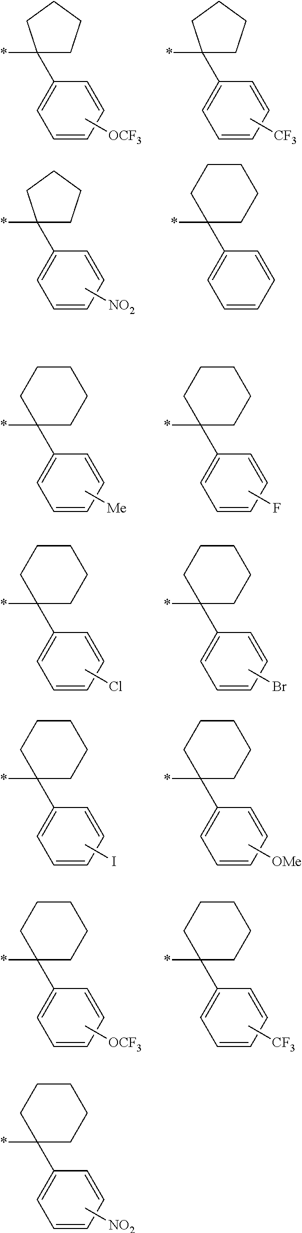

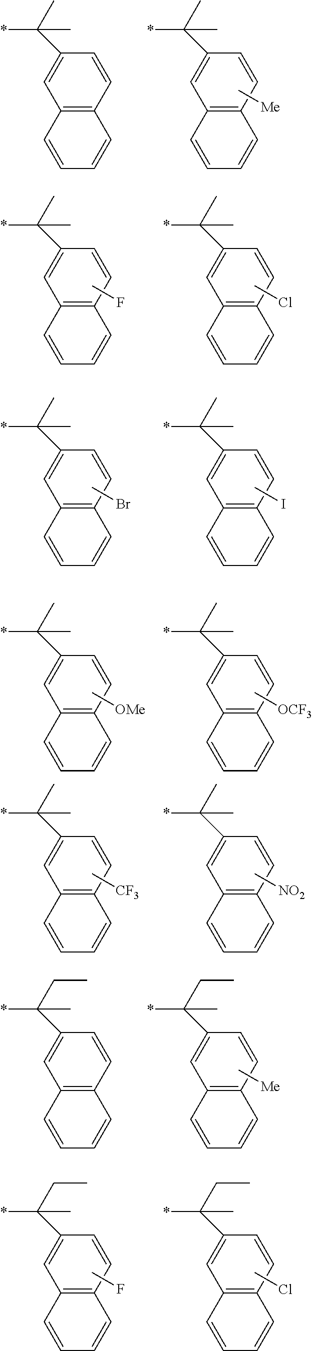

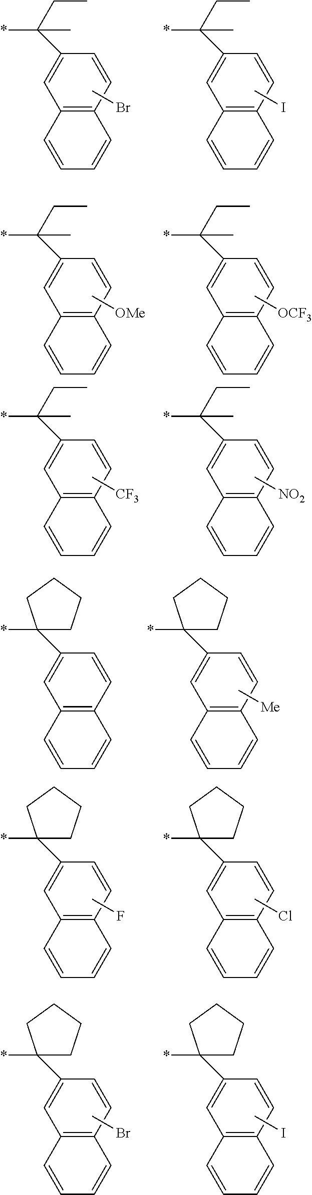

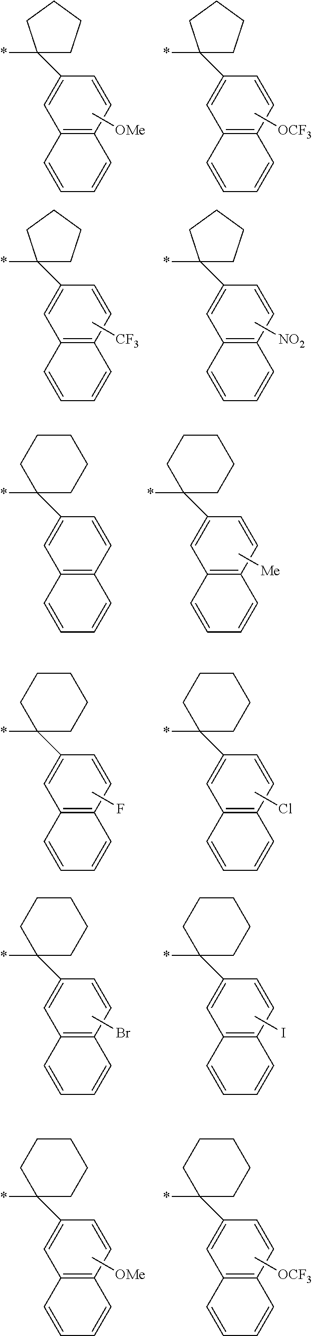

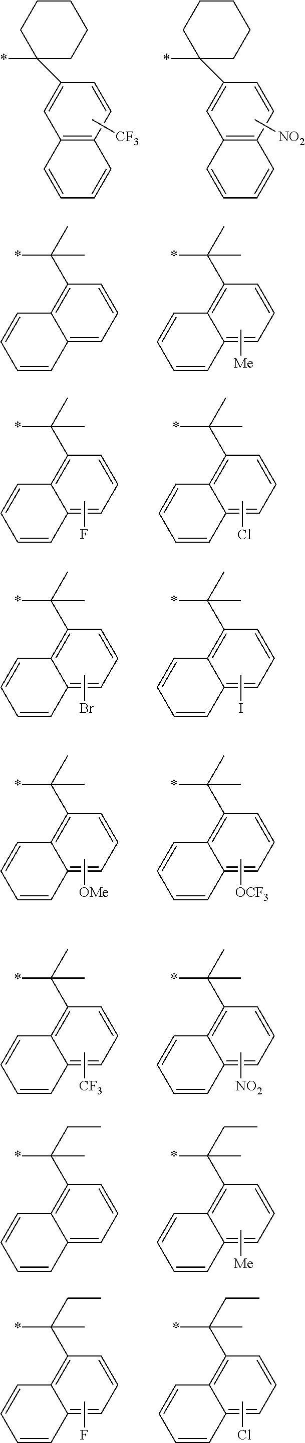

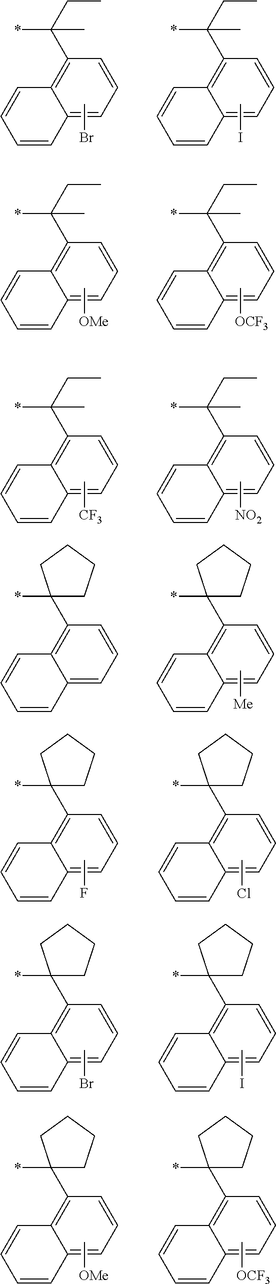

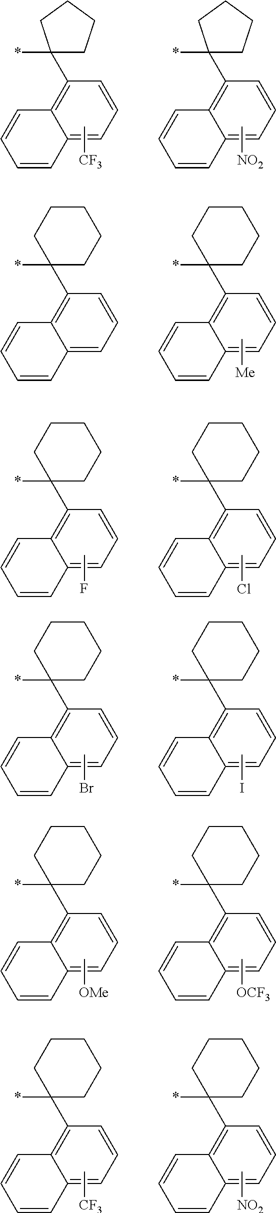

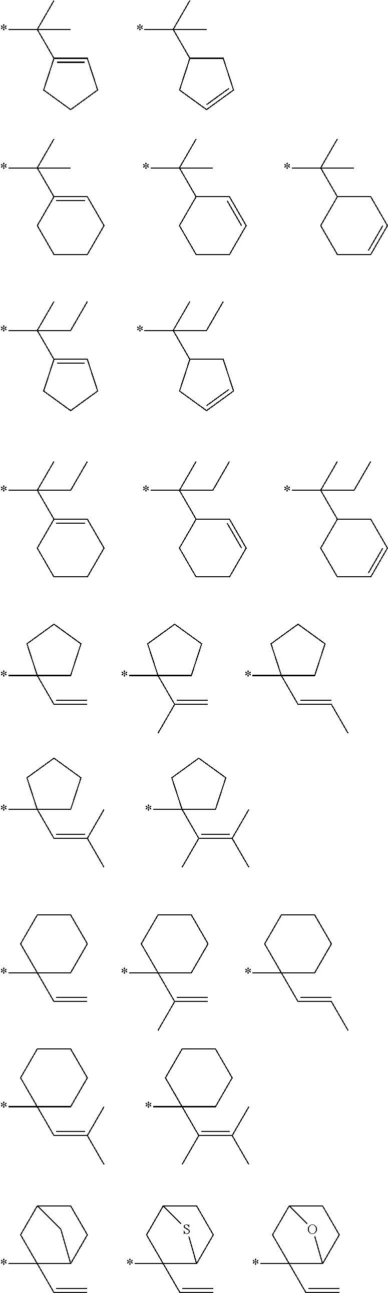

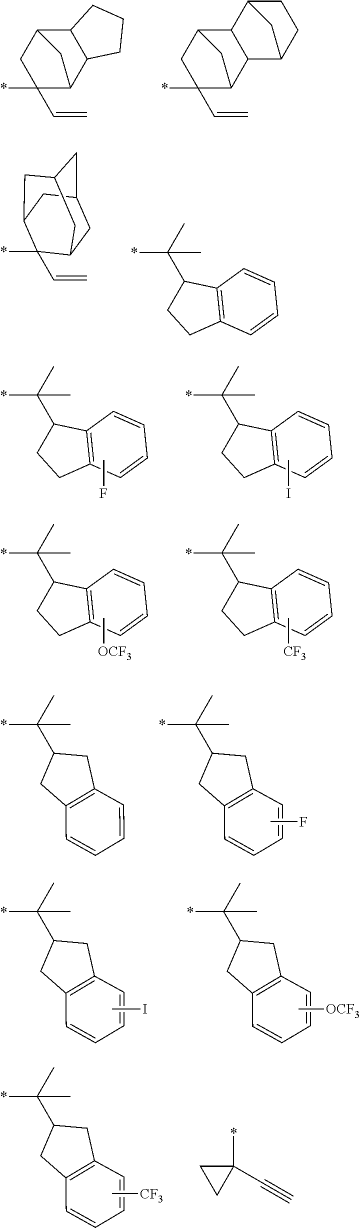

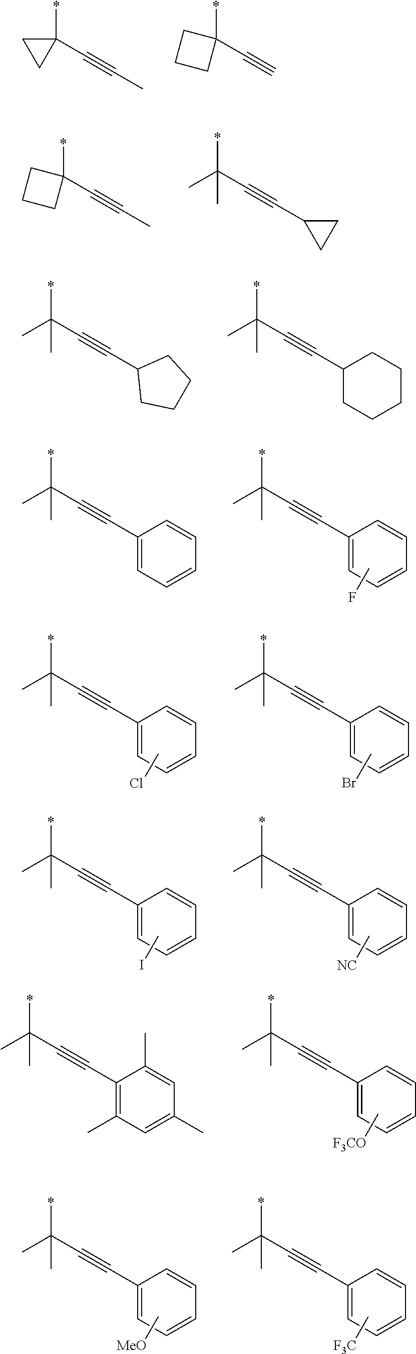

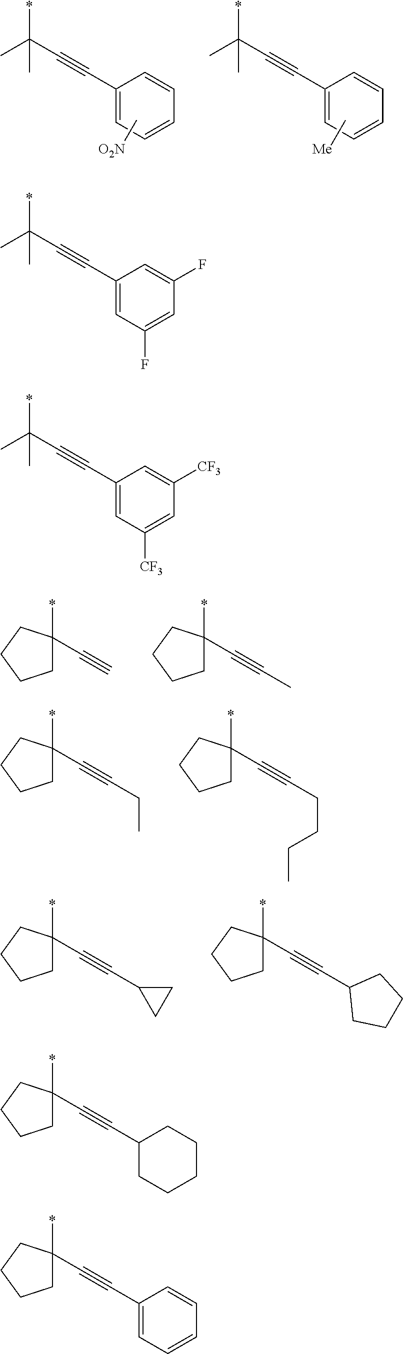

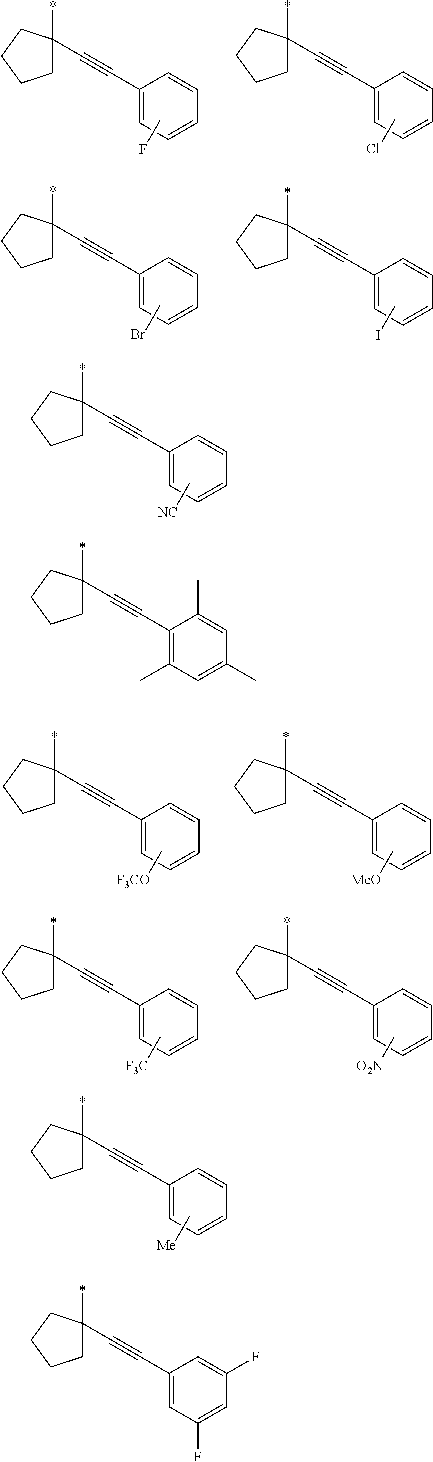

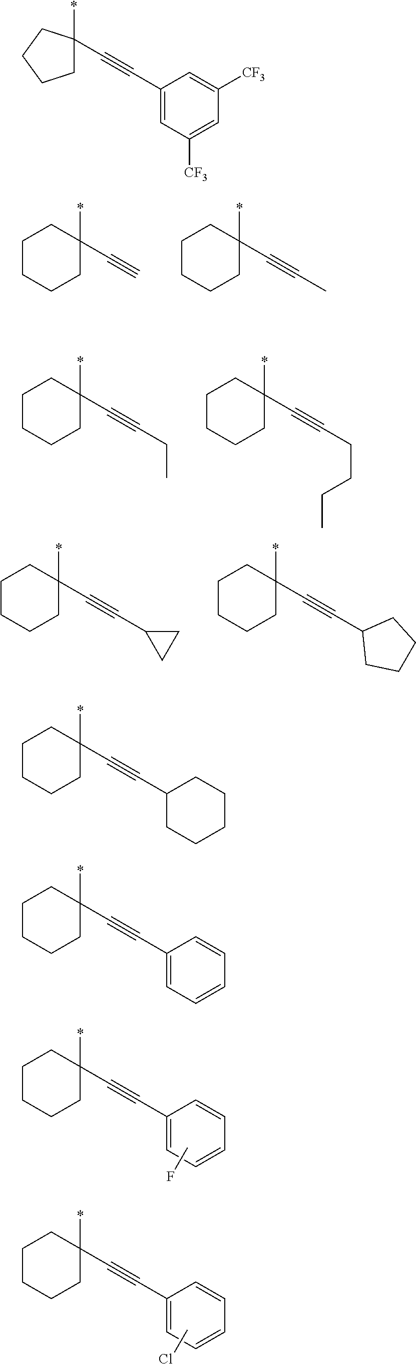

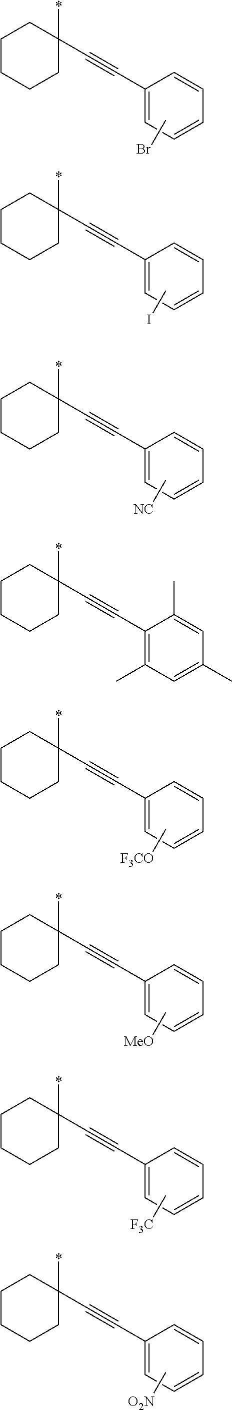

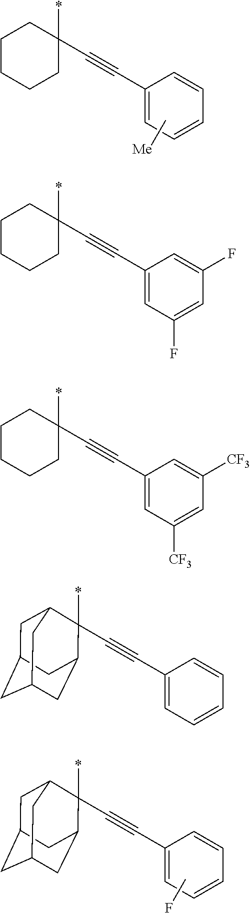

In the formula (A-1), L^{A} represents a single bond, an ether bond, an ester bond, a sulfonic acid ester bond, a carbonate bond, or a carbamate bond. In particular, L^{A} is preferably a single bond, an ether bond, or an ester bond, and is further preferably a single bond or an ester bond.

In the formula (A-1), X^{L} represents a single bond or a hydrocarbylene group having 1 to 40 carbon atoms and optionally containing a heteroatom. The hydrocarbylene group may be linear, branched, or cyclic, and specific examples of the hydrocarbylene group include an alkanediyl group, a divalent saturated cyclic hydrocarbon group, etc. Examples of the heteroatom include an oxygen atom, a nitrogen atom, a sulfur atom, etc.

As the hydrocarbylene group represented by X^{L} having 1 to 40 carbon atoms and optionally containing a heteroatom, the following are preferable. Note that, in the following formulae, “*” represents a bond with L^{A} or the carbon atom in the adjacent carboxy group.

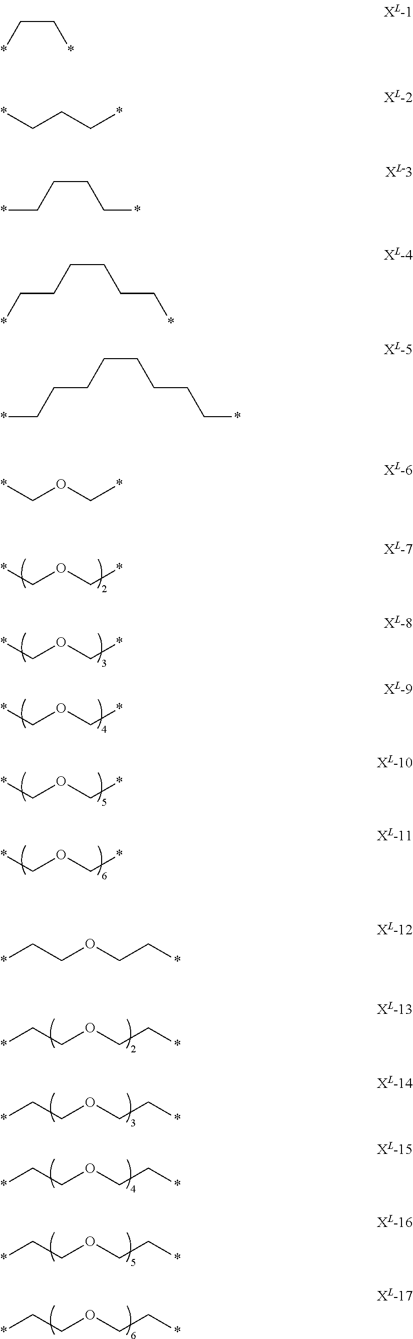

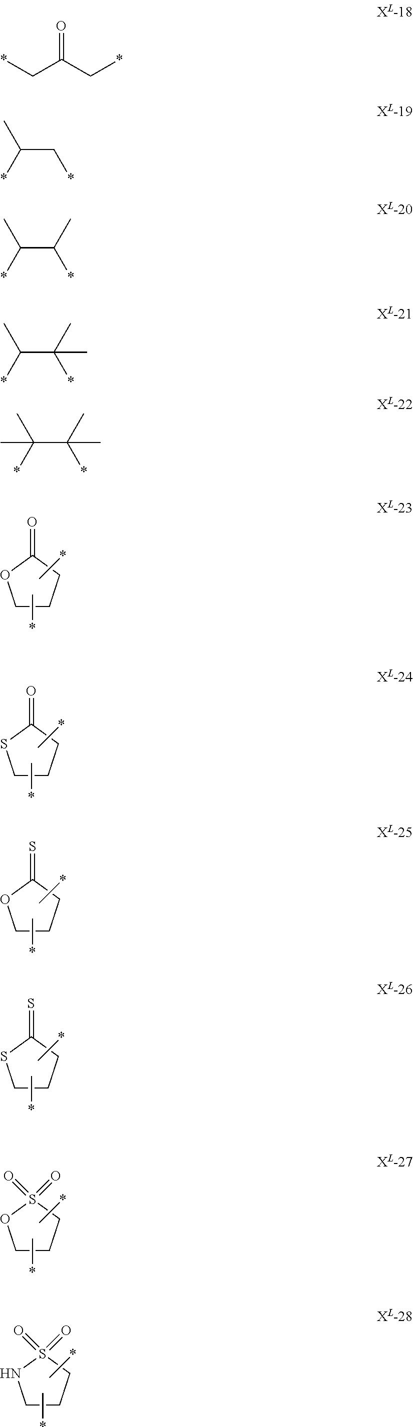

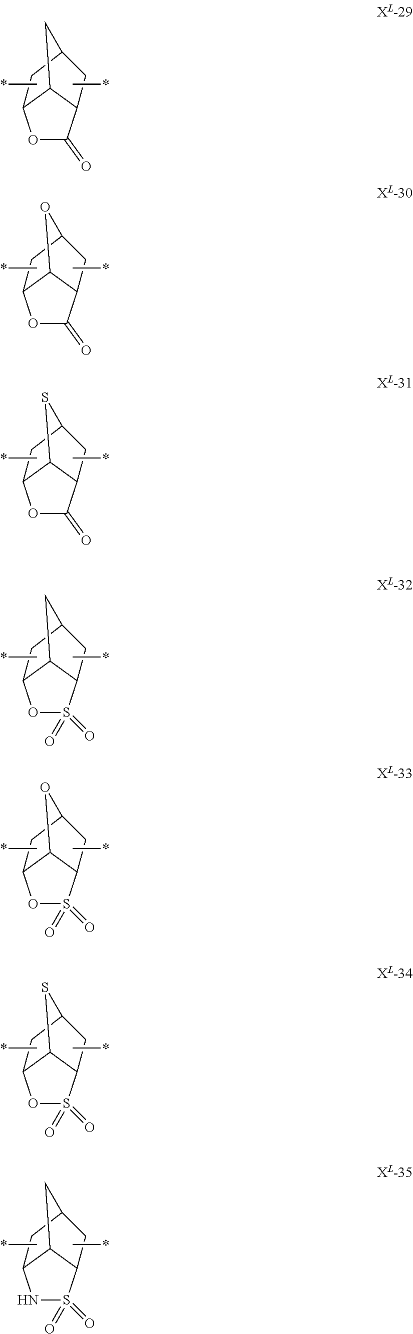

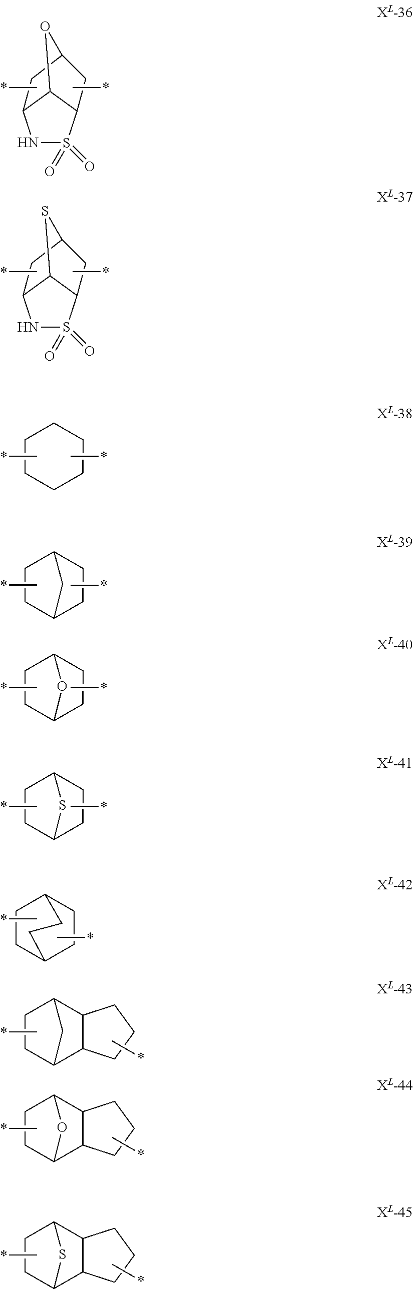

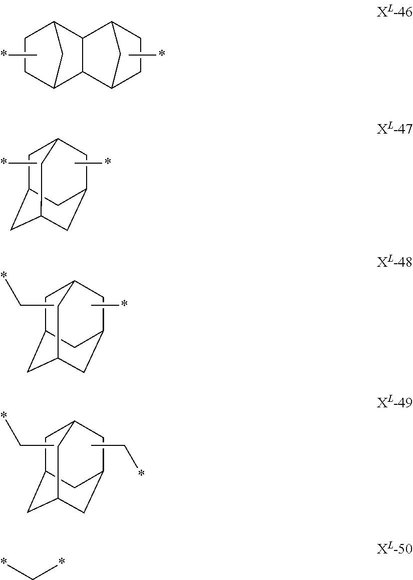

In particular, X^{L}-1 to X^{L}-3, X^{L}-29 to X^{L}-34, and X^{L}-47 to X^{L}-50 are preferable, and X^{L}-1 to X^{L}-2, X^{L}-29, X^{L}-47, and X^{L}-50 are more preferable.

In the formula (A-1), R¹ represents a halogen atom or a hydrocarbyl group having 1 to 20 carbon atoms and optionally having a heteroatom. Examples of the halogen atom include a fluorine atom, a chlorine atom, a bromine atom, and an iodine atom, and the halogen atom is further preferably a fluorine atom or an iodine atom. The hydrocarbyl group may be saturated or unsaturated, and may be linear, branched, or cyclic. Specific examples include alkyl groups having 1 to 20 carbon atoms, such as a methyl group, an ethyl group, an n-propyl group, an isopropyl group, an n-butyl group, and a tert-butyl group; cyclic saturated hydrocarbyl groups having 3 to 20 carbon atoms, such as a cyclopropyl group, a cyclopentyl group, a cyclohexyl group, a cyclopropylmethyl group, a 4-methylcyclohexyl group, a cyclohexylmethyl group, a norbornyl group, and an adamantyl group; alkenyl groups having 2 to 20 carbon atoms, such as a vinyl group, an allyl group, a propenyl group, a butenyl group, and a hexenyl group; cyclic unsaturated hydrocarbyl groups having 3 to 20 carbon atoms, such as a cyclohexenyl group; aryl groups having 6 to 20 carbon atoms, such as a phenyl group and a naphthyl group; aralkyl groups having 7 to 20 carbon atoms, such as a benzyl group, a 1-phenylethyl group, and a 2-phenylethyl group; groups obtained by combining these groups; etc. In particular, the aryl groups are preferable. In addition, some or all of the hydrogen atoms of the hydrocarbyl group may be substituted with a group containing a heteroatom, such as an oxygen atom, a sulfur atom, a nitrogen atom, or a halogen atom, while some —CH₂— contained in the hydrocarbyl group may be substituted with a group containing a heteroatom such as an oxygen atom, a sulfur atom, or a nitrogen atom. Thus, the resulting hydrocarbyl group may contain a hydroxy group, a cyano group, a fluorine atom, a chlorine atom, a bromine atom, an iodine atom, a carbonyl group, an ether bond, an ester bond, a sulfonic acid ester bond, a carbonate bond, a lactone ring, a sultone ring, a carboxylic anhydride, a haloalkyl group, etc.

In the formula (A-1), n1 represents an integer of 0 or 1. When n1=0, a benzene ring is indicated, and when n1=1, a naphthalene ring is indicated. From the viewpoint of solvent solubility, a benzene ring, where n1=0, is further preferable.

In the formula (A-1), n2 represents an integer of 1 or 2.

In the formula (A-1), n3 represents an integer 0 to 6. When n1 is 0, 1≤n2+n3≤5, and when n1 is 1, 1≤n2+n3≤7. When n3≤2, the multiple R's may be bonded to each other to form a ring structure together with the carbon atom on the aromatic ring to which the R¹s are bonded.

The repeating unit A represented by the formula (A-1) is further preferably a repeating unit represented by the following formula (A-2).

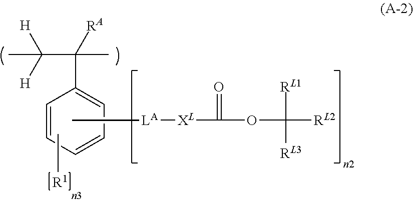

In the formula, R^{A}, R^{L1}, R^{L2}, R^{L3}, R¹, L^{A}, X^{L}, n2, and n3 are as defined above.

The repeating unit A represented by the formula (A-2) is further preferably a repeating unit represented by the following formula (A-3).

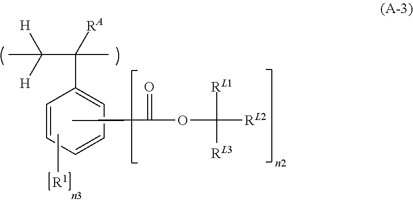

In the formula, R^{A}, R^{L1}, R^{L2}, R^{L3}, R¹, n2, and n3 are as defined above.

The repeating unit A represented by the formulae (A-1) to (A-3) can be synthesized, for example, by the method disclosed in paragraph [0340] of JP7055070B2, but synthesis methods are not limited thereto.

Specific examples of the structure of the repeating unit A represented by the formulae (A-1) to (A-3) include the following, but are not limited thereto. Note that in the following formulae, R^{A} is as defined above.

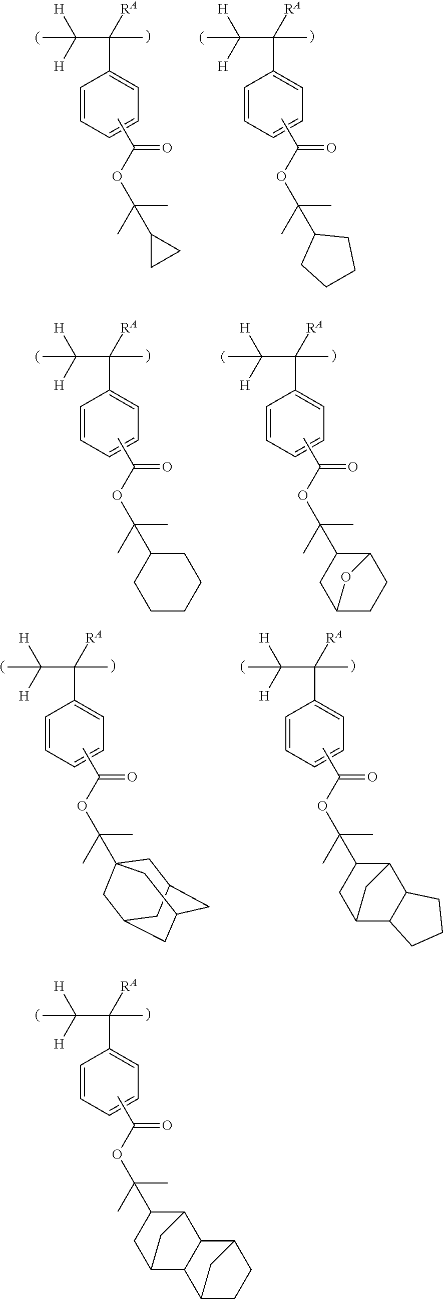

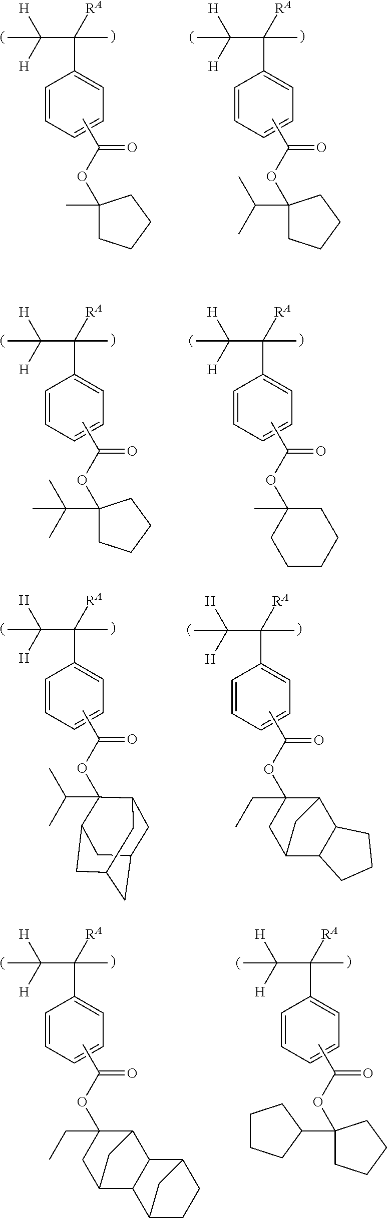

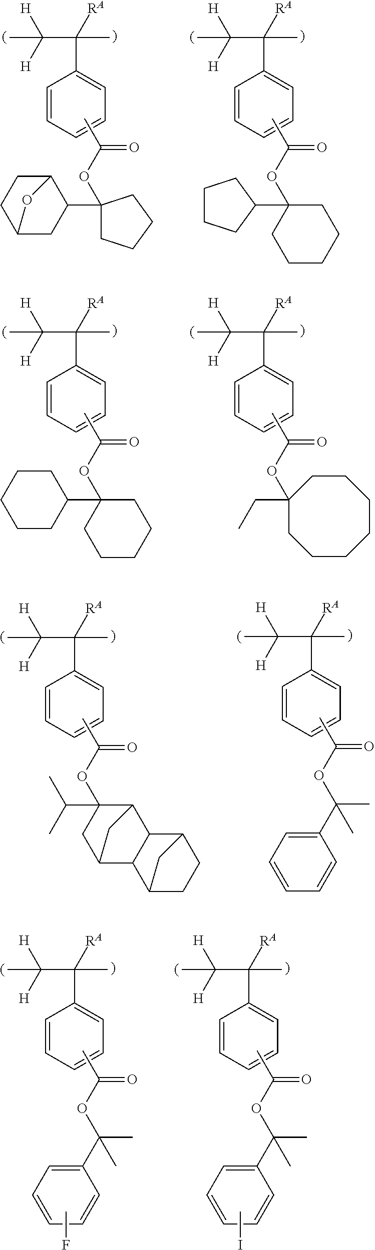

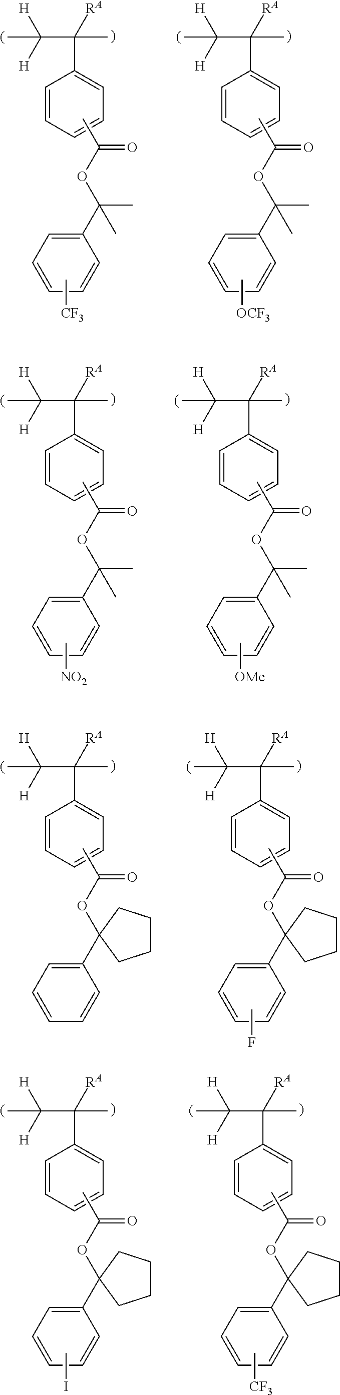

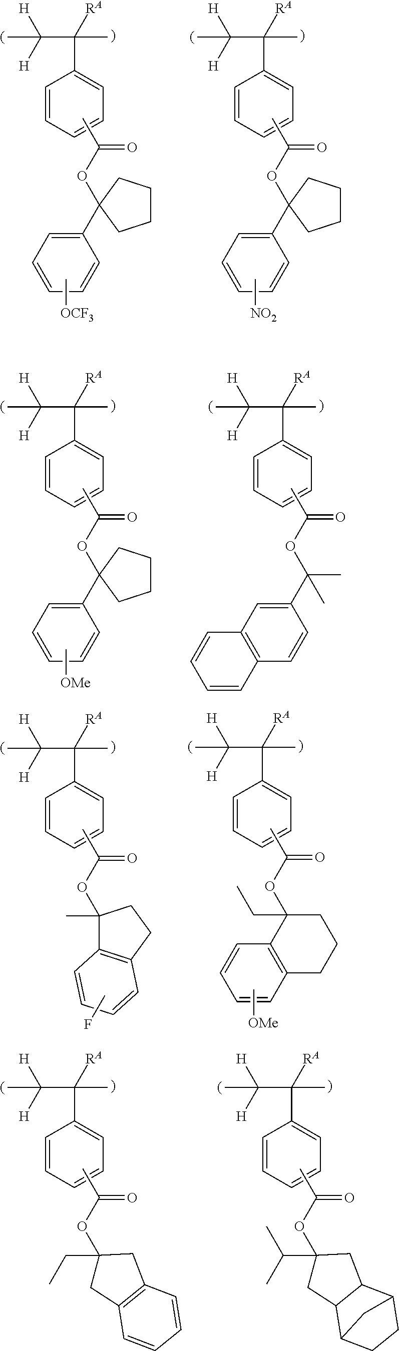

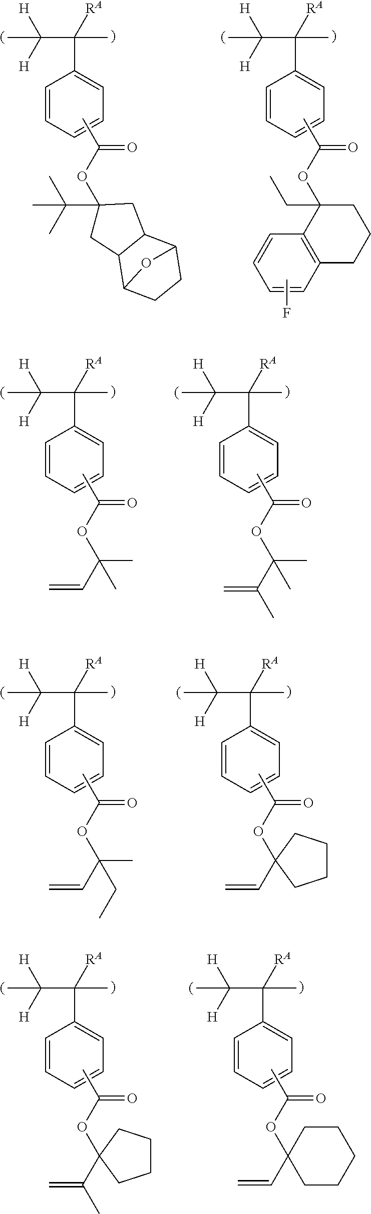

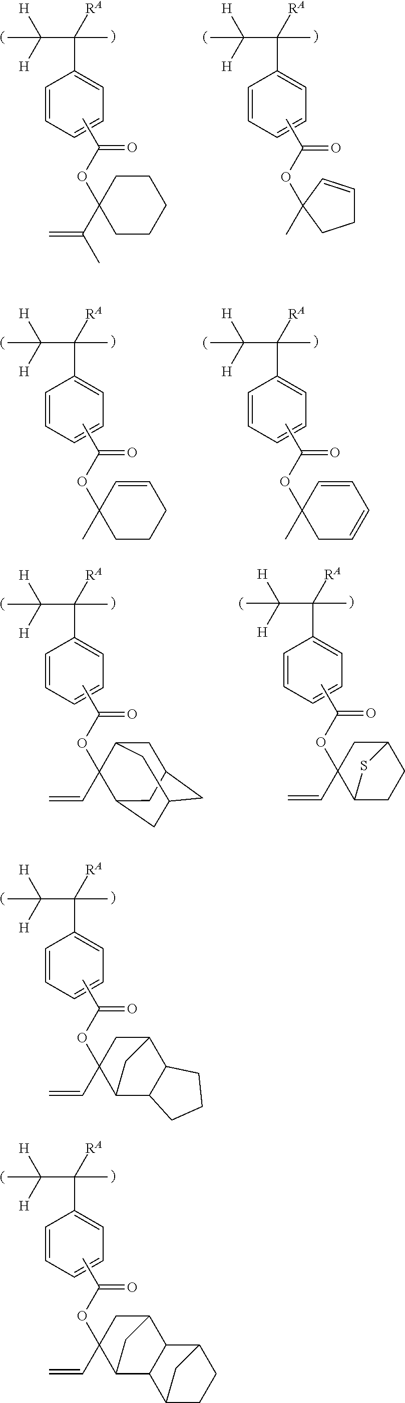

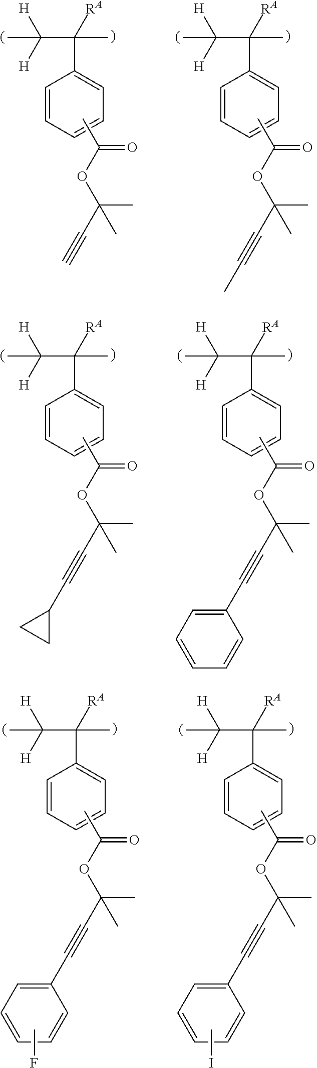

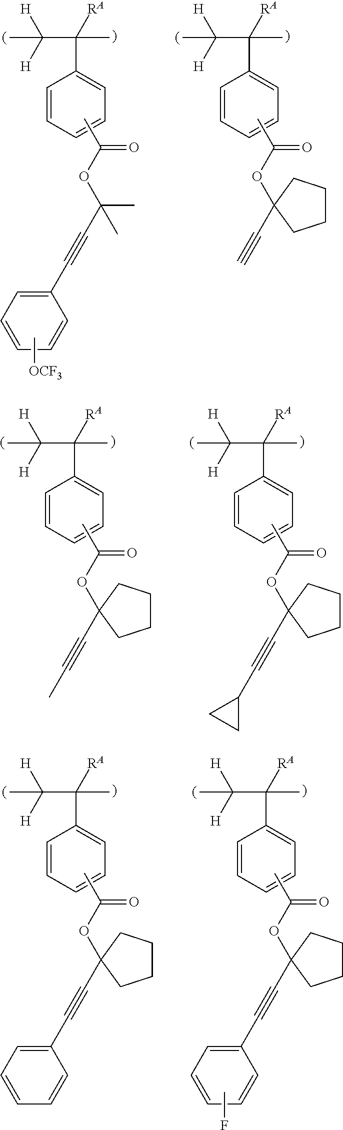

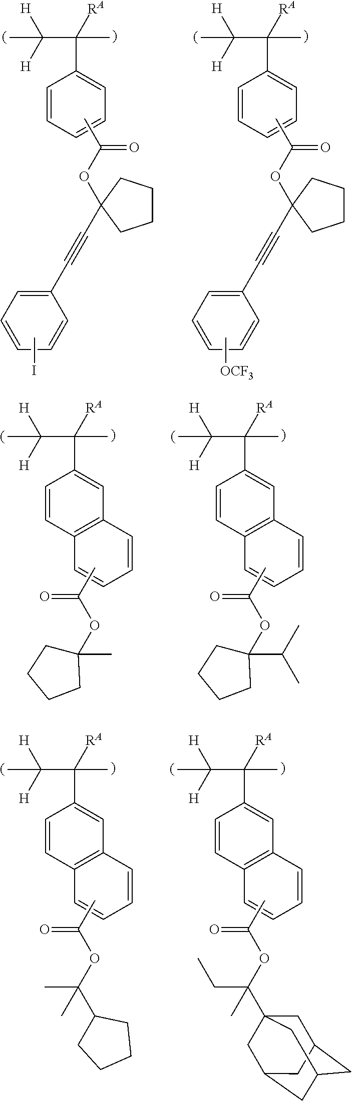

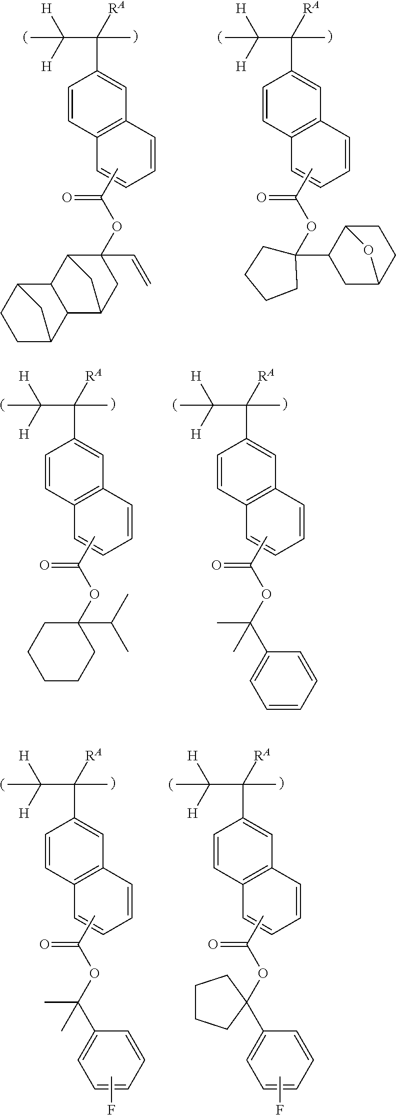

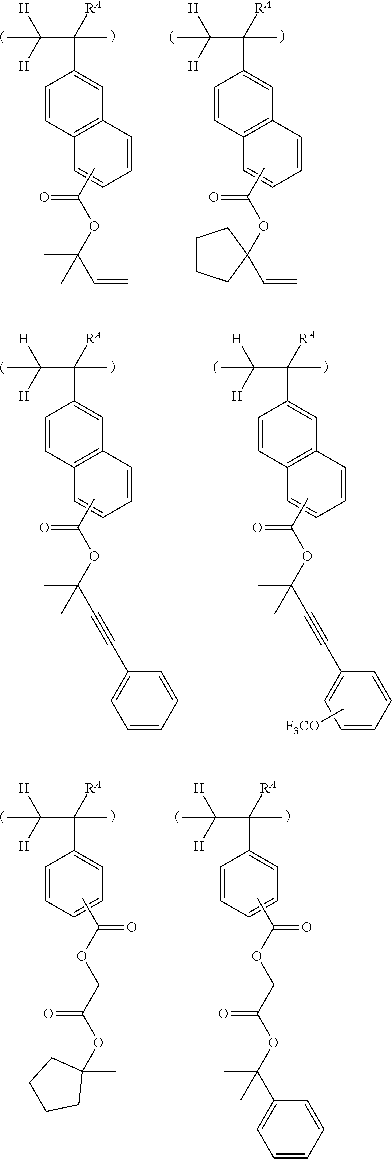

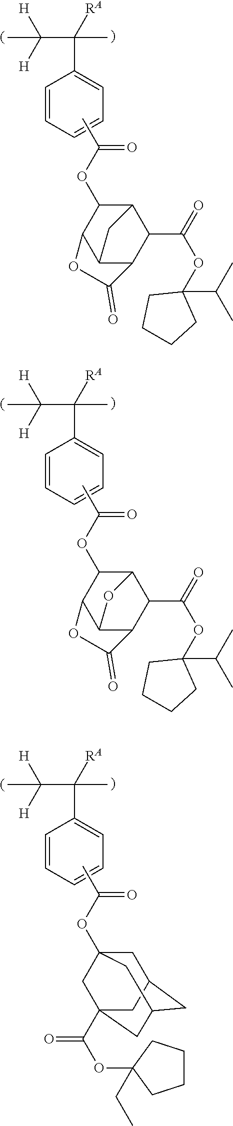

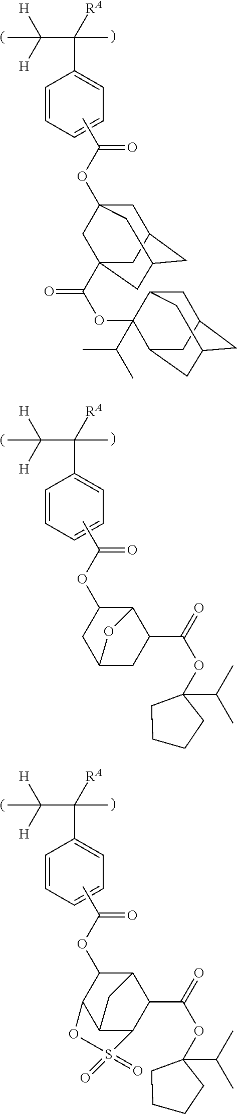

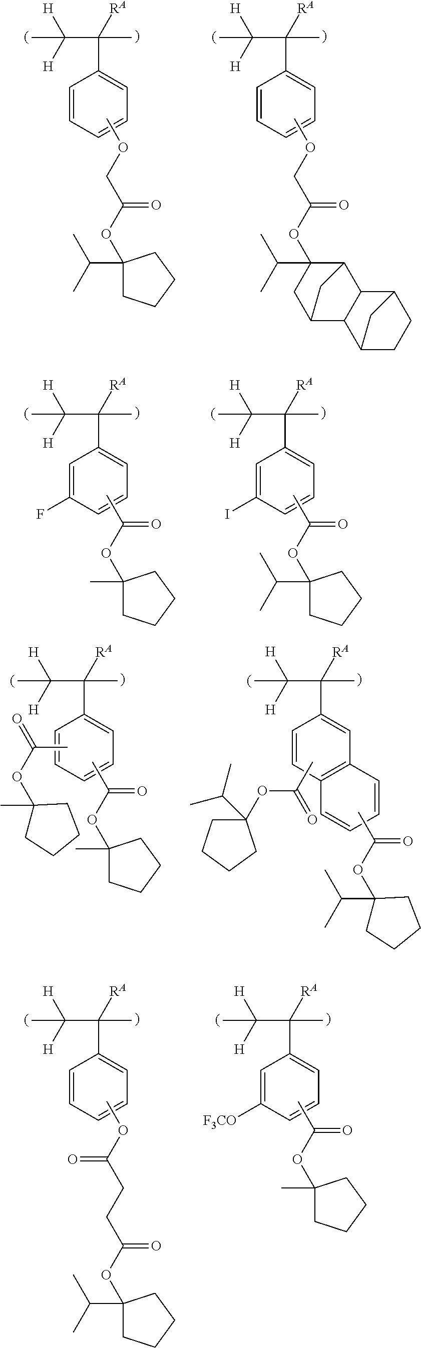

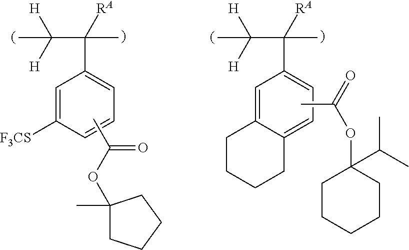

### [Repeating Unit to Generate Acid by Light Exposure (Repeating Unit B)]

The inventive polymer contains a repeating unit (hereinafter, also referred to as a repeating unit B) to generate an acid by light exposure. The repeating unit B is any one or more of a repeating unit represented by the following formula (B-1) (hereinafter, also referred to as a repeating unit B1), a repeating unit represented by the following formula (B-2) (hereinafter, also referred to as a repeating unit B2), a repeating unit represented by the following formula (B-3) (hereinafter, also referred to as a repeating unit B3), and a repeating unit represented by the following formula (B-4) (hereinafter, also referred to as a repeating unit B4).

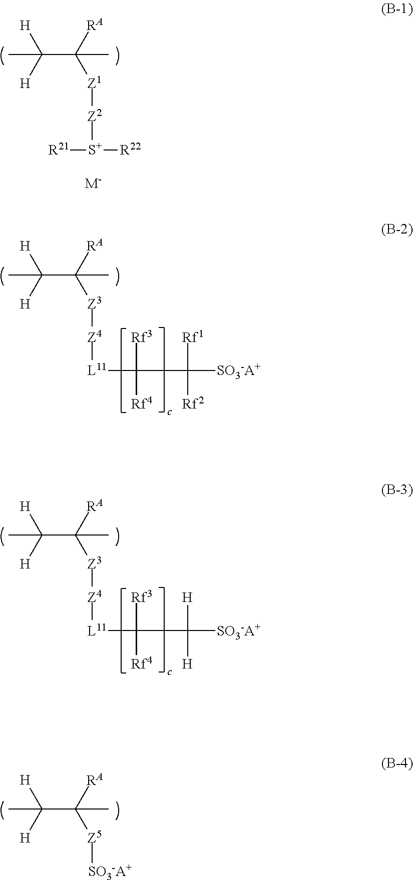

In the formulae (B-1) to (B-4), R^{A} is as defined above. Z¹ represents a single bond or a phenylene group. Z² represents —C(═O)—O—Z²¹—, —C(═O)—NH—Z²¹—, or —O—Z²¹—. Z²¹ represents an aliphatic hydrocarbylene group having 1 to 6 carbon atoms, a phenylene group, or a divalent group obtained by combining these groups, Z²¹ optionally having a carbonyl group, an ester bond, an ether bond, or a hydroxy group. Z³ represents a single bond, a phenylene group, a naphthylene group, or (main chain) —C(═O)—O—Z³¹—. Z³¹ represents an aliphatic hydrocarbylene group having 1 to 10 carbon atoms, or a phenylene group or a naphthylene group optionally having a hydroxy group, an ether bond, an ester bond, or a lactone ring. Z⁴ represents a single bond or —Z⁴¹—C(═O)—O—. Z⁴¹ represents a hydrocarbylene group having 1 to 20 carbon atoms and optionally having a heteroatom. Z⁵ represents a single bond, a methylene group, an ethylene group, a phenylene group, a fluorinated phenylene group, a phenylene group substituted with a trifluoromethyl group, —C(═O)—O—Z⁵¹—, —C(═O)—NH—Z⁵¹—, or —O—Z⁵¹—. Z⁵¹ represents an aliphatic hydrocarbylene group having 1 to 6 carbon atoms, a phenylene group, a fluorinated phenylene group, or a phenylene group substituted with a trifluoromethyl group, Z⁵¹ optionally having a carbonyl group, an ester bond, an ether bond, or a hydroxy group. R²¹ and R²² each independently represent a hydrocarbyl group having 1 to 20 carbon atoms and optionally having a heteroatom. R²¹ and R²² are optionally bonded to each other to form a ring together with a sulfur atom to which R²¹ and R²² are bonded. L¹¹ represents a single bond, an ether bond, an ester bond, a carbonyl group, a sulfonic acid ester bond, a carbonate bond, or a carbamate bond. Rf¹ and Rf² each independently represent a fluorine atom or a fluorinated alkyl group having 1 to 6 carbon atoms. Rf³ and Rf⁴ each independently represent a hydrogen atom, a fluorine atom, or a fluorinated alkyl group having 1 to 6 carbon atoms. M⁻ represents a non-nucleophilic counterion. A⁺ represents an onium cation. “c” represents an integer of 0 to 3.

In the formulae (B-1) to (B-4), R^{A} is as defined above. Z¹ represents a single bond or a phenylene group. Z² represents —C(═O)—O—Z²¹—, —C(═O)—NH—Z²¹—, or —O—Z²¹—. Z²¹ represents an aliphatic hydrocarbylene group having 1 to 6 carbon atoms, a phenylene group, or a divalent group obtained by combining these groups, Z²¹ optionally having a carbonyl group, an ester bond, an ether bond, or a hydroxy group. Z³ represents a single bond, a phenylene group, a naphthylene group, or (main chain) —C(═O)—O—Z³¹—. Z³¹ represents an aliphatic hydrocarbylene group having 1 to 10 carbon atoms, or a phenylene group or a naphthylene group optionally having a hydroxy group, an ether bond, an ester bond, or a lactone ring. Z⁴ represents a single bond, a methylene group, or —Z⁴¹—C(═O)—O—. Z⁴¹ represents a hydrocarbylene group having 1 to 20 carbon atoms and optionally containing a heteroatom, an ether bond, or an ester bond. Z⁵ represents a single bond, a methylene group, an ethylene group, a phenylene group substituted with a trifluoromethyl group, a phenylene group, a fluorinated phenylene group, —C(═O)—O—Z⁵¹—, —C(═O)—NH—Z⁵¹—, or —O—Z⁵¹—. Z⁵¹ represents an aliphatic hydrocarbylene group having 1 to 6 carbon atoms, a phenylene group, a fluorinated phenylene group, or a phenylene group substituted with a trifluoromethyl group, Z⁵¹ optionally having a carbonyl group, an ester bond, an ether bond, or a hydroxy group.

The aliphatic hydrocarbylene groups represented by Z²¹, Z³¹, and Z⁵¹ may be any of linear, branched, and cyclic groups. Specific examples of the aliphatic hydrocarbylene groups include the groups given as examples in the description of X^{L} in the formula (A-1).

The hydrocarbylene group represented by Z⁴¹ may be a saturated or unsaturated group, and may be any of linear, branched, and cyclic groups. Specific examples thereof include the following groups, but the hydrocarbylene group is not limited thereto.

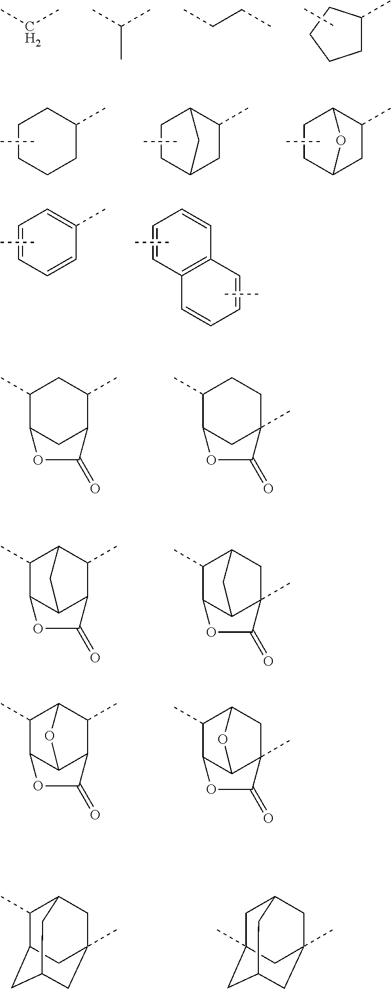

In the formulae, a broken line represents an attachment point.

In the formula (B-1), R²¹ and R²² each independently represent a hydrocarbyl group having 1 to 20 carbon atoms and optionally having a heteroatom. The hydrocarbyl group represented by R²¹ and R²² may be a saturated or unsaturated group, and may be any of linear, branched, and cyclic groups. Specific examples thereof include: alkyl groups, such as a methyl group, an ethyl group, an n-propyl group, an isopropyl group, an n-butyl group, and a tert-butyl group; cyclic saturated hydrocarbyl groups, such as a cyclopropyl group, a cyclopentyl group, a cyclohexyl group, a cyclopropylmethyl group, a 4-methylcyclohexyl group, a cyclohexylmethyl group, a norbornyl group, and an adamantyl group; alkenyl groups, such as a vinyl group, an allyl group, a propenyl group, a butenyl group, and a hexenyl group; cyclic unsaturated hydrocarbyl groups, such as a cyclohexenyl group; aryl groups, such as a phenyl group, a naphthyl group, and a thienyl group; aralkyl groups, such as a benzyl group, a 1-phenylethyl group, and a 2-phenylethyl group; and groups obtained by combining these groups. Aryl groups are preferable. A part of the hydrogen atoms in the hydrocarbyl group is optionally substituted with a group having a heteroatom such as an oxygen atom, a sulfur atom, a nitrogen atom, and a halogen atom. Between carbon atoms in these groups, a group having a heteroatom such as an oxygen atom, a sulfur atom, and a nitrogen atom are optionally interposed. As a result, a hydroxy group, a cyano group, a carbonyl group, an ether bond, an ester bond, a sulfonic acid ester bond, a carbonate bond, a lactone ring, a sultone ring, a carboxylic anhydride, a haloalkyl group, etc. are optionally contained.

R²¹ and R²² are optionally bonded with each other to form a ring together with the sulfur atom to which R²¹ and R²² are bonded. Specific examples thereof include the structures represented by the following formulae.

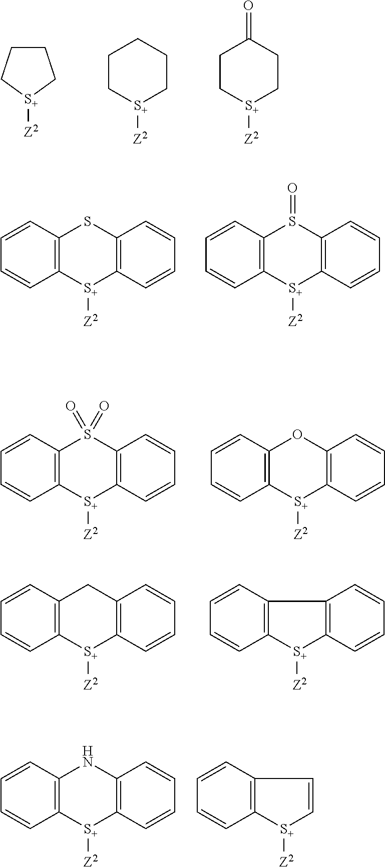

Examples of the cation of the repeating unit B1 include the following cations, but the cation is not limited thereto. Note that in the following formulae, R^{A} is as defined above.

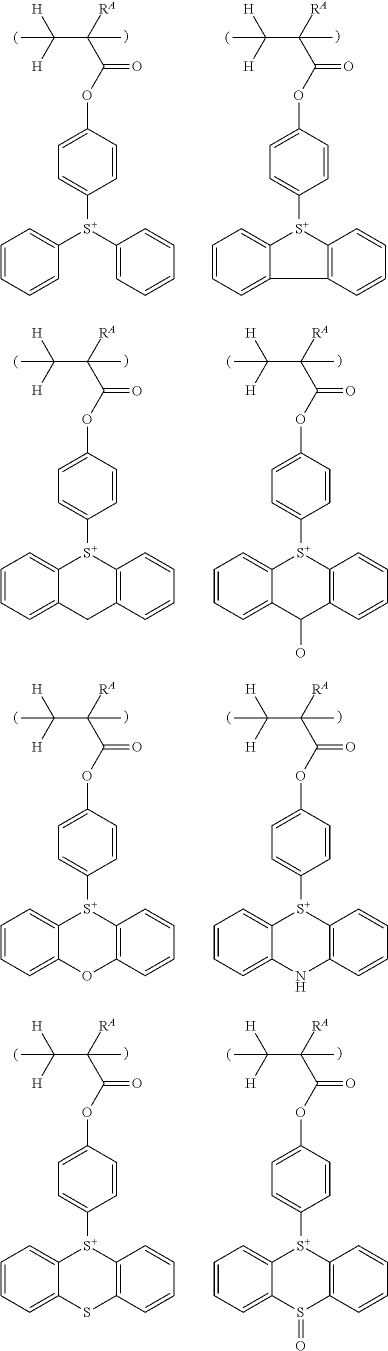

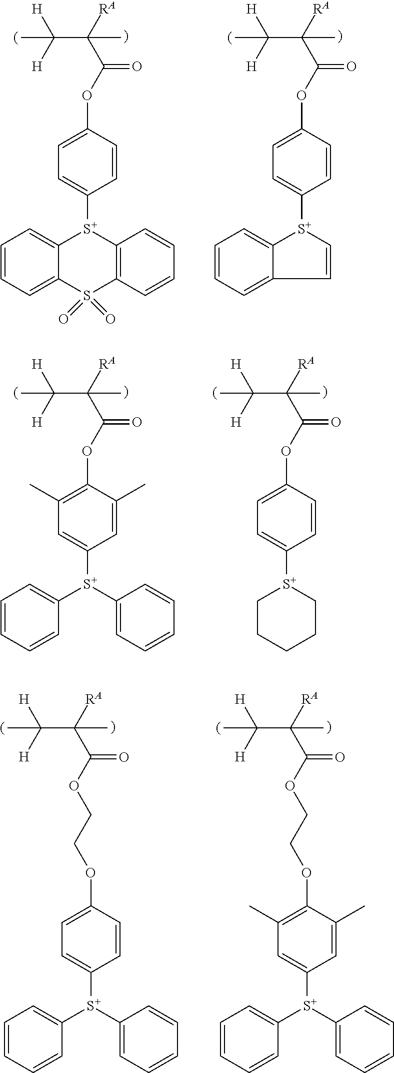

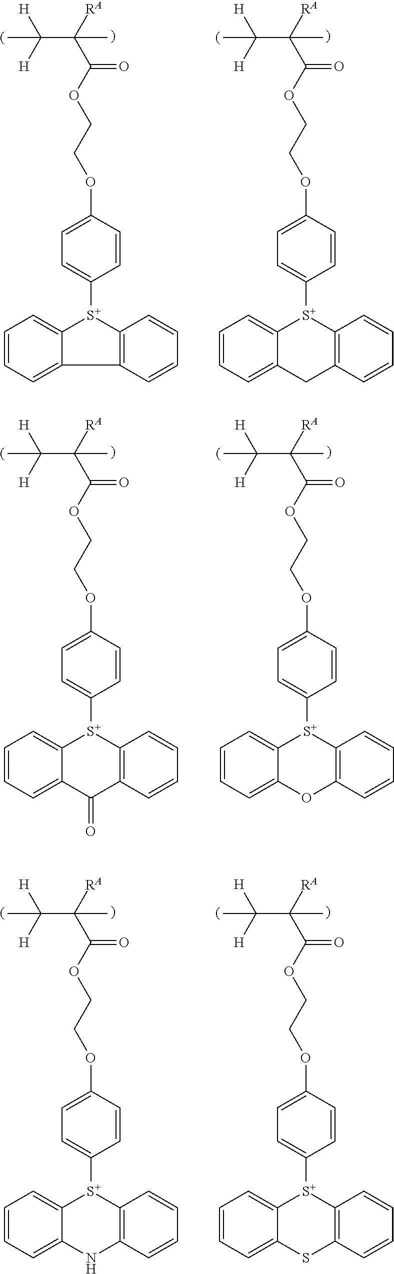

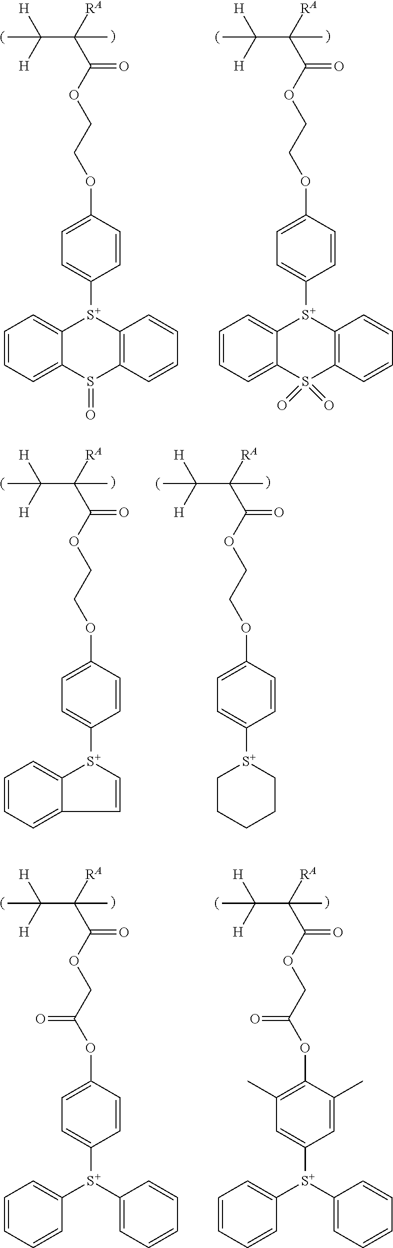

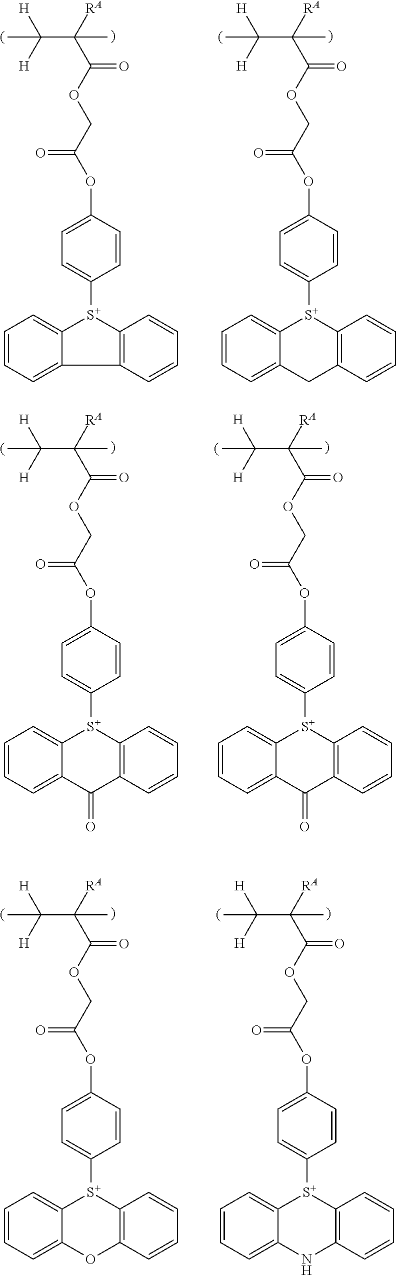

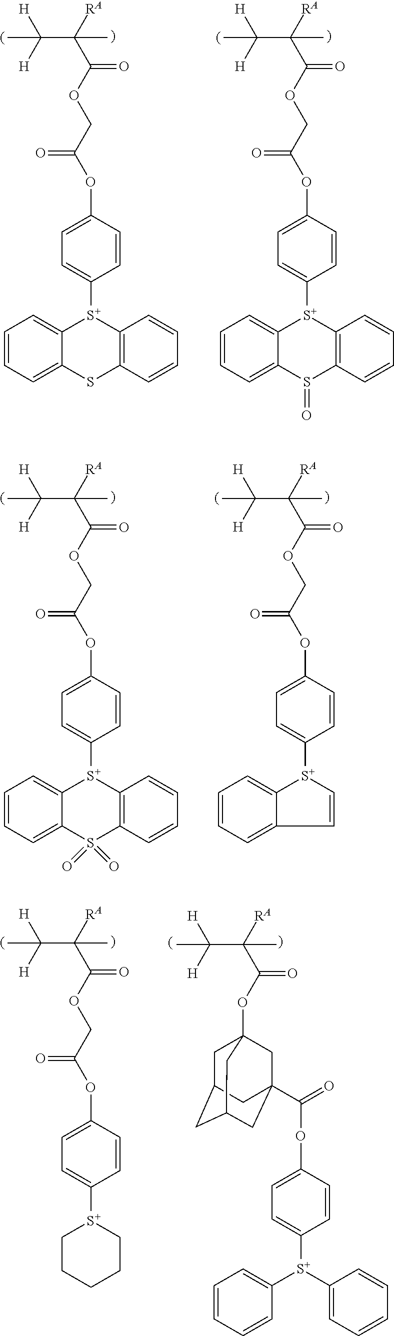

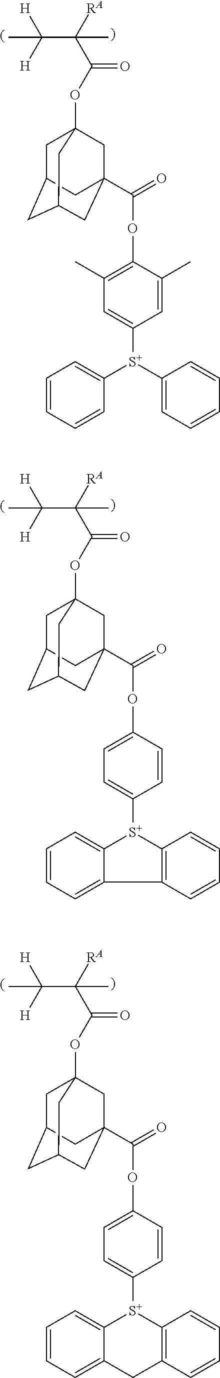

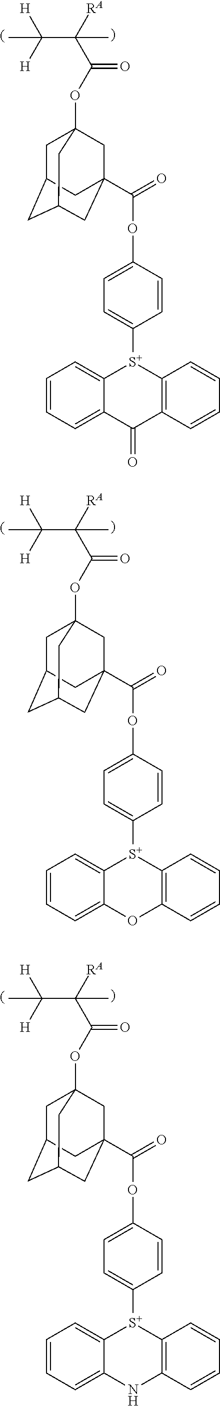

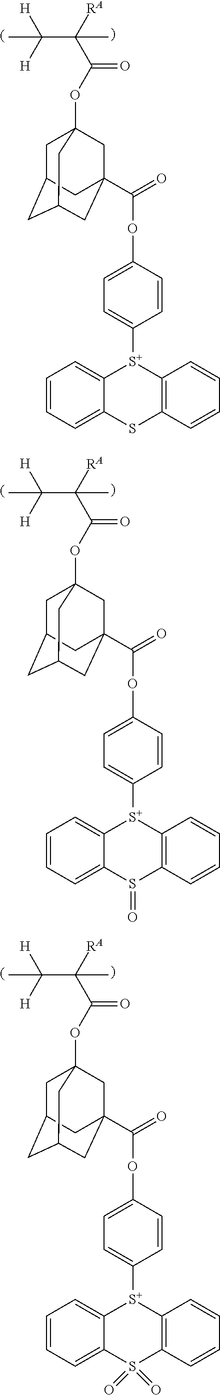

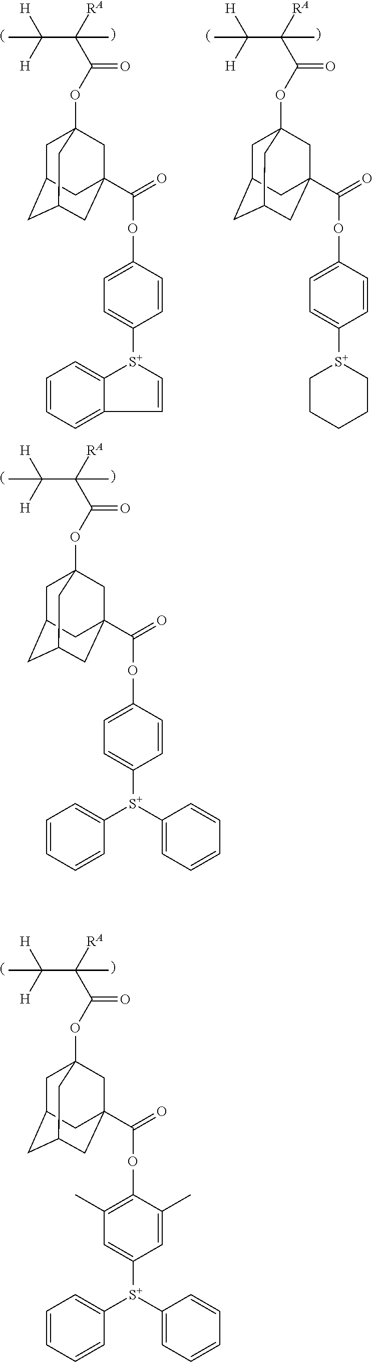

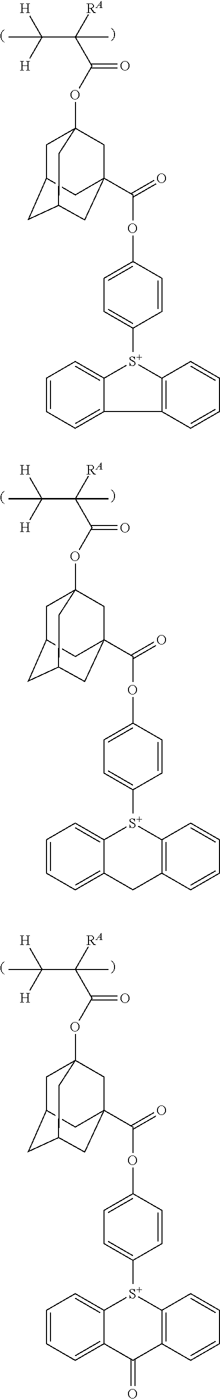

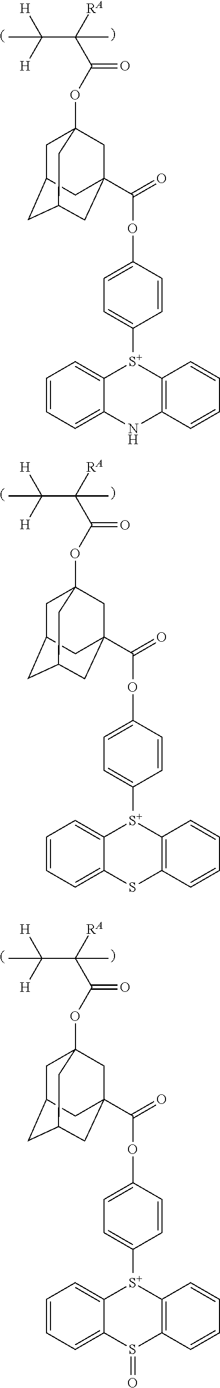

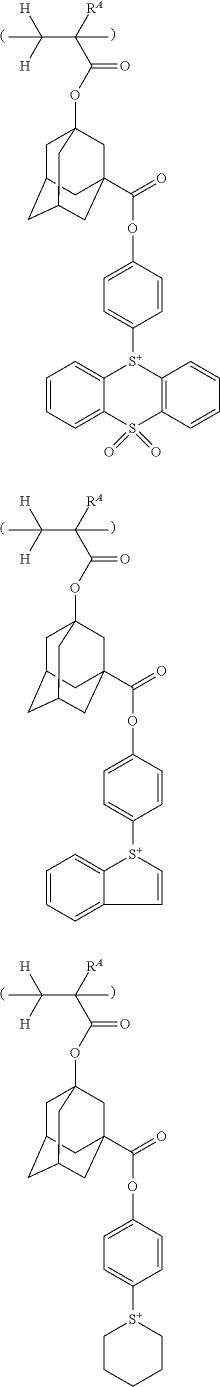

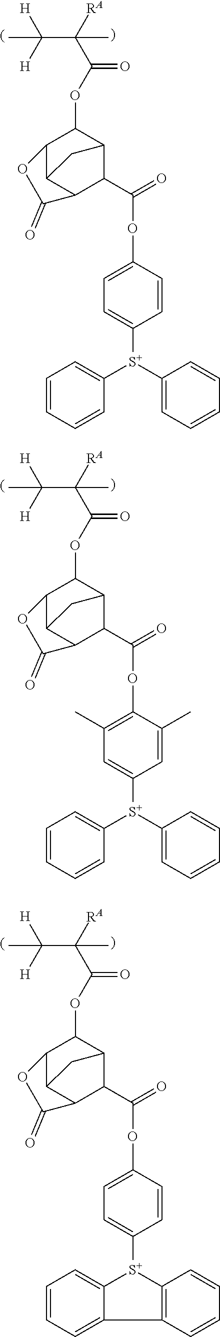

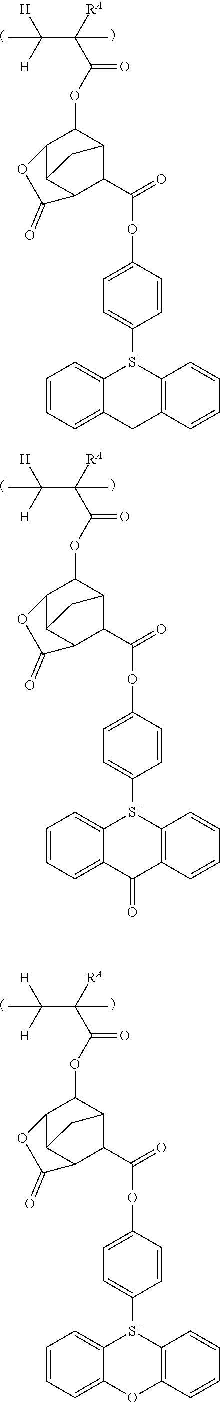

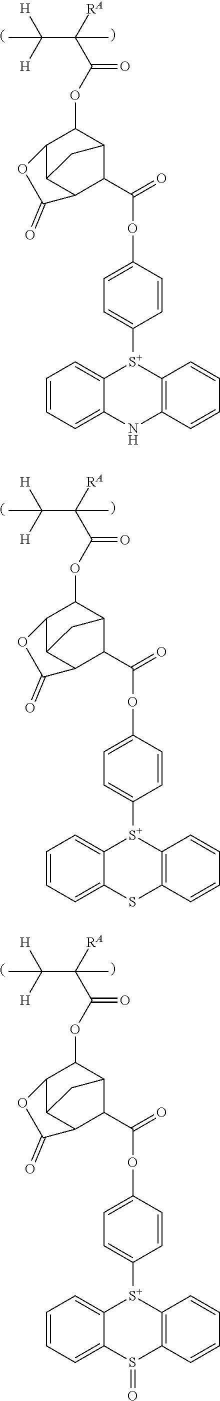

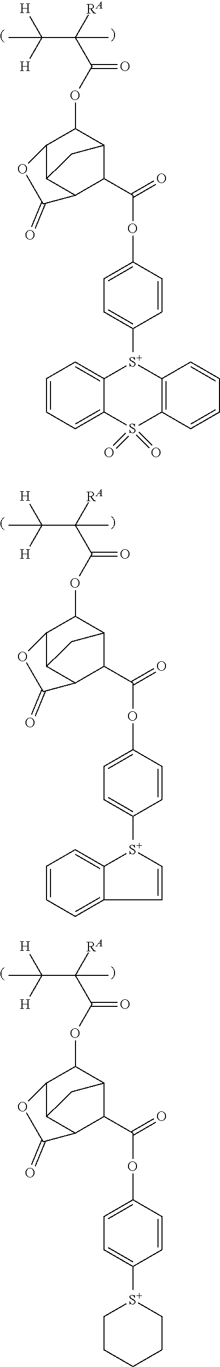

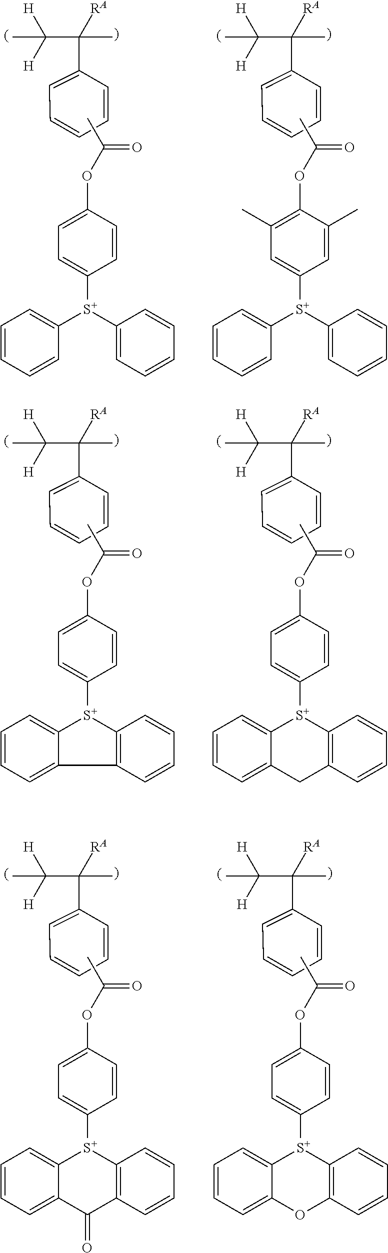

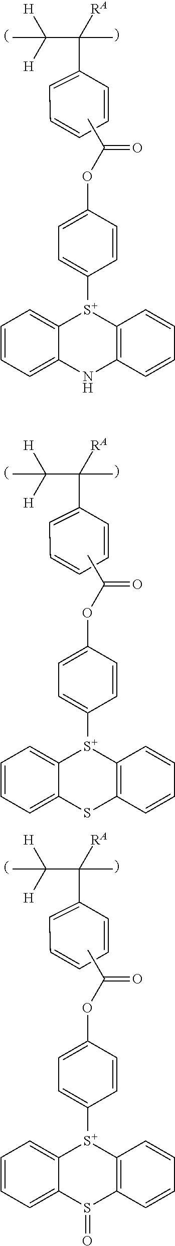

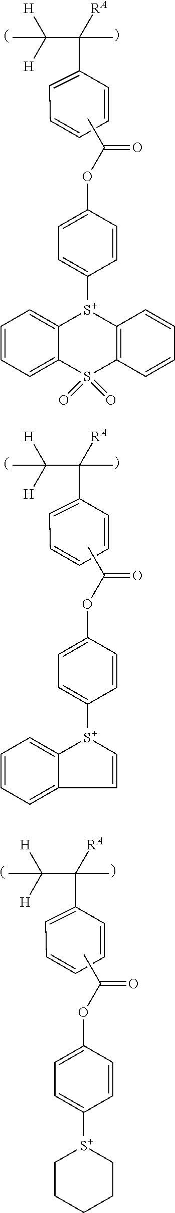

In the formula (B-1), M⁻ represents a non-nucleophilic counterion. Examples of the non-nucleophilic counterion represented by M⁻ include: halide ions, such as a chloride ion and a bromide ion; fluoroalkylsulfonate ions, such as a triflate ion, a 1,1,1-trifluoroethanesulfonate ion, and a nonafluorobutanesulfonate ion; arylsulfonate ions, such as a tosylate ion, a benzenesulfonate ion, a 4-fluorobenzenesulfonate ion, and a 1,2,3,4,5-pentafluorobenzenesulfonate ion; alkylsulfonate ions, such as a mesylate ion and a butanesulfonate ion; imidic acid ions, such as a bis(trifluoromethylsulfonyl)imide ion, a bis(perfluoroethylsulfonyl)imide ion, and a bis(perfluorobutylsulfonyl)imide ion; and methide acid ions, such as a tris(trifluoromethylsulfonyl)methide ion and a tris(perfluoroethylsulfonyl)methide ion.

Examples of the non-nucleophilic counterion further include: sulfonic acid anions represented by the following formula (B-1-1), whose α-position is substituted with a fluorine atom; and sulfonic acid anions represented by the following formula (B-1-2), in which the α-position is substituted with a fluorine atom and the β-position is substituted with a trifluoromethyl group.

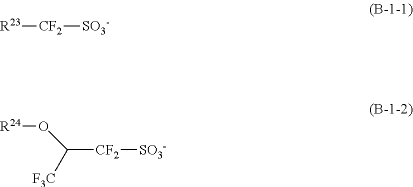

In the formula (B-1-1), R²³ represents a hydrogen atom or a hydrocarbyl group having 1 to 20 carbon atoms and optionally having an ether bond, an ester bond, a carbonyl group, a lactone ring, or a fluorine atom. The hydrocarbyl group may be a saturated or unsaturated group, and may be any of linear, branched, and cyclic groups. Specific examples thereof include groups that will be described below as a hydrocarbyl group represented by R¹⁰⁵ in the formula (3A′).

In the formula (B-1-2), R²⁴ represents a hydrogen atom, a hydrocarbyl group having 1 to 30 carbon atoms, a hydrocarbylcarbonyl group having 2 to 30 carbon atoms, or an aryloxy group having 6 to 20 carbon atoms. These groups optionally have an ether bond, an ester bond, a carbonyl group, or a lactone ring. The hydrocarbyl group and the hydrocarbyl moiety in the hydrocarbylcarbonyl group may be a saturated or unsaturated group, and may be any of linear, branched, and cyclic groups. Specific examples thereof include groups that will be described below as a hydrocarbyl group represented by R¹⁰⁵ in the formula (3A′).

Specific examples of the sulfonic acid anion represented by the non-nucleophilic counterion include the following anions, but the sulfonic acid anion is not limited thereto. In the following formulae, Q³ represents a hydrogen atom, a fluorine atom, or a fluorinated alkyl group having 1 to 6 carbon atoms. Ac represents an acetyl group.

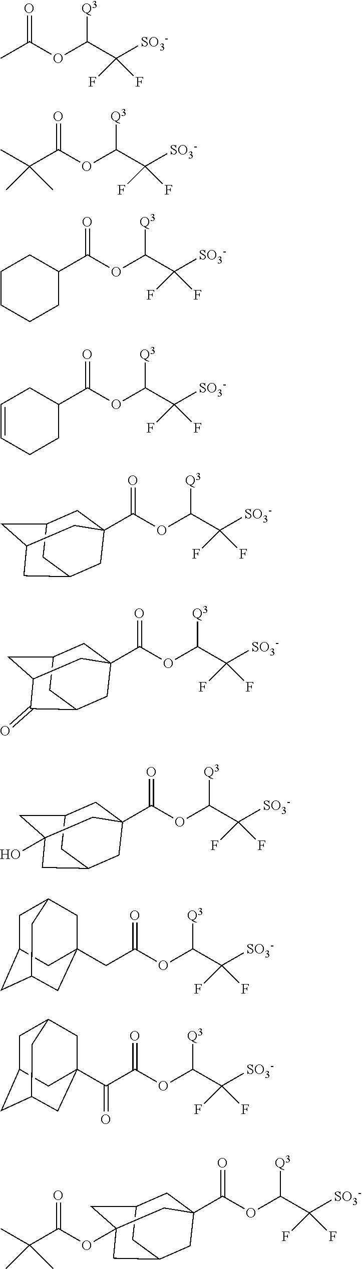

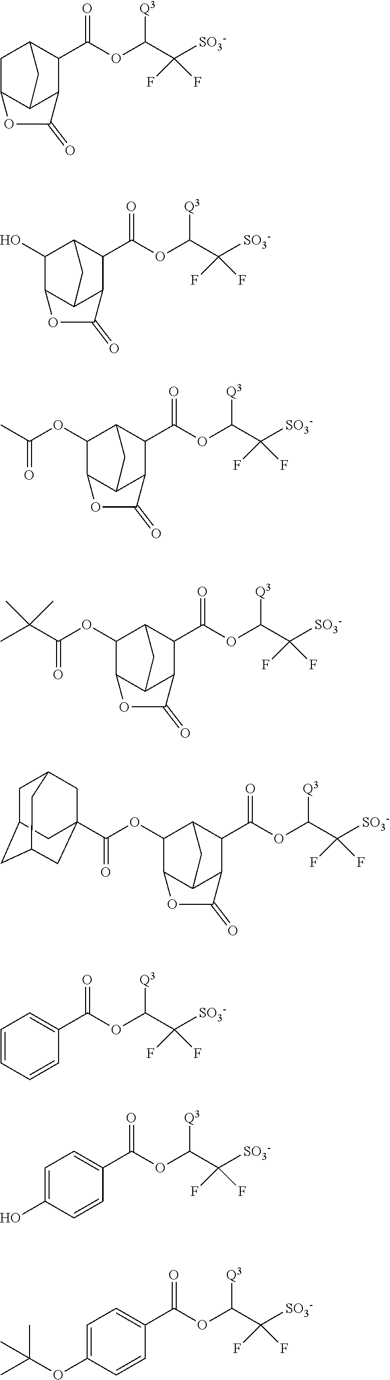

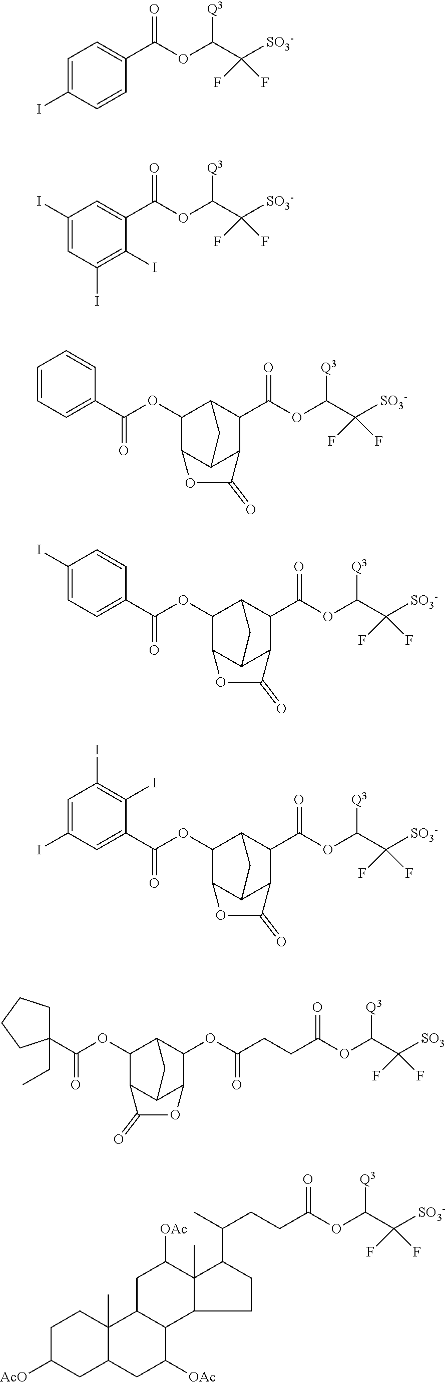

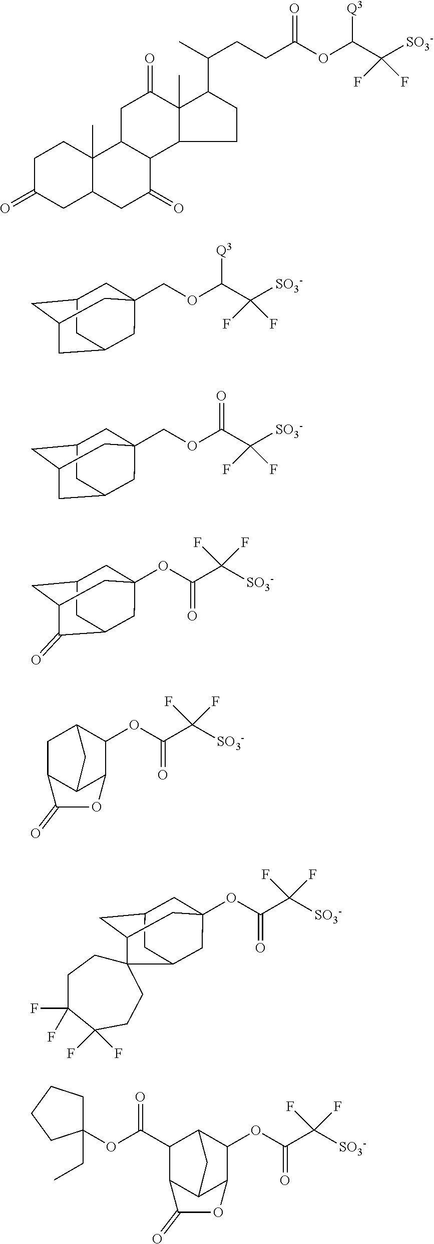

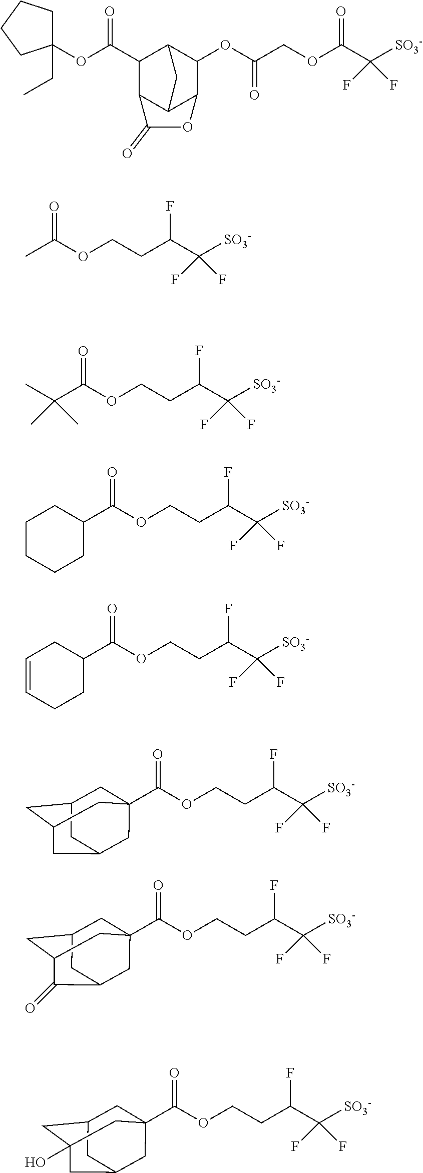

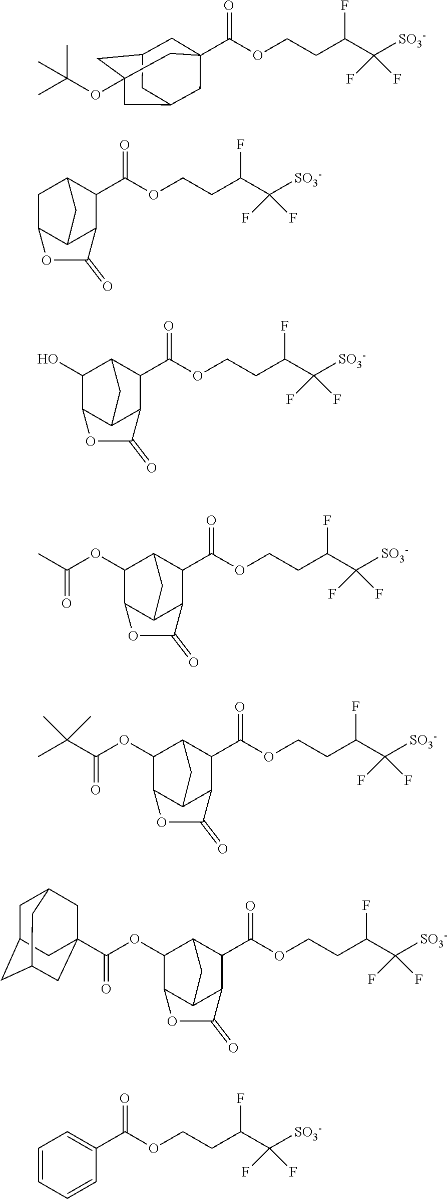

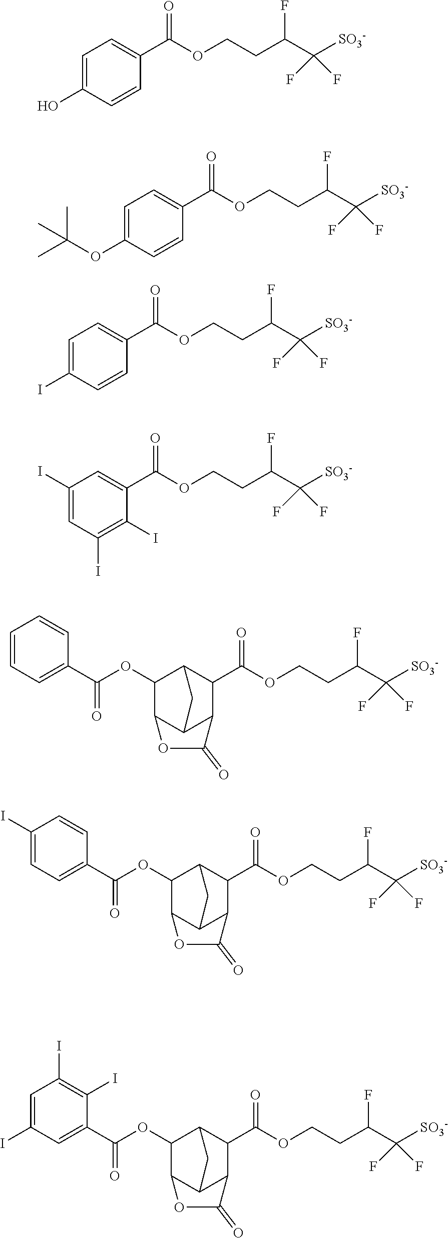

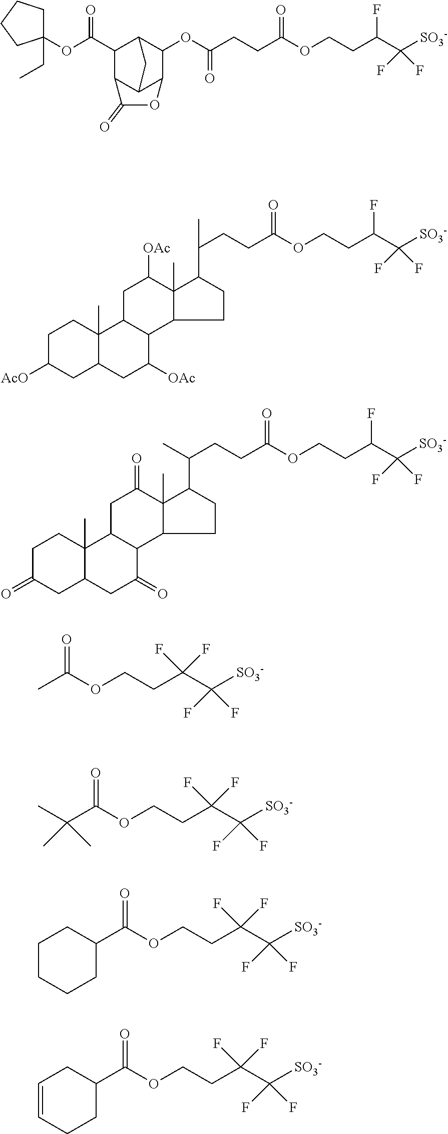

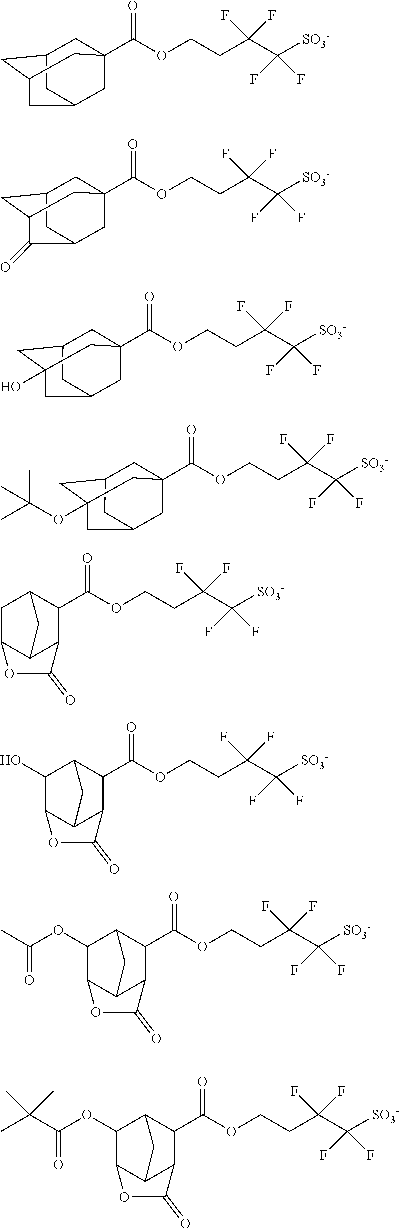

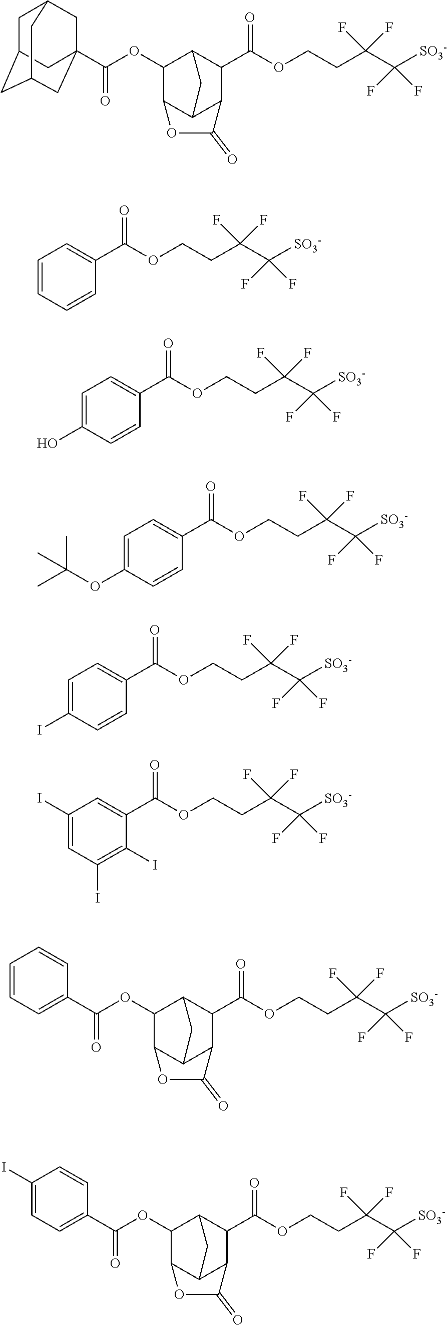

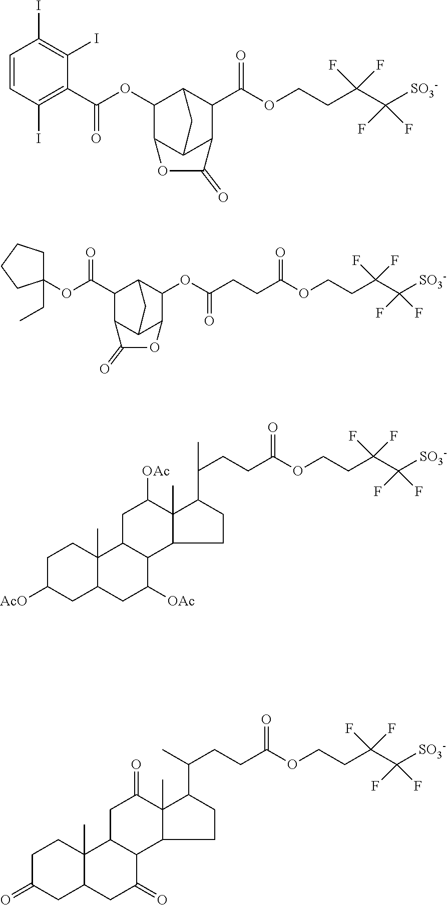

In the formula (B-2), L¹¹ represents a single bond, an ether bond, an ester bond, a carbonyl group, a sulfonic acid ester bond, a carbonate bond, or a carbamate bond. Among these, an ether bond, an ester bond, and a carbonyl group are preferable, and an ester bond and a carbonyl group are further preferable, from the viewpoint of synthesis.

In the formula (B-2), Rf¹ and Rf² each independently represent a fluorine atom or a fluorinated alkyl group having 1 to 6 carbon atoms. Among these, both Rf¹ and Rf² are preferably fluorine atoms in terms of increase in acid strength of the generated acid. Rf³ and Rf⁴ each independently represent a hydrogen atom, a fluorine atom, or a fluorinated alkyl group having 1 to 6 carbon atoms. Among these, at least one of Rf³ and Rf⁴ is preferably a trifluoromethyl group in terms of improvement of the solvent solubility.

In the formula (B-2), “c” represents an integer of 0 to 3, preferably 1.

Specific examples of the anion of the repeating unit represented by the formula (B-2) include the following anions, but the anion is not limited thereto. In the following formulae, R^{A} is as defined above.

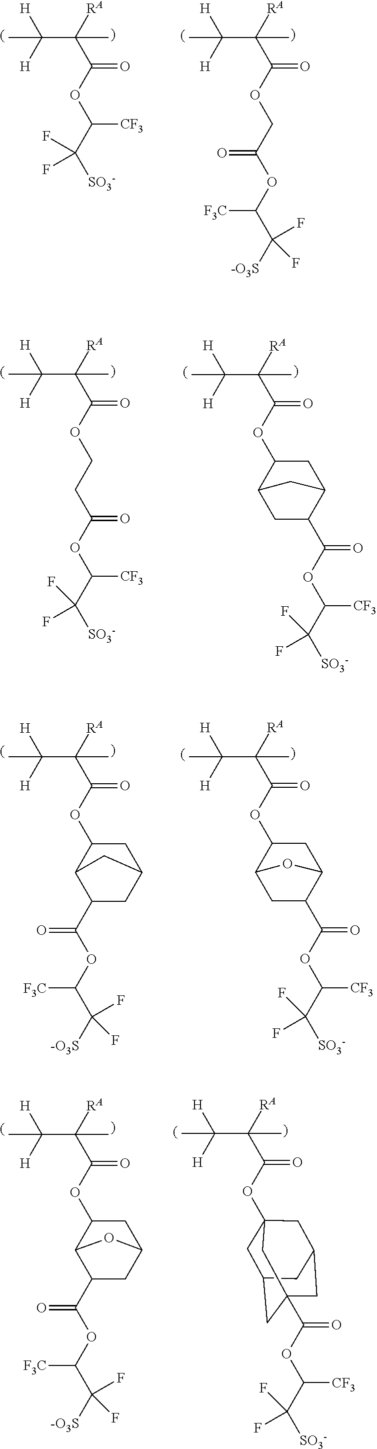

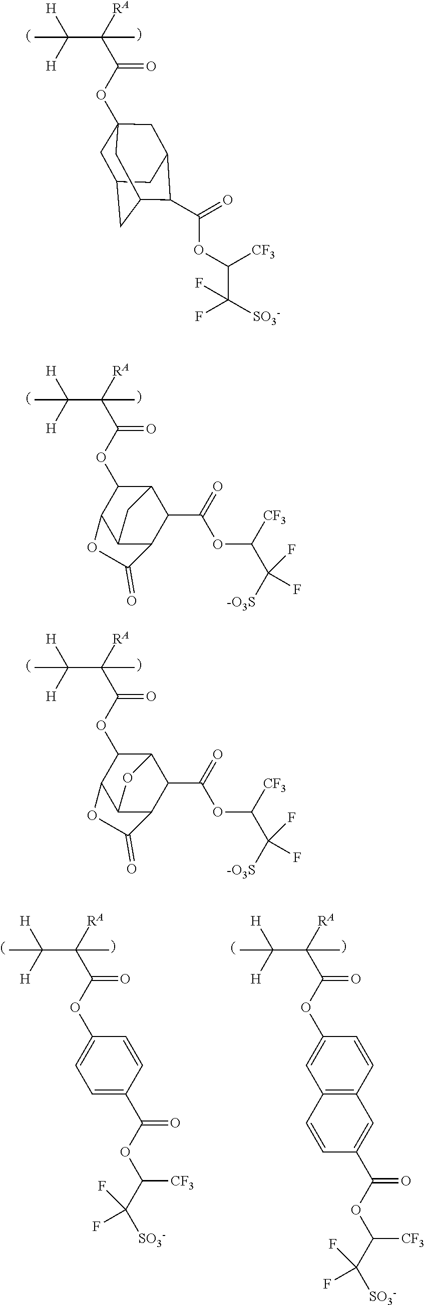

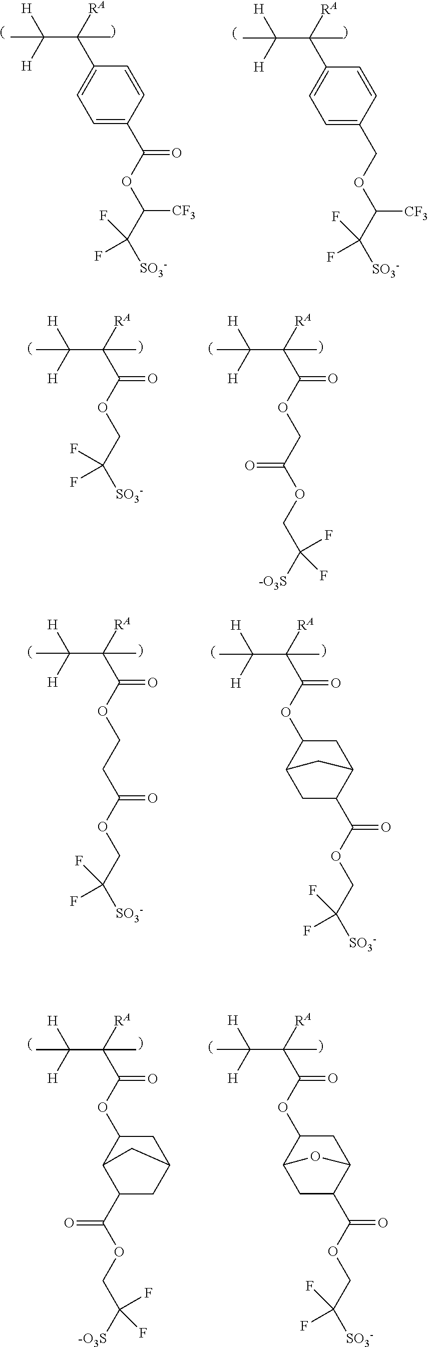

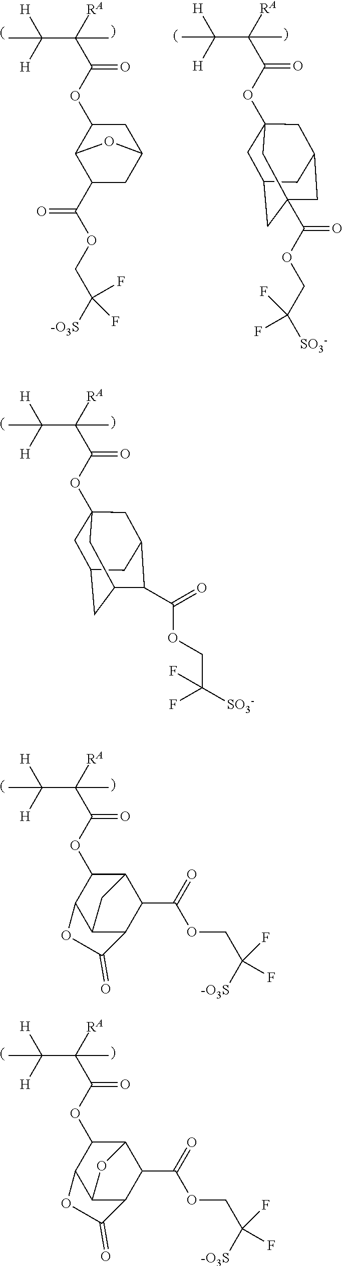

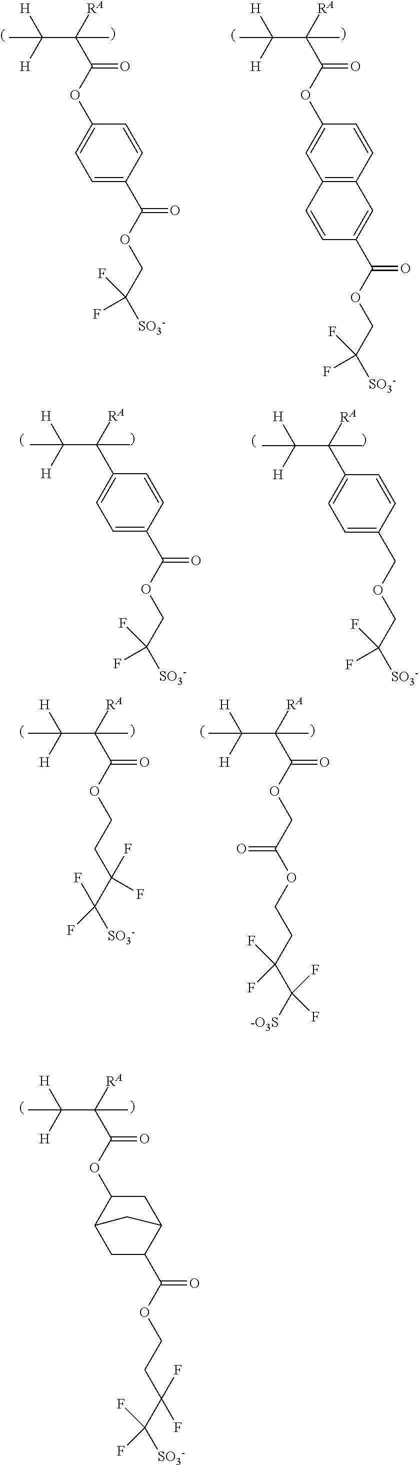

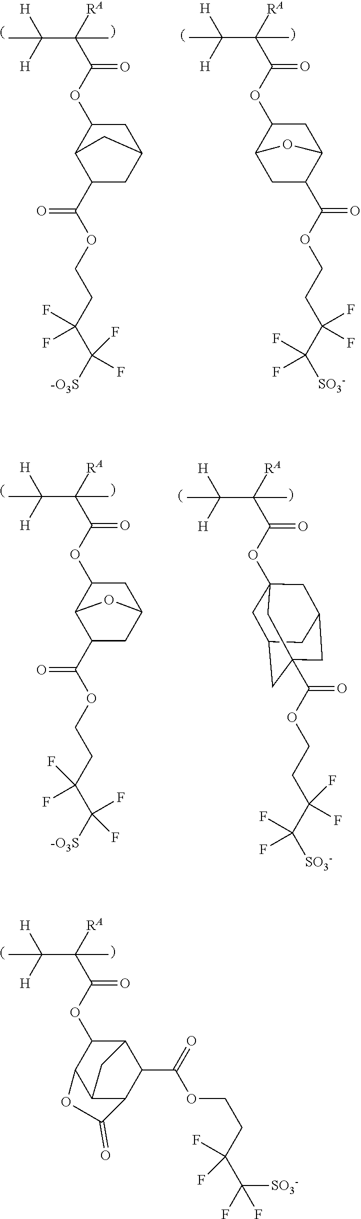

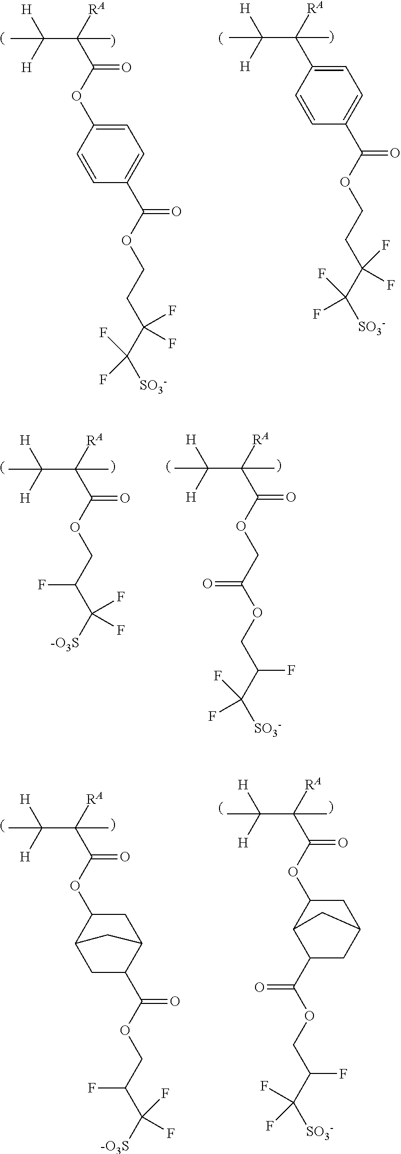

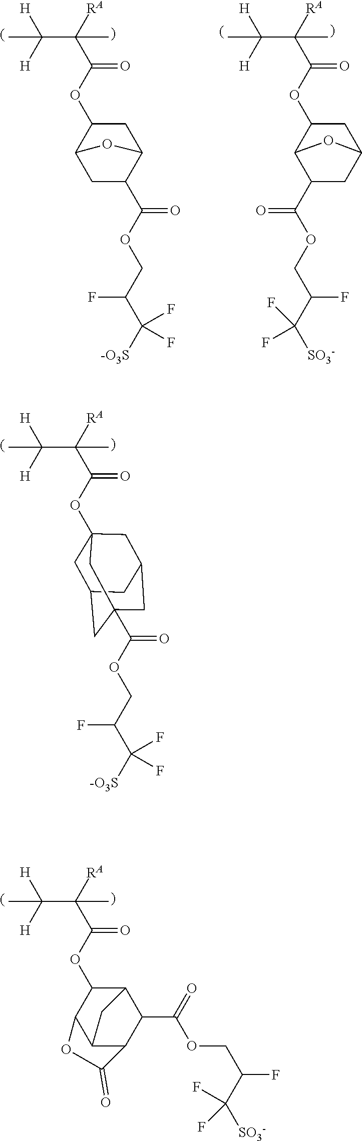

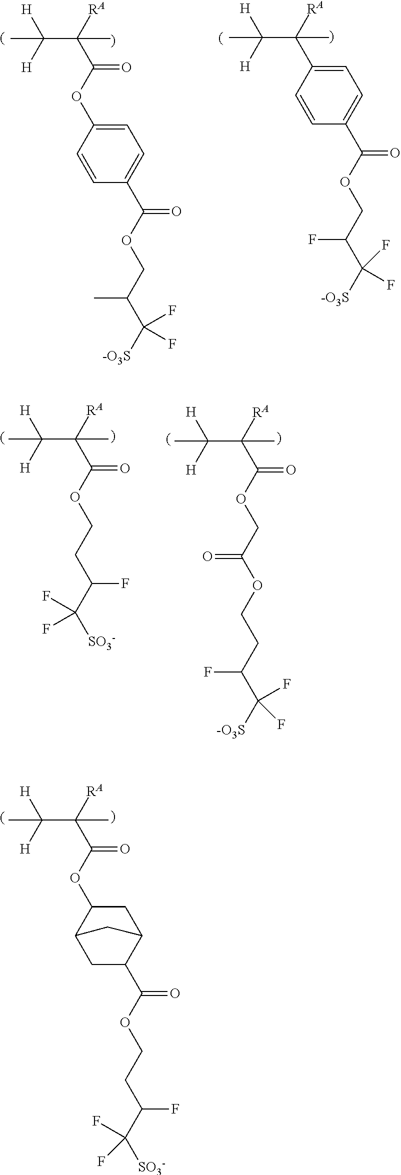

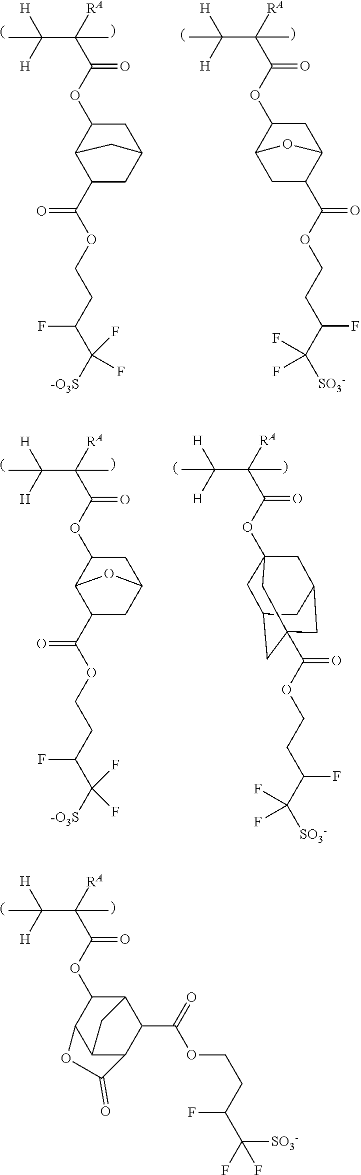

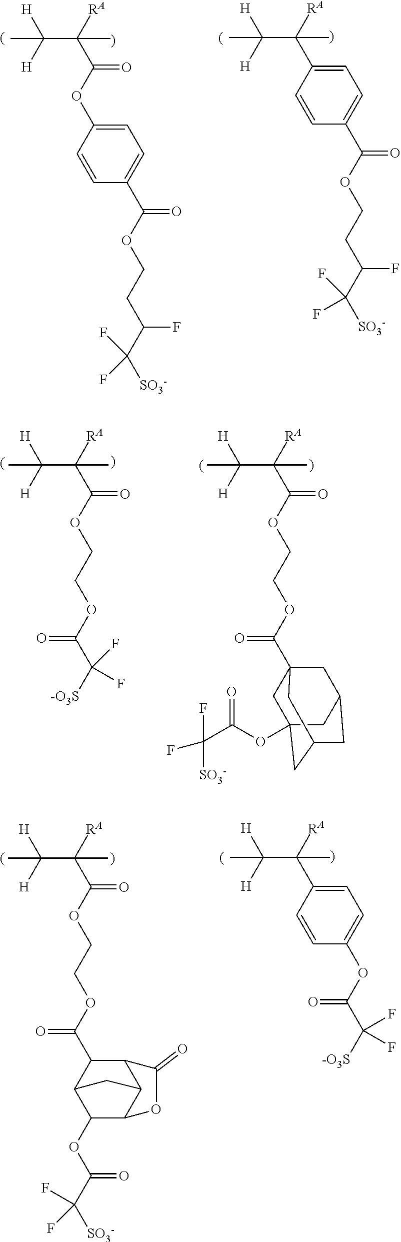

Specific examples of a monomer to give the anion of the repeating unit represented by the formula (B-2) include the following, but are not limited thereto. In the following formulae, R^{A} is as defined above.

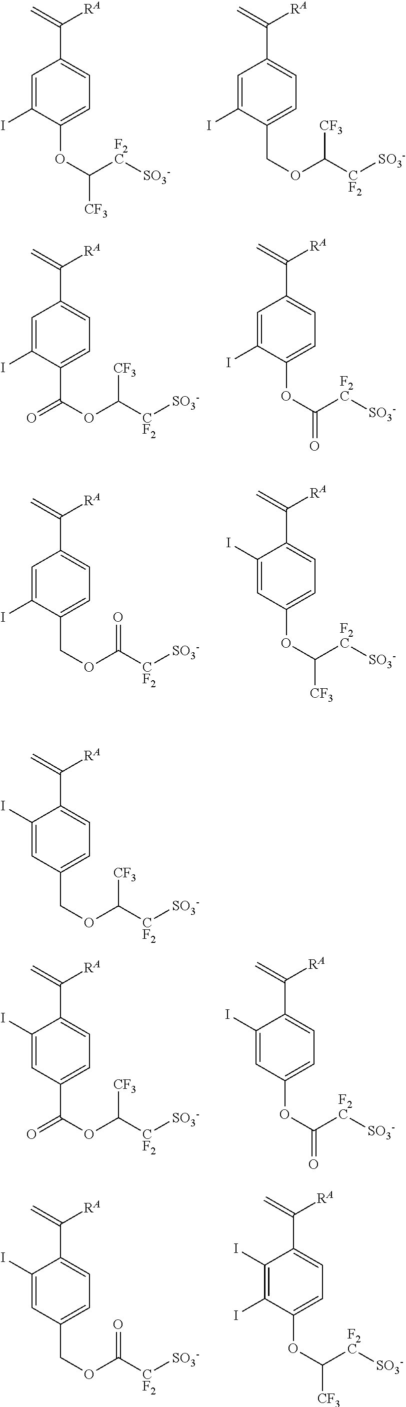

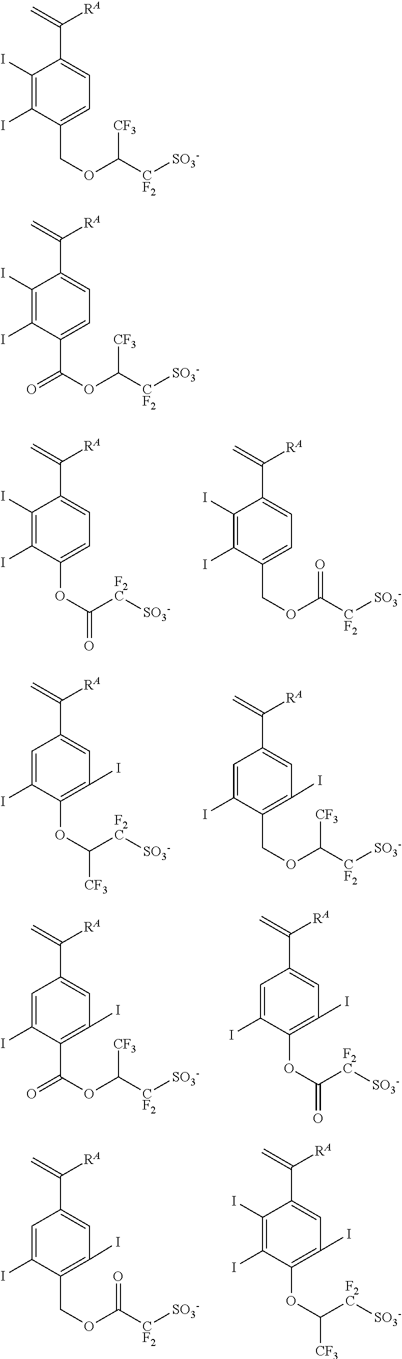

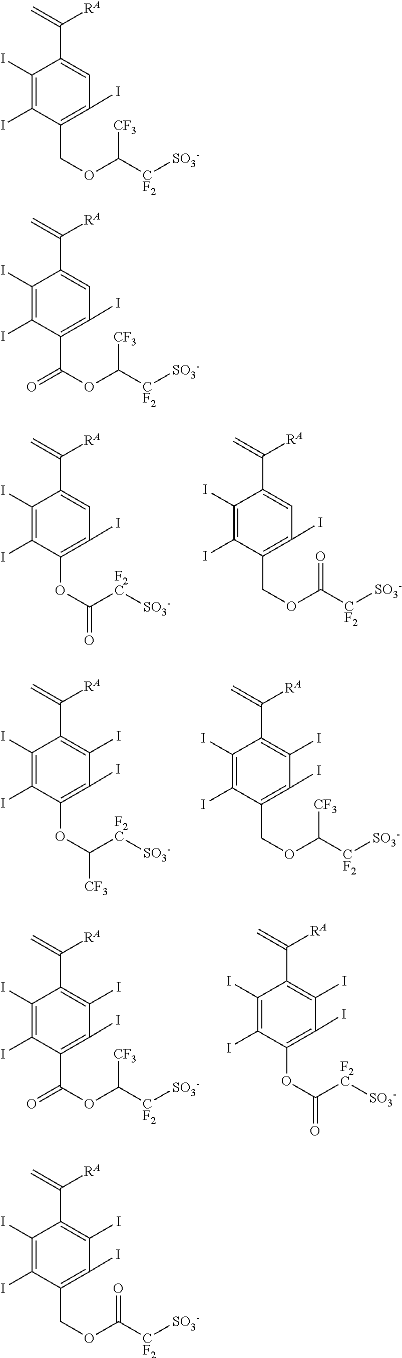

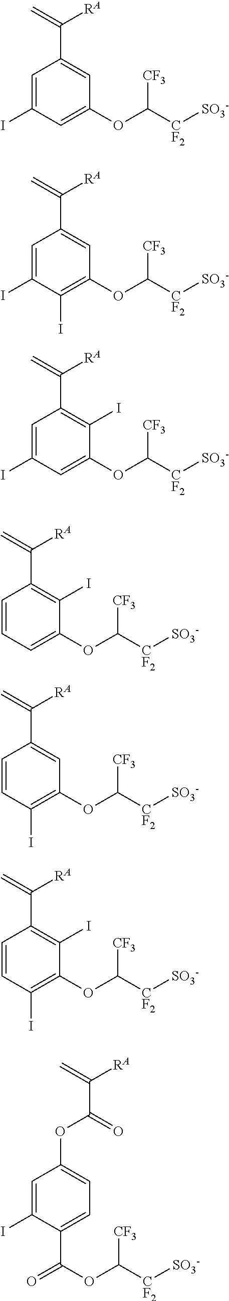

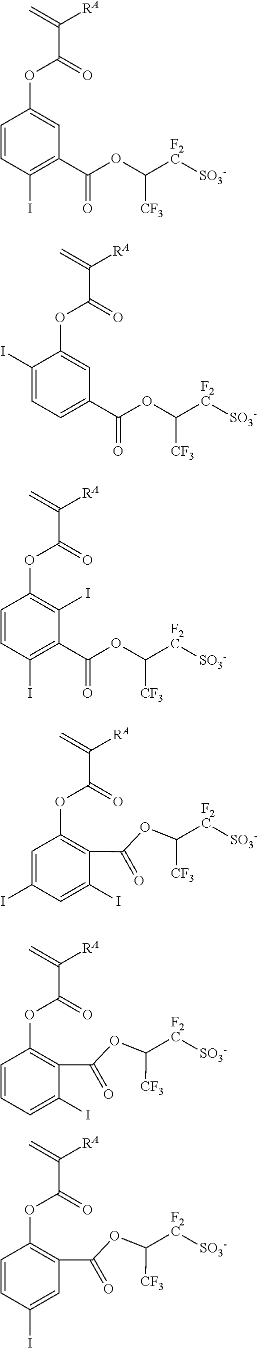

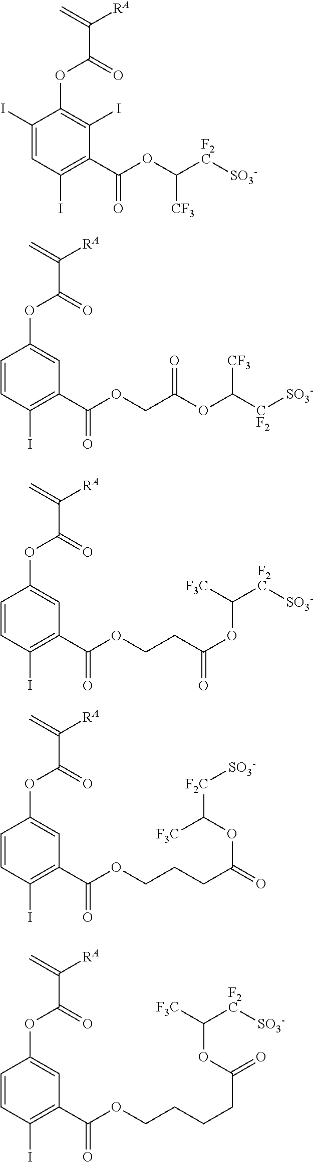

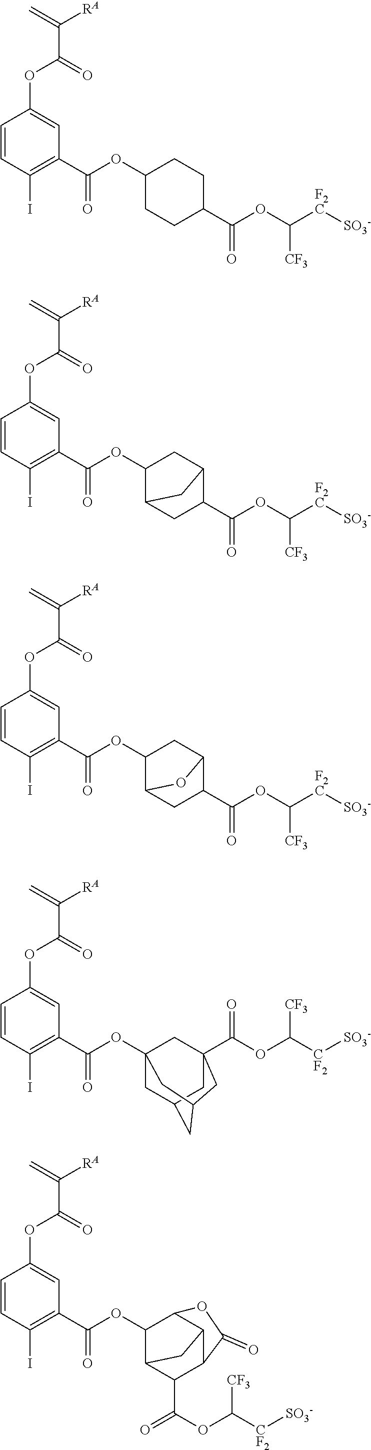

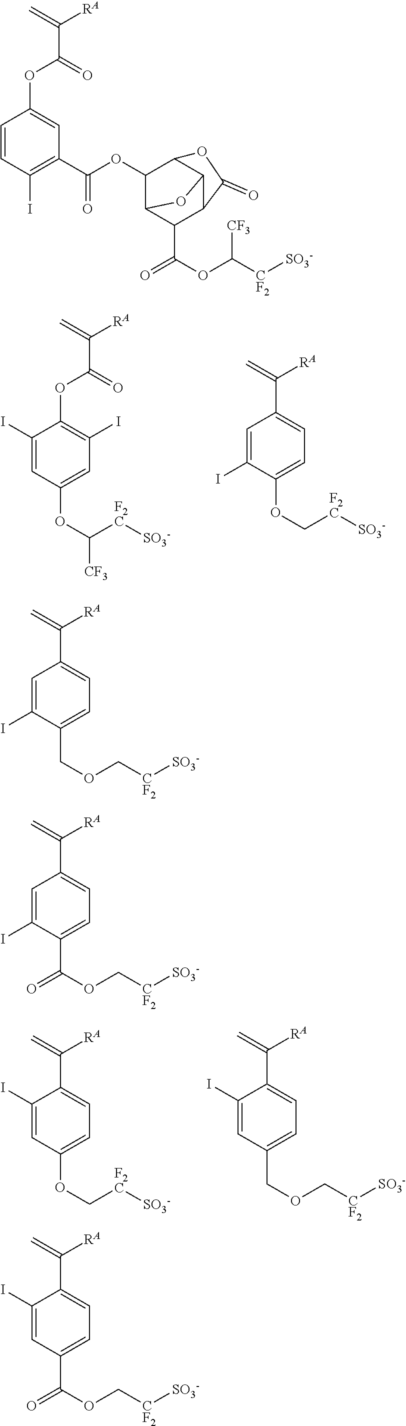

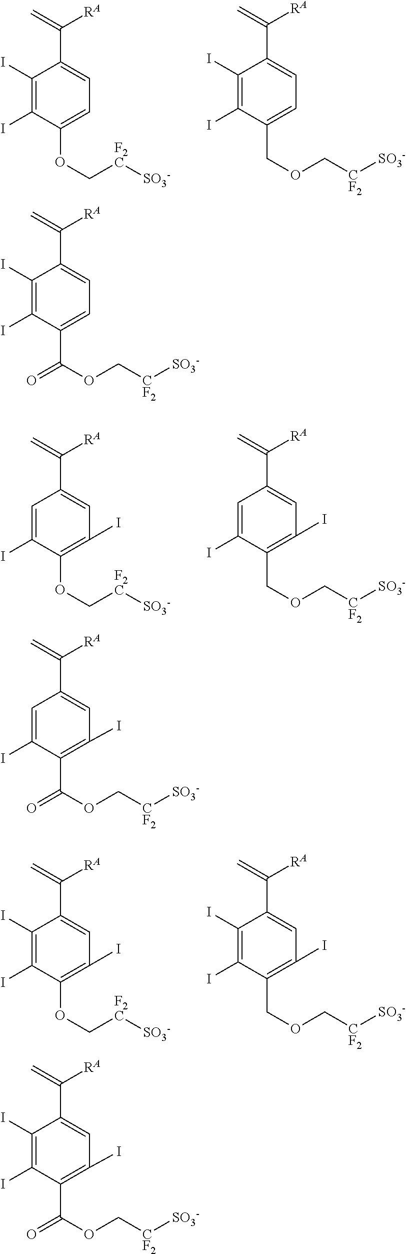

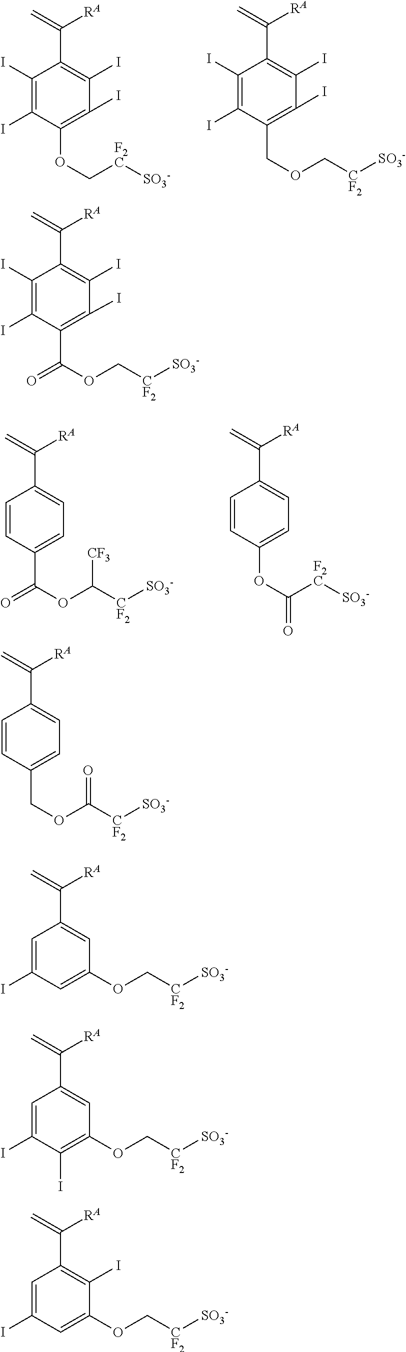

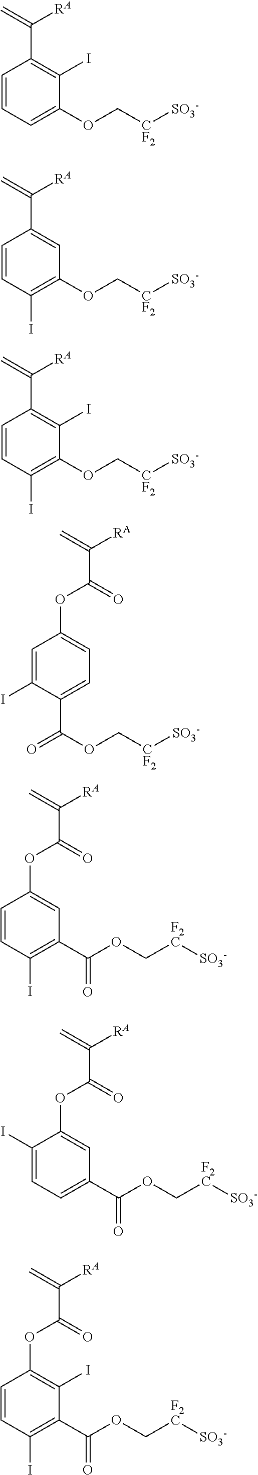

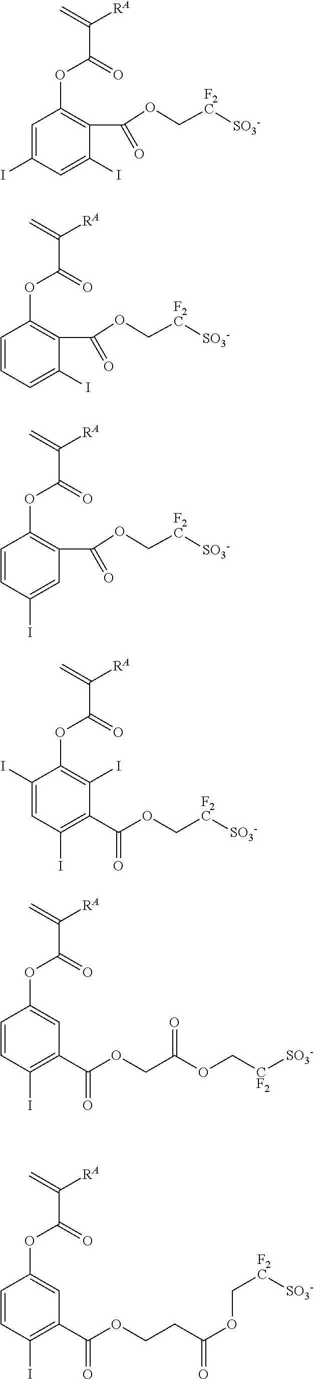

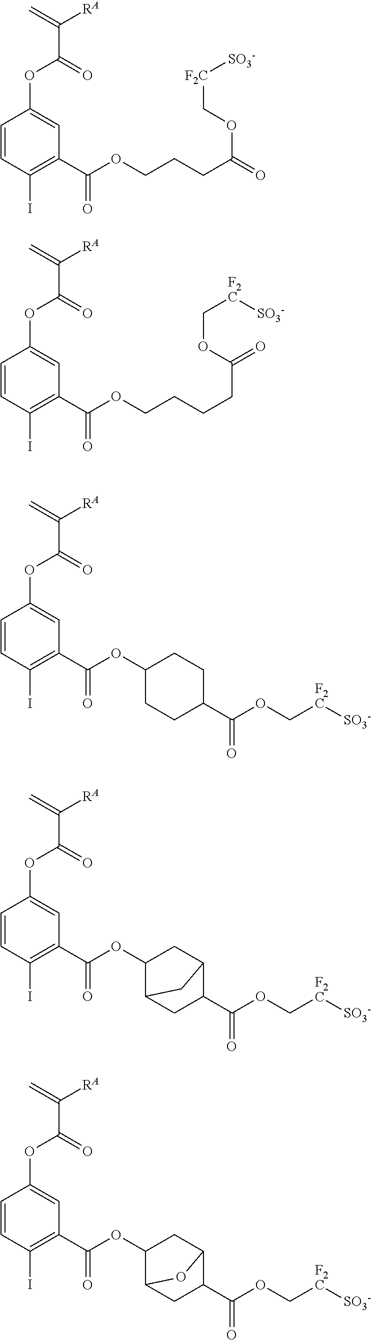

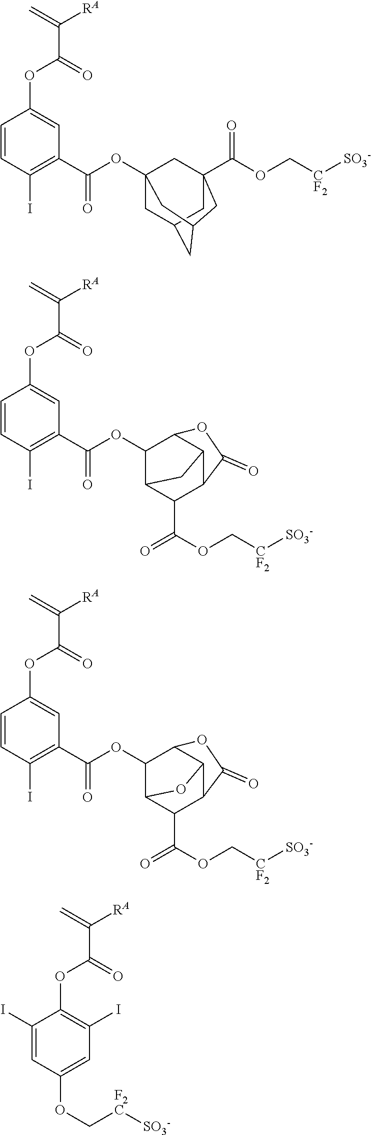

In the formula (B-3), L¹¹ represents a single bond, an ether bond, an ester bond, a carbonyl group, a sulfonic acid ester bond, a carbonate bond, or a carbamate bond. Among these, an ether bond, an ester bond, and a carbonyl group are preferable, and an ester bond and a carbonyl group are further preferable, from the viewpoint of synthesis.

In the formula (B-3), Rf³ and Rf⁴ each independently represent a hydrogen atom, a fluorine atom, or a fluorinated alkyl group having 1 to 6 carbon atoms. Among these, at least one of Rf³ and Rf⁴ is preferably a trifluoromethyl group in terms of improvement of the solvent solubility.

In the formula (B-3), “c” represents an integer of 0 to 3, preferably 1.

Specific examples of the anion of the repeating unit represented by the formula (B-3) include the following anions, but the anion is not limited thereto. In the following formulae, R^{A} is as defined above.

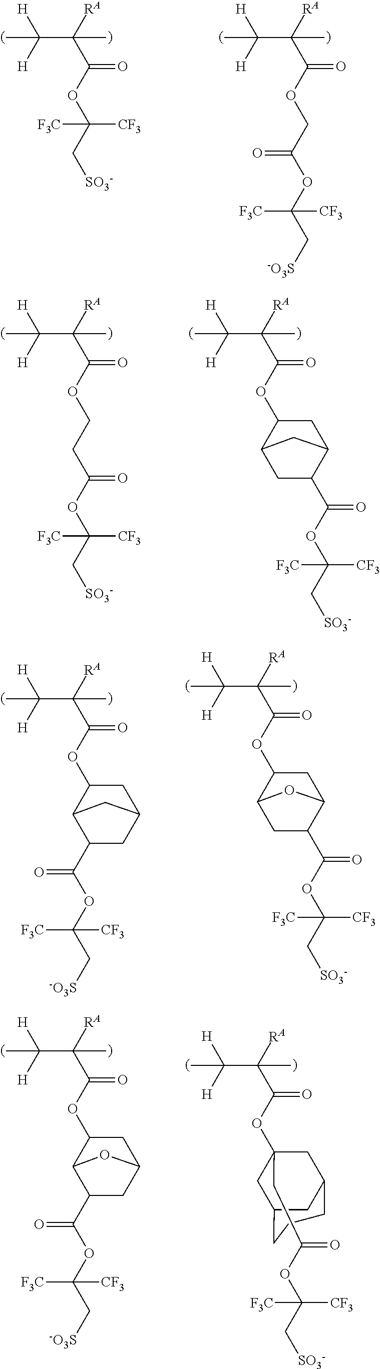

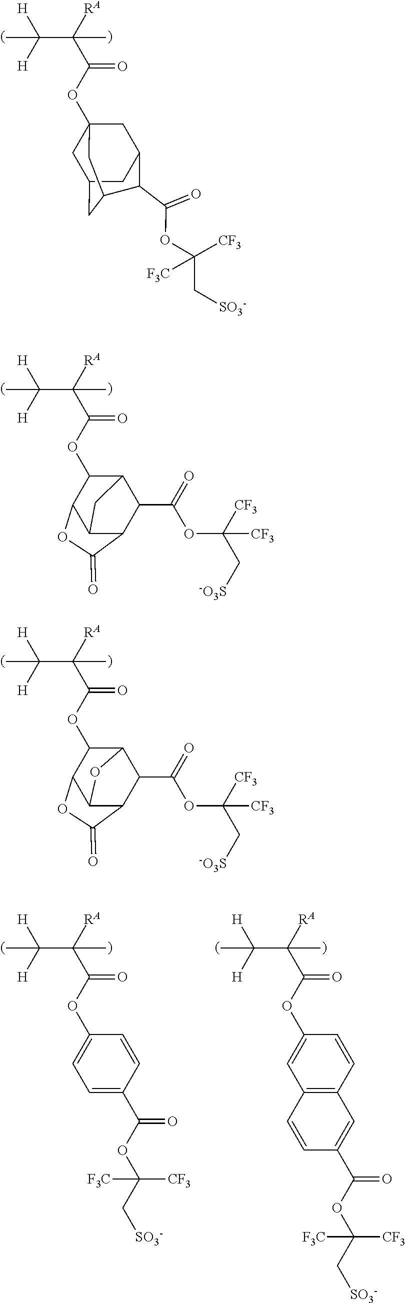

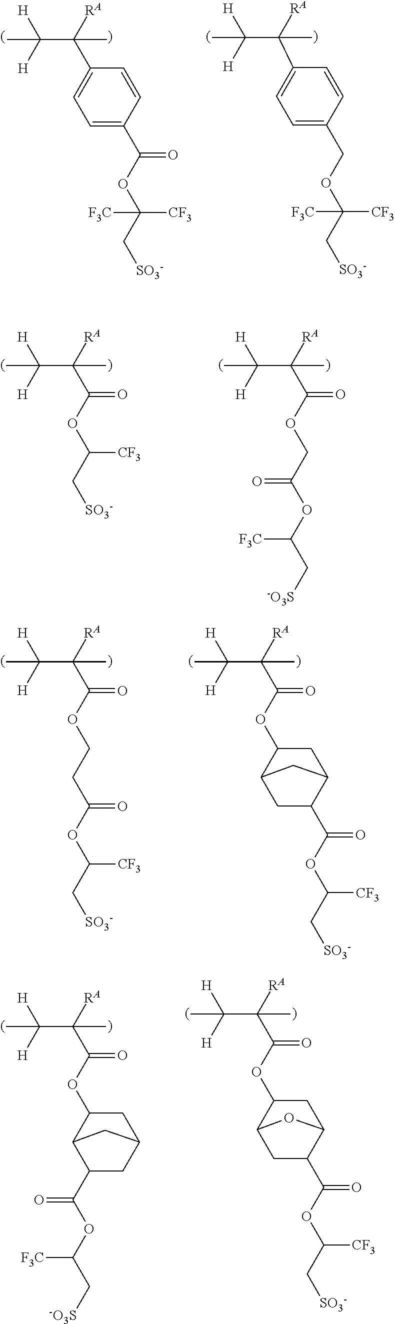

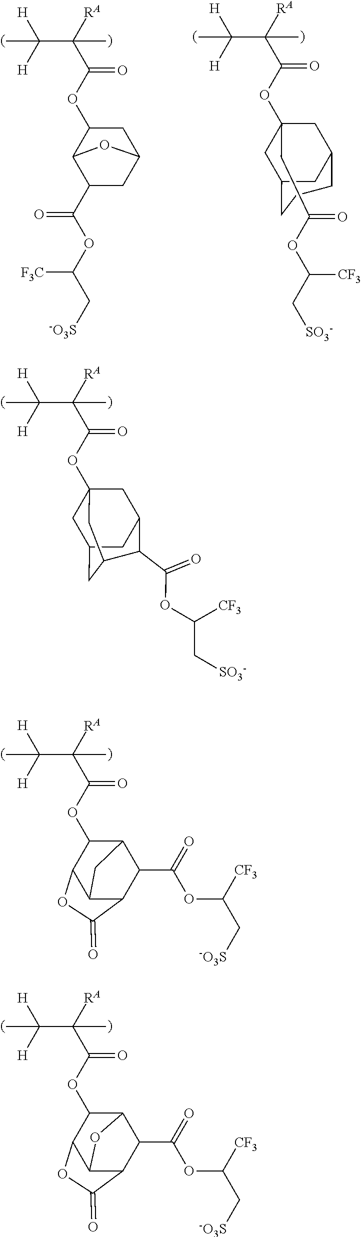

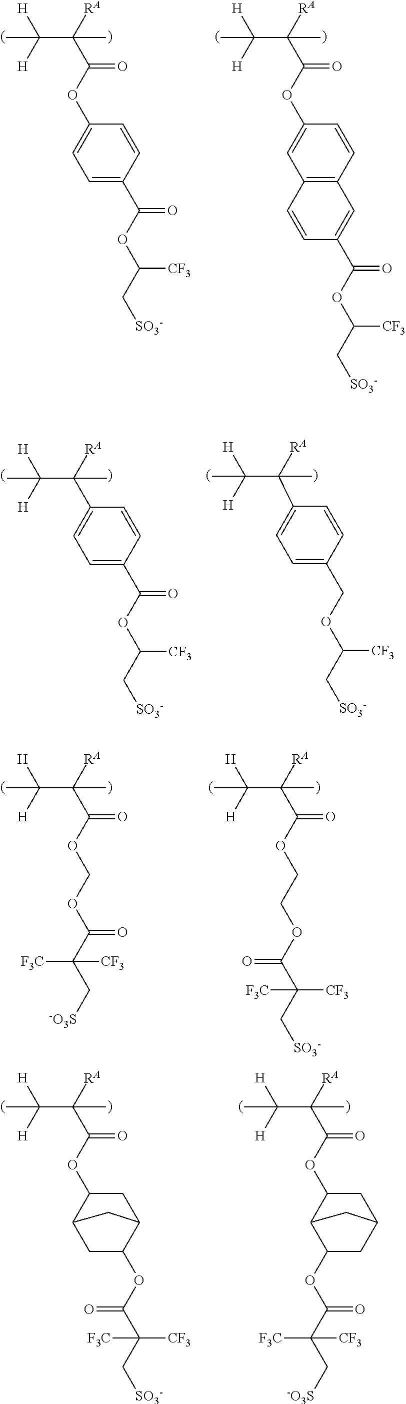

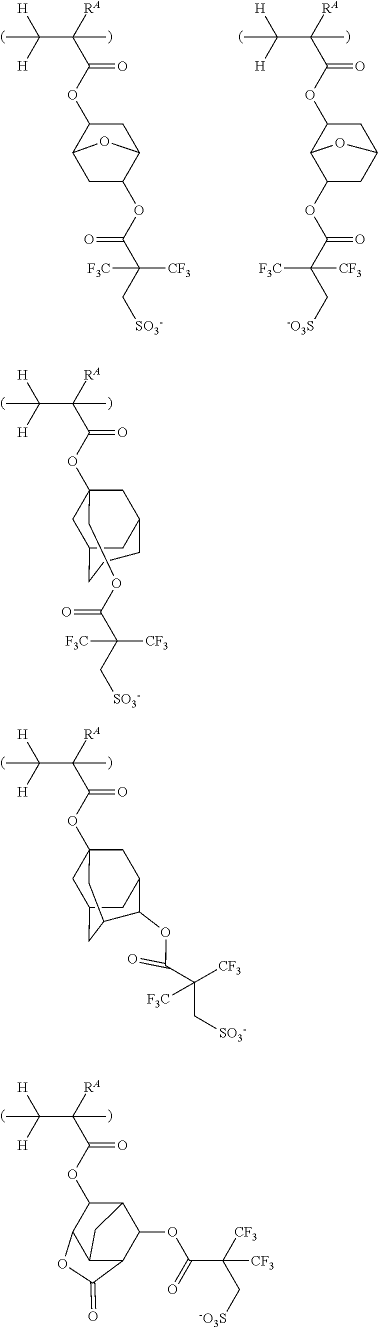

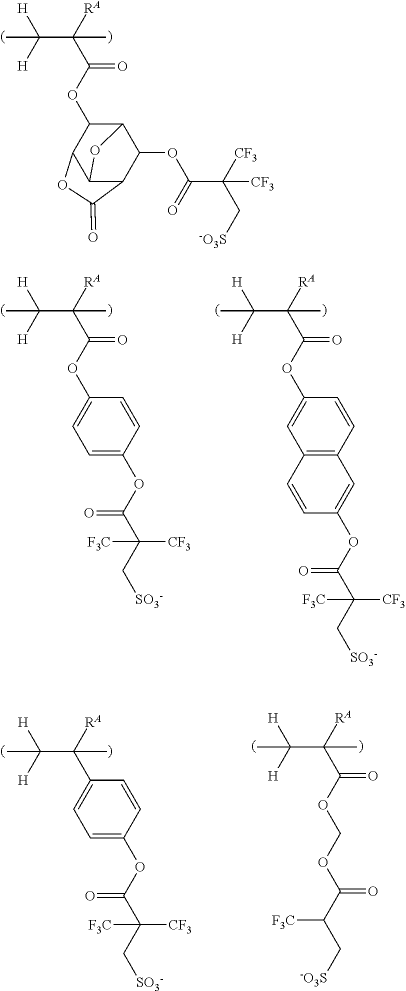

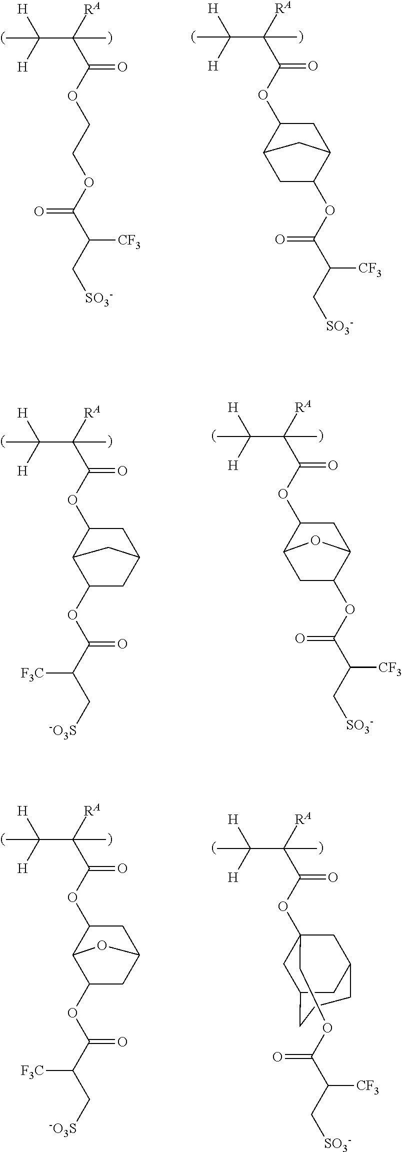

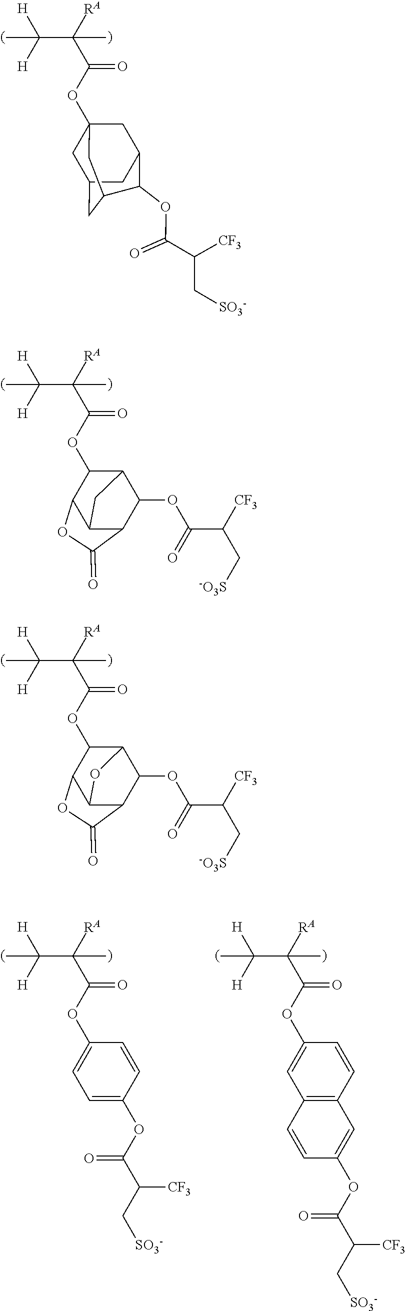

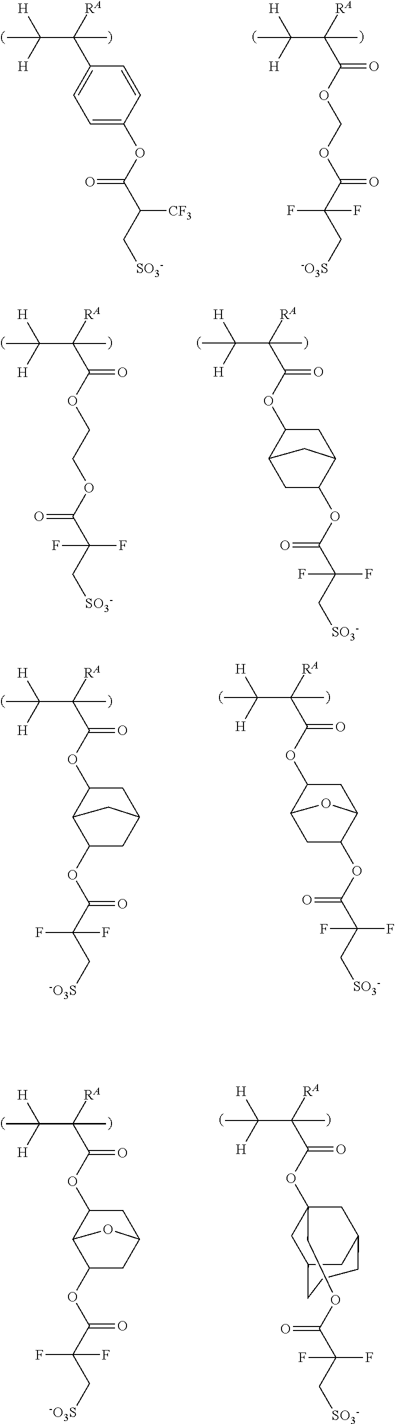

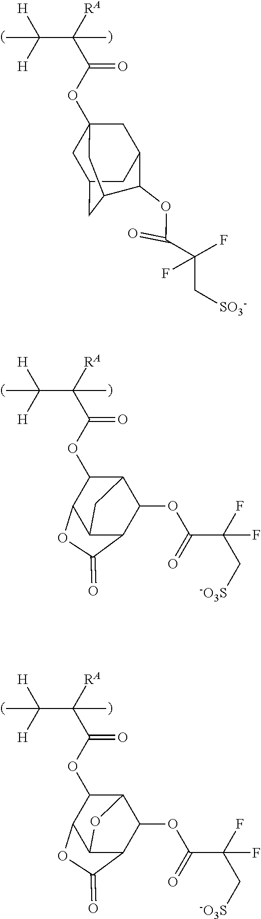

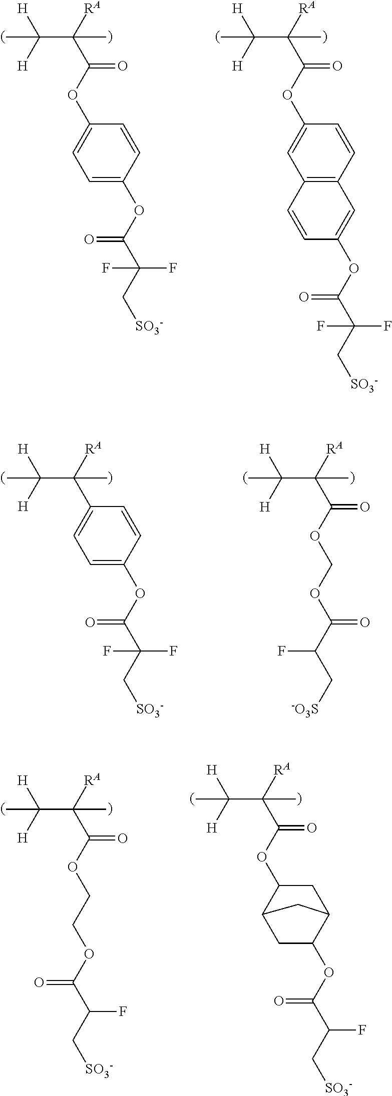

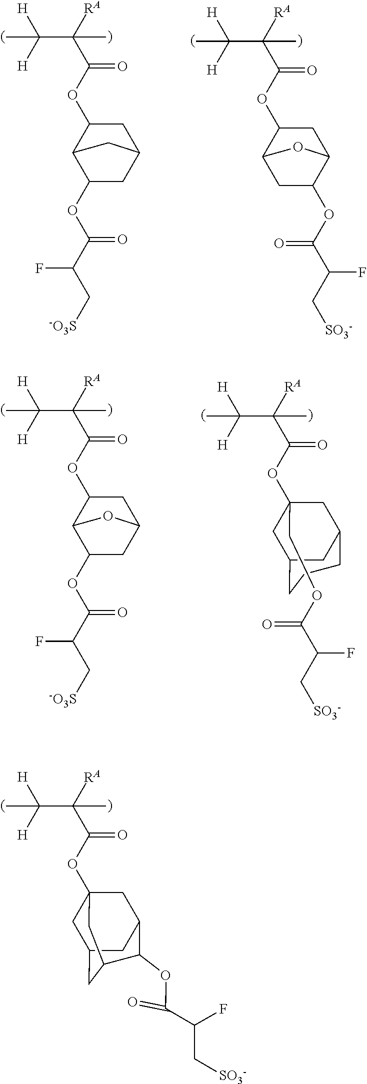

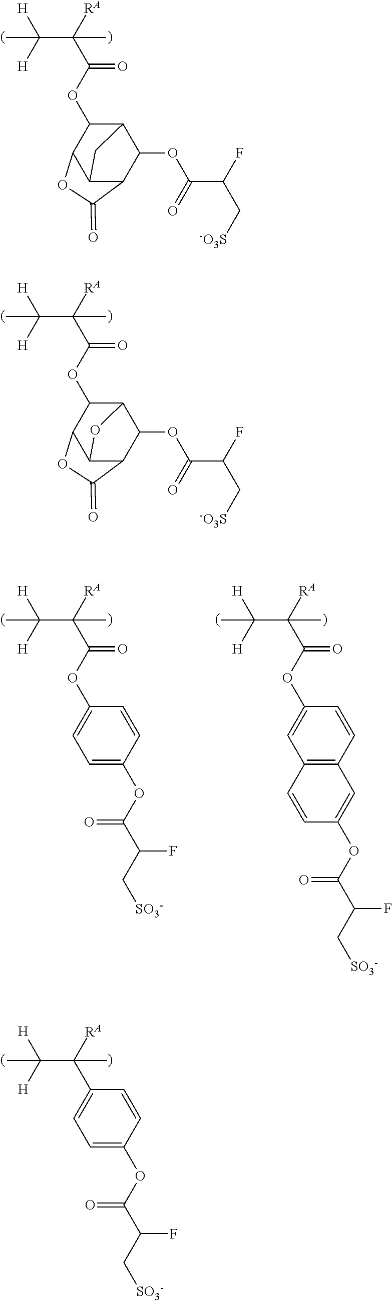

Specific examples of the anion of the repeating unit represented by the formula (B-4) include the following anions, but the anion is not limited thereto. In the following formulae, R^{A} is as defined above.

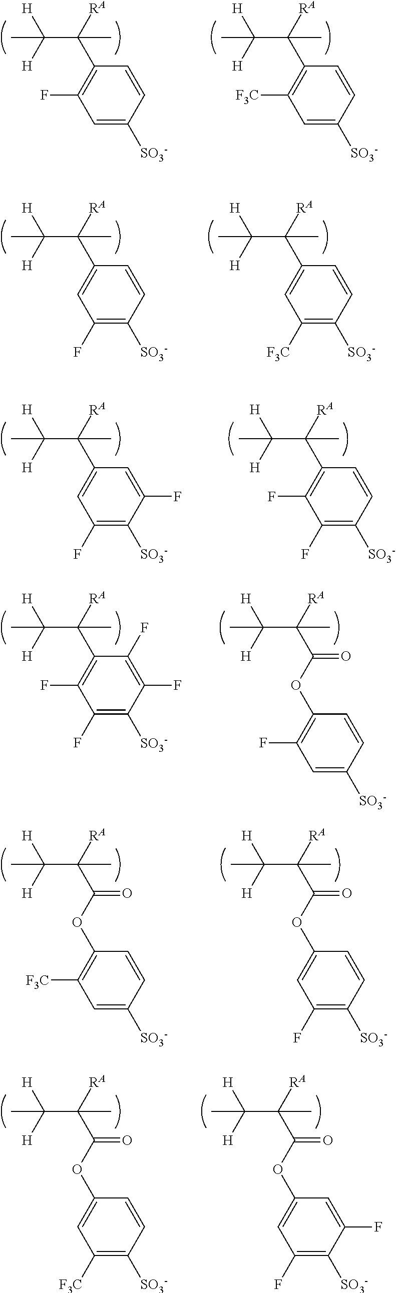

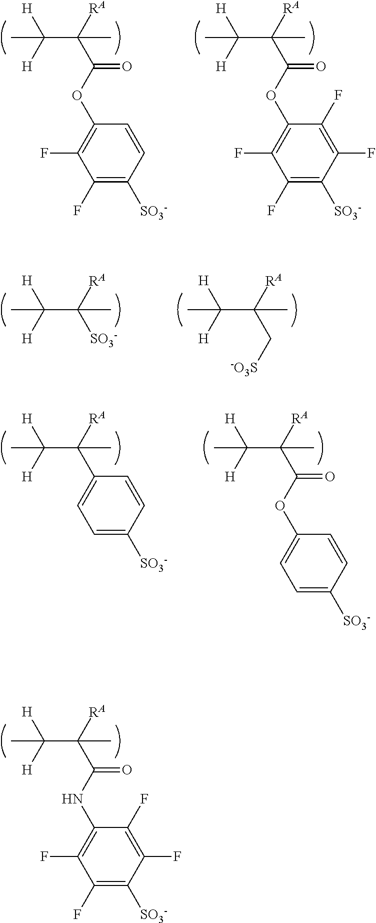

In the formulae (B-2) to (B-4), A⁺ represents an onium cation. Examples of the onium cation include an ammonium cation, a sulfonium cation, and an iodonium cation. A sulfonium cation and an iodonium cation are preferable. A sulfonium cation represented by the following formula (cation-1) and an iodonium cation represented by the following formula (cation-2) are more preferable. That is, the repeating unit represented by the formula (B-2), (B-3), and (B-4) to generate an acid by light exposure preferably contains an onium cation represented by the following formula (cation-1) or (cation-2) as the onium cation A⁺.

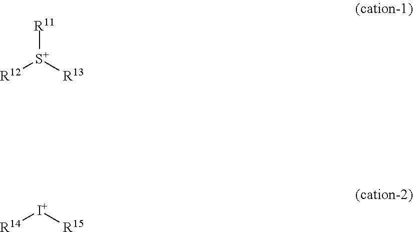

In the formula, R¹¹, R¹², and R¹³ each independently represent a linear, branched, or cyclic hydrocarbyl group having 1 to 30 carbon atoms and optionally having a heteroatom. Any two of R¹¹, R¹², and R¹³ are optionally bonded to each other to form a ring together with a sulfur atom in the formula. R¹⁴ and R¹⁵ each independently represent a linear, branched, or cyclic hydrocarbyl group having 1 to 30 carbon atoms and optionally having a heteroatom.

In the formulae (cation-1) and (cation-2), R¹¹ to R¹⁵ each independently represent a hydrocarbyl group having 1 to 30 carbon atoms and optionally having a heteroatom. The hydrocarbyl group may be a saturated or unsaturated group, and may be any of linear, branched, and cyclic groups. Specific examples thereof include: alkyl groups, such as a methyl group, an ethyl group, an n-propyl group, an isopropyl group, an n-butyl group, and a tert-butyl group; cyclic saturated hydrocarbyl groups, such as a cyclopropyl group, a cyclopentyl group, a cyclohexyl group, a cyclopropylmethyl group, a 4-methylcyclohexyl group, a cyclohexylmethyl group, a norbornyl group, and an adamantyl group; alkenyl groups, such as a vinyl group, an allyl group, a propenyl group, a butenyl group, and a hexenyl group; cyclic unsaturated hydrocarbyl groups, such as a cyclohexenyl group; aryl groups, such as a phenyl group, a naphthyl group, and a thienyl group; aralkyl groups, such as a benzyl group, a 1-phenylethyl group, and a 2-phenylethyl group; and groups obtained by combining these groups. Aryl groups are preferable. A part of the hydrogen atoms in the hydrocarbyl group is optionally substituted with a group having a heteroatom such as an oxygen atom, a sulfur atom, a nitrogen atom, and a halogen atom. Between carbon atoms in these groups, a group having a heteroatom such as an oxygen atom, a sulfur atom, and a nitrogen atom are optionally interposed. As a result, a hydroxy group, a cyano group, a carbonyl group, an ether bond, an ester bond, a sulfonic acid ester bond, a carbonate bond, a lactone ring, a sultone ring, a carboxylic anhydride, a haloalkyl group, etc. are optionally contained.

Any two of R¹¹, R¹², and R¹³ are optionally bonded to each other to form a ring together with the sulfur atom bonded thereto. In this event, examples of the sulfonium cation represented by the formula (cation-1) include cations shown by the following formulae.

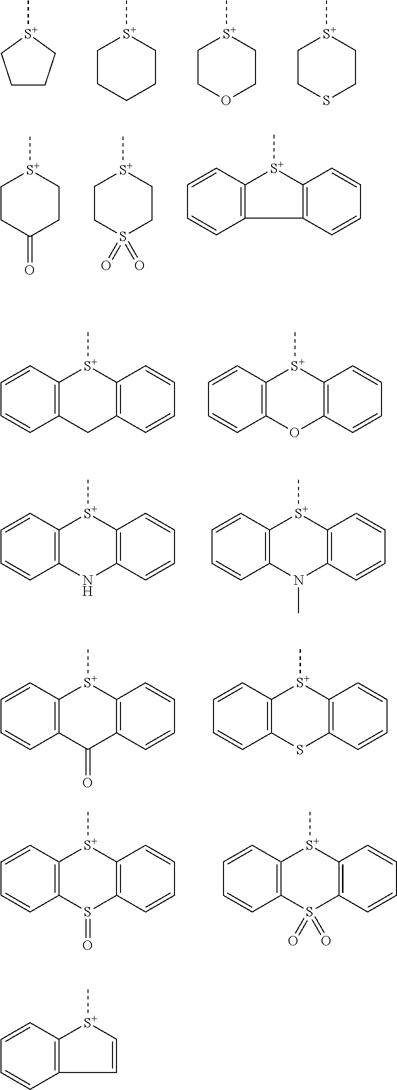

In the formulae, a broken line represents an attachment point to R¹³, for example.

Examples of the sulfonium cation represented by the formula (cation-1) include the cations shown below, but are not limited thereto.

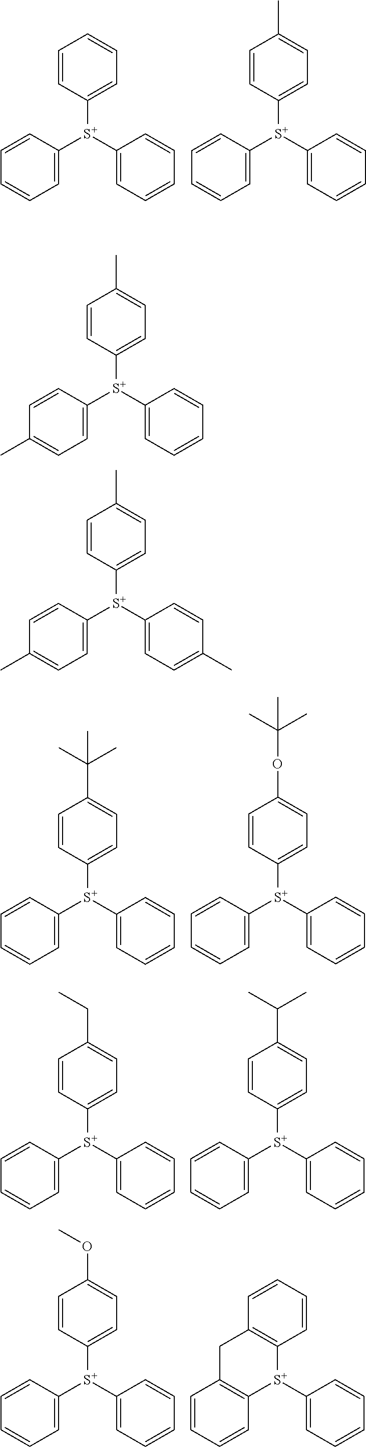

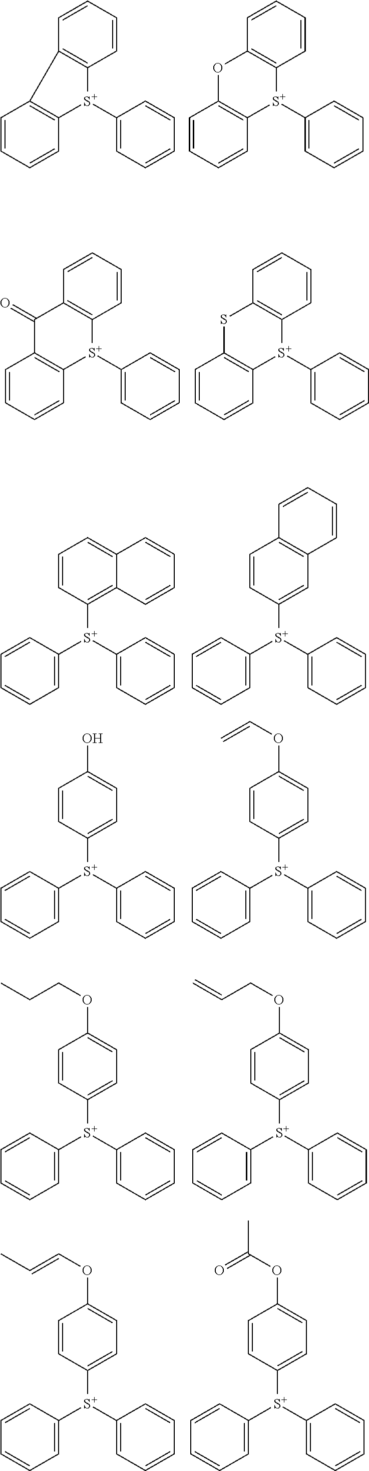

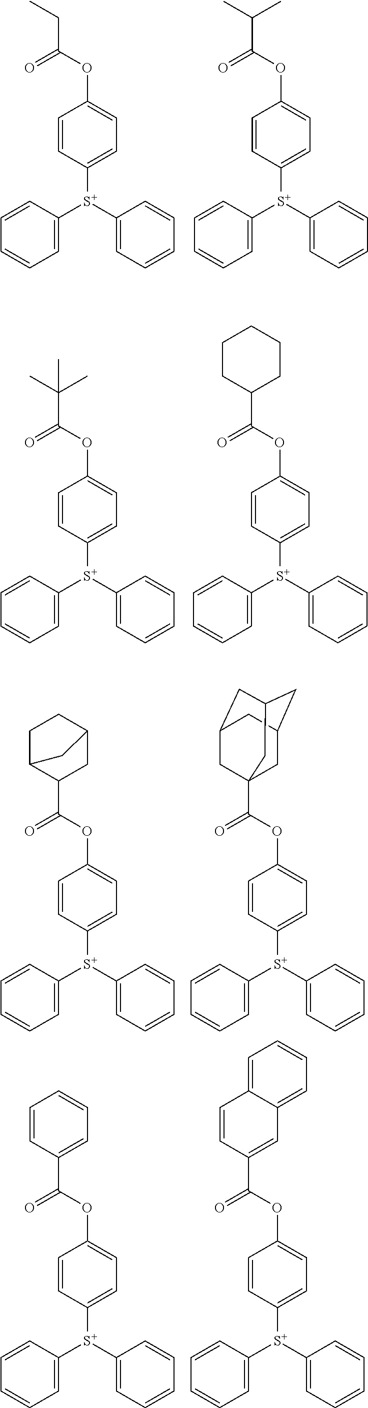

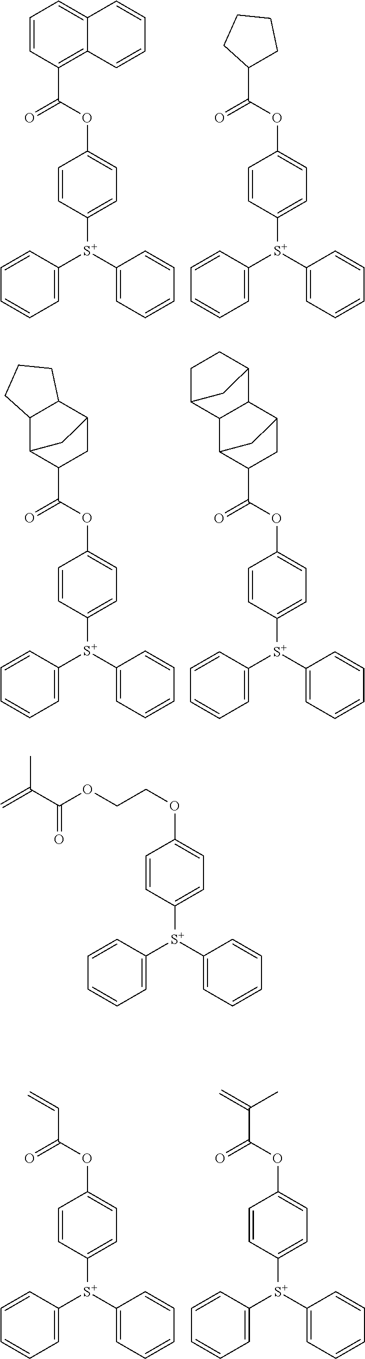

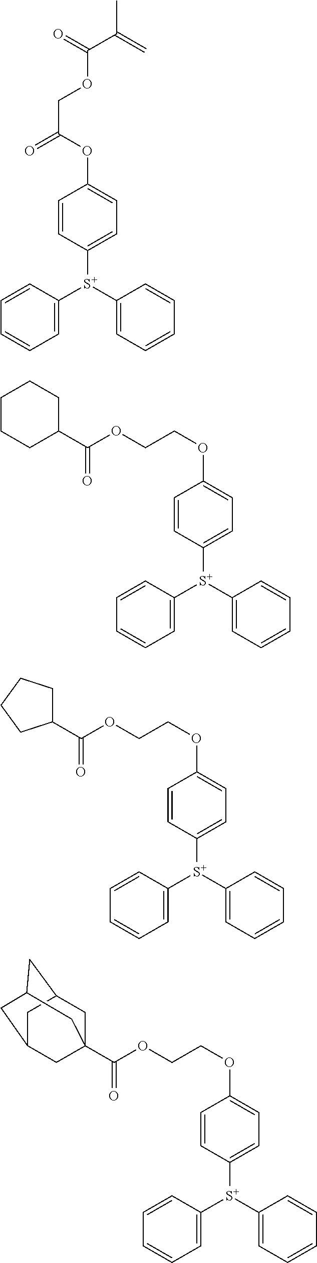 [SMILES: C=C(C)C(=O)OCC(=O)Oc1ccc([S+](c2ccccc2)c2ccccc2)cc1 ; O=C(OCCOc1ccc([S+](c2ccccc2)c2ccccc2)cc1)C1CCCCC1 ; O=C(OCCOc1ccc([S+](c2ccccc2)c2ccccc2)cc1)C1CCCC1 ; O=C(OCCOc1ccc([S+](c2ccccc2)c2ccccc2)cc1)C12CC3CC(CC(C3)C1)C2]

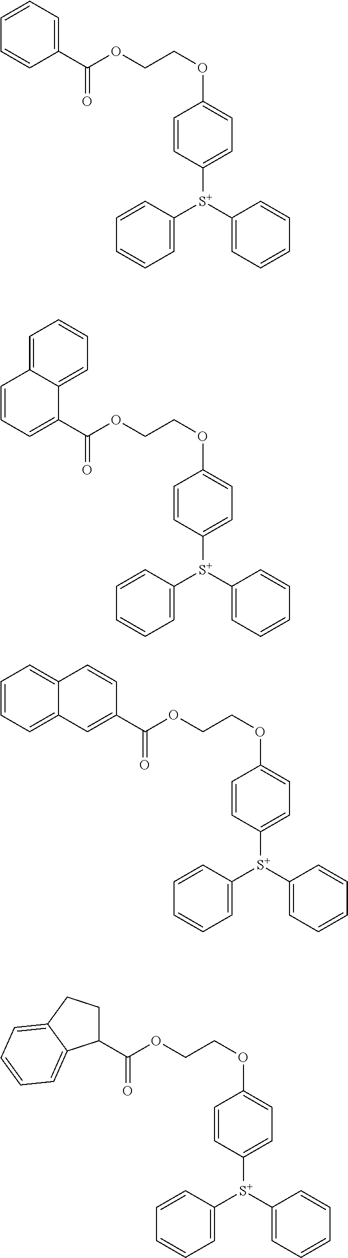 [SMILES: O=C(OCCOc1ccc([S+](c2ccccc2)c2ccccc2)cc1)c1ccccc1 ; O=C(OCCOc1ccc([S+](c2ccccc2)c2ccccc2)cc1)c1cccc2ccccc12 ; O=C(OCCOc1ccc([S+](c2ccccc2)c2ccccc2)cc1)c1ccc2ccccc2c1 ; O=C(OCCOc1ccc([S+](c2ccccc2)c2ccccc2)cc1)C1CCc2ccccc21]

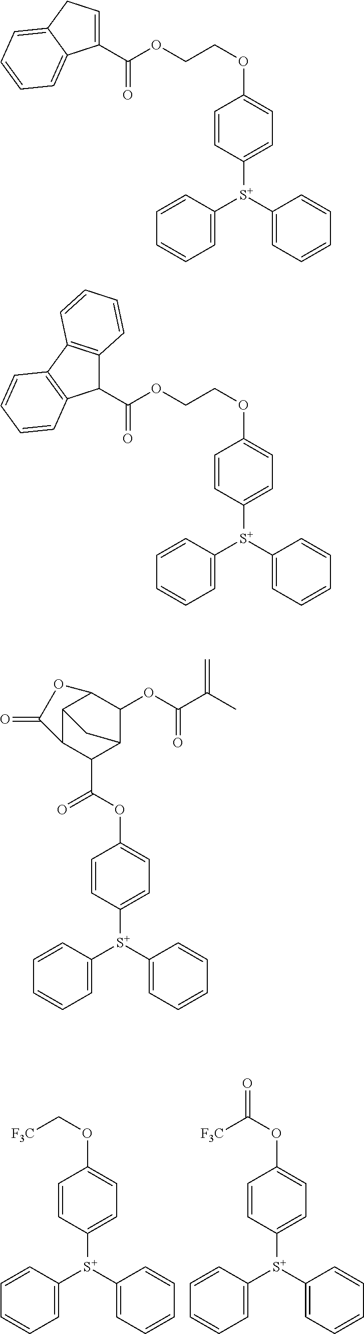 [SMILES: O=C(OCCOc1ccc([S+](c2ccccc2)c2ccccc2)cc1)C1=CCc2ccccc21 ; O=C(OCCOc1ccc([S+](c2ccccc2)c2ccccc2)cc1)C1c2ccccc2-c2ccccc21 ; C=C(C)C(=O)OC1C2CC3C1OC(=O)C3C2C(=O)Oc1ccc([S+](c2ccccc2)c2ccccc2)cc1 ; FC(F)(F)COc1ccc([S+](c2ccccc2)c2ccccc2)cc1 ; O=C(Oc1ccc([S+](c2ccccc2)c2ccccc2)cc1)C(F)(F)F]

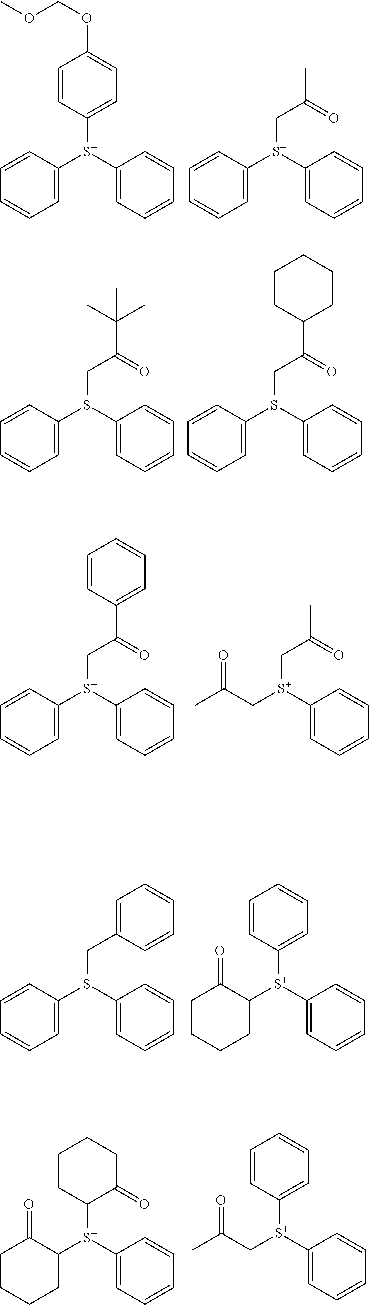

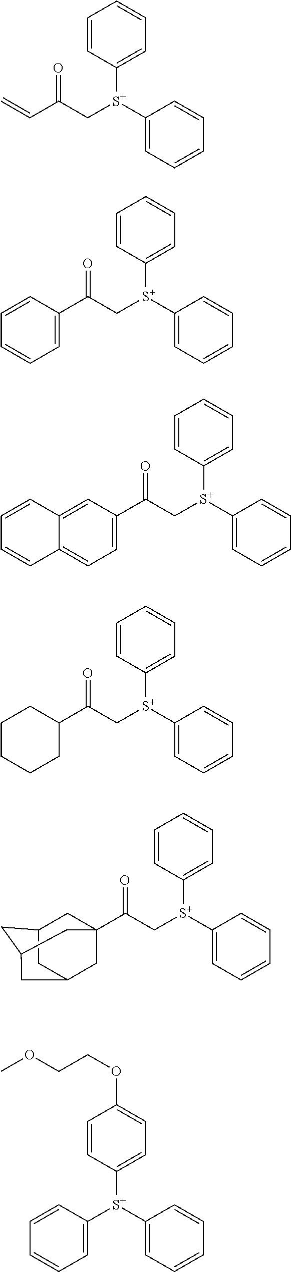 [SMILES: C=CC(=O)C[S+](c1ccccc1)c1ccccc1 ; O=C(C[S+](c1ccccc1)c1ccccc1)c1ccccc1 ; O=C(C[S+](c1ccccc1)c1ccccc1)c1ccc2ccccc2c1 ; O=C(C[S+](c1ccccc1)c1ccccc1)C1CCCCC1 ; O=C(C[S+](c1ccccc1)c1ccccc1)C12CC3CC(CC(C3)C1)C2 ; COCCOc1ccc([S+](c2ccccc2)c2ccccc2)cc1]

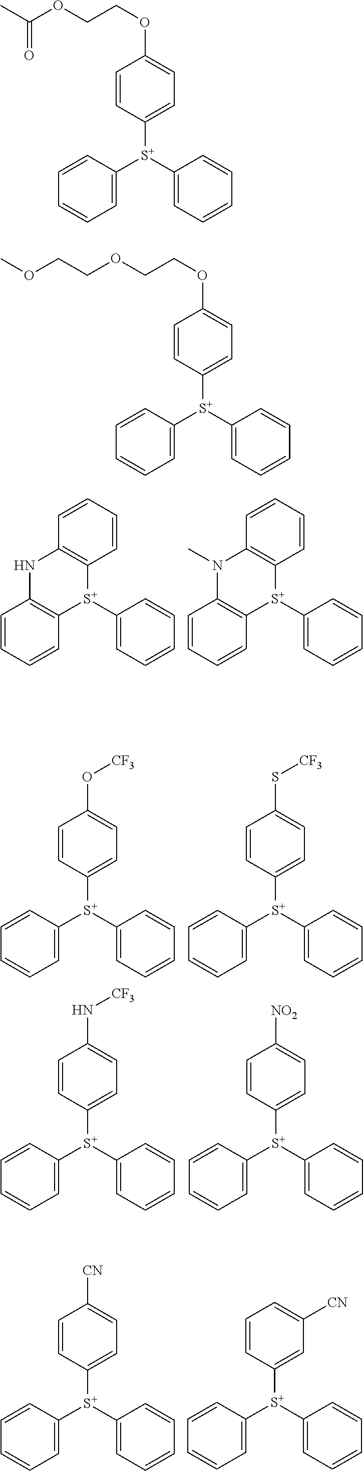

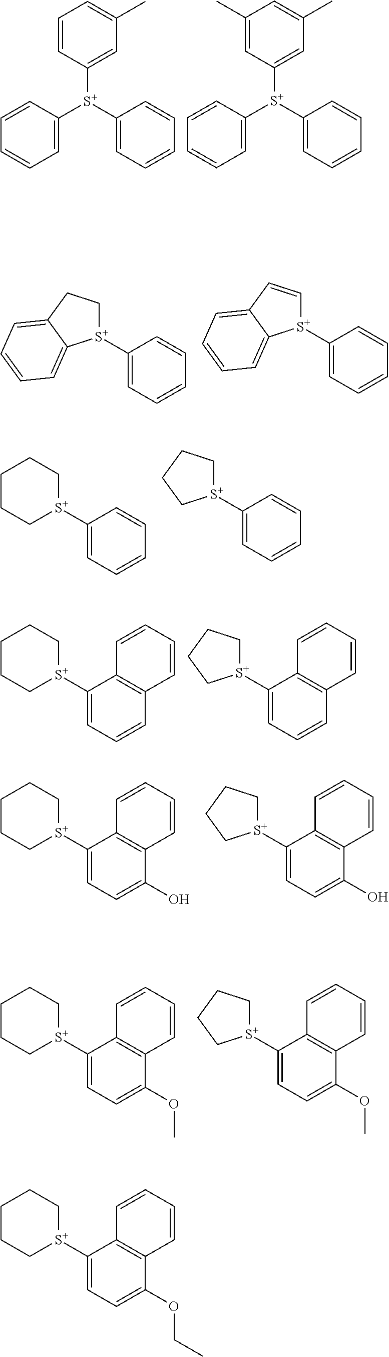

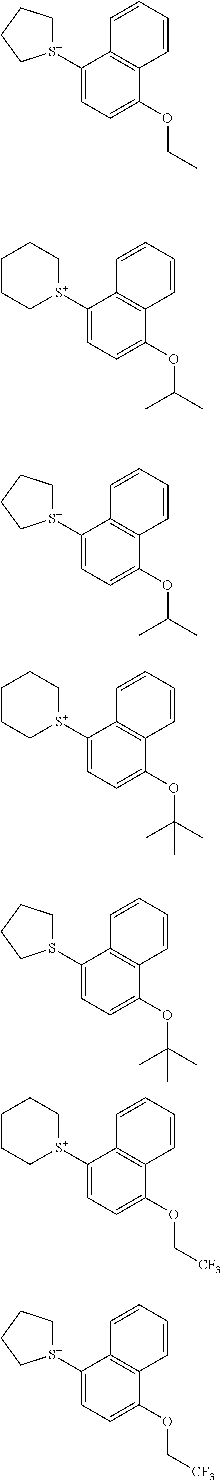

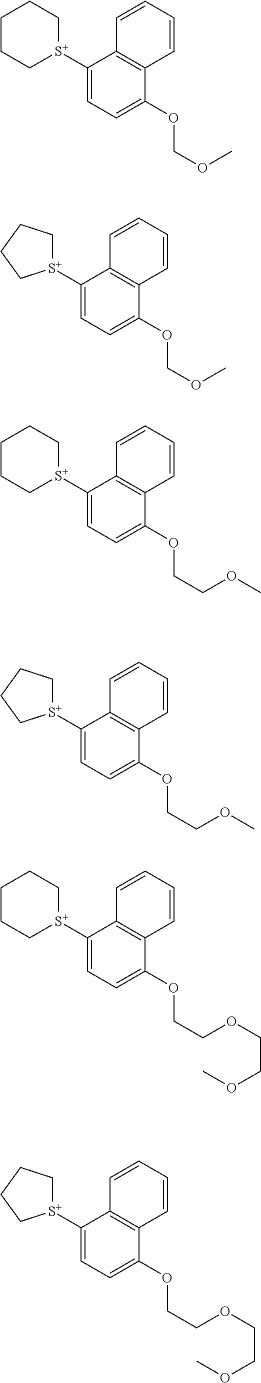 [SMILES: COCOc1ccc([S+]2CCCCC2)c2ccccc12 ; COCOc1ccc([S+]2CCCC2)c2ccccc12 ; COCCOc1ccc([S+]2CCCCC2)c2ccccc12 ; COCCOc1ccc([S+]2CCCC2)c2ccccc12 ; COCCOCCOc1ccc([S+]2CCCCC2)c2ccccc12 ; COCCOCCOc1ccc([S+]2CCCC2)c2ccccc12]

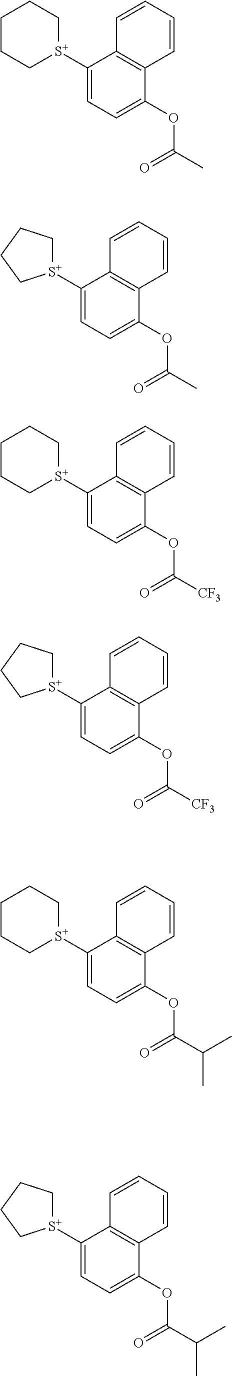 [SMILES: CC(=O)Oc1ccc([S+]2CCCCC2)c2ccccc12 ; CC(=O)Oc1ccc([S+]2CCCC2)c2ccccc12 ; O=C(Oc1ccc([S+]2CCCCC2)c2ccccc12)C(F)(F)F ; O=C(Oc1ccc([S+]2CCCC2)c2ccccc12)C(F)(F)F ; CC(C)C(=O)Oc1ccc([S+]2CCCCC2)c2ccccc12 ; CC(C)C(=O)Oc1ccc([S+]2CCCC2)c2ccccc12]

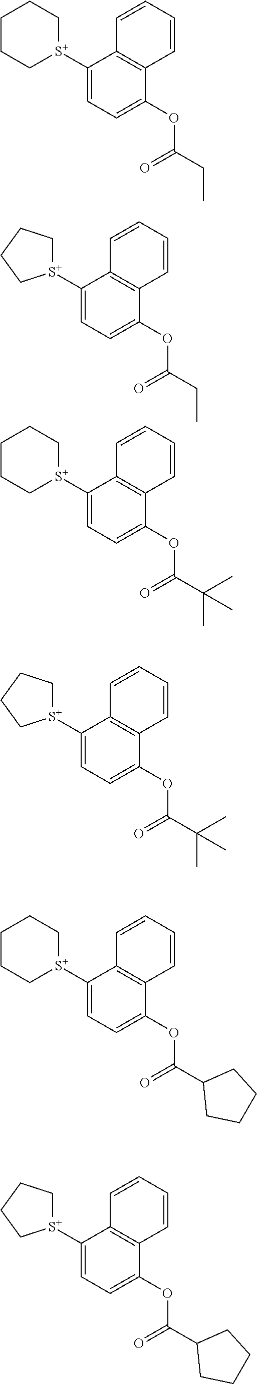 [SMILES: CCC(=O)Oc1ccc([S+]2CCCCC2)c2ccccc12 ; CCC(=O)Oc1ccc([S+]2CCCC2)c2ccccc12 ; CC(C)(C)C(=O)Oc1ccc([S+]2CCCCC2)c2ccccc12 ; CC(C)(C)C(=O)Oc1ccc([S+]2CCCC2)c2ccccc12 ; O=C(Oc1ccc([S+]2CCCCC2)c2ccccc12)C1CCCC1 ; O=C(Oc1ccc([S+]2CCCC2)c2ccccc12)C1CCCC1]

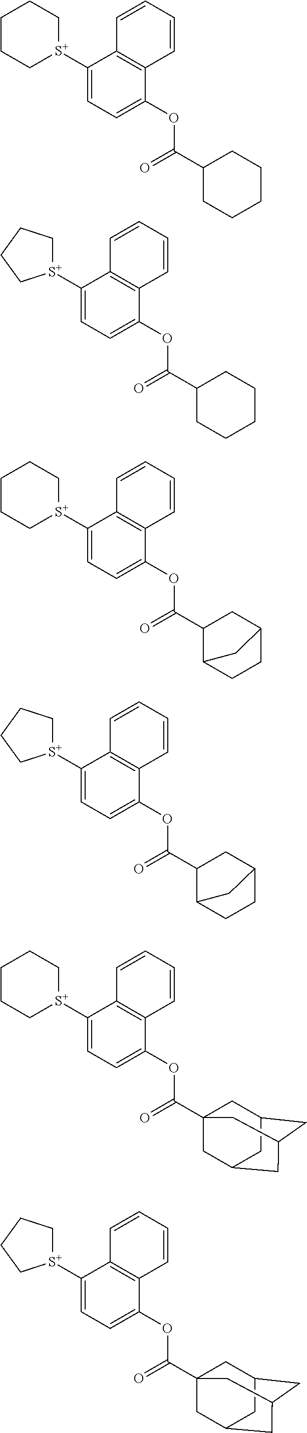 [SMILES: O=C(Oc1ccc([S+]2CCCCC2)c2ccccc12)C1CCCCC1 ; O=C(Oc1ccc([S+]2CCCC2)c2ccccc12)C1CCCCC1 ; O=C(Oc1ccc([S+]2CCCCC2)c2ccccc12)C1CC2CCC1C2 ; O=C(Oc1ccc([S+]2CCCC2)c2ccccc12)C1CC2CCC1C2 ; O=C(Oc1ccc([S+]2CCCCC2)c2ccccc12)C12CC3CC(CC(C3)C1)C2 ; O=C(Oc1ccc([S+]2CCCC2)c2ccccc12)C12CC3CC(CC(C3)C1)C2]

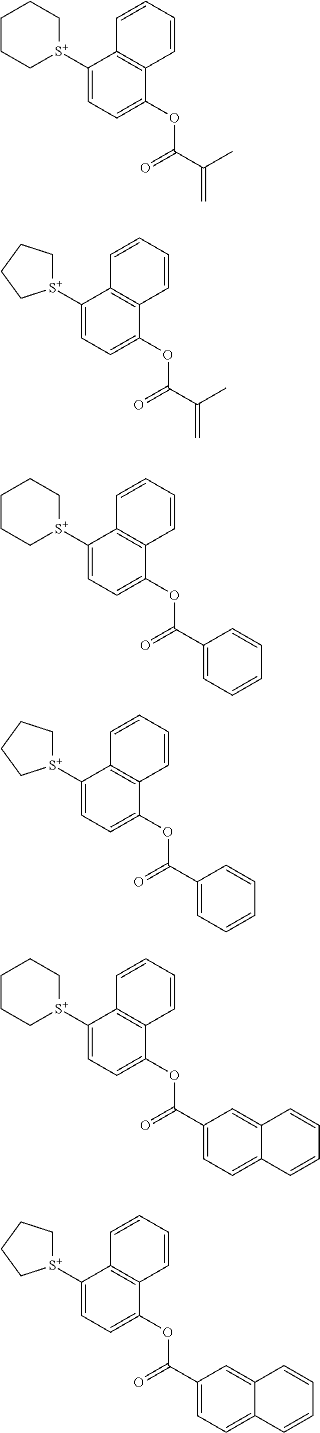 [SMILES: C=C(C)C(=O)Oc1ccc([S+]2CCCCC2)c2ccccc12 ; C=C(C)C(=O)Oc1ccc([S+]2CCCC2)c2ccccc12 ; O=C(Oc1ccc([S+]2CCCCC2)c2ccccc12)c1ccccc1 ; O=C(Oc1ccc([S+]2CCCC2)c2ccccc12)c1ccccc1 ; O=C(Oc1ccc([S+]2CCCCC2)c2ccccc12)c1ccc2ccccc2c1 ; O=C(Oc1ccc([S+]2CCCC2)c2ccccc12)c1ccc2ccccc2c1]

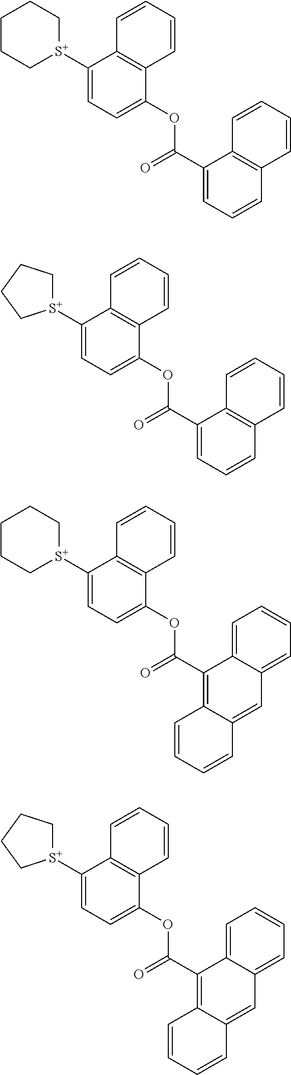 [SMILES: O=C(Oc1ccc([S+]2CCCCC2)c2ccccc12)c1cccc2ccccc12 ; O=C(Oc1ccc([S+]2CCCC2)c2ccccc12)c1cccc2ccccc12 ; O=C(Oc1ccc([S+]2CCCCC2)c2ccccc12)c1c2ccccc2cc2ccccc12 ; O=C(Oc1ccc([S+]2CCCC2)c2ccccc12)c1c2ccccc2cc2ccccc12]

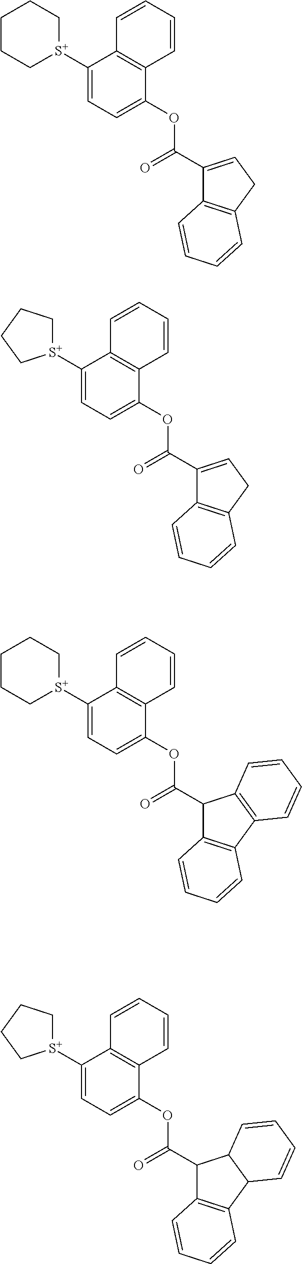 [SMILES: O=C(Oc1ccc([S+]2CCCCC2)c2ccccc12)C1=CCc2ccccc21 ; O=C(Oc1ccc([S+]2CCCC2)c2ccccc12)C1=CCc2ccccc21 ; O=C(Oc1ccc([S+]2CCCCC2)c2ccccc12)C1c2ccccc2-c2ccccc21 ; O=C(Oc1ccc([S+]2CCCC2)c2ccccc12)C1c2ccccc2C2C=CC=CC21]

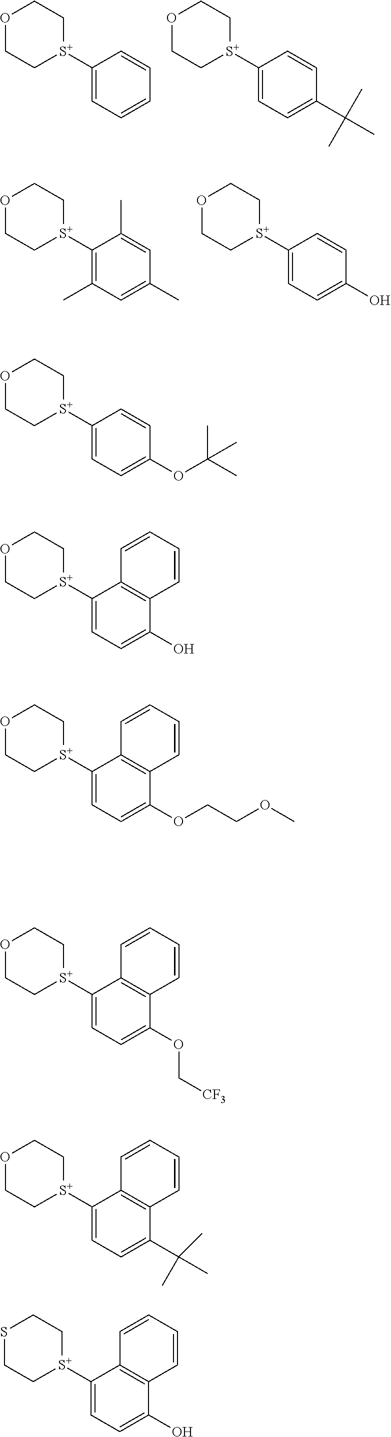

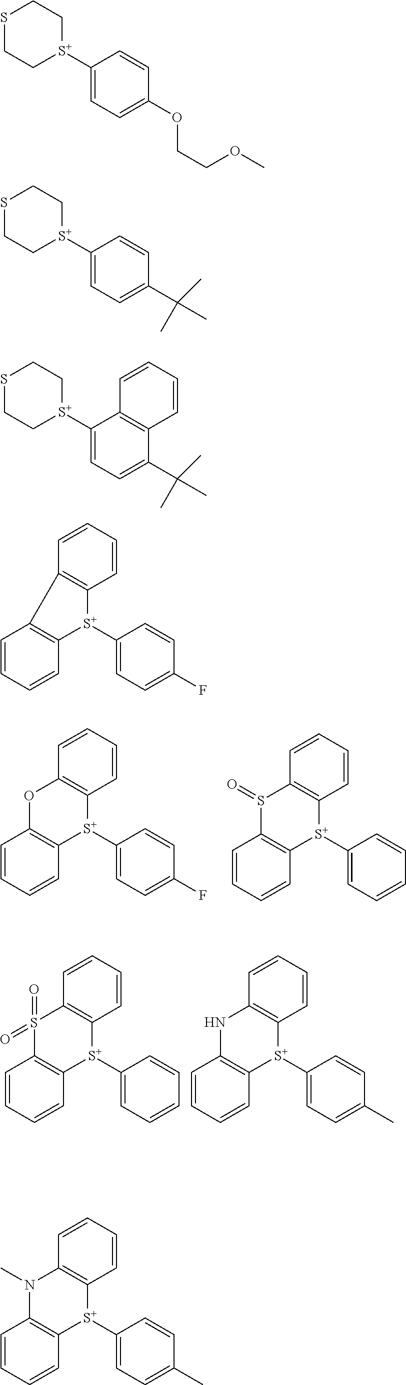

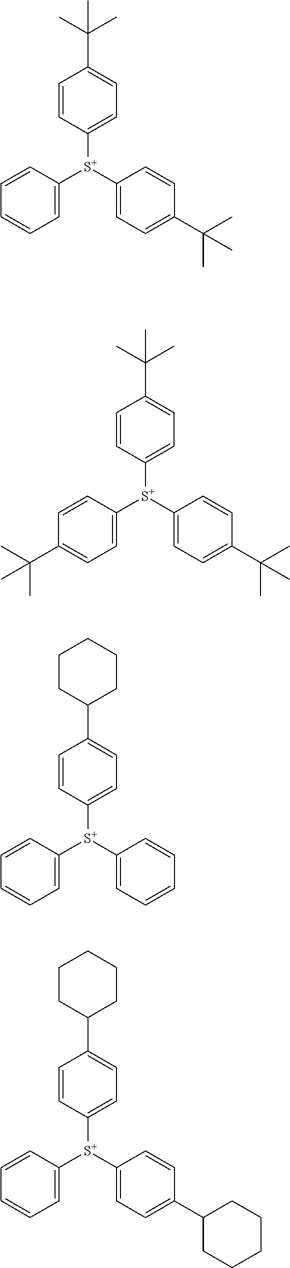

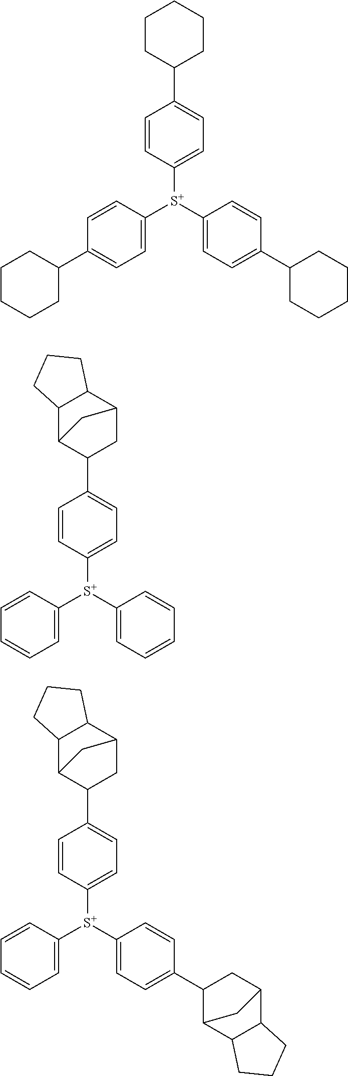 [SMILES: c1cc([S+](c2ccc(C3CCCCC3)cc2)c2ccc(C3CCCCC3)cc2)ccc1C1CCCCC1 ; c1ccc([S+](c2ccccc2)c2ccc(C3CC4CC3C3CCCC43)cc2)cc1 ; c1ccc([S+](c2ccc(C3CC4CC3C3CCCC43)cc2)c2ccc(C3CC4CC3C3CCCC43)cc2)cc1]

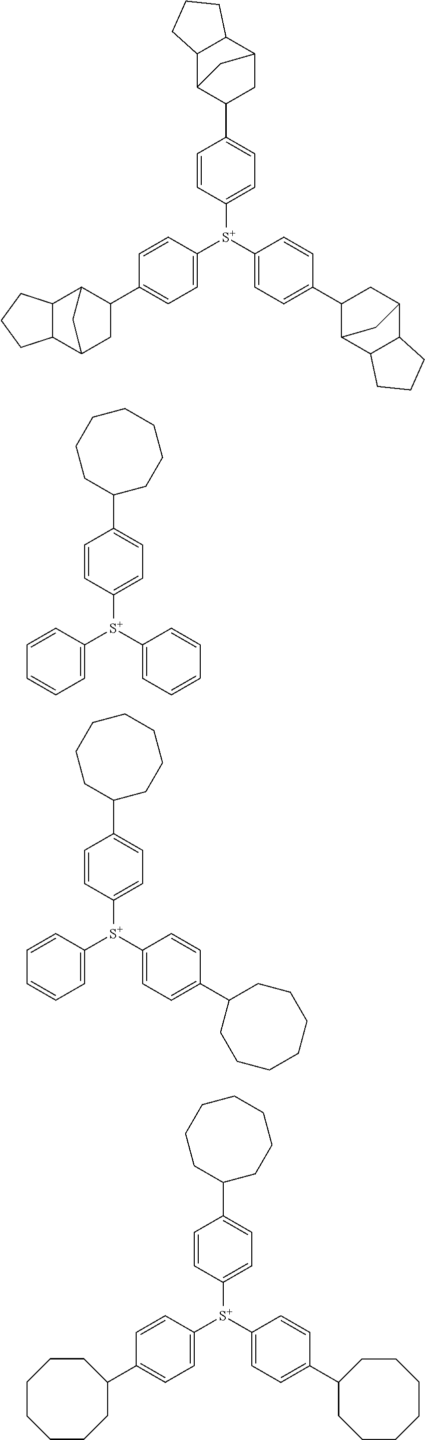 [SMILES: c1cc([S+](c2ccc(C3CC4CC3C3CCCC43)cc2)c2ccc(C3CC4CC3C3CCCC43)cc2)ccc1C1CC2CC1C1CCCC21 ; c1ccc([S+](c2ccccc2)c2ccc(C3CCCCCCC3)cc2)cc1 ; c1ccc([S+](c2ccc(C3CCCCCCC3)cc2)c2ccc(C3CCCCCCC3)cc2)cc1 ; c1cc([S+](c2ccc(C3CCCCCCC3)cc2)c2ccc(C3CCCCCCC3)cc2)ccc1C1CCCCCCC1]

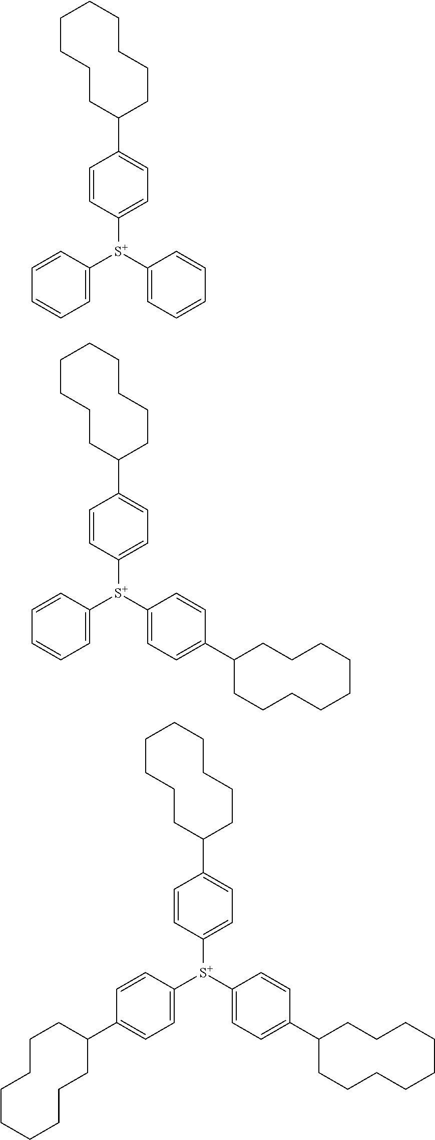 [SMILES: c1ccc([S+](c2ccccc2)c2ccc(C3CCCCCCCCC3)cc2)cc1 ; c1ccc([S+](c2ccc(C3CCCCCCCCC3)cc2)c2ccc(C3CCCCCCCCC3)cc2)cc1 ; c1cc([S+](c2ccc(C3CCCCCCCCC3)cc2)c2ccc(C3CCCCCCCCC3)cc2)ccc1C1CCCCCCCCC1]

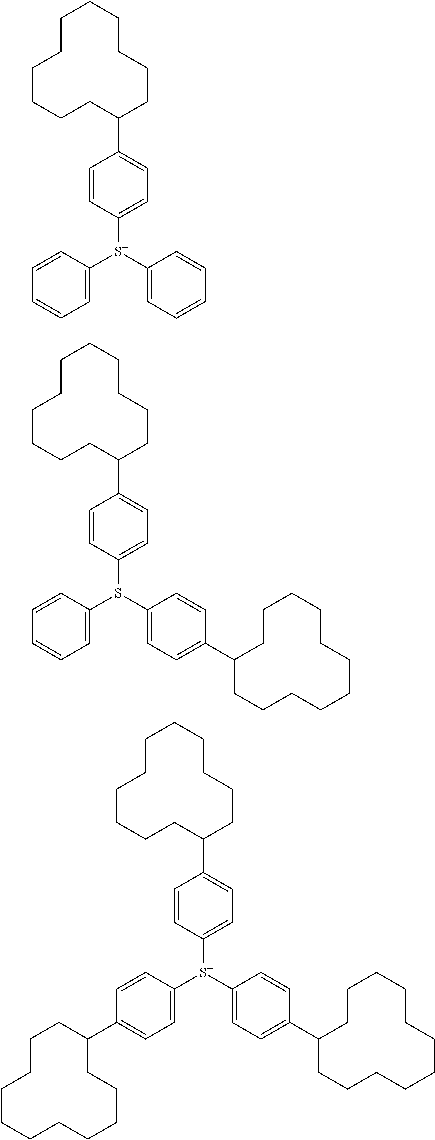 [SMILES: c1ccc([S+](c2ccccc2)c2ccc(C3CCCCCCCCCCC3)cc2)cc1 ; c1ccc([S+](c2ccc(C3CCCCCCCCCCC3)cc2)c2ccc(C3CCCCCCCCCCC3)cc2)cc1 ; c1cc([S+](c2ccc(C3CCCCCCCCCCC3)cc2)c2ccc(C3CCCCCCCCCCC3)cc2)ccc1C1CCCCCCCCCCC1]

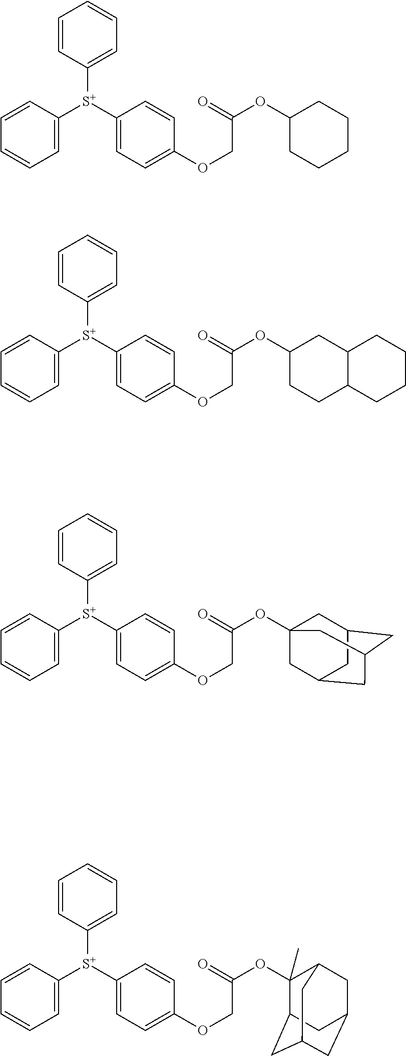 [SMILES: O=C(COc1ccc([S+](c2ccccc2)c2ccccc2)cc1)OC1CCCCC1 ; O=C(COc1ccc([S+](c2ccccc2)c2ccccc2)cc1)OC1CCC2CCCCC2C1 ; O=C(COc1ccc([S+](c2ccccc2)c2ccccc2)cc1)OC12CC3CC(CC(C3)C1)C2 ; CC1(OC(=O)COc2ccc([S+](c3ccccc3)c3ccccc3)cc2)C2CC3CC(C2)CC1C3]

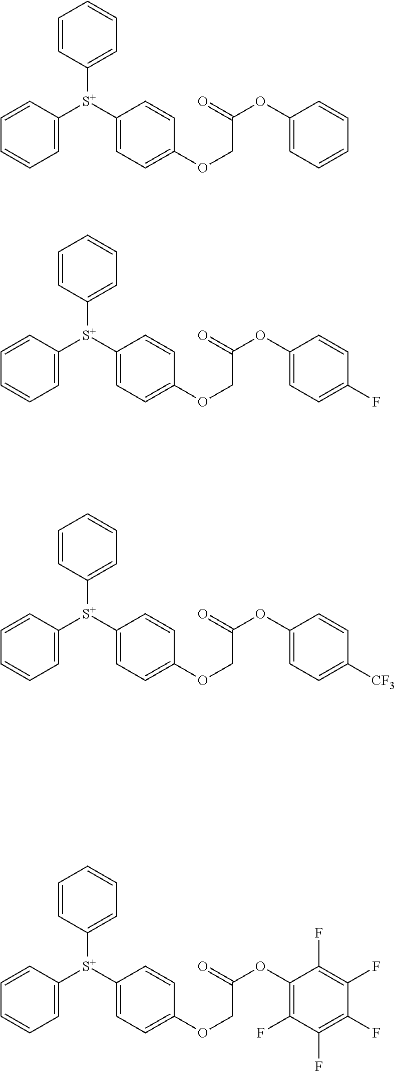 [SMILES: O=C(COc1ccc([S+](c2ccccc2)c2ccccc2)cc1)Oc1ccccc1 ; O=C(COc1ccc([S+](c2ccccc2)c2ccccc2)cc1)Oc1ccc(F)cc1 ; O=C(COc1ccc([S+](c2ccccc2)c2ccccc2)cc1)Oc1ccc(C(F)(F)F)cc1 ; O=C(COc1ccc([S+](c2ccccc2)c2ccccc2)cc1)Oc1c(F)c(F)c(F)c(F)c1F]

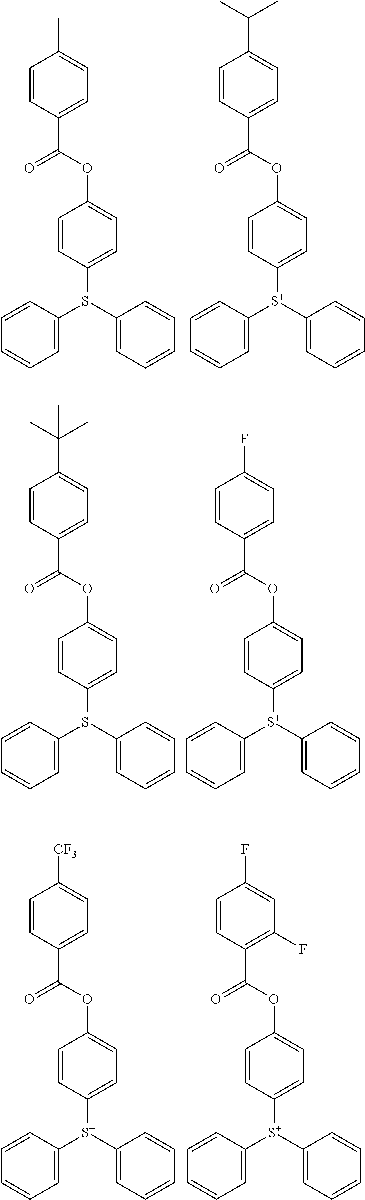 [SMILES: Cc1ccc(C(=O)Oc2ccc([S+](c3ccccc3)c3ccccc3)cc2)cc1 ; CC(C)c1ccc(C(=O)Oc2ccc([S+](c3ccccc3)c3ccccc3)cc2)cc1 ; CC(C)(C)c1ccc(C(=O)Oc2ccc([S+](c3ccccc3)c3ccccc3)cc2)cc1 ; O=C(Oc1ccc([S+](c2ccccc2)c2ccccc2)cc1)c1ccc(F)cc1 ; O=C(Oc1ccc([S+](c2ccccc2)c2ccccc2)cc1)c1ccc(C(F)(F)F)cc1 ; O=C(Oc1ccc([S+](c2ccccc2)c2ccccc2)cc1)c1ccc(F)cc1F]

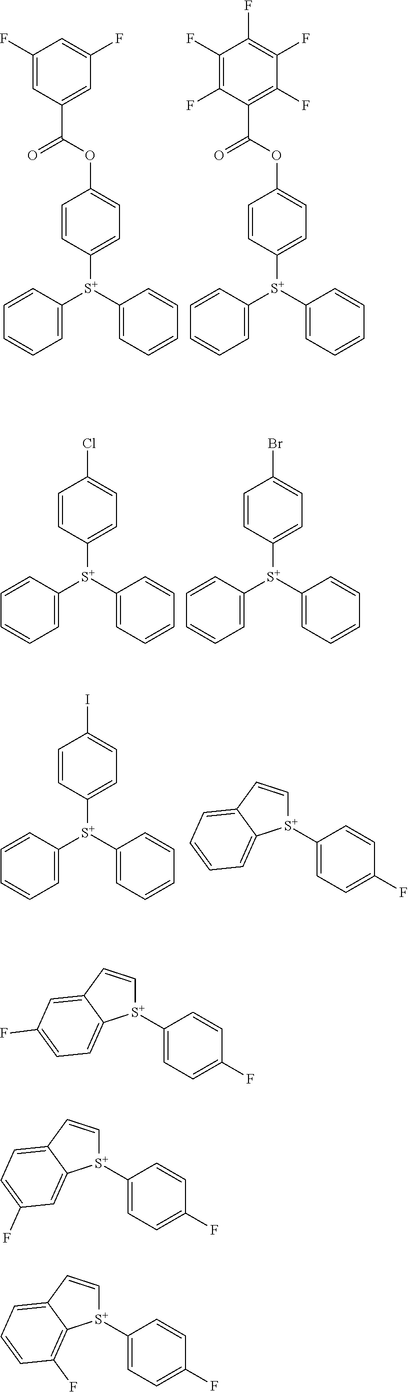

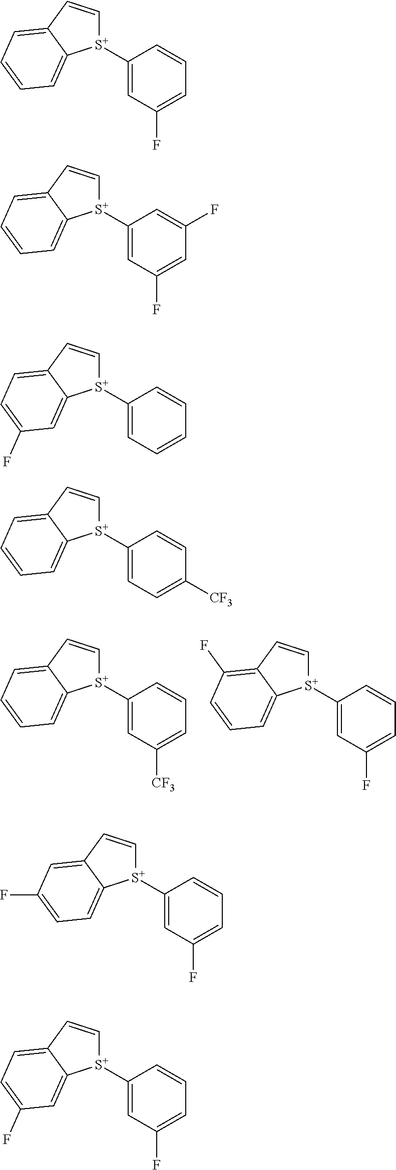

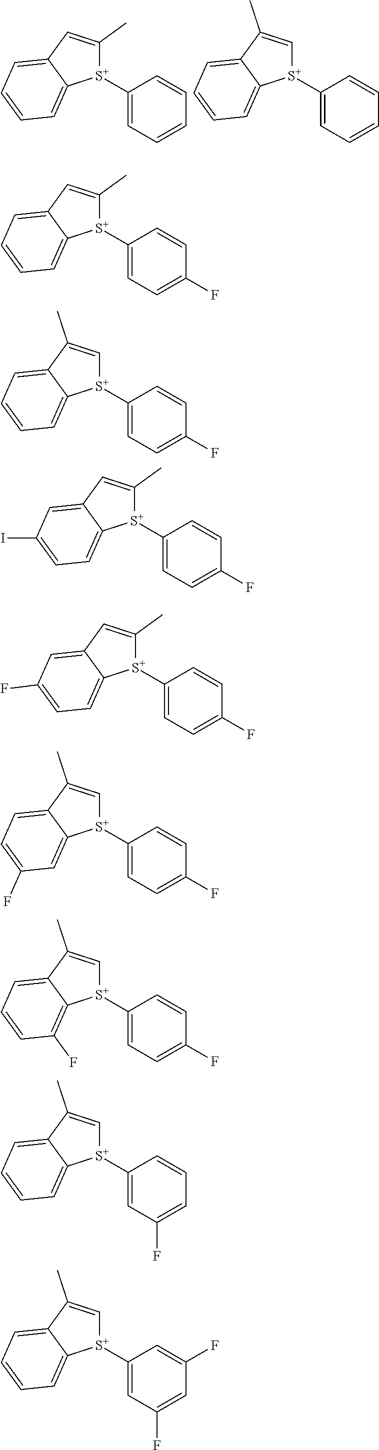

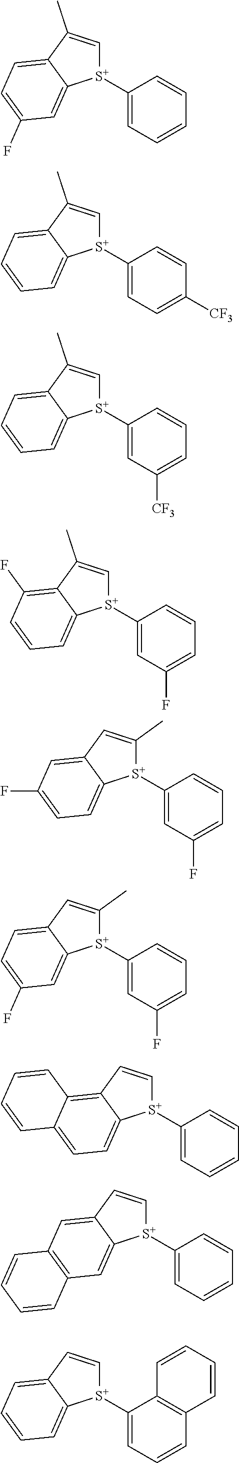

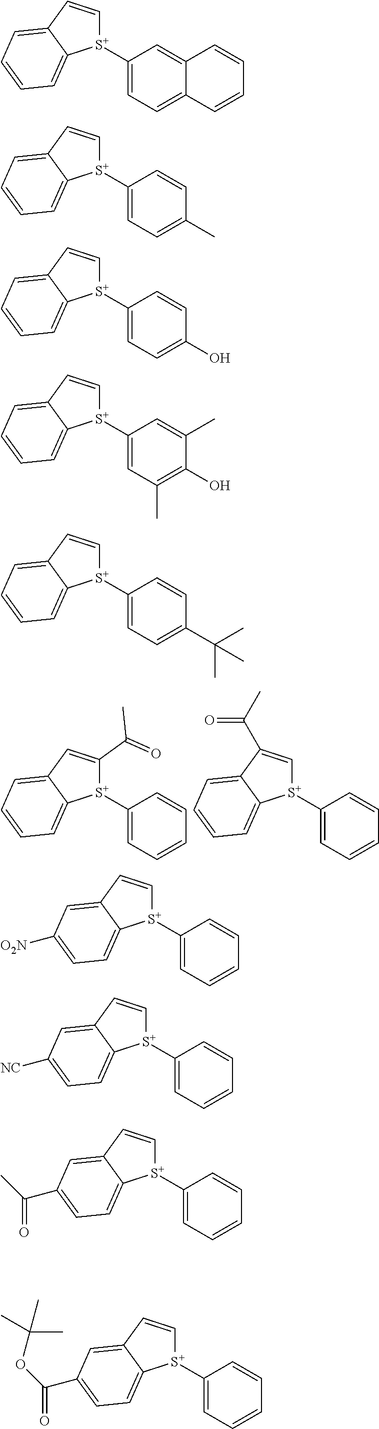

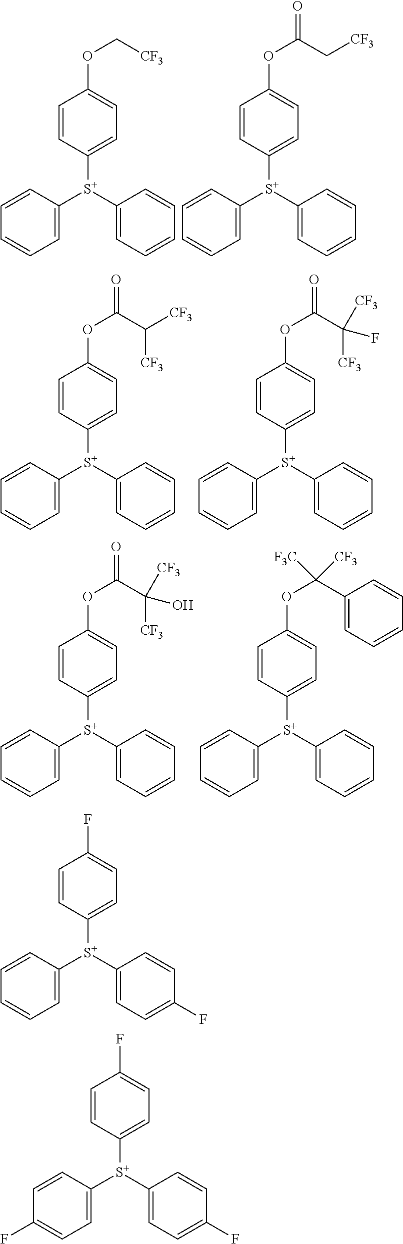

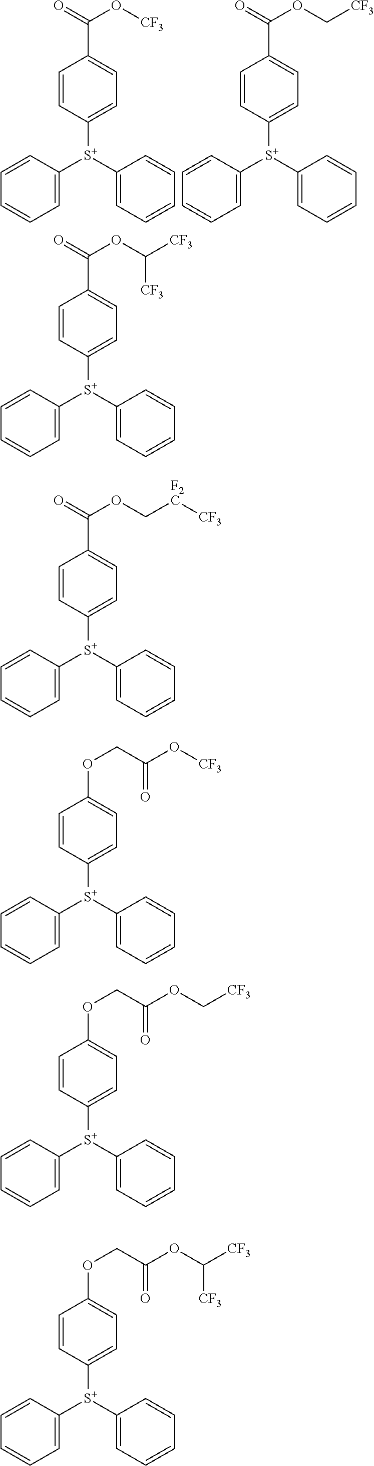

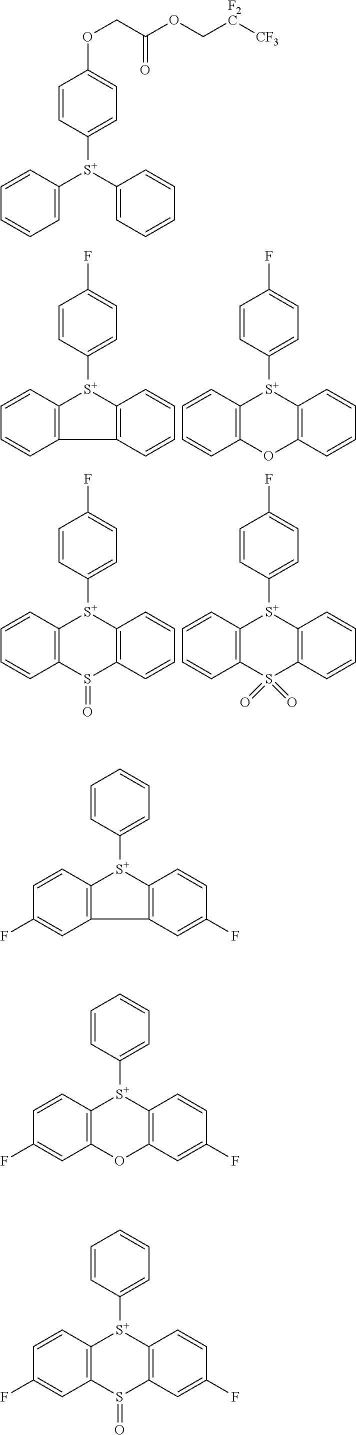

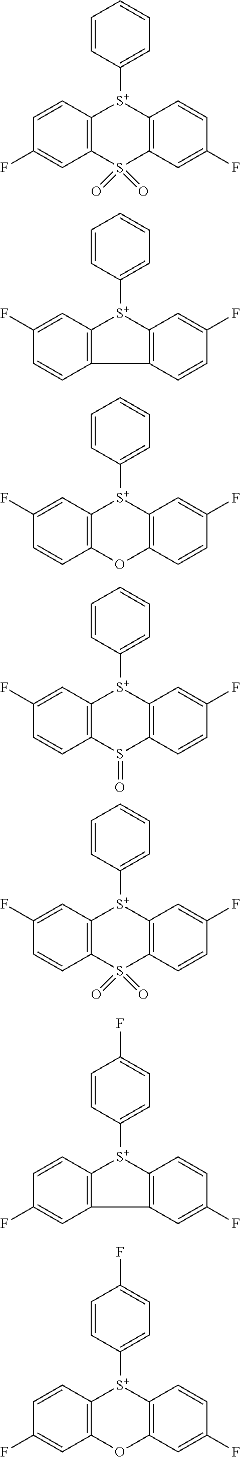

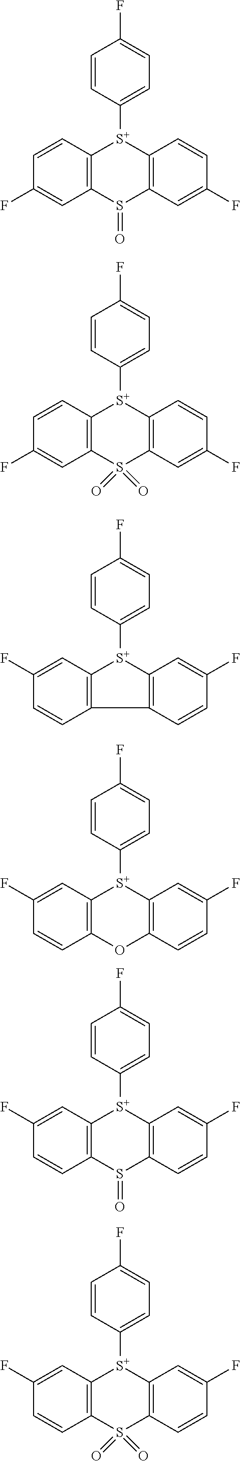 [SMILES: O=S1c2cc(F)ccc2[S+](c2ccc(F)cc2)c2ccc(F)cc21 ; O=S1(=O)c2cc(F)ccc2[S+](c2ccc(F)cc2)c2ccc(F)cc21 ; Fc1ccc(-[s+]2c3cc(F)ccc3c3ccc(F)cc32)cc1 ; Fc1ccc([S+]2c3cc(F)ccc3Oc3ccc(F)cc32)cc1 ; O=S1c2ccc(F)cc2[S+](c2ccc(F)cc2)c2cc(F)ccc21 ; O=S1(=O)c2ccc(F)cc2[S+](c2ccc(F)cc2)c2cc(F)ccc21]

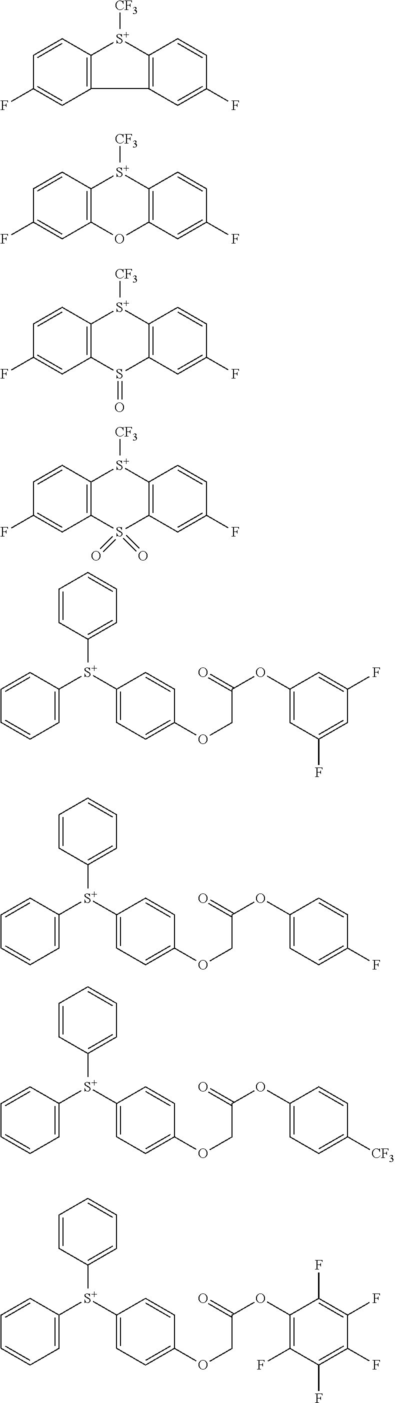

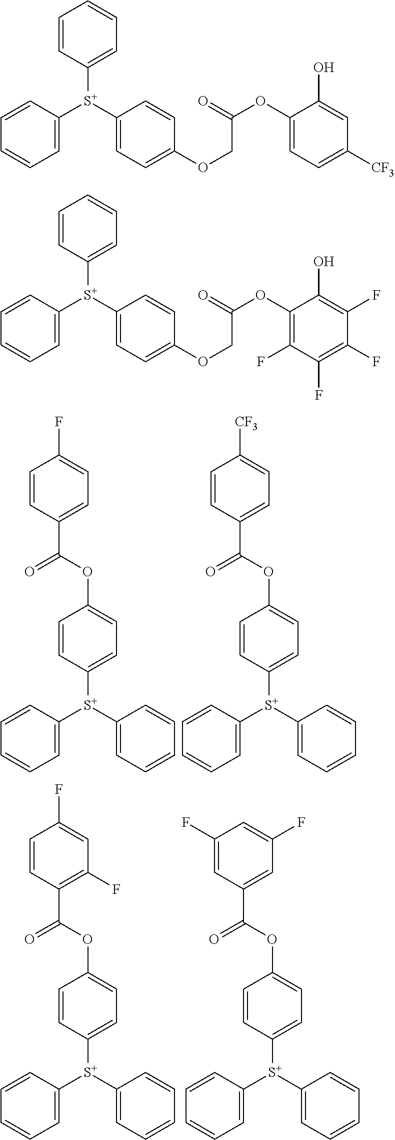 [SMILES: O=C(COc1ccc([S+](c2ccccc2)c2ccccc2)cc1)Oc1ccc(C(F)(F)F)cc1O ; O=C(COc1ccc([S+](c2ccccc2)c2ccccc2)cc1)Oc1c(O)c(F)c(F)c(F)c1F ; O=C(Oc1ccc([S+](c2ccccc2)c2ccccc2)cc1)c1ccc(F)cc1 ; O=C(Oc1ccc([S+](c2ccccc2)c2ccccc2)cc1)c1ccc(C(F)(F)F)cc1 ; O=C(Oc1ccc([S+](c2ccccc2)c2ccccc2)cc1)c1ccc(F)cc1F ; O=C(Oc1ccc([S+](c2ccccc2)c2ccccc2)cc1)c1cc(F)cc(F)c1]

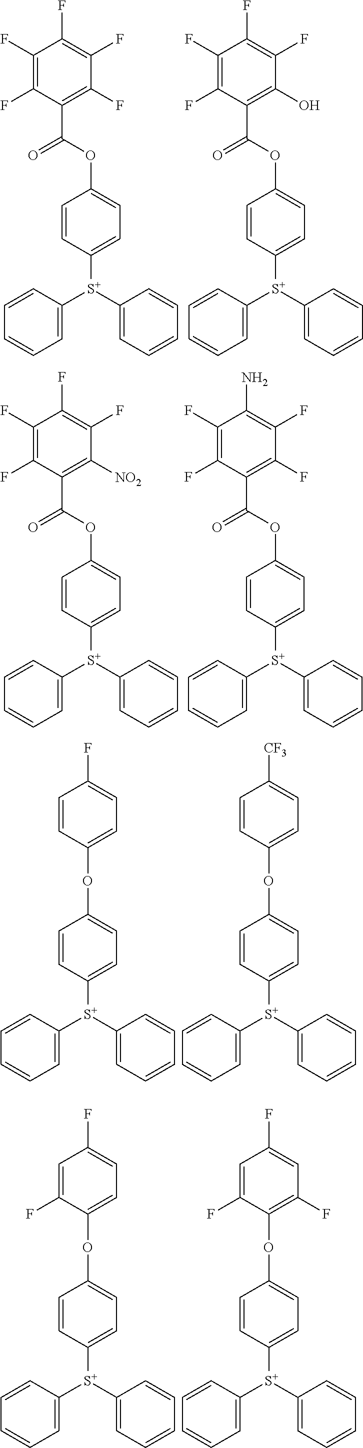

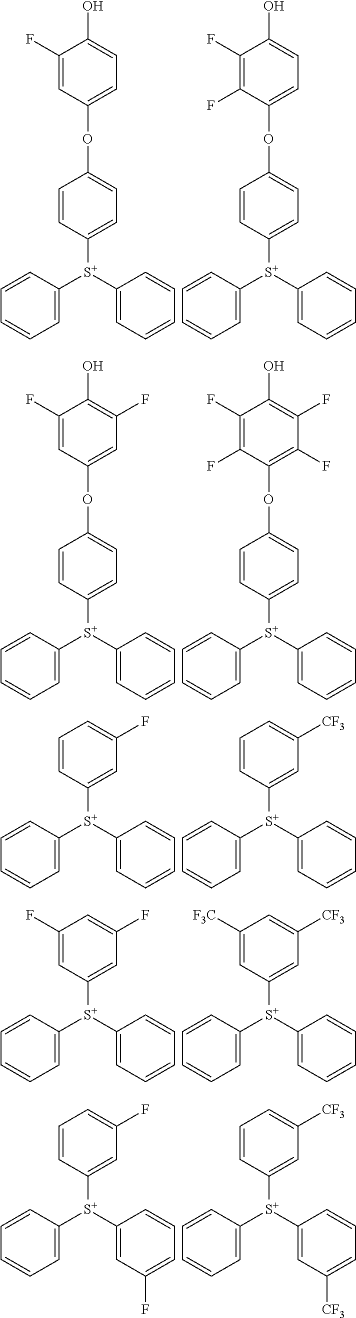

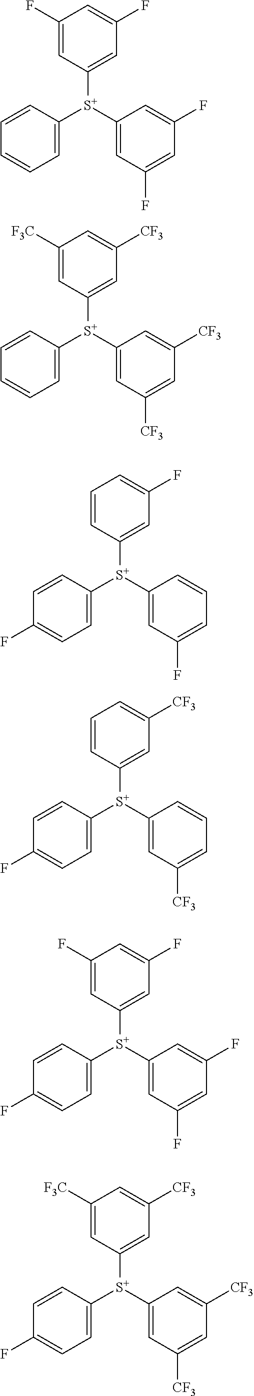 [SMILES: Fc1cc(F)cc([S+](c2ccccc2)c2cc(F)cc(F)c2)c1 ; FC(F)(F)c1cc([S+](c2ccccc2)c2cc(C(F)(F)F)cc(C(F)(F)F)c2)cc(C(F)(F)F)c1 ; Fc1ccc([S+](c2cccc(F)c2)c2cccc(F)c2)cc1 ; Fc1ccc([S+](c2cccc(C(F)(F)F)c2)c2cccc(C(F)(F)F)c2)cc1 ; Fc1ccc([S+](c2cc(F)cc(F)c2)c2cc(F)cc(F)c2)cc1 ; Fc1ccc([S+](c2cc(C(F)(F)F)cc(C(F)(F)F)c2)c2cc(C(F)(F)F)cc(C(F)(F)F)c2)cc1]

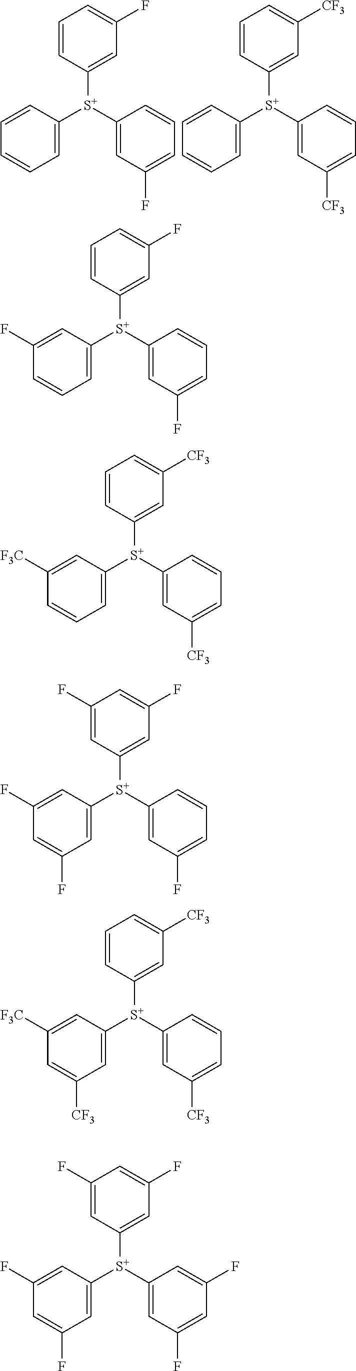

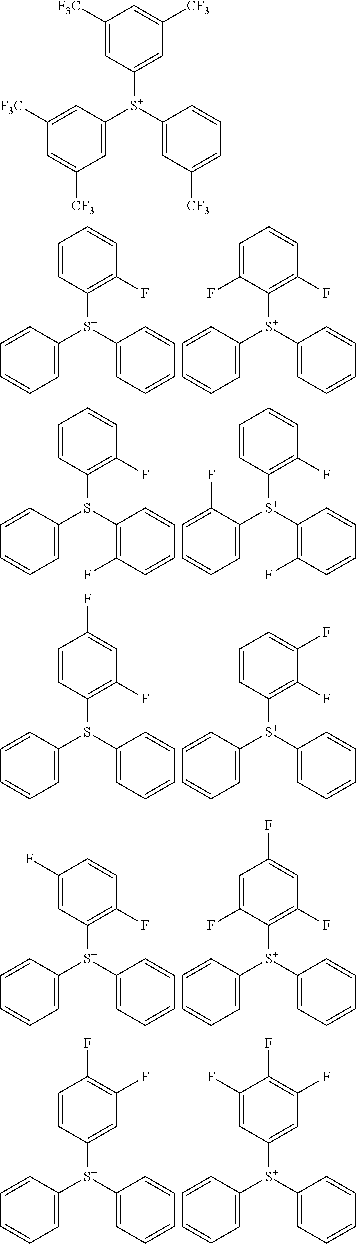

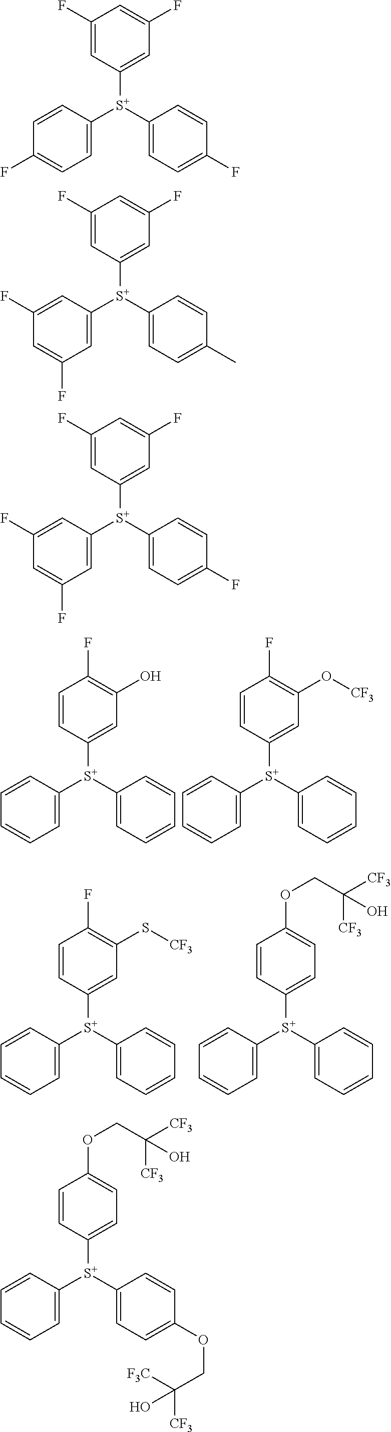

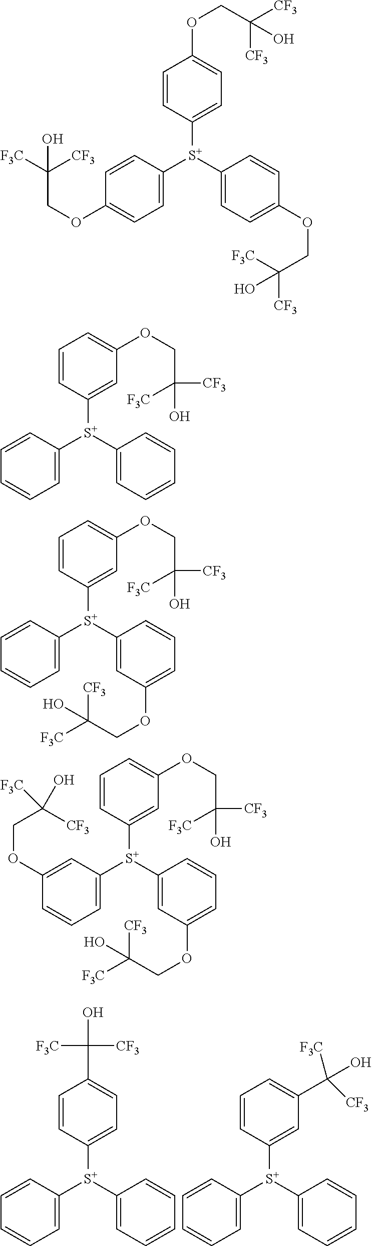 [SMILES: OC(COc1ccc([S+](c2ccc(OCC(O)(C(F)(F)F)C(F)(F)F)cc2)c2ccc(OCC(O)(C(F)(F)F)C(F)(F)F)cc2)cc1)(C(F)(F)F)C(F)(F)F ; OC(COc1cccc([S+](c2ccccc2)c2ccccc2)c1)(C(F)(F)F)C(F)(F)F ; OC(COc1cccc([S+](c2ccccc2)c2cccc(OCC(O)(C(F)(F)F)C(F)(F)F)c2)c1)(C(F)(F)F)C(F)(F)F ; OC(COc1cccc([S+](c2cccc(OCC(O)(C(F)(F)F)C(F)(F)F)c2)c2cccc(OCC(O)(C(F)(F)F)C(F)(F)F)c2)c1)(C(F)(F)F)C(F)(F)F ; OC(c1ccc([S+](c2ccccc2)c2ccccc2)cc1)(C(F)(F)F)C(F)(F)F ; OC(c1cccc([S+](c2ccccc2)c2ccccc2)c1)(C(F)(F)F)C(F)(F)F]

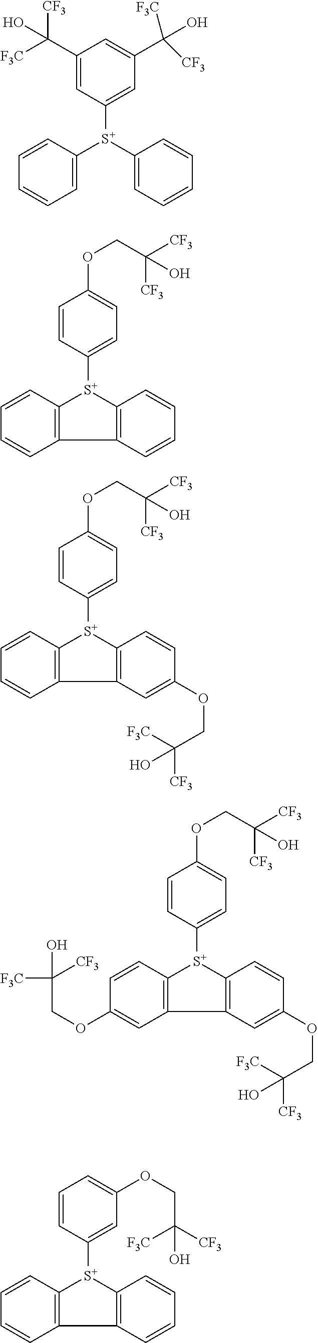 [SMILES: OC(c1cc([S+](c2ccccc2)c2ccccc2)cc(C(O)(C(F)(F)F)C(F)(F)F)c1)(C(F)(F)F)C(F)(F)F ; OC(COc1ccc(-[s+]2c3ccccc3c3ccccc32)cc1)(C(F)(F)F)C(F)(F)F ; OC(COc1ccc(-[s+]2c3ccccc3c3cc(OCC(O)(C(F)(F)F)C(F)(F)F)ccc32)cc1)(C(F)(F)F)C(F)(F)F ; OC(COc1ccc(-[s+]2c3ccc(OCC(O)(C(F)(F)F)C(F)(F)F)cc3c3cc(OCC(O)(C(F)(F)F)C(F)(F)F)ccc32)cc1)(C(F)(F)F)C(F)(F)F ; OC(COc1cccc(-[s+]2c3ccccc3c3ccccc32)c1)(C(F)(F)F)C(F)(F)F]

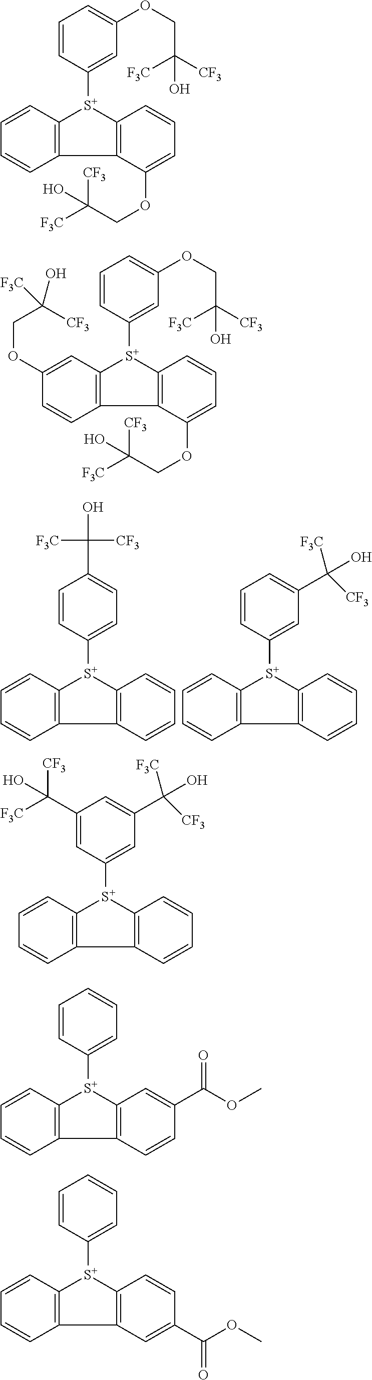

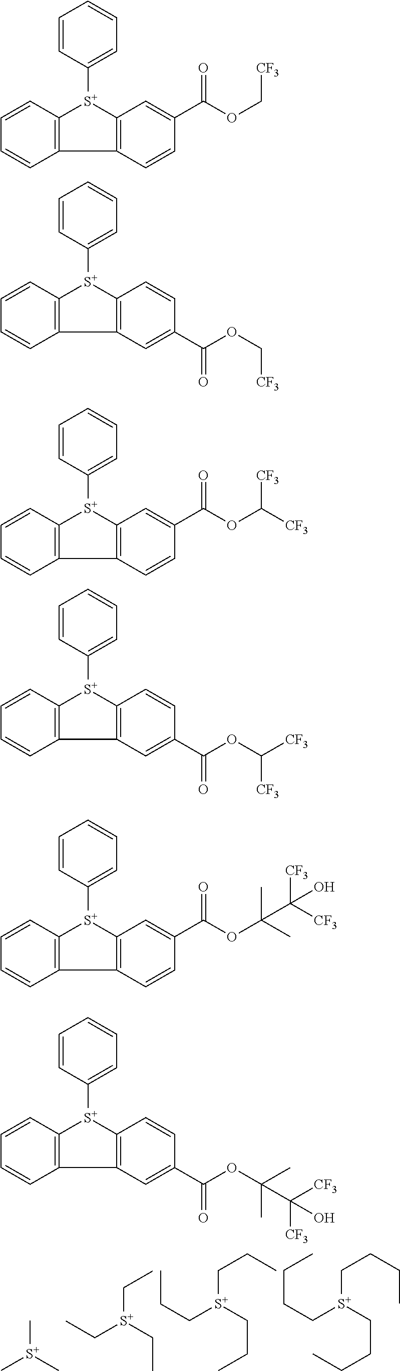

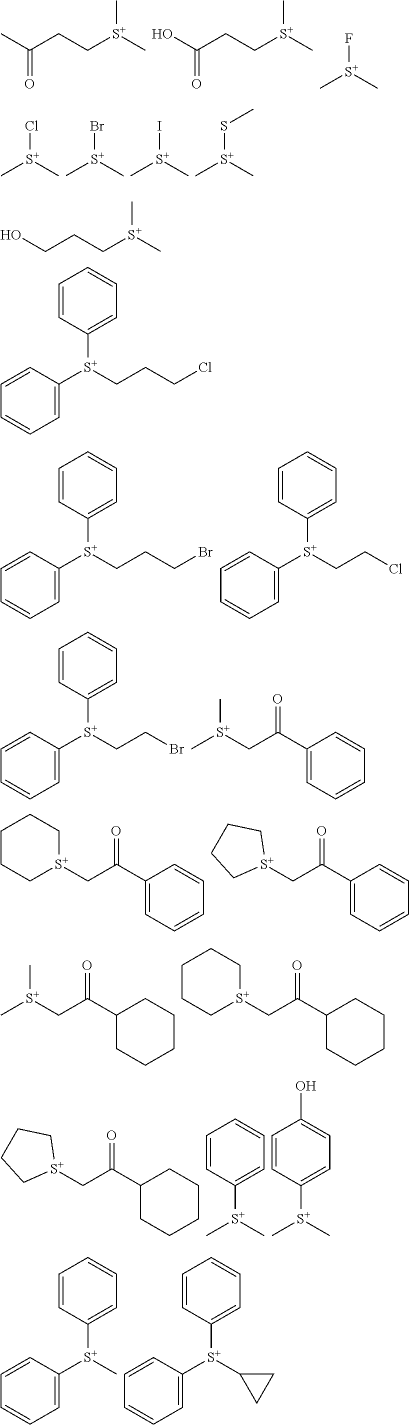

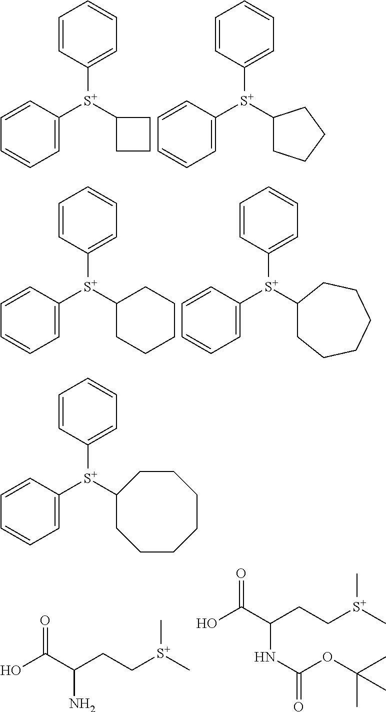

Examples of the iodonium cation represented by the formula (cation-2) include the following, but are not limited thereto.

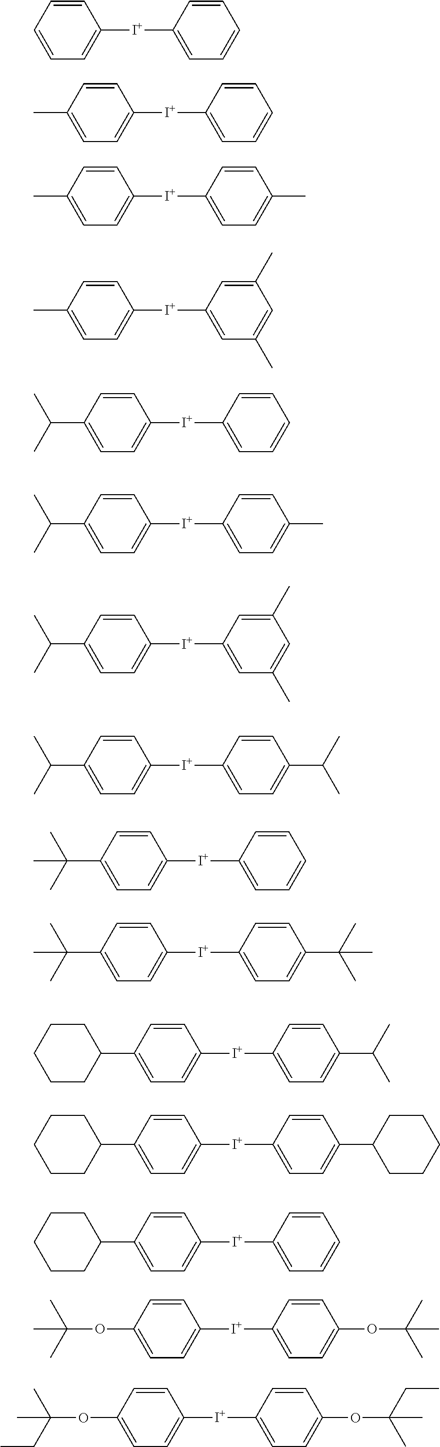

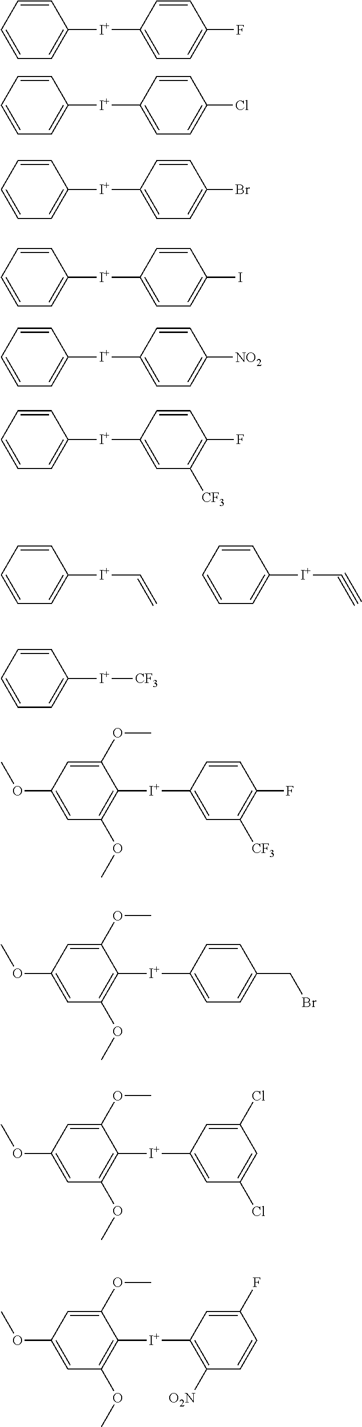

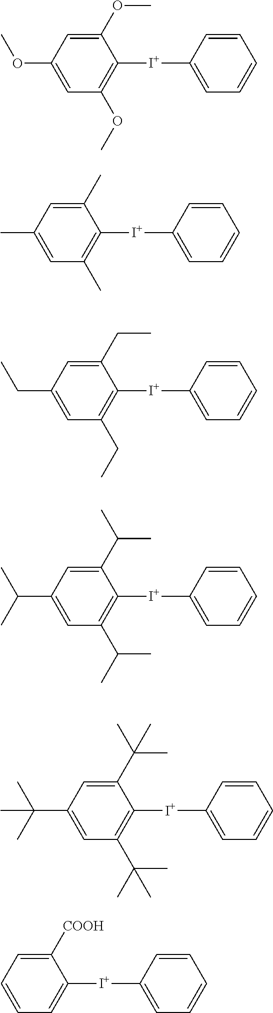 [SMILES: COc1cc(OC)c([I+]c2ccccc2)c(OC)c1 ; Cc1cc(C)c([I+]c2ccccc2)c(C)c1 ; CCc1cc(CC)c([I+]c2ccccc2)c(CC)c1 ; CC(C)c1cc(C(C)C)c([I+]c2ccccc2)c(C(C)C)c1 ; CC(C)(C)c1cc(C(C)(C)C)c([I+]c2ccccc2)c(C(C)(C)C)c1 ; O=C(O)c1ccccc1[I+]c1ccccc1]

Examples of specific structures of the repeating units represented by the formulae (B-1) to (B-4) include any combination of the above anions and cations.

The repeating unit B is preferably the repeating unit B2, B3, or B4 from the viewpoint of inhibition of the acid diffusion. The repeating units B2 and B4 are further preferable from the viewpoint of the acid strength of the generated acid, and the repeating unit B2 is more preferable from the viewpoint of the solvent solubility.

The characteristic of the inventive polymer is to have repeating units including: the repeating unit A having an acid-labile group having a vinyl aromatic unit as a polymerizable group; and the repeating unit B to generate an acid by light exposure. It is considered that the base polymer having the repeating unit to generate an acid by light-exposure can inhibit excessive acid diffusion, particularly when the anion bound type, in which the acid generated after light exposure is bonded to the main chain of the base polymer, is employed, and secondary electrons generated at the sensitizer moiety do not diffuse to contribute to the cation decomposition. Meanwhile, the repeating unit having an acid-labile group and having a vinyl aromatic unit as a polymerizable group contributes to the change in solubility in the developer in the deprotection reaction after the light exposure. The aromatic carboxylic acid generated after the deprotection reaction has higher acidity than an aliphatic carboxylic acid, and therefore, has a high affinity with alkaline developers, so that the aromatic carboxylic acid is removed efficiently when the exposed portion is subjected to alkaline development. In addition, since a repeating unit that generates an acid by exposure to light has a salt structure, the glass transition temperature (Tg) of the polymer tends to be low, but the rigidity of the polymer main chain is improved by introducing the repeating unit having an acid-labile group containing a vinyl aromatic unit as a polymerizable group. By the synergistic effect of these repeating units, higher sensitivity, higher contrast, and furthermore, suppression of acid diffusion can be achieved at the same time, and the LWR of line patterns and the CDU of hole patterns can be reduced. Moreover, a pattern excellent in etching resistance can be formed. Therefore, the inventive polymer is suitable as a positive resist material.

[Repeating Units a1 and a2]

The inventive polymer further contains besides the repeating unit represented by the formula (A-1) at least one selected from: a repeating unit represented by the following formula (a-1) (hereinafter, also referred to as a repeating unit a1); and a repeating unit represented by the following formula (a-2) (hereinafter, also referred to as a repeating unit a2).

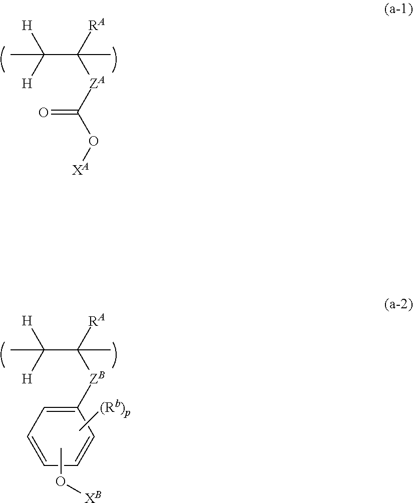

In the formulae (a-1) and (a-2), R^{A} is as defined above. Z^{A} represents a single bond, a phenylene group, a naphthylene group, or (main chain) —C(═O)—O—Z^{A1}, and Z^{A1} represents a linear, branched, or cyclic alkanediyl group having 1 to 10 carbon atoms, or a phenylene group or a naphthylene group optionally having a hydroxy group, an ether bond, an ester bond, or a lactone ring. Z^{B} represents a single bond or (main chain) —C(═O)—O—. R^{b} represents a linear, branched, or cyclic hydrocarbyl group having 1 to 20 carbon atoms and optionally having a heteroatom. “p” represents an integer of 0 to 4. X^{A} and X^{B} each independently represent an acid-labile group.

In the formulae (a-1) and (a-2), examples of the acid-labile group represented by X^{A} and X^{B} include groups disclosed in JP 2013-080033 A and JP 2013-083821 A.

Typical examples of the acid-labile group include groups represented by the following formulae (AL-1) to (AL-3).

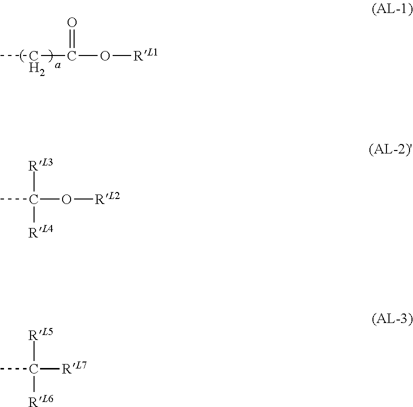

In the formulae, a broken line represents an attachment point.

In the formulae (AL-1) and (AL-2), R′^{L1} and R′^{L2} each independently represent a saturated hydrocarbyl group having 1 to 40 carbon atoms and optionally having a heteroatom such as an oxygen atom, a sulfur atom, a nitrogen atom, and a fluorine atom. The saturated hydrocarbyl group may be any of linear, branched, and cyclic groups. The saturated hydrocarbyl group preferably has 1 to 20 carbon atoms.

In the formula (AL-1), “a” represents an integer of 0 to 10, preferably an integer of 1 to 5.

In the formula (AL-2), R′^{L3} and R′^{L4} each independently represent a hydrogen atom or a saturated hydrocarbyl group having 1 to 20 carbon atoms and optionally having a heteroatom such as an oxygen atom, a sulfur atom, a nitrogen atom, and a fluorine atom. The saturated hydrocarbyl group may be any of linear, branched, and cyclic groups. Any two of R′^{L2}, R′^{L3}, and R′^{L4} are optionally bonded to each other to form a ring having 3 to 20 carbon atoms together with the carbon atom or together with the carbon atom and the oxygen atom to which these two groups are bonded. The ring preferably has 4 to 16 carbon atoms, and is particularly preferably an aliphatic ring.

In the formula (AL-3), R′^{L3}, R′^{L6}, and R′^{L7} each independently represent a saturated hydrocarbyl group having 1 to 20 carbon atoms and optionally having a heteroatom such as an oxygen atom, a sulfur atom, a nitrogen atom, and a fluorine atom. The hydrocarbyl group may be any of linear, branched, and cyclic groups. Any two of R′^{L3}, R′^{L6}, and R′^{L7} are optionally bonded to each other to form a ring having 3 to 20 carbon atoms together with the carbon atom to which these two groups are bonded. The ring preferably has 4 to 16 carbon atoms, and is particularly preferably an aliphatic ring.

Examples of the repeating unit a1 include the following repeating units, but the repeating unit a1 is not limited thereto. In the following formulae, R^{A} and X^{A} are as defined above.

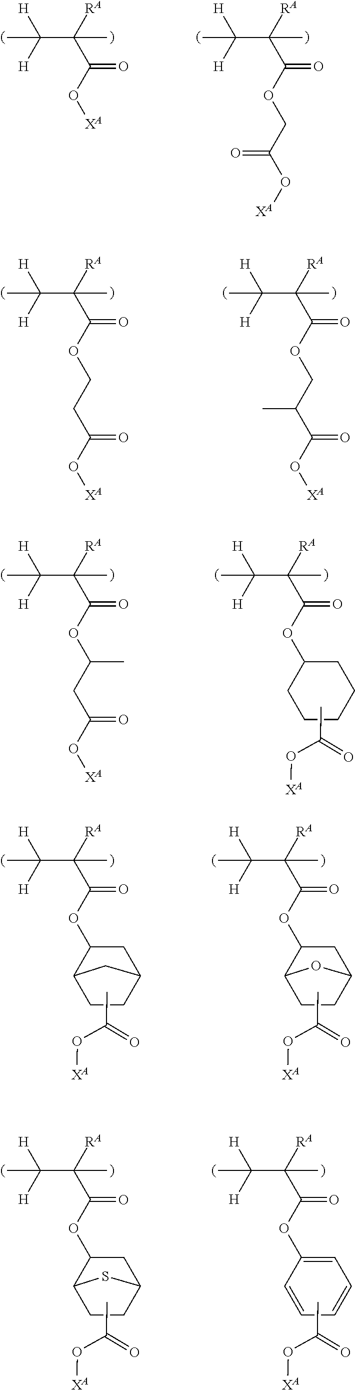

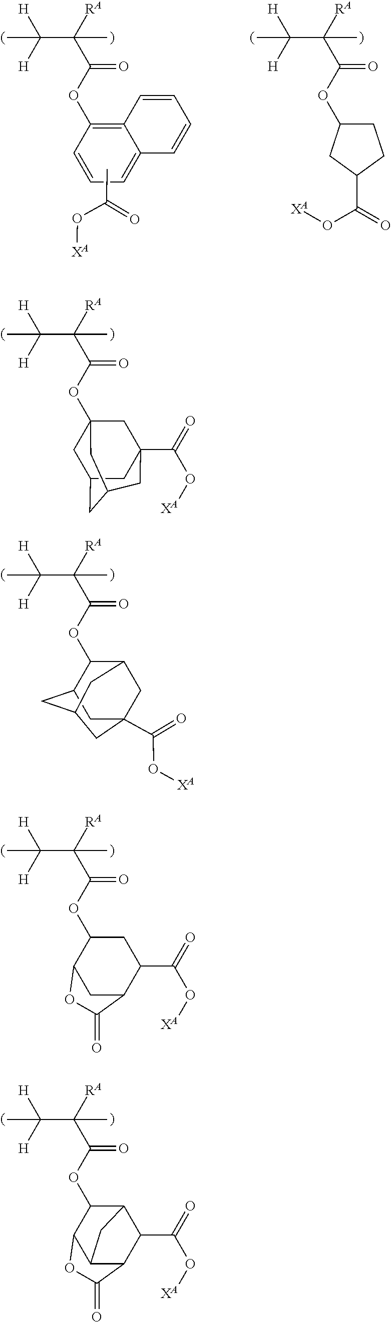

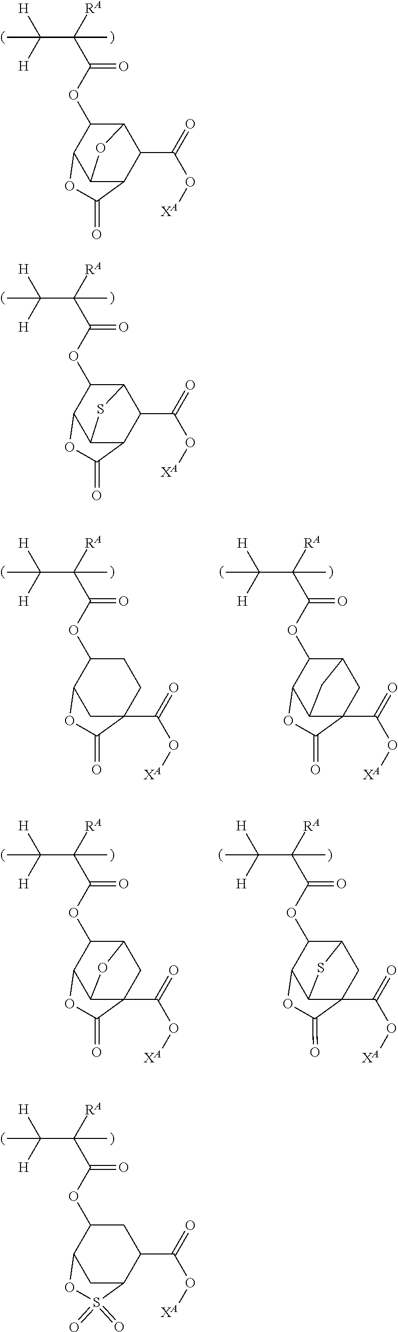

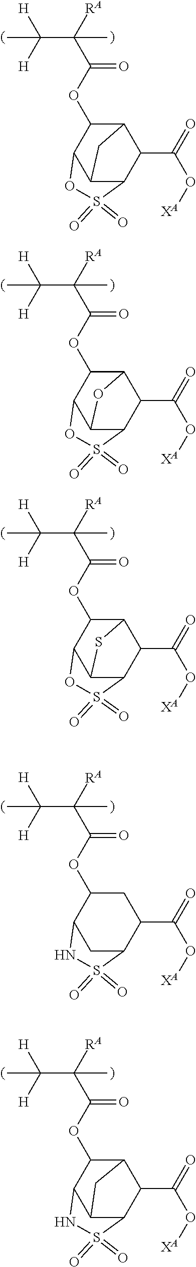

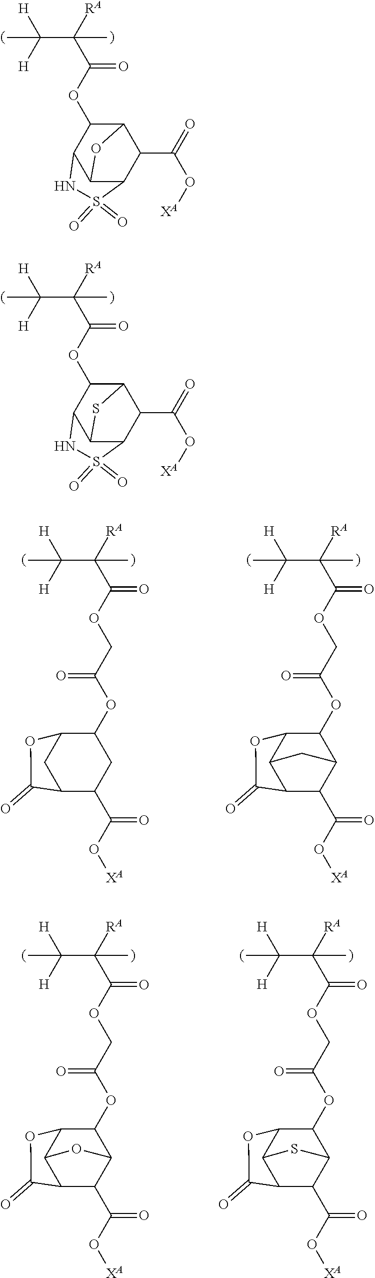

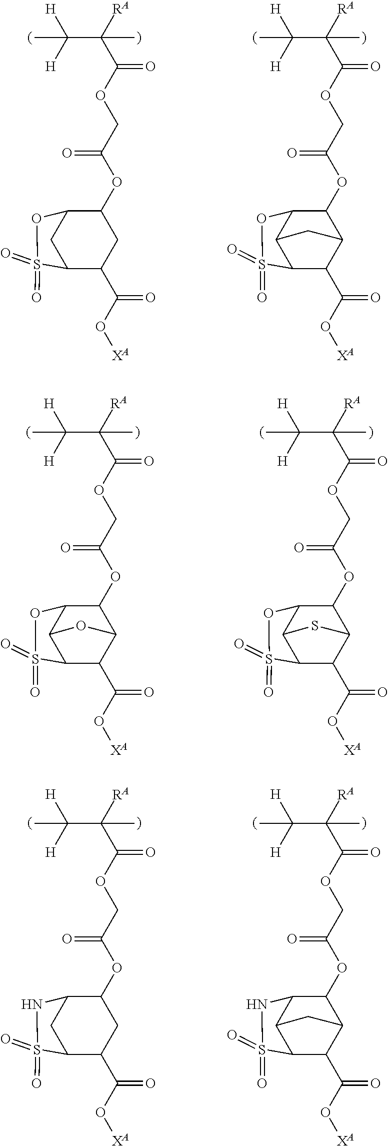

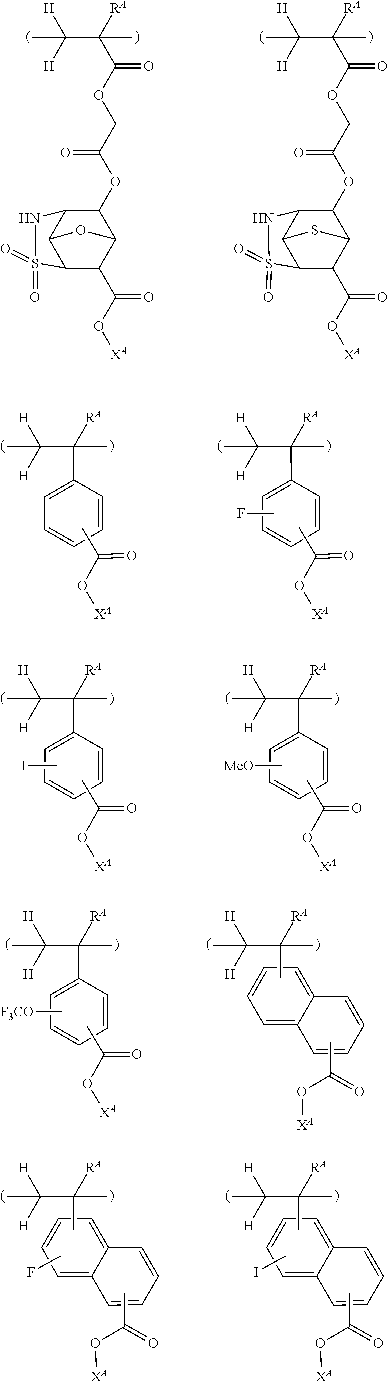

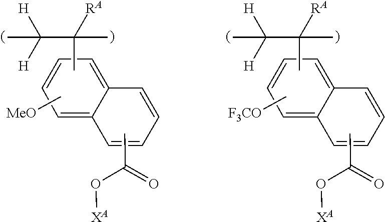

Examples of the repeating unit a2 include the following repeating units, but are not limited thereto. In the following formulae, R^{A} and X^{B} are as defined above.

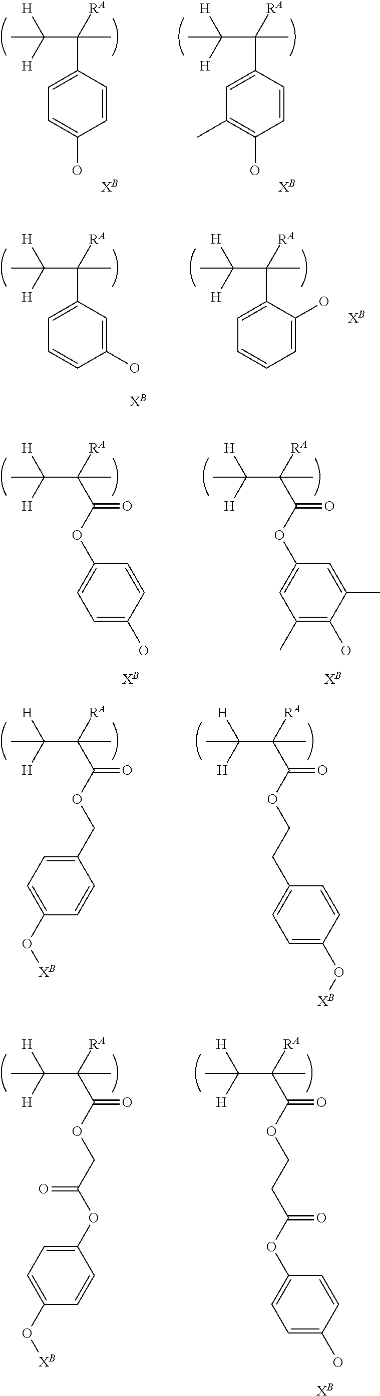

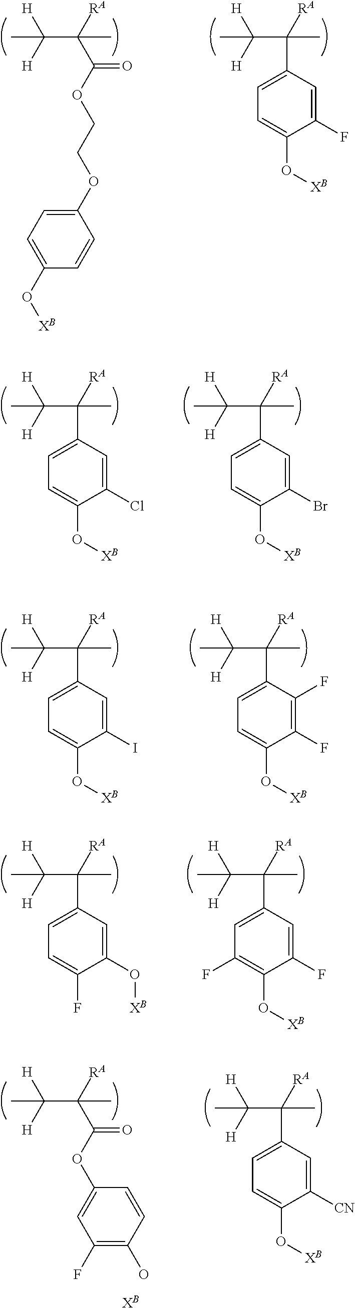

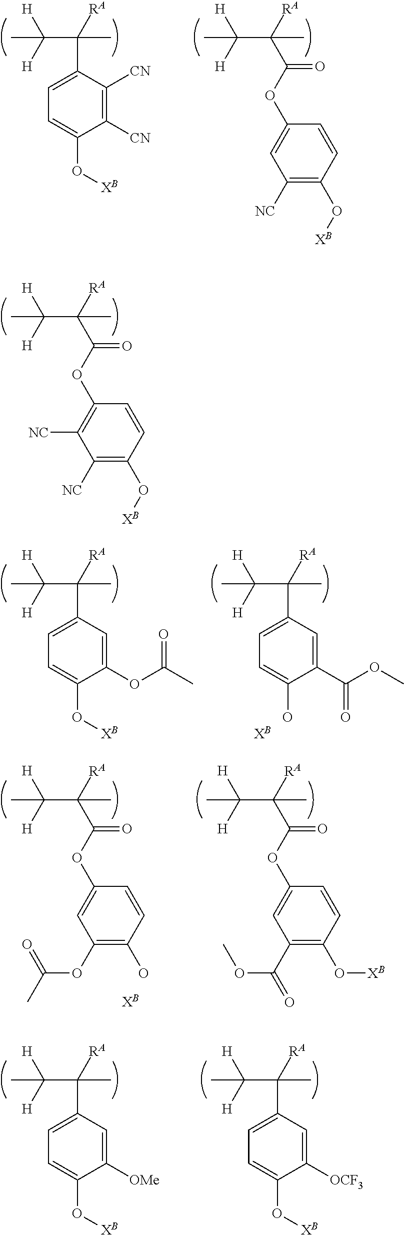

### [Repeating Unit Having Phenolic Hydroxy Group (Repeating Unit C)]

The inventive polymer may contain a repeating unit having a phenolic hydroxy group (hereinafter, also referred to as a repeating unit C). The repeating unit C is preferably a repeating unit represented by the following formula (C-1).

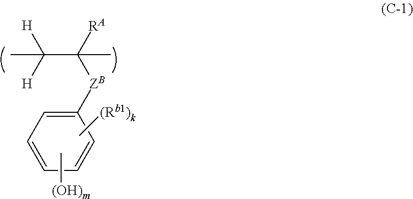

In the formula (C-1), R^{A} is as defined above. Z^{B} represents a single bond or (main chain) —C(═O)—O—. R^{b1} represents a halogen atom, a cyano group, a hydrocarbyl group having 1 to 20 carbon atoms and optionally having a heteroatom, a hydrocarbyloxy group having 1 to 20 carbon atoms and optionally having a heteroatom, a hydrocarbylcarbonyl group having 2 to 20 carbon atoms and optionally having a heteroatom, a hydrocarbylcarbonyloxy group having 2 to 20 carbon atoms and optionally having a heteroatom, or a hydrocarbyloxycarbonyl group having 2 to 20 carbon atoms and optionally having a heteroatom. “m” represents an integer of 1 to 4, “k” represents an integer of 0 to 3, and “m+k” is an integer of 1 to 4.

The hydrocarbyl group represented by R^{b1} may be a saturated or unsaturated group, and may be any of linear, branched, and cyclic groups. Specific examples thereof include the groups given as examples in the description of R¹ in the formula (A-1). Specific examples of the hydrocarbyl moiety of the hydrocarbyloxy group and the hydrocarbylcarbonyl group also include the groups given as examples in the description of R¹.

Examples of the repeating unit C include the following repeating units, but are not limited thereto. In the following formulae, R^{A} is as defined above.

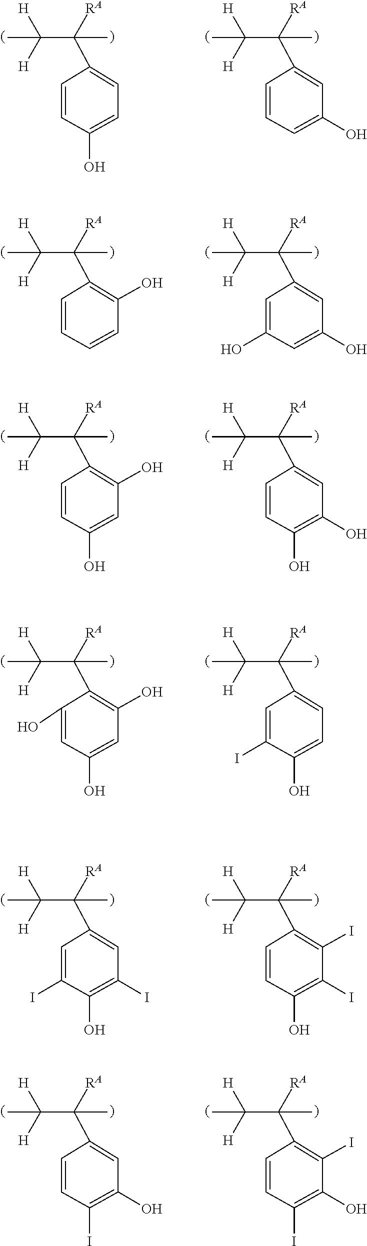

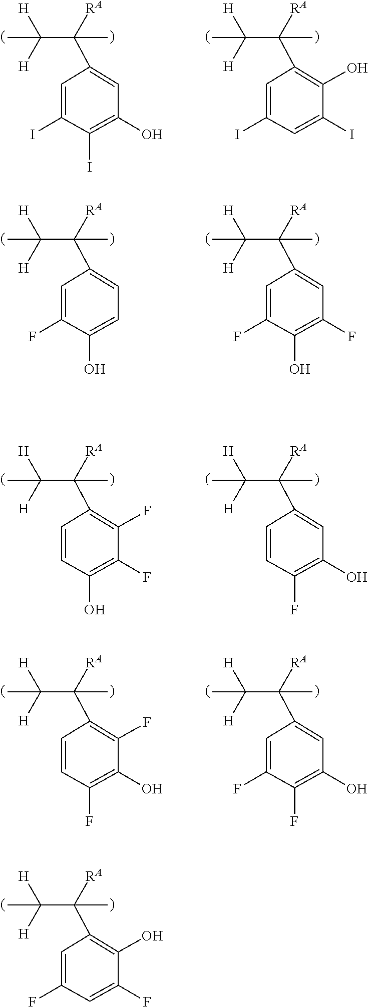

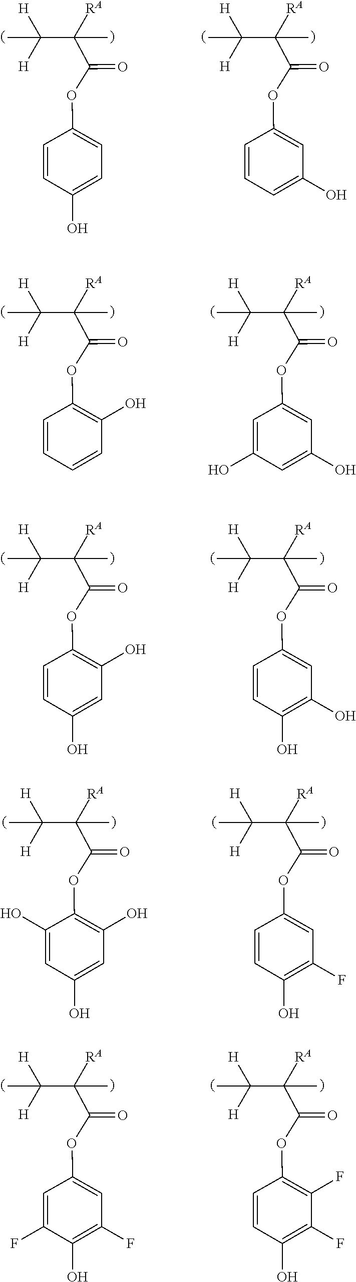

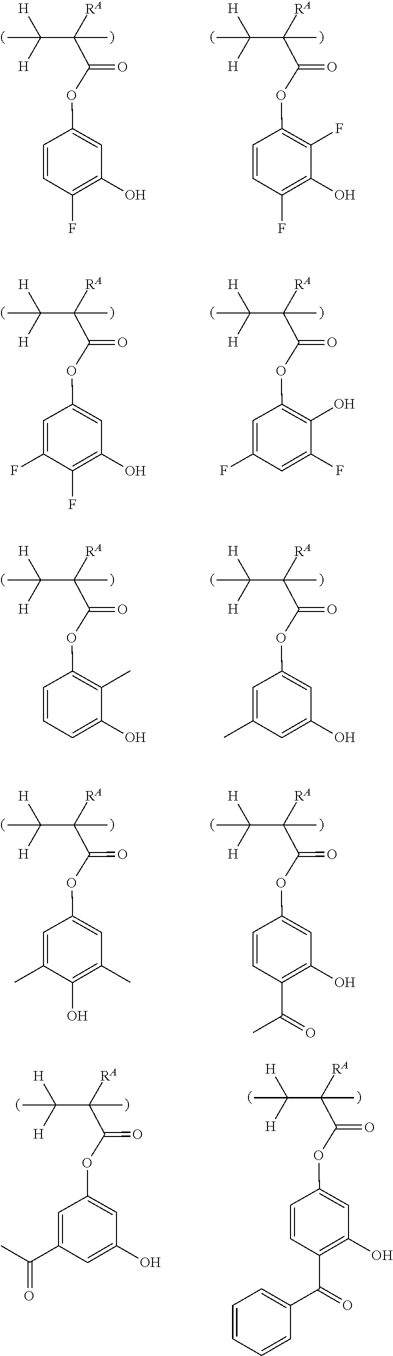

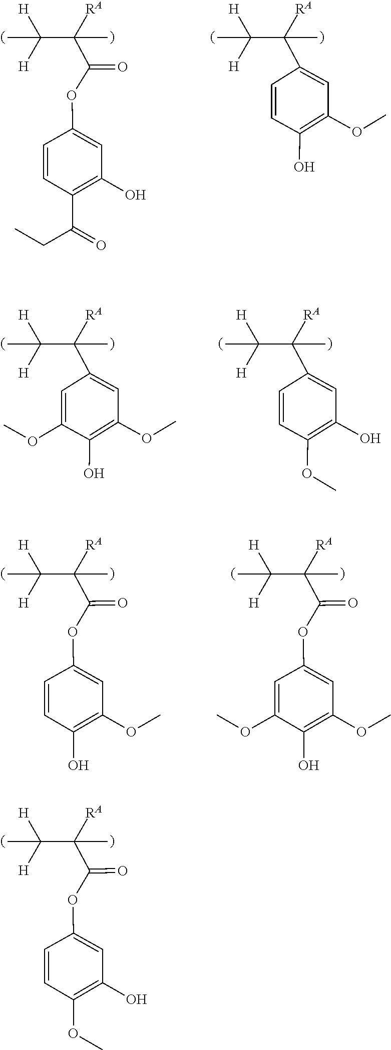

### [Repeating Unit D]

The inventive polymer may further contain a repeating unit represented by the following formula (D-1) (hereinafter, also referred to as a repeating unit D)

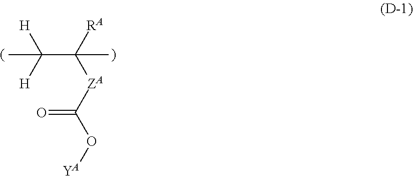

In the formula, R^{A} and Z^{A} are as defined above. Y^{A} represents a hydrogen atom or a polar group having at least one structure selected from a hydroxy group, a cyano group, a carbonyl group, a carboxy group, an ether bond, an ester bond, a sulfonic acid ester bond, a sulfonic acid amide bond, a carbonate bond, a lactone ring, a sultone ring, a sulfur atom, and a carboxylic anhydride.

The Y^{A} may represent a hydrogen atom or a polar group having at least one structure selected from a hydroxy group other than a phenolic hydroxy group, a cyano group, a carbonyl group, a carboxy group, an ether bond, an ester bond, a sulfonic acid ester bond, a carbonate bond, a lactone ring, a sultone ring, and a carboxylic anhydride.

Examples of the repeating unit D include the following, but are not limited thereto. In the following formulae, R^{A} is as defined above.

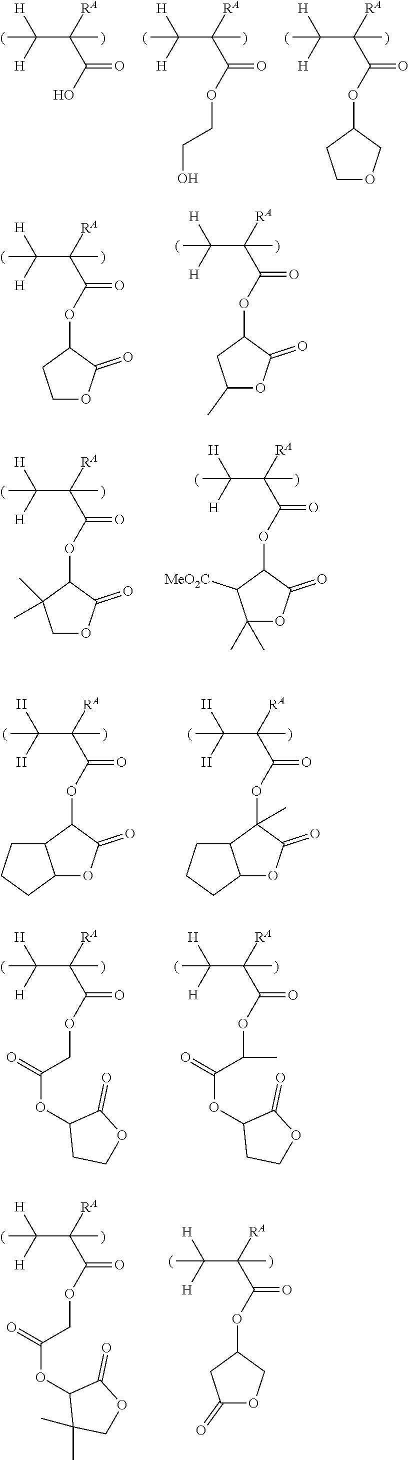

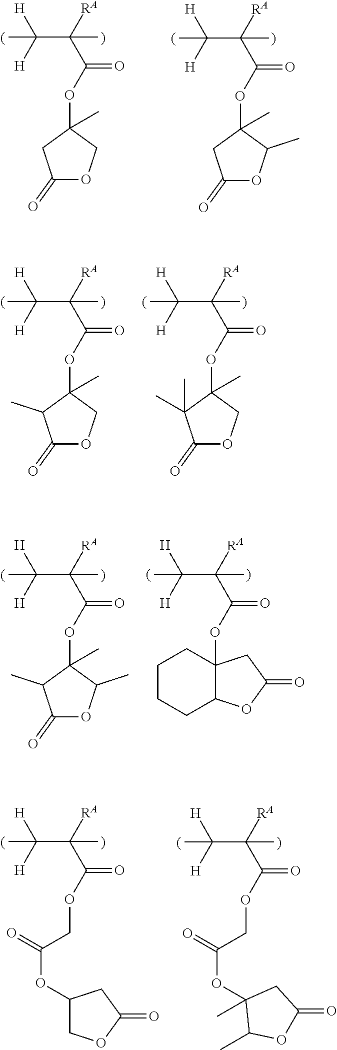

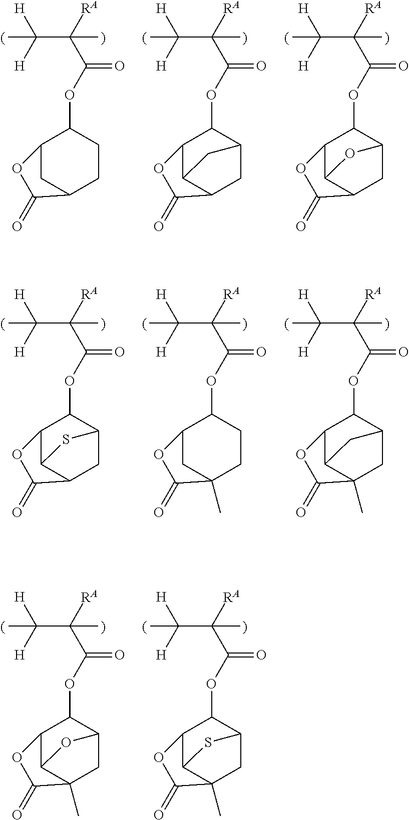

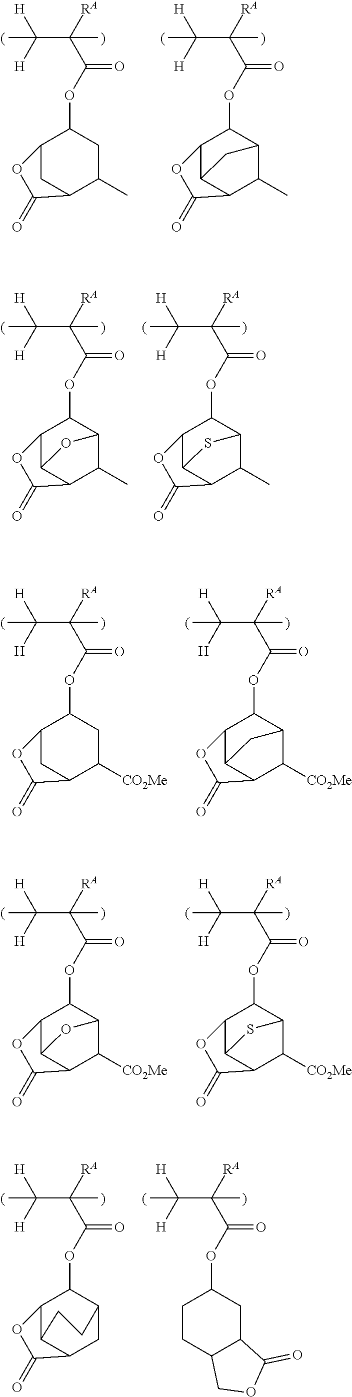

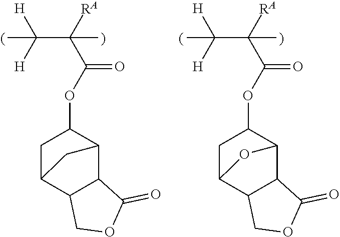

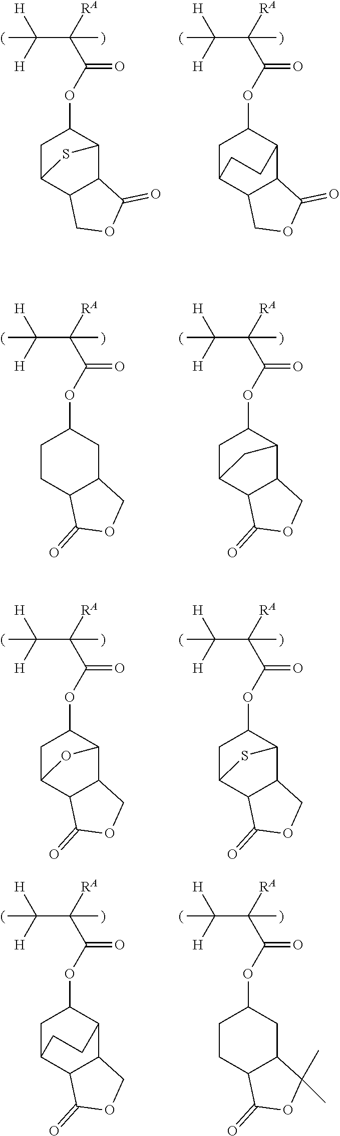

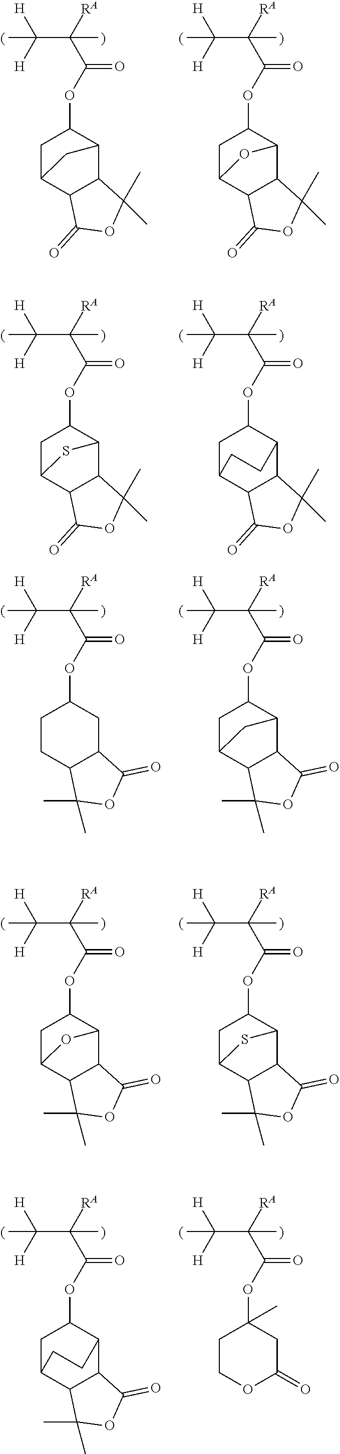

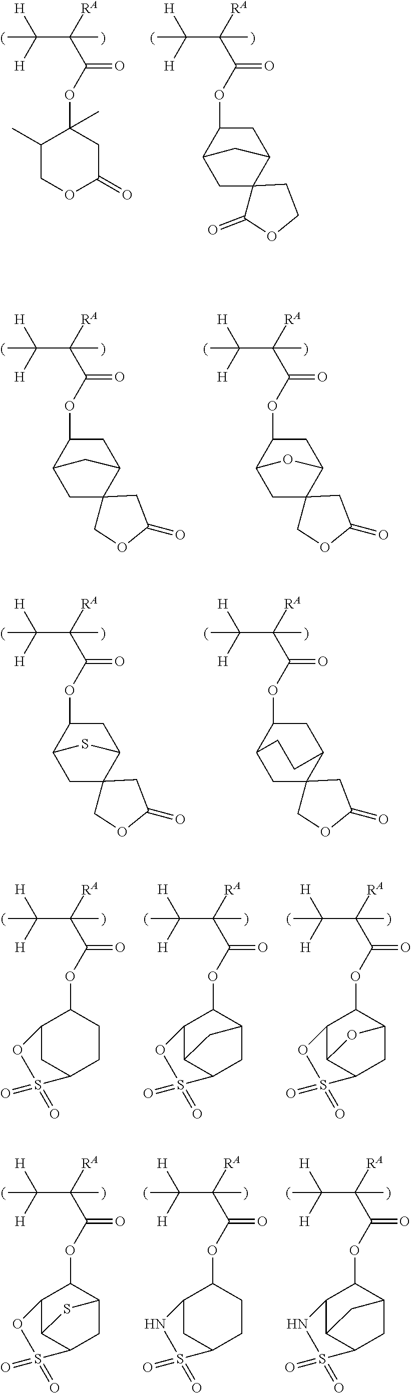

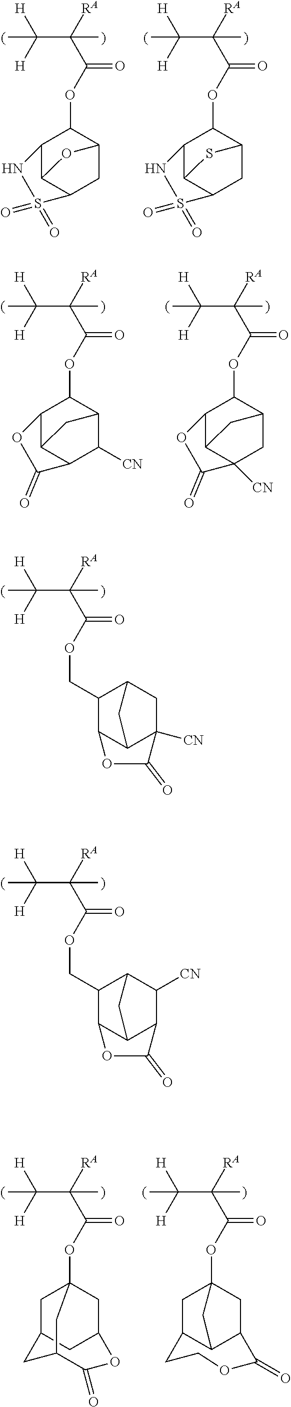

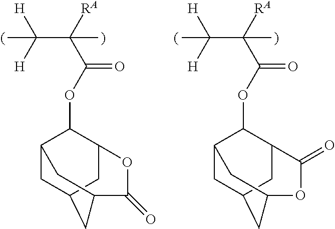

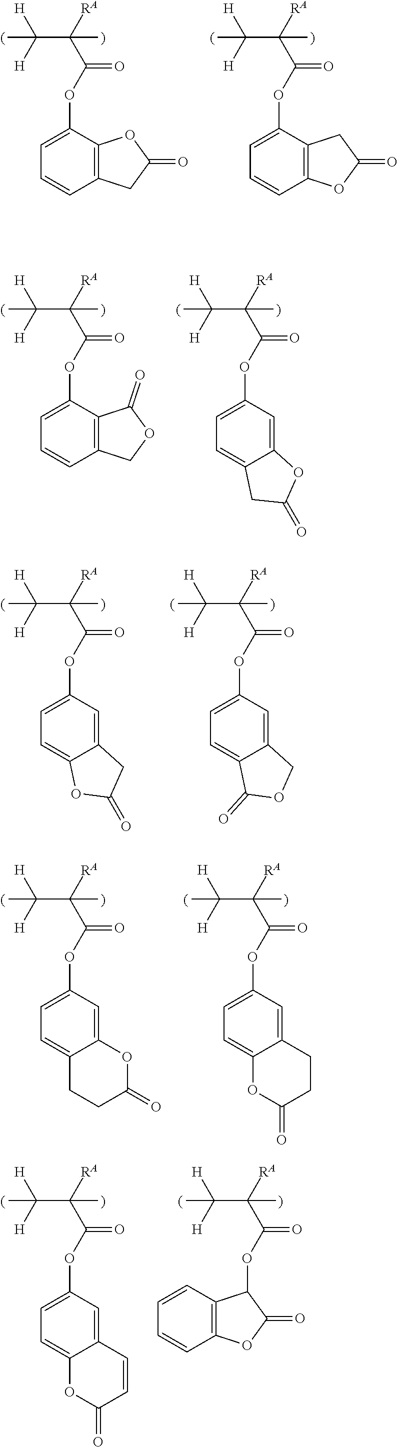

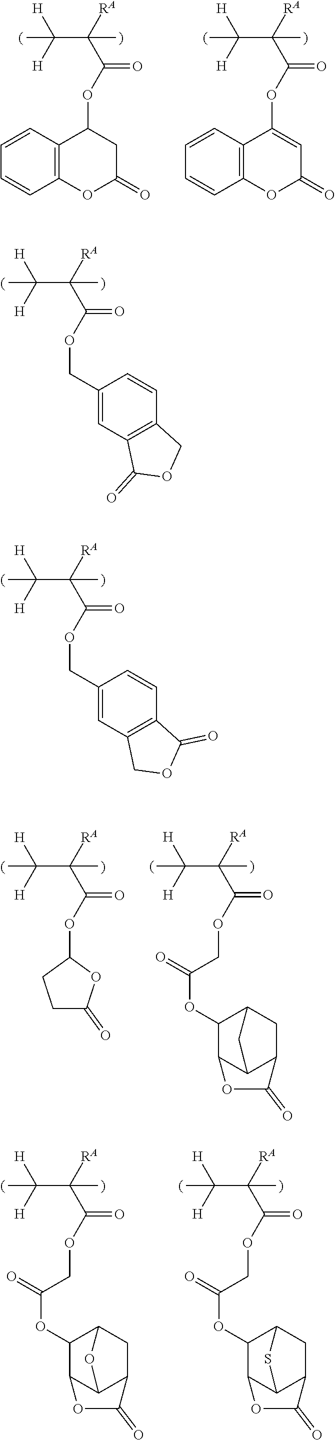

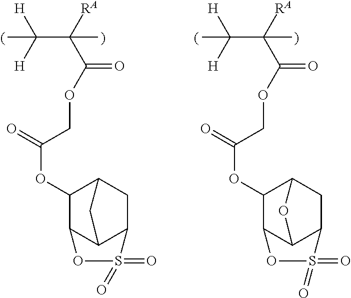

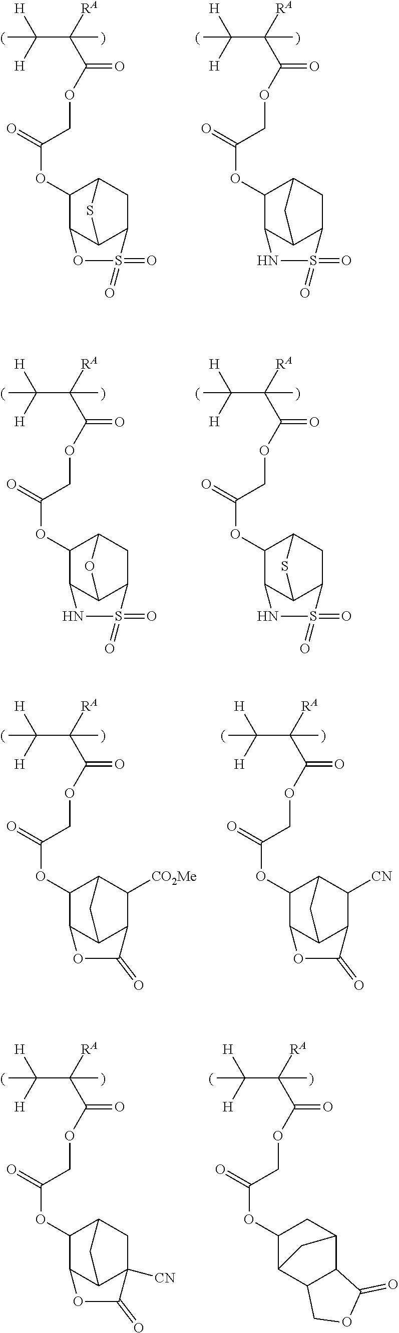

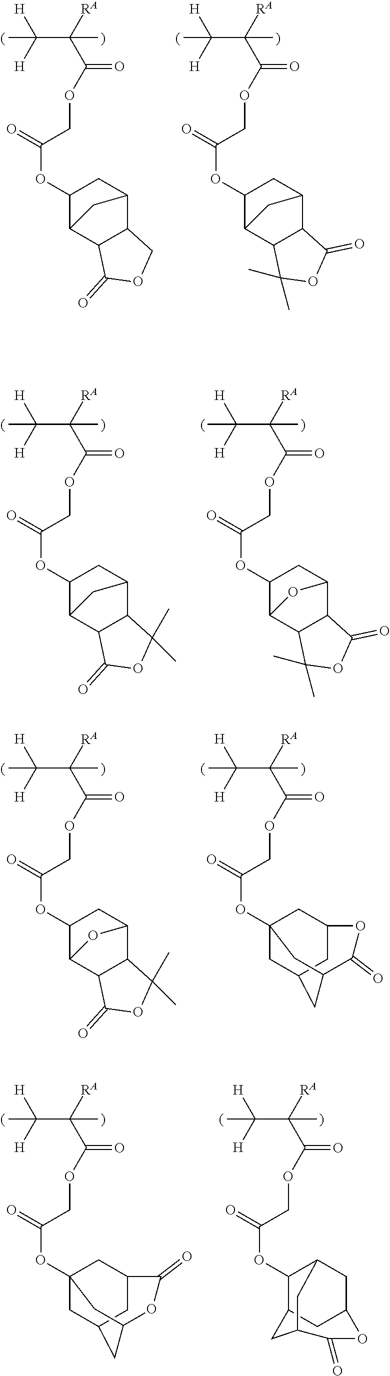

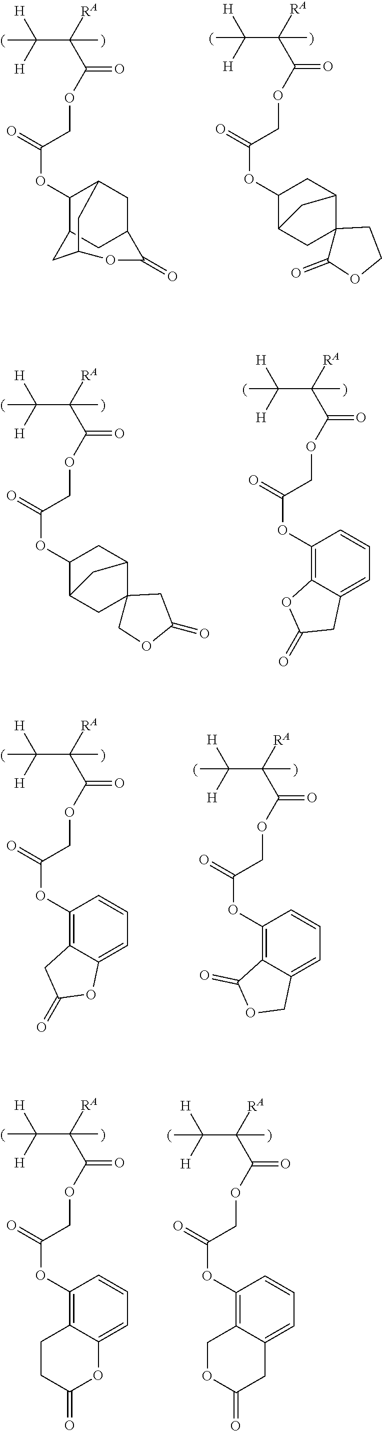

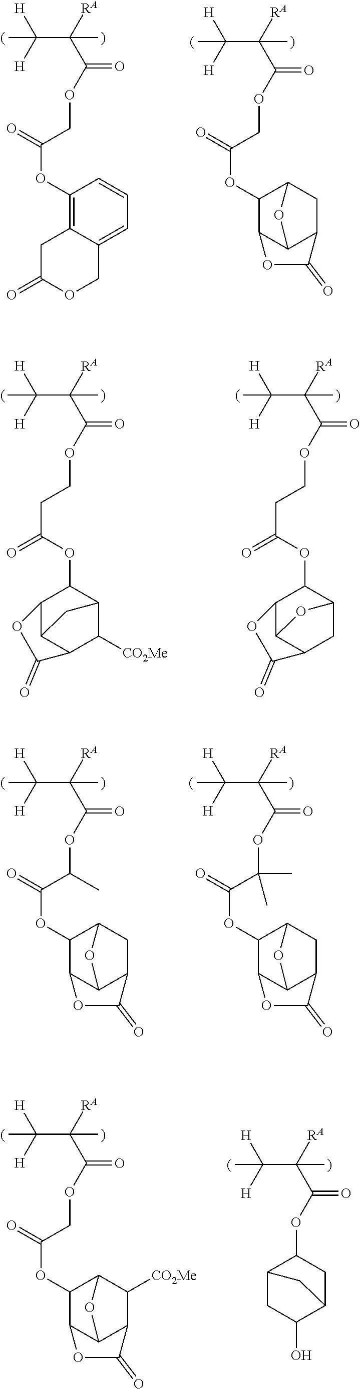

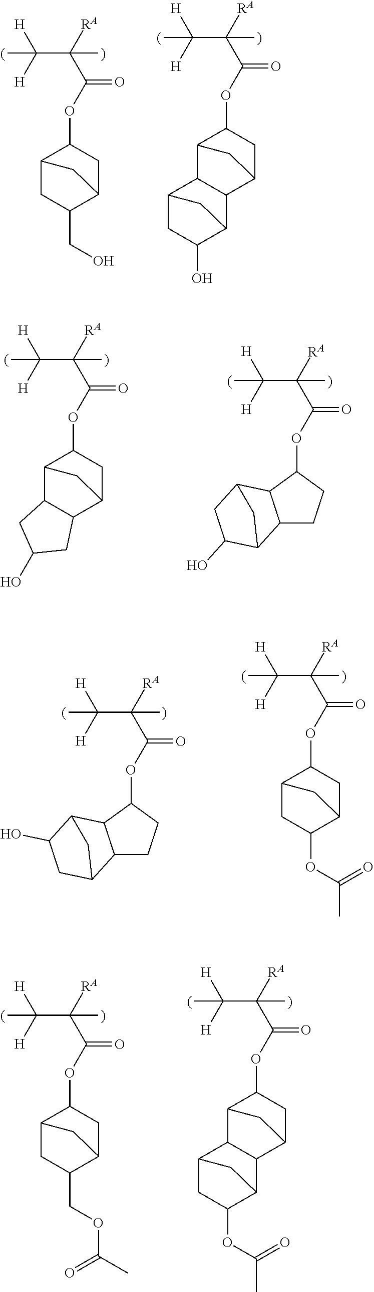

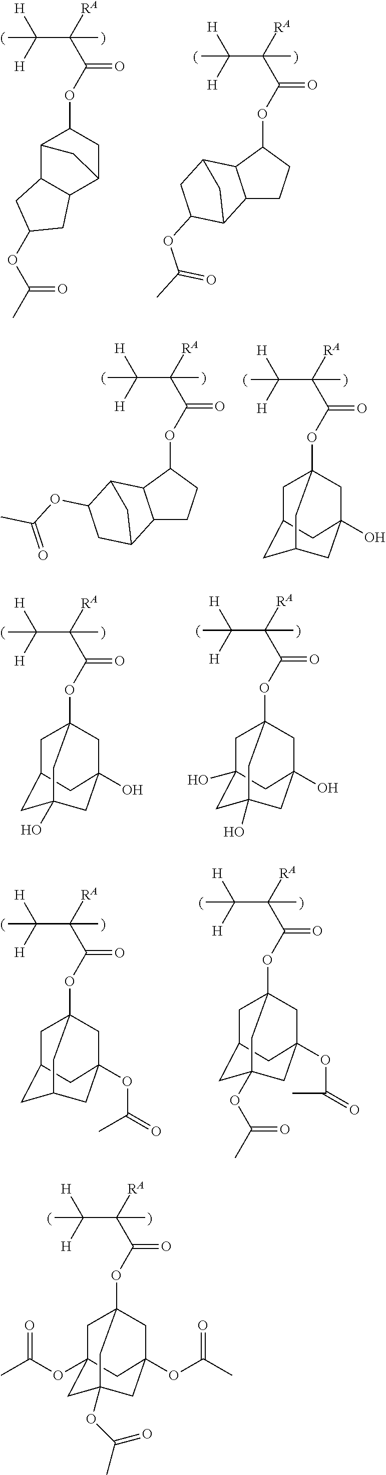

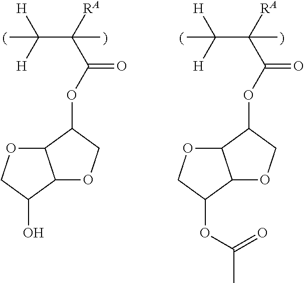

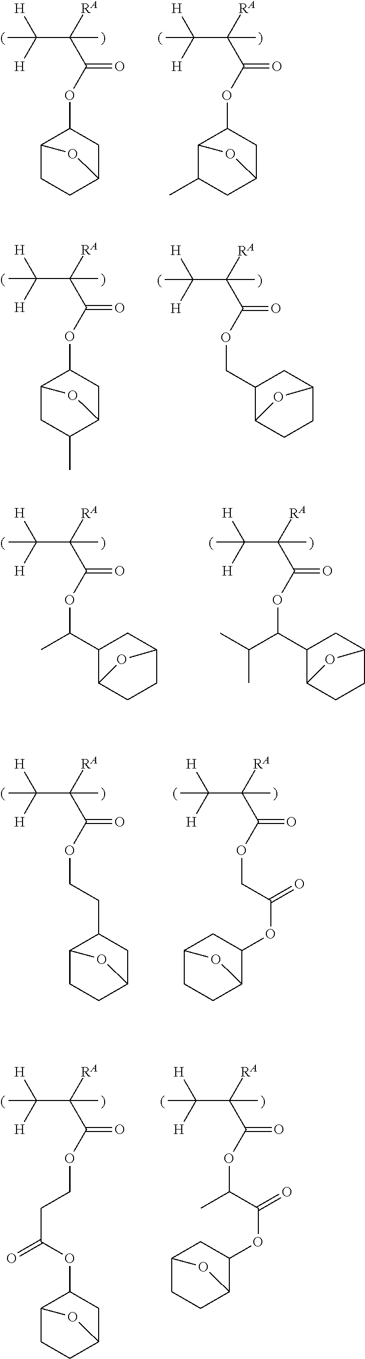

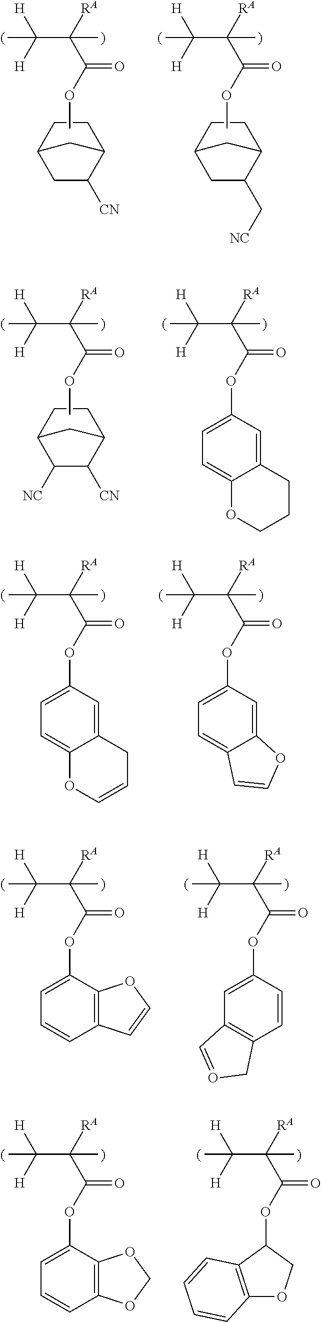

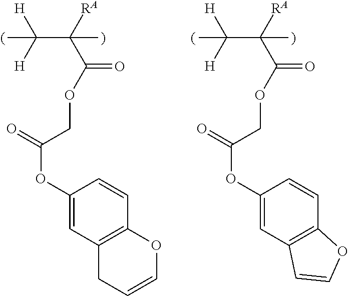

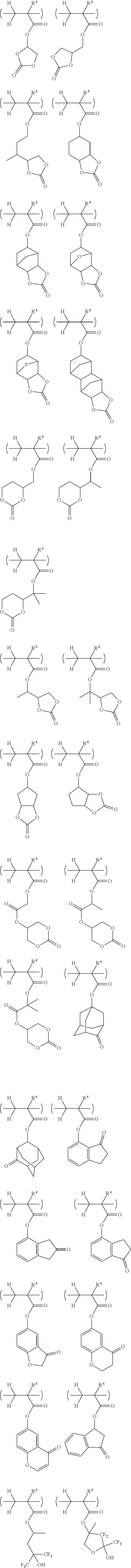

[chemical structure]

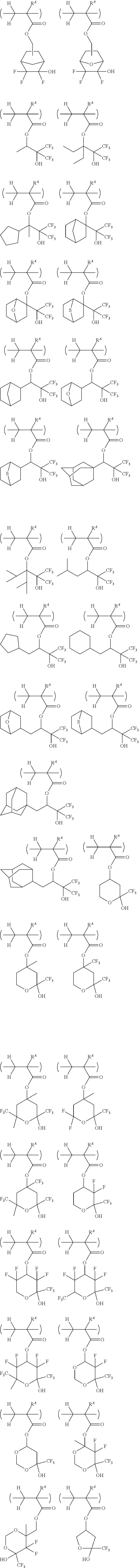

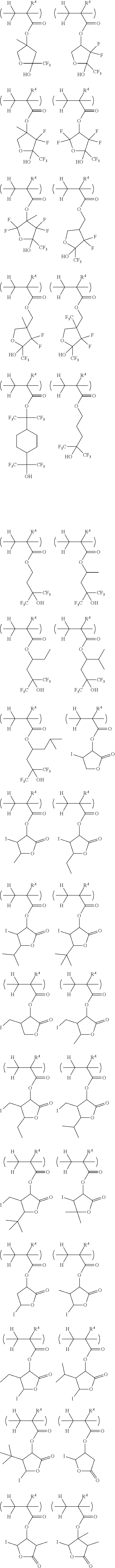

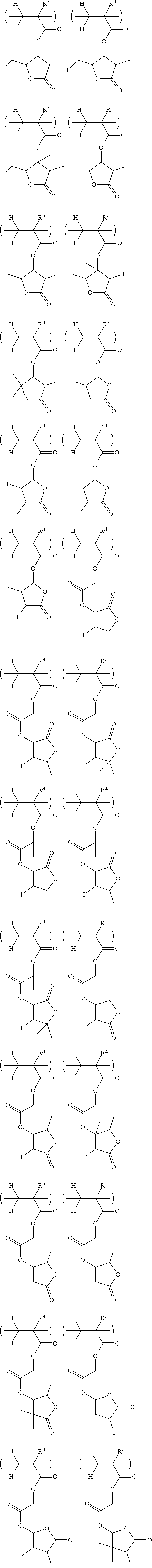

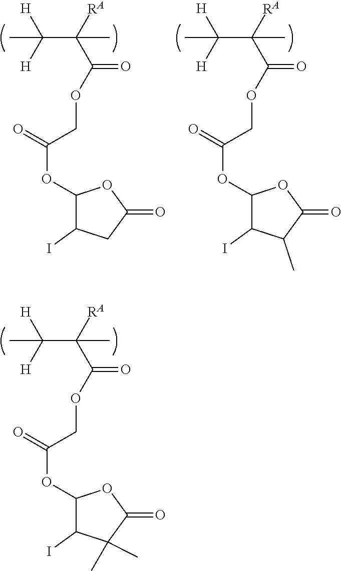

### [Repeating Unit E]

The inventive polymer may further contain a repeating unit E derived from indene, benzofuran, benzothiophene, acenaphthylene, chromone, coumarin, norbornadiene, or a derivative thereof. Examples of a monomer to give the repeating unit E include the following, but are not limited thereto.

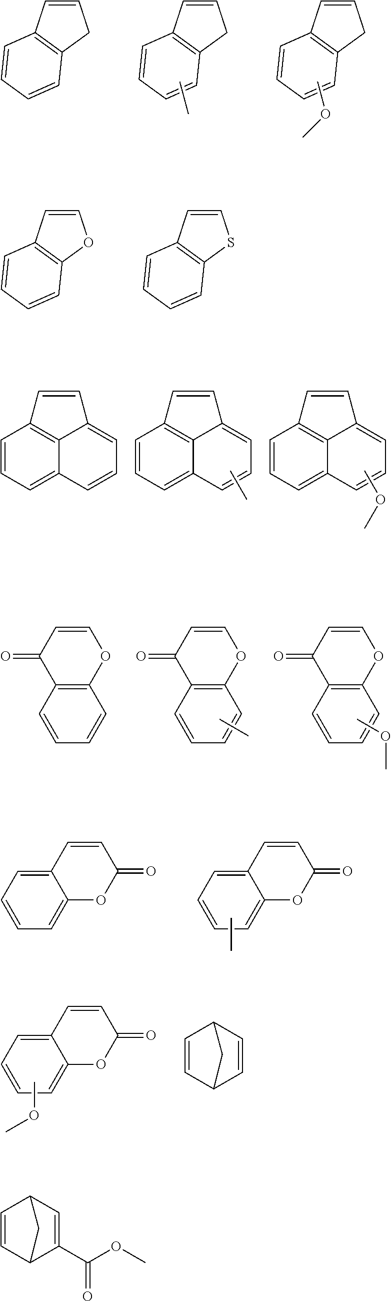

### [Repeating Unit F]

The inventive polymer may further contain a repeating unit F derived from indane, vinylpyridine, or vinylcarbazole.

In the inventive polymer, the proportions of the contained repeating units A, a1, a2, B, C, D, E, and F are preferably 0<A<1.0, 0≤a1≤0.8, 0≤a≤0.8, 0<a1+a≤0.8, 0<B<1.0, 0≤C<1.0, 0≤D≤0.8, 0≤E≤0.8, and 0≤F≤0.4; more preferably 0.05≤A≤0.9, 0≤a1≤0.7, 0≤a≤0.7, 0<a1+a≤0.7, 0.01≤B≤0.4, 0.09≤C≤0.55, 0≤D≤0.7, 0≤E≤0.7, and 0≤F≤0.3; and further preferably 0.1≤A≤0.8, 0≤a1≤0.6, 0≤a≤0.6, 0<a1+a≤0.4, 0.1≤B≤0.45, 0.1≤C≤0.45, 0≤D≤0.6, 0≤E≤0.6, and 0≤F≤0.2.

When the repeating unit B is at least one selected from the repeating units B1 to B4, B=B1+B2+B3+B4 and A+a1+a2+B+C+D+E+F=1.

A weight-average molecular weight (Mw) of the polymer is preferably 1,000 to 500,000, and more preferably 3,000 to 100,000. Mw within this range yields sufficient etching resistance and has no risk of degradation of resolution due to failure to achieve a difference in the dissolution rate before and after the light exposure. Mw in the present invention is a polystyrene-converted measurement value by gel permeation chromatography (GPC) using tetrahydrofuran (THF) or N,N-dimethylformamide (DMF) as an eluent.

Furthermore, the finer the pattern rule, the stronger the influences of the molecular weight distribution (Mw/Mn) of the polymer. Hence, in order to obtain a resist composition suitably used for finer pattern dimension, the polymer preferably has a narrow dispersity Mw/Mn of 1.0 to 2.0. Within this range, there are few polymers having a low molecular weight and a high molecular weight, and there is no risk of foreign matter being found on the pattern or degradation of the pattern shape after the light exposure.

As a method for manufacturing the polymer, monomers to yield the above-described repeating units can be polymerized in an organic solvent by adding a radical polymerization initiator and heating, for example.

Examples of the organic solvent used in the polymerization include toluene, benzene, THF, diethyl ether, dioxane, cyclohexane, cyclopentane, methyl ethyl ketone (MEK), propylene glycol monomethyl ether acetate (PGMEA), and γ-butyrolactone (GBL). Examples of the radical polymerization initiator include 2,2′-azobisisobutyronitrile (AIBN), 2,2′-azobis(2,4-dimethylvaleronitrile), dimethyl-2,2-azobis(2-methylpropionate), 1,1′-azobis(1-acetoxy-1-phenylethane), benzoyl peroxide, and lauroyl peroxide. These initiators are preferably added in an amount of 0.01 to 25 mol % relative to a total of the monomers to be polymerized. The reaction temperature is preferably 50 to 150° C., more preferably 60 to 100° C. The reaction time is preferably 2 to 24 hours, and from the viewpoint of production efficiency, more preferably 2 to 12 hours.

The radical polymerization initiator may be added into a solution of the monomers to be fed into a reaction vessel, or an initiator solution may be prepared separately from the monomer solution and each of the solutions may be independently fed into a reaction vessel. Since a radical generated from the initiator may cause the polymerization reaction to proceed during the waiting time to generate a polymer having an ultra-high molecular weight, the monomer solution and the initiator solution are preferably each independently prepared to be added dropwise from the viewpoint of quality control. The acid-labile group may be introduced into the monomer to be used as it is, or may be protected or partially protected after the polymerization. To regulate the molecular weight, known chain transfer agents, such as dodecyl mercaptan and 2-mercaptoethanol may be used in combination. In this case, an addition amount of these chain transfer agents is preferably 0.01 to 20 mol % relative to the total of the monomers to be polymerized.

When the monomer has a hydroxy group, the hydroxy group may be substituted with an acetal group, such as an ethoxyethoxy group, which is easily deprotected by an acid, during the polymerization, and the protected hydroxy group may be deprotected by a weak acid and water after the polymerization. Alternatively, the hydroxy group may be substituted with an acetyl group, a formyl group, a pivaloyl group, etc. to be hydrolyzed with an alkali after the polymerization.

When hydroxystyrene or hydroxyvinylnaphthalene is copolymerized, hydroxystyrene or hydroxyvinylnaphthalene and other monomers may be heat-polymerized in the organic solvent with adding the radical polymerization initiator. Alternatively, acetoxystyrene or acetoxyvinylnaphthalene may be used, and the acetoxy group may be deprotected with alkaline hydrolysis after the polymerization to be converted into polyhydroxystyrene or hydroxypolyvinylnaphthalene.

As a base in the alkaline hydrolysis, aqueous ammonia, triethylamine, etc. can be used. The reaction temperature is preferably −20 to 100° C., more preferably 0 to 60° C. The reaction time is preferably 0.2 to 100 hours, more preferably 0.5 to 20 hours.

An amount of each monomer in the monomer solution is appropriately set so as to be in a preferable content ratio of the above repeating units, for example.

As for the polymer obtained in the producing method, a reaction solution obtained by the polymerization reaction may be a final product. Alternatively, a powder obtained via a purification step, such as reprecipitation method in which the polymerization solution is added into a poor solvent to obtain a powder, may be treated as a final product. From the viewpoints of operation efficiency and quality stabilization, the powder obtained in the purification step is preferably dissolved in a solvent to form a polymer solution to be operated as a final product.

Specific examples of the solvent used in this case include solvents described in paragraphs [0144] to [0145] in JP 2008-111103 A, and specifically include: ketones, such as cyclohexanone and methyl-2-n-pentylketone; alcohols, such as 3-methoxybutanol, 3-methyl-3-methoxybutanol, 1-methoxy-2-propanol, and 1-ethoxy-2-propanol; ethers, such as propylene glycol monomethyl ether (PGME), ethylene glycol monomethyl ether, propylene glycol monoethyl ether, ethylene glycol monoethyl ether, propylene glycol dimethyl ether, and diethylene glycol dimethyl ether; esters, such as PGMEA, propylene glycol monoethyl ether acetate, ethyl lactate, ethyl pyruvate, butyl acetate, methyl 3-methoxypropionate, ethyl 3-ethoxypropionate, tert-butyl acetate, tert-butyl propionate, and propylene glycol mono-tert-butyl ether acetate; lactones, such as GBL; alcohols, such as diacetone alcohol (DAA); alcoholic solvents having a high boiling point, such as diethylene glycol, propylene glycol, glycerin, 1,4-butanediol, and 1,3-butanediol; and mixed solvents thereof.

In the polymer solution, a concentration of the polymer is preferably 0.01 to 30 mass %, more preferably 0.1 to 20 mass %.

The reaction solution and the polymer solution are preferably filtered with a filter. The filtration can remove a foreign matter and gel, which may cause a defect, and is effective in terms of quality stabilization.

Examples of a material of the filter used for the filtration include a fluorocarbon, cellulose, nylon, a polyester, and a hydrocarbon. In the step of filtering the resist composition, the filter is preferably formed with a fluorocarbon, so-called Teflon®, a hydrocarbon such as polyethylene and polypropylene, or nylon. A pore size of the filter can be appropriately selected depending on target cleanliness, and is preferably 100 nm or smaller, and more preferably 20 nm or smaller. One of these filters may be used alone, or a plurality of these filters may be used in combination. As for the filtration method, the solution may be passed through the filter once, but the solution is preferably circulated to be filtered a plurality of times. In the step for producing the polymer, the filtration step may be performed in any order any number of times, but the reaction solution after the polymerization reaction, the polymer solution, or both thereof are preferably filtered.

The polymer may contain two or more polymers having different composition ratios, Mw, and molecular weight distributions.

The present invention can also provide a resist composition containing the above-described polymer. Specifically, the present invention can provide a chemically amplified resist composition described below.

### [Chemically Amplified Resist Composition]

The chemically amplified resist composition of the present invention preferably contains:
(P) a polymer;
(G) a quencher; and
(H) an organic solvent.

The chemically amplified resist composition may contain, as necessary, at least one selected from:
(I) a photo-acid generator other than the photo-acid generator bonded to a chain of the polymer;
(J) a nitrogen-containing quencher; and
(K) a surfactant insoluble or hardly soluble in water and soluble in an alkaline developer; and/or a surfactant insoluble or hardly soluble in water and an alkaline developer.

The chemically amplified resist composition can further contain, as necessary,
(L) other components.

### [(G) Quencher]

Examples of the quencher (G) include an onium salt represented by the following formula (1) or (2).

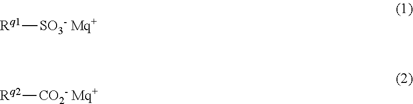

In the formula (1), R^{q1} represents a hydrogen atom or a hydrocarbyl group having 1 to 40 carbon atoms and optionally having a heteroatom, except for a group in which a hydrogen atom bonded to a carbon atom at the α-position of the sulfo group is substituted with a fluorine atom or a fluoroalkyl group. In the formula (2), R^{q2} represents a hydrogen atom or a hydrocarbyl group having 1 to 40 carbon atoms and optionally having a heteroatom.

Specific examples of the hydrocarbyl group represented by R^{q1} include: alkyl groups, such as a methyl group, an ethyl group, a propyl group, an isopropyl group, an n-butyl group, a sec-butyl group, a tert-butyl group, an n-pentyl group, a tert-pentyl group, an n-hexyl group, an n-octyl group, a 2-ethylhexyl group, an n-nonyl group, and an n-decyl group; cyclic saturated hydrocarbyl groups, such as a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a norbornyl group, a tricyclo[5.2.1.0^{2,6}]decanyl group, and an adamantyl group; and aryl groups, such as a phenyl group, a naphthyl group, and an anthracenyl group. A part or all of hydrogen atoms in these groups are optionally substituted with a group having a heteroatom, such as an oxygen atom, a sulfur atom, a nitrogen atom, and a halogen atom. A part of carbon atoms in these groups is optionally substituted with a group having a heteroatom, such as an oxygen atom, a sulfur atom, and a nitrogen atom. As a result, a hydroxy group, a cyano group, a carbonyl group, an ether bond, an ester bond, a sulfonic acid ester bond, a carbonate bond, a lactone ring, a sultone ring, a carboxylic anhydride, a haloalkyl group, etc. are optionally contained.

Specific examples of the hydrocarbyl group represented by R^{q2} include: the substituents given as the specific examples of R^{q1}; fluorinated alkyl groups, such as a trifluoromethyl group and a trifluoroethyl group; and fluorinated aryl groups, such as a pentafluorophenyl group and 4-trifluoromethylphenyl group.

Examples of the anion of the onium salt represented by the formula (1) include the following anions, but the anion is not limited thereto.

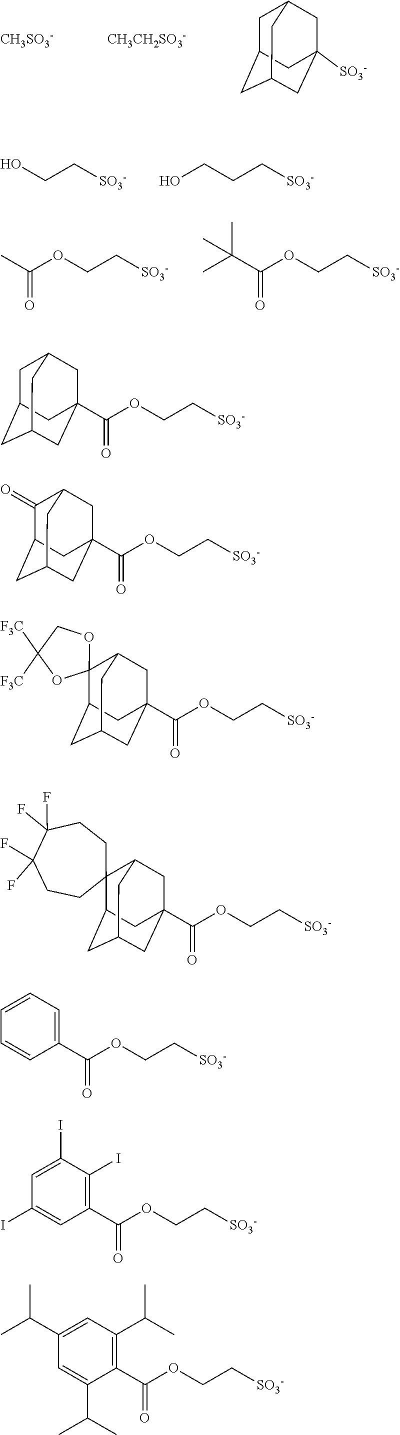

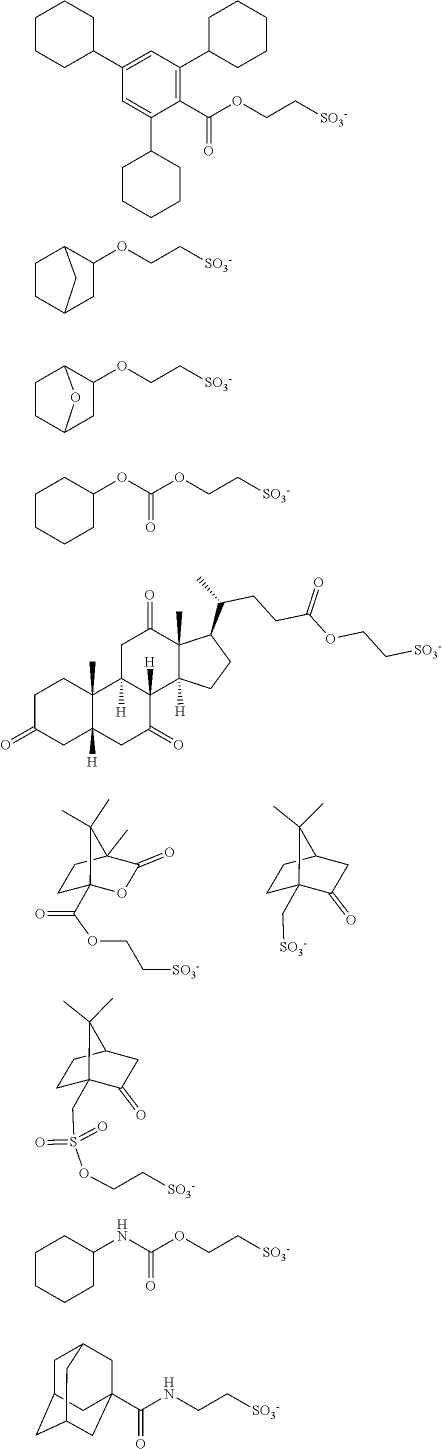

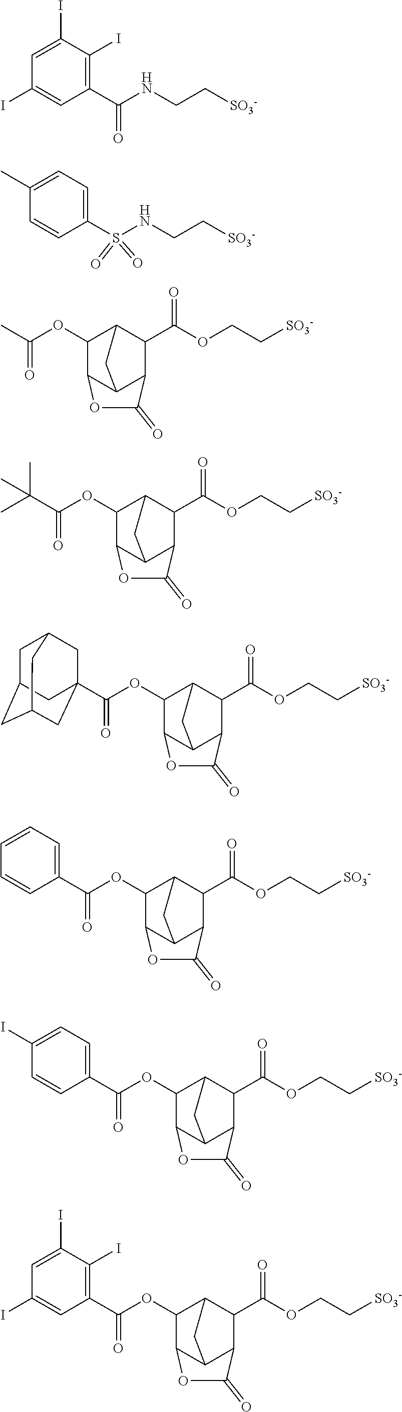

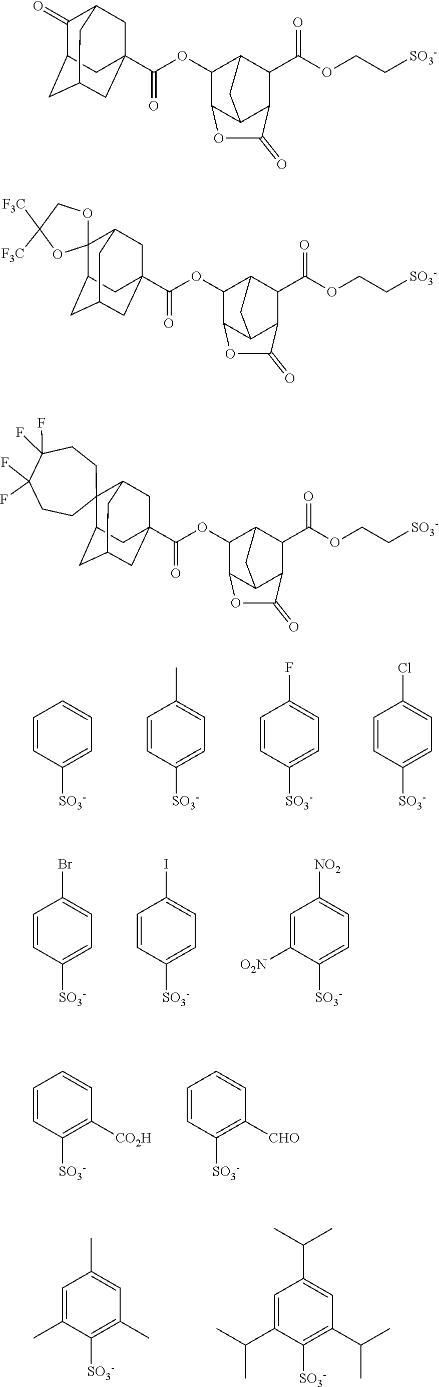

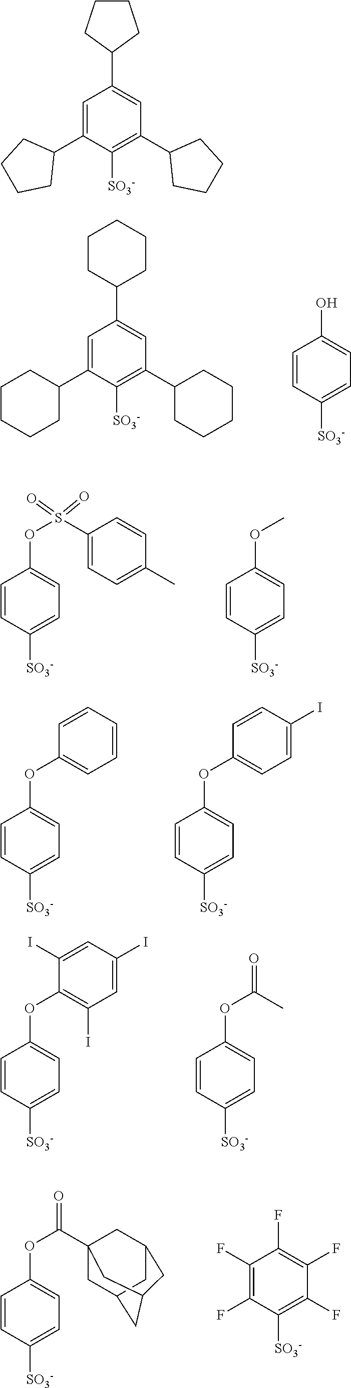

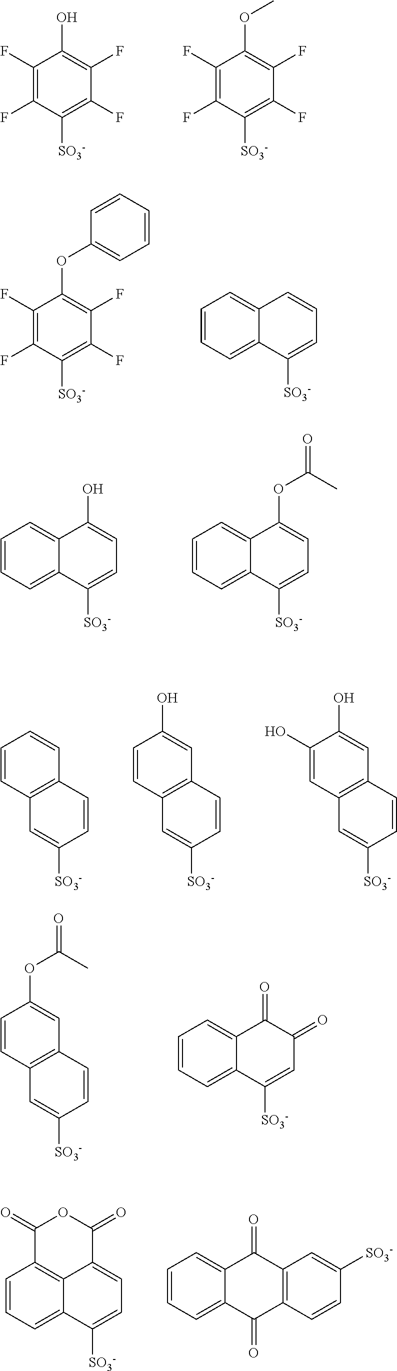

Examples of the anion of the onium salt represented by the formula (2) include the following anions, but the anion is not limited thereto.

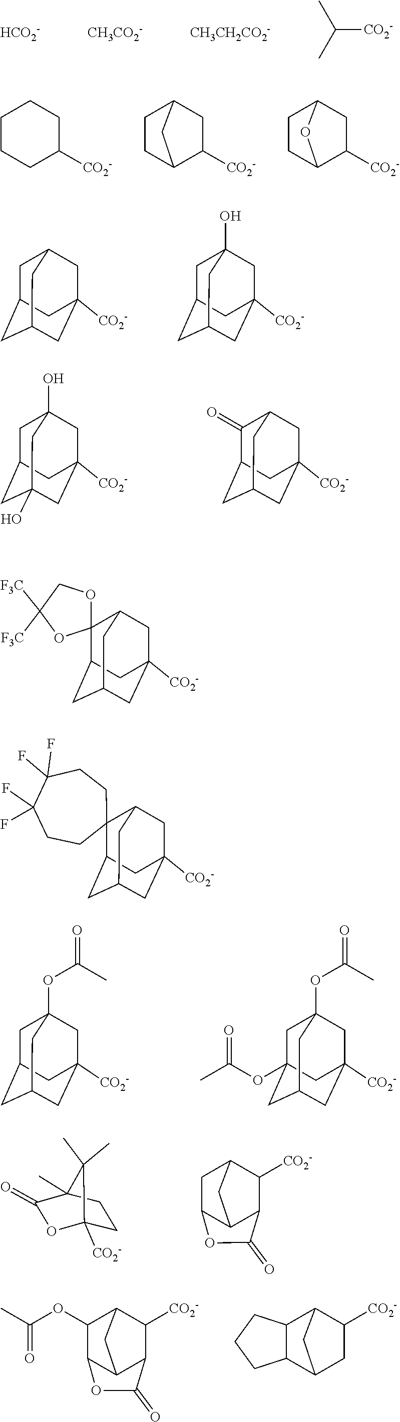

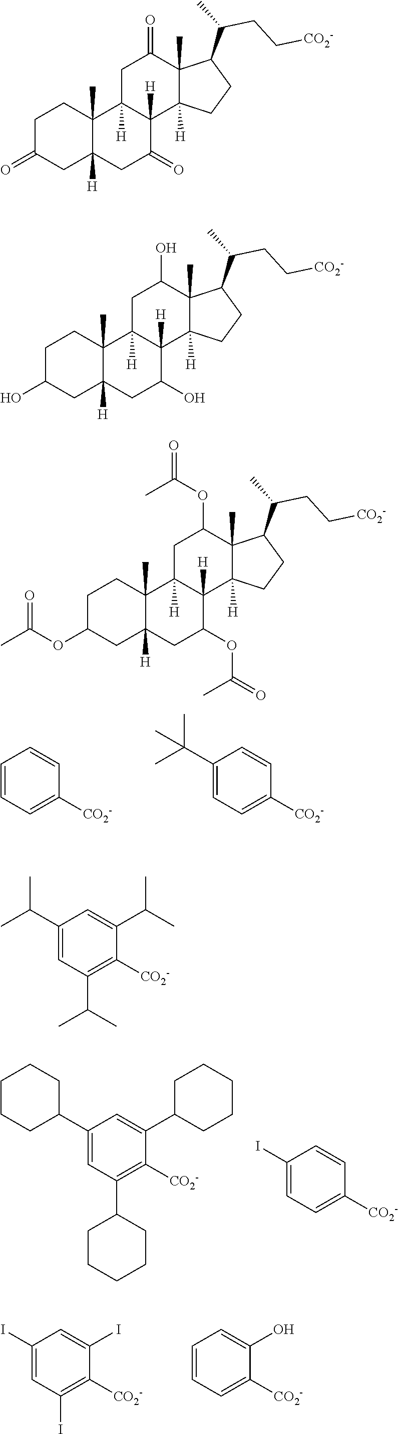

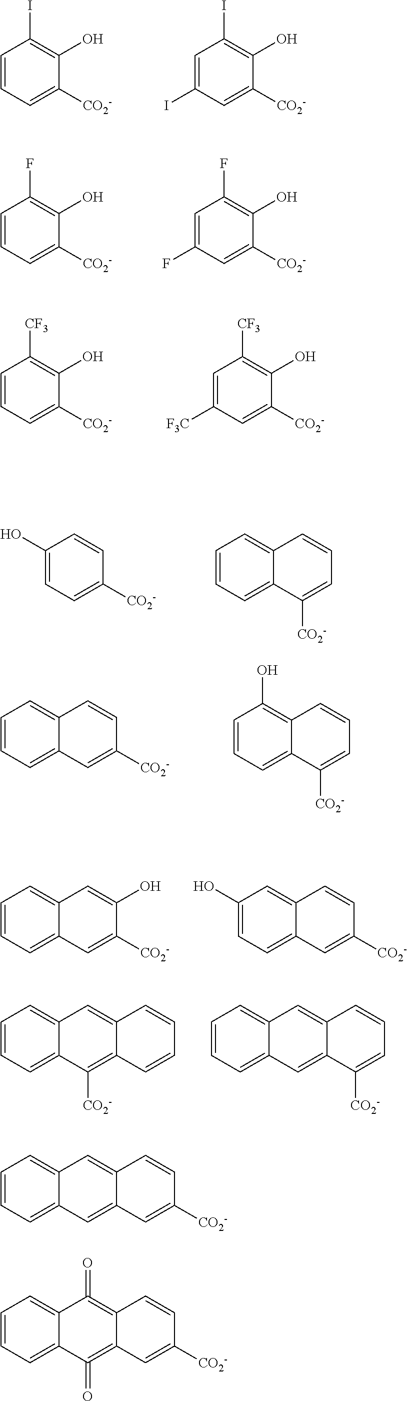

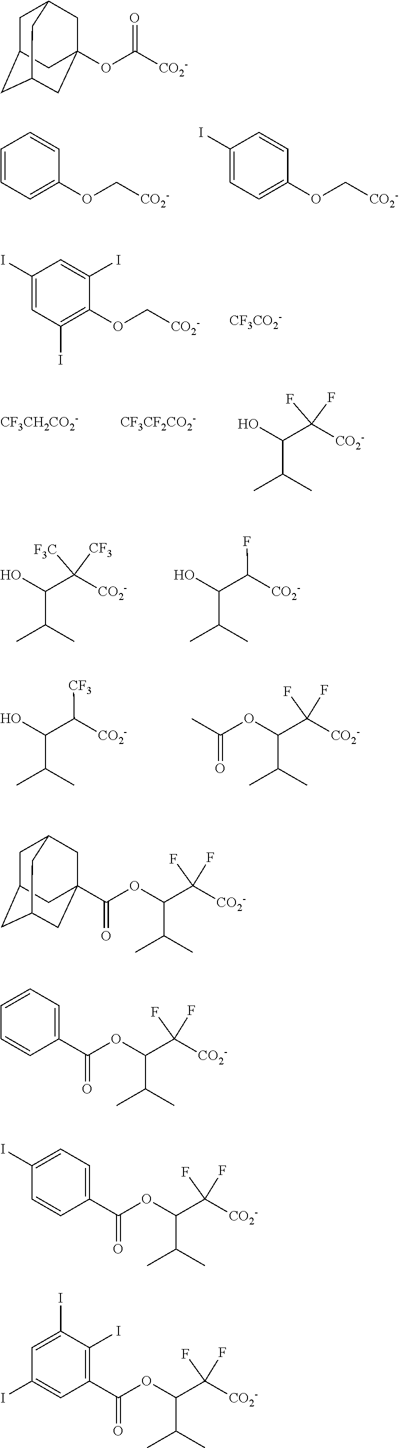

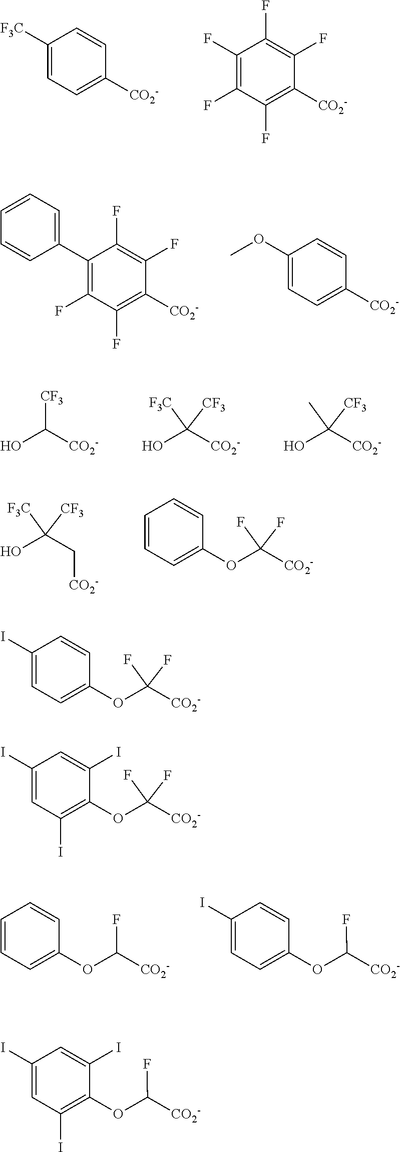

In the formulae (1) and (2), Mq⁺ represents an onium cation. The onium cation is preferably represented by the following formula (cation-1), (cation-2), or (cation-3).

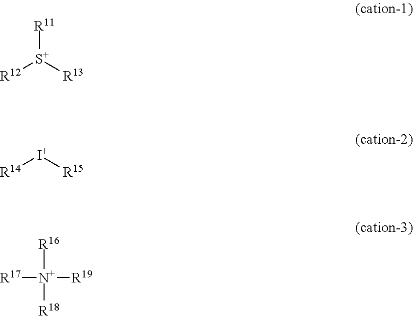

Examples of the cations represented by the formulae (cation-1) and (cation-2) include the same cations as A⁺ in the formulae (B-2) to (B-4). In (cation-3), R¹⁶ to R¹⁹ each independently represent a hydrocarbyl group having 1 to 40 carbon atoms and optionally having a heteroatom. Any two of R¹⁶, R¹⁷, R¹⁸, and R¹⁹ may be bonded to each other to form a ring together with the nitrogen atom bonded thereto. Examples of the hydrocarbyl group include the groups given as examples in the description of R¹¹ to R¹⁵ in the formulae (cation-1) and (cation-2).

In the onium cation represented by Mq⁺, examples of the ammonium cation represented by (cation-3) include the following cations, but the cation is not limited thereto.

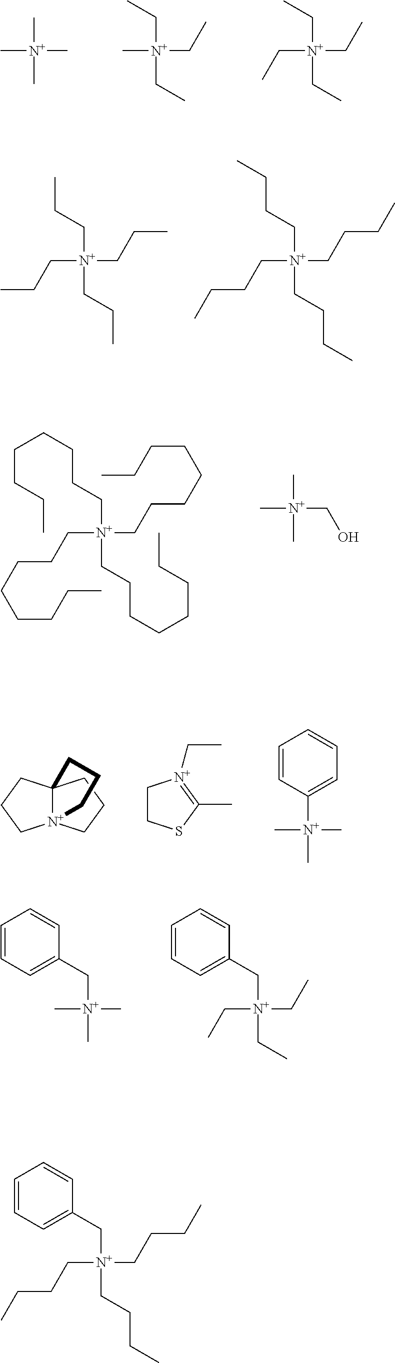

Specific examples of the onium salt represented by the formula (1) or (2) include any combination of the aforementioned anions and cations. These onium salts are easily prepared by an ion-exchange reaction using a known organic chemical method. Regarding the ion-exchange reaction, JP 2007-145797 A can be referred to, for example.

The onium salt represented by the formula (1) or (2) acts as a quencher in the chemically amplified resist composition of the present invention. This is because each counter anion of the onium salt is a conjugated base of a weak acid. The weak acid herein means an acid that exhibits acidity that cannot deprotect the acid-labile group in the acid-labile group-containing unit used for the polymer.

The onium salt represented by the formula (1) or (2) functions as a quencher when used in combination with an onium-salt type photo-acid generator having a conjugated base of a strong acid, such as an α-fluorinated sulfonic acid, as a counter anion. That is, when an onium salt to generate a strong acid, such as an α-fluorinated sulfonic acid, and an onium salt to generate a weak acid, such as non-fluorinated sulfonic acid and a carboxylic acid, are mixed to be used, the strong acid generated from the photo-acid generator by high-energy ray irradiation collides with the unreacted onium salt having the weak acid anion to release the weak acid with salt exchange, resulting in generation of an onium salt having the strong acid anion. This process exchanges the strong acid into the weak acid having low catalytic ability, and the acid is apparently deactivated to enable to control the acid diffusion.

When the photo-acid generator to generate the strong acid is an onium salt, the strong acid generated by irradiation with a high-energy beam can be exchanged into the weak acid, as described above. Meanwhile, it is considered that the weak acid generated by high-energy beam irradiation hardly collides with the unreacted onium salt to generate the strong acid to cause salt exchange. This is because of a phenomenon that an onium cation is more likely to form an ion pair with an anion of a stronger acid.

When the onium salt represented by the formula (1) or (2) is contained as the quencher (G), the contained amount of the onium salt is preferably 0.1 to 20 parts by mass, more preferably 0.1 to 10 parts by mass, relative to 80 parts by mass of the polymer (P). The quencher of the component (G) within the above range is preferable in terms of the good resolution without considerable degradation of the sensitivity. One kind of the onium salt represented by the formula (1) or (2) can be used, or two or more kinds of the onium salt can be used in combination.

### [(H) Organic Solvent]

The organic solvent of the component (H) is not particularly limited as long as it can dissolve each component described above and each component described below. Examples of such an organic solvent include: ketones, such as cyclopentanone, cyclohexanone, and methyl-2-n-pentyl ketone; alcohols, such as 3-methoxybutanol, 3-methyl-3-methoxybutanol, 1-methoxy-2-propanol, and 1-ethoxy-2-propanol; keto alcohols, such as DAA; ethers, such as PGME, ethylene glycol monomethyl ether, propylene glycol monoethyl ether, ethylene glycol monoethyl ether, propylene glycol dimethyl ether, and diethylene glycol dimethyl ether; esters, such as PGMEA, propylene glycol monoethyl ether acetate, ethyl lactate, ethyl pyruvate, butyl acetate, methyl 3-methoxypropionate, ethyl 3-ethoxypropionate, tert-butyl acetate, tert-butyl propionate, and propylene glycol mono-tert-butyl ether acetate; lactones, such as GBL; and mixed solvents thereof.

When the polymer having an acetal-based acid-labile group is used, an alcoholic solvent having a high boiling point can be added to accelerate the deprotection reaction of the acetal. Specific examples of such an alcoholic solvent having a high boiling point include diethylene glycol, propylene glycol, glycerin, 1,4-butanediol, and 1,3-butanediol.

Among these organic solvents, 1-ethoxy-2-propanol, PGMEA, cyclohexanone, GBL, DAA, ethyl lactate, and mixed solvents thereof, which have particularly excellent solubility of the polymer of the component (P), are preferable.

A used amount of the organic solvent is preferably 200 to 5,000 parts by mass, more preferably 400 to 3,000 parts by mass, relative to 80 parts by mass of the polymer (P). One kind of the organic solvent (H) can be used, or two or more kinds thereof can be used in mixture.

[(I) Photo-Acid Generator Other than Photo-Acid Generator Bonded to Polymer Chain]

The chemically amplified resist composition of the present invention may contain a photo-acid generator, as a component (I), other than the photo-acid generator bonded to the polymer chain. The photo-acid generator is not particularly limited as long as it is a compound to generate an acid by irradiation with a high-energy beam. Examples of suitable photo-acid generators include compounds represented by the following formula (3).

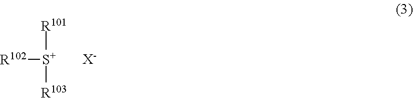

In the formula (3), R¹⁰¹, R¹⁰², and R¹⁰³ each independently represent a hydrocarbyl group having 1 to 20 carbon atoms and optionally having a heteroatom. Any two of R¹⁰¹, R¹⁰², and R¹⁰³ are optionally bonded to each other to form a ring together with the sulfur atom to which R¹⁰¹, R¹⁰², and R¹⁰³ are bonded. The hydrocarbyl group may be a saturated or unsaturated group, and may be any of linear, branched, and cyclic groups. Specific examples thereof include the groups given as examples in the description of R¹¹ to R¹⁵ in the formulae (cation-1) and (cation-2). Specific examples of the cation of the sulfonium salt represented by the formula (3) include the cations given as specific examples of the sulfonium cation represented by the formula (cation-1).

In the formula (3), X⁻ represents an anion selected from the following formulae (3A) to (3D).

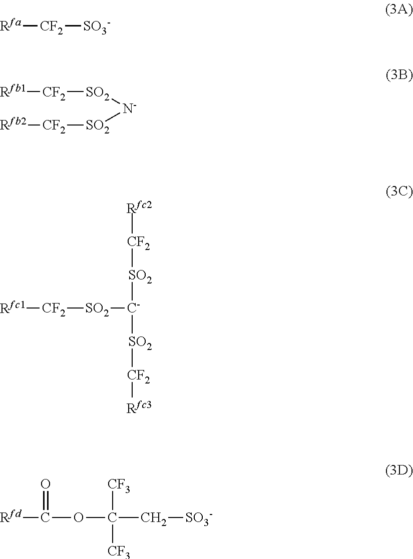

In the formula (3A), R^{fa} represents a fluorine atom or a hydrocarbyl group having 1 to 40 carbon atoms and optionally having a heteroatom. The hydrocarbyl group may be a saturated or unsaturated group, and may be any of linear, branched, and cyclic groups. Specific examples thereof include groups same as groups described below in the description of R¹⁰⁵ in the formula (3A′).

The anion represented by the formula (3A) is preferably represented by the following formula (3A′).

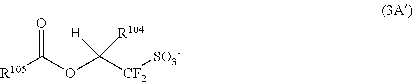

In the formula (3A′), R¹⁰⁴ represents a hydrogen atom or a trifluoromethyl group, preferably a trifluoromethyl group. R¹⁰⁵ represents a hydrocarbyl group having 1 to 38 carbon atoms and optionally having a heteroatom. The heteroatom is preferably an oxygen atom, a nitrogen atom, a sulfur atom, a halogen atom, etc., and more preferably an oxygen atom. The hydrocarbyl group particularly preferably has 6 to 30 carbon atoms in terms of obtaining high resolution in the fine pattern formation.

The hydrocarbyl group represented by R¹⁰⁵ may be a saturated or unsaturated group, and may be any of linear, branched, and cyclic groups. Specific examples thereof include: alkyl groups, such as a methyl group, an ethyl group, a propyl group, an isopropyl group, a butyl group, an isobutyl group, a sec-butyl group, a tert-butyl group, a pentyl group, a neopentyl group, a hexyl group, a heptyl group, a 2-ethylhexyl group, a nonyl group, an undecyl group, a tridecyl group, a pentadecyl group, a heptadecyl group, and an icosanyl group; cyclic saturated hydrocarbyl groups, such as a cyclopentyl group, a cyclohexyl group, a 1-adamantyl group, a 2-adamantyl group, a 1-adamantylmethyl group, a norbornyl group, a norbornylmethyl group, a tricyclodecanyl group, a tetracyclododecanyl group, a tetracyclododecanylmethyl group, and a dicyclohexylmethyl group; unsaturated aliphatic hydrocarbyl groups, such as an allyl group and a 3-cyclohexenyl group; aryl groups, such as a phenyl group, a 1-naphthyl group, and a 2-naphthyl group; and aralkyl groups, such as a benzyl group and a diphenylmethyl group. Among these, aliphatic groups are preferable as R¹⁰⁵. A part or all of hydrogen atoms in these groups are optionally substituted with a group having a heteroatom, such as an oxygen atom, a sulfur atom, a nitrogen atom, and a halogen atom. A part of carbon atoms in these groups is optionally substituted with a group having a heteroatom, such as an oxygen atom, a sulfur atom, and a nitrogen atom. As a result, a hydroxy group, a cyano group, a carbonyl group, an ether bond, an ester bond, a sulfonic acid ester bond, a carbonate group, a lactone ring, a sultone ring, a carboxylic anhydride, a haloalkyl group, etc. are optionally contained. Examples of the hydrocarbyl groups having a heteroatom include a tetrahydrofuryl group, a methoxymethyl group, an ethoxymethyl group, a methylthiomethyl group, an acetamidemethyl group, a trifluoroethyl group, a (2-methoxyethoxy)methyl group, an acetoxymethyl group, a 2-carboxy-1-cyclohexyl group, a 2-oxopropyl group, a 4-oxo-1-adamantyl group, and a 3-oxocyclohexyl group.

Synthesis of the sulfonium salt having the anion represented by the formula (3A′) is described in detail in JP 2007-145797 A, JP 2008-106045 A, JP 2009-007327 A, and JP 2009-258695 A. It is also suitable to use the sulfonium salts described in JP 2010-215608 A, JP 2012-041320 A, JP 2012-106986 A, JP 2012-153644 A, etc.

Examples of the anion represented by the formula (3A) include anions same as the anions described in M⁻ in the formula (B-1), but the anion is not limited thereto.

In the formula (3B), R^{fb1} and R^{fb2} each independently represent a fluorine atom or a hydrocarbyl group having 1 to 40 carbon atoms and optionally having a heteroatom. The hydrocarbyl group may be a saturated or unsaturated group, and may be any of linear, branched, and cyclic groups. Specific examples thereof include groups same as the groups exemplified in the description of R¹⁰⁵ in the formula (3A′). R^{fb1} and R^{fb2} are preferably a fluorine atom or a linear fluorinated alkyl group having 1 to 4 carbon atoms. R^{fb1} and R^{fb2} are optionally bonded to each other to form a ring together with the group to which R^{fb1} and R^{fb2} are bonded (—CF₂—SO₂—N—SO₂—CF₂—), and the group obtained by bonding R^{fb1} and R^{fb2} to each other is preferably a fluorinated ethylene group or a fluorinated propylene group.

In the formula (3C), R^{fc1}, R^{fc2}, and R^{fc3} each independently represent a fluorine atom or a hydrocarbyl group having 1 to 40 carbon atoms and optionally having a heteroatom. The hydrocarbyl group may be a saturated or unsaturated group, and may be any of linear, branched, and cyclic groups. Specific examples thereof include the groups given as examples in the description of R¹⁰⁵ in the formula (3A′). R^{fc1}, R^{fc2}, and R^{fc3} are preferably a fluorine atom or a linear fluorinated alkyl group having 1 to 4 carbon atoms. Any two of R^{fc1}, R^{fc2}, and R^{fc3} are optionally bonded to each other to form a ring together with the group to which R^{fc1}, R^{fc2}, and R^{fc3} are bonded (—CF₂—SO₂—C—SO₂—CF₂—). In this event, the group obtained by bonding two of R^{fc1}, R^{fc2}, and R^{fc3} to each other is preferably a fluorinated ethylene group or a fluorinated propylene group.

In the formula (3D), R^{fd} represents a hydrocarbyl group having 1 to 40 carbon atoms and optionally having a heteroatom. The hydrocarbyl group may be a saturated or unsaturated group, and may be any of linear, branched, and cyclic groups. Specific examples thereof include groups same as the groups exemplified in the description of R¹⁰³ in the formula (3A′).

Synthesis of the sulfonium salt having the anion represented by the formula (3D) is described in detail in JP 2010-215608 A and JP 2014-133723 A.

Examples of the anion represented by the formula (3D) include the following anions, but the anion is not limited thereto.

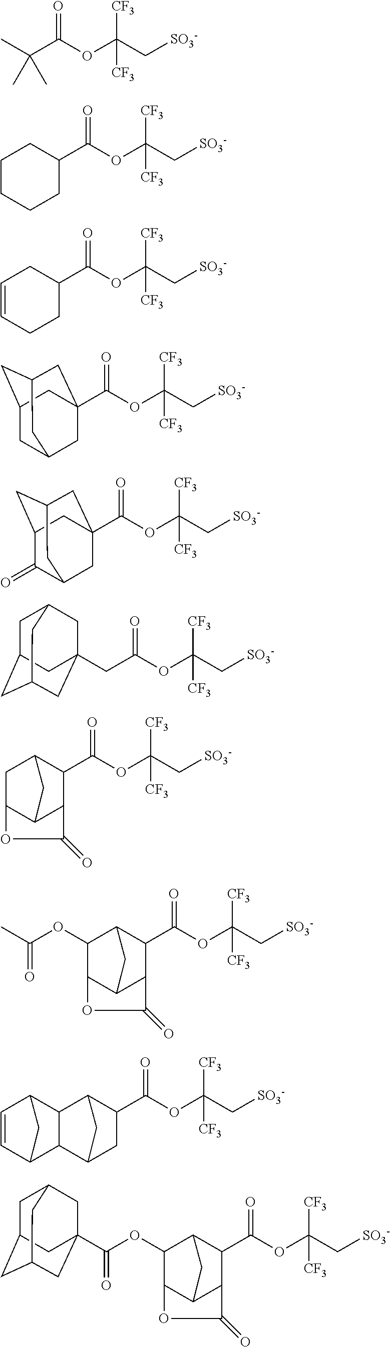

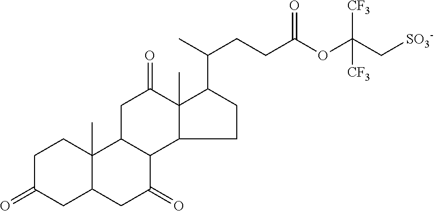

Although having no fluorine atom at the α-position of the sulfo group, the photo-acid generator having the anion represented by the formula (3D) has sufficient acidity for cleaving the acid-labile group in the polymer because the anion has two trifluoromethyl groups at the β-position. Thus, it can be used as a photo-acid generator.

The photo-acid generator other than the photo-acid generator bonded to the polymer chain of the component (I) is also preferably a photo-acid generator represented by the following formula (4).

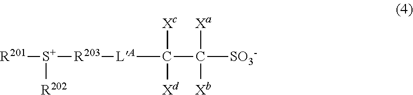

In the formula (4), R²⁰¹ and R²⁰² each independently represent a hydrocarbyl group having 1 to 30 carbon atoms and optionally having a heteroatom. R²⁰³ represents a hydrocarbylene group having 1 to 30 carbon atoms and optionally having a heteroatom. Any two of R²⁰¹, R²⁰², and R²⁰³ are optionally bonded to each other to form a ring together with the sulfur atom to which R²⁰¹, R²⁰², and R²⁰³ are bonded. Examples of the ring include the rings given as examples of the ring that can be formed by bonding R²¹ and R²² to each other together with the sulfur atom to which R²¹ and R²² are bonded in the description of the formula (B-1).

The hydrocarbyl group represented by R²⁰¹ and R²⁰² may be a saturated or unsaturated group, and may be any of linear, branched, and cyclic groups. Specific examples thereof include: alkyl groups, such as a methyl group, an ethyl group, a propyl group, an isopropyl group, an n-butyl group, a sec-butyl group, a tert-butyl group, an n-pentyl group, a tert-pentyl group, an n-hexyl group, an n-octyl group, a 2-ethylhexyl group, an n-nonyl group, and an n-decyl group; cyclic saturated hydrocarbyl groups, such as a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a norbornyl group, a tricyclo[5.2.1.0^{2,6}]decanyl group, and an adamantyl group; and aryl groups, such as a phenyl group, a naphthyl group, and an anthracenyl group. A part of hydrogen atoms in these groups is optionally substituted with a group having a heteroatom such as an oxygen atom, a sulfur atom, a nitrogen atom, and a halogen atom. A part of carbon atoms in these groups is optionally substituted with a group having a heteroatom such as an oxygen atom, a sulfur atom, and a nitrogen atom. As a result, a hydroxy group, a cyano group, a carbonyl group, an ether bond, an ester bond, a sulfonic acid ester bond, a carbonate group, a lactone ring, a sultone ring, a carboxylic anhydride, a haloalkyl group, etc. are optionally contained.

The hydrocarbylene group represented by R²⁰³ may be a saturated or unsaturated group, and may be any of linear, branched, and cyclic groups. Specific examples thereof include: alkanediyl groups, such as a methylene group, an ethylene group, a propane-1,3-diyl group, a butane-1,4-diyl group, a pentane-1,5-diyl group, a hexane-1,6-diyl group, a heptane-1,7-diyl group, an octane-1,8-diyl group, a nonane-1,9-diyl group, a decane-1,10-diyl group, an undecane-1,11-diyl group, a dodecane-1,12-diyl group, a tridecane-1,13-diyl group, a tetradecane-1,14-diyl group, a pentadecane-1,15-diyl group, a hexadecane-1,16-diyl group, and a heptadecane-1,17-diyl group; cyclic saturated hydrocarbylene groups, such as a cyclopentanediyl group, a cyclohexanediyl group, a norbornanediyl group, and an adamantanediyl group; and arylene groups, such as a phenylene group, a methylphenylene group, an ethylphenylene group, an n-propylphenylene group, an isopropylphenylene group, an n-butylphenylene group, an isobutylphenylene group, a sec-butylphenylene group, a tert-butylphenylene group, a naphthylene group, a methylnaphthylene group, an ethylnaphthylene group, an n-propylnaphthylene group, an isopropylnaphthylene group, an n-butylnaphthylene group, an isobutylnaphthylene group, a sec-butylnaphthylene group, and a tert-butylnaphthylene group. A part of hydrogen atoms in these groups is optionally substituted with a group having a heteroatom, such as an oxygen atom, a sulfur atom, a nitrogen atom, and a halogen atom. A part of carbon atoms in these groups is optionally substituted with a group having a heteroatom, such as an oxygen atom, a sulfur atom, and a nitrogen atom. As a result, a hydroxy group, a cyano group, a carbonyl group, an ether bond, an ester bond, a sulfonic acid ester bond, a carbonate group, a lactone ring, a sultone ring, a carboxylic anhydride, a haloalkyl group, etc. are optionally contained. The heteroatom is preferably an oxygen atom.

In the formula (4), L′^{A} represents a single bond, an ether bond, or a hydrocarbylene group having 1 to 20 carbon atoms and optionally having a heteroatom. The hydrocarbylene group may be a saturated or unsaturated group, and may be any of linear, branched, and cyclic groups. Specific examples thereof include the groups given as examples of the hydrocarbylene group represented by R²⁰³.

In the formula (4), X^{a}, X^{b}, X^{c}, and X^{d} each independently represent a hydrogen atom, a fluorine atom, or a trifluoromethyl group. At least one of X^{a}, X^{b}, X^{c}, and X^{d} represents a fluorine atom or a trifluoromethyl group.

The photo-acid generator represented by the formula (4) is preferably a photo-acid generator represented by the following formula (4′).

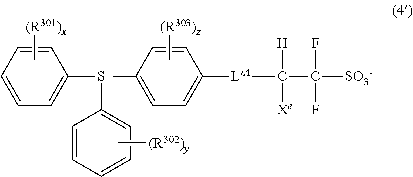

In the formula (4′), L′^{A} is as defined above. X^{e} represents a hydrogen atom or a trifluoromethyl group, and preferably represents a trifluoromethyl group. R³⁰¹, R³⁰², and R³⁰³ each independently represent a hydrogen atom or a hydrocarbyl group having 1 to 20 carbon atoms and optionally having a heteroatom. The hydrocarbyl group may be a saturated or unsaturated group, and may be any of linear, branched, and cyclic groups. Specific examples thereof include the groups given as examples in the description of R¹⁰⁵ in the formula (3A′). “x” and “y” each independently represent an integer of 0 to 5. “z” represents an integer of 0 to 4.

Examples of the photo-acid generator represented by the formula (4) include the photo-acid generators given as examples of the photo-acid generators represented by the formula (4) in JP 2017-026980 A.

Among the above photo-acid generators, the photo-acid generators having the anion represented by the formula (3A′) or (3D) are particularly preferable since such photo-acid generators have small acid diffusion and excellent solubility in the resist solvent. The photo-acid generators having the anion represented by the formula (4′) are particularly preferable for having extremely small acid diffusion.

As other acid generators, onium salts represented by the following formula (5-1) or (5-2) can also be used.

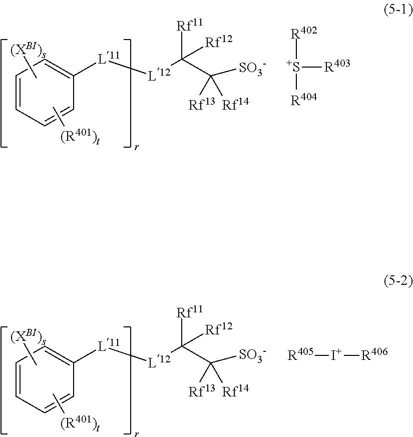

In the formulae (5-1) and (5-2), “r” represents an integer satisfying 1≤r≤3. “s” and “t” represent integers satisfying 1≤s≤5, 0≤t≤3, and 1≤s+t≤5. “s” preferably represents an integer satisfying 1≤s≤3, and more preferably represents 2 or 3. “t” preferably represents an integer satisfying 0≤t≤2.

In the formulae (5-1) and (5-2), X^{BI} represents an iodine atom or a bromine atom. When “s” represents 2 or more, X^{BI} may be identical to or different from each other.

In the formulae (5-1) and (5-2), L′¹¹ represents a single bond, an ether bond, an ester bond, or a saturated hydrocarbylene group having 1 to 6 carbon atoms and optionally having an ether bond or an ester bond. The saturated hydrocarbylene group may be any of linear, branched, and cyclic groups.

In the formulae (5-1) and (5-2), L′¹² represents a single bond or a divalent linkage group having 1 to 20 carbon atoms when “r” represents 1, and L′¹² represents a trivalent or tetravalent linkage group having 1 to 20 carbon atoms when “r” represents 2 or 3. The linkage group optionally has an oxygen atom, a sulfur atom, or a nitrogen atom.

In the formulae (5-1) and (5-2), R⁴⁰¹ represents a hydroxy group, a carboxy group, a fluorine atom, a chlorine atom, a bromine atom, an amino group, a saturated hydrocarbyl group having 1 to 20 carbon atoms, a saturated hydrocarbyloxy group having 1 to 20 carbon atoms, a saturated hydrocarbyloxycarbonyl group having 2 to 10 carbon atoms, a saturated hydrocarbylcarbonyloxy group having 2 to 20 carbon atoms, a saturated hydrocarbylsulfonyloxy group having 1 to 20 carbon atoms, —NR^{401A}—C(═O)—R^{401B}, or —NR^{401A}—C(═O)—O—R^{401B}. The saturated hydrocarbyl group, the saturated hydrocarbyloxy group, the saturated hydrocarbyloxycarbonyl group, the saturated hydrocarbylcarbonyloxy group, and the saturated hydrocarbylsulfonyloxy group optionally have a fluorine atom, a chlorine atom, a bromine atom, a hydroxy group, an amino group, or an ether bond.

R^{401A} represents a hydrogen atom or a saturated hydrocarbyl group having 1 to 6 carbon atoms. R^{401A} optionally has a halogen atom, a hydroxy group, a saturated hydrocarbyloxy group having 1 to 6 carbon atoms, a saturated hydrocarbyloxycarbonyl group having 2 to 6 carbon atoms, a saturated hydrocarbylcarbonyl group having 2 to 6 carbon atoms, or a saturated hydrocarbylcarbonyloxy group having 2 to 6 carbon atoms.

R^{401B} represents an aliphatic hydrocarbyl group having 1 to 16 carbon atoms or an aryl group having 6 to 12 carbon atoms. R^{401B} optionally has a halogen atom, a hydroxy group, a saturated hydrocarbyloxy group having 1 to 6 carbon atoms, a saturated hydrocarbyloxycarbonyl group having 2 to 6 carbon atoms, a saturated hydrocarbylcarbonyl group having 2 to 6 carbon atoms, or a saturated hydrocarbylcarbonyloxy group having 2 to 6 carbon atoms.

The aliphatic hydrocarbyl group may be a saturated or unsaturated group, and may be any of linear, branched, and cyclic groups. The saturated hydrocarbyl group, the saturated hydrocarbyloxy group, the saturated hydrocarbyloxycarbonyl group, the saturated hydrocarbylcarbonyl group, and the saturated hydrocarbylcarbonyloxy group may be any of linear, branched, and cyclic groups.

When “t” represents 2 or more, each R⁴⁰¹ may be identical to or different from each other.

Among these, R⁴⁰¹ preferably represents a hydroxy group, —NR^{401A}—C(═O)—R^{401B}, —NR^{401A}—C(═O)—O—R^{401B}, a fluorine atom, a chlorine atom, a bromine atom, a methyl group, a methoxy group, etc.

In the formulae (5-1) and (5-2), Rf¹¹, Rf¹², Rf¹³, and Rf¹⁴ each independently represent a hydrogen atom, a fluorine atom, or a trifluoromethyl group, and at least one of them represents a fluorine atom or a trifluoromethyl group. Rf¹¹ and Rf¹² are optionally combined to form a carbonyl group together with the carbon atom bonded thereto. Both Rf¹³ and Rf¹⁴ particularly preferably represent fluorine atoms.

In the formulae (5-1) and (5-2), R⁴⁰², R⁴⁰³, R⁴⁰⁴, R⁴⁰⁵, and R⁴⁰⁶ each independently represent a hydrocarbyl group having 1 to 20 carbon atoms and optionally having a heteroatom. The hydrocarbyl group may be a saturated or unsaturated group, and may be any of linear, branched, and cyclic groups. Specific examples thereof include alkyl groups having 1 to 20 carbon atoms, cycloalkyl groups having 3 to 20 carbon atoms, alkenyl groups having 2 to 12 carbon atoms, alkynyl groups having 2 to 12 carbon atoms, aryl groups having 6 to 20 carbon atoms, and aralkyl groups having 7 to 12 carbon atoms.

A part or all of hydrogen atoms in these groups are optionally substituted with a hydroxy group, a carboxy group, a halogen atom, a cyano group, a nitro group, a mercapto group, a sultone group, a sulfone group, or a sulfonium salt-containing group. A part of carbon atoms in these groups is optionally substituted with an ether bond, an ester bond, a carbonyl group, an amide bond, a carbonate group, or a sulfonic acid ester bond.

Any two of R⁴⁰², R⁴⁰³, and R⁴⁰⁴ are optionally bonded to each other to form a ring together with the sulfur atom to which R⁴⁰², R⁴⁰³, and R⁴⁰⁴ are bonded. In this event, examples of the ring include the rings given as examples of the ring that can be formed by bonding two out of R¹⁰¹, R¹⁰², and R¹⁰³ to each other together with the sulfur atom to which R¹⁰¹, R¹⁰², and R¹⁰³ are bonded in the description of the formula (3).

Examples of the cation of the sulfonium salt represented by the formula (5-1) include cations same as the cations exemplified as the sulfonium cation represented by the formula (cation-1). Examples of the cation of the iodonium salt represented by the formula (5-2) include cations same as the cations exemplified as the iodonium cation represented by the formula (cation-2).

Examples of the anion of the onium salt represented by the formulae (5-1) and (5-2) include anions exemplified as the anion of the onium salt represented by the formulae (5-1) and (5-2) in JP 2018-197853 A, and in addition, anions in which the iodine atom in the anion is substituted with a bromine atom.

When the photo-acid generator other than the photo-acid generator bonded to the polymer chain of the component (I) is contained, the contained amount thereof is preferably 0.1 to 40 parts by mass, and more preferably 0.5 to 20 parts by mass, relative to 80 parts by mass of the polymer (P). The addition amount of the photo-acid generator other than the photo-acid generator bonded to the polymer chain of the component (I) within the above range is preferable because of good resolution and no risk of generation of a foreign matter problem after the development or during the removal of the resist film. One kind of the photo-acid generator other than the photo-acid generator bonded to the polymer chain of the component (I) may be used, or two or more kinds thereof may be used in combination.

### [(J) Nitrogen-Containing Quencher]

The chemically amplified resist composition of the present invention may further contain a nitrogen-containing quencher. In the present invention, the nitrogen-containing quencher refers to a material that traps the acid generated from the photo-acid generator in the chemically amplified resist composition for inhibiting the diffusion toward an unexposed portion to form a desired pattern.

Examples of the nitrogen-containing quencher of the component (J) include primary, secondary, or tertiary amine compounds described in paragraphs [0146] to [0164] of JP 2008-111103 A, in particular, amine compounds having a hydroxy group, an ether bond, an ester bond, a lactone ring, a cyano group, or a sulfonic acid ester bond. Examples thereof also include compounds in which a primary or secondary amine is protected with a carbamate group, such as compounds described in JP 3790649 B2.

As the nitrogen-containing quencher, a sulfonium sulfonate salt having a nitrogen-containing substituent may also be used. Such a compound functions as a so-called photodegradable base, which functions as a quencher in an unexposed portion, and loses the quenching ability by neutralization with a generated acid of the photodegradable base itself in an exposed portion. Using the photodegradable base can further enhance the contrast between the exposed portion and the unexposed portion. As the photodegradable base, JP 2009-109595 A and JP 2012-046501 A can be referred to, for example.

When the nitrogen-containing quencher of the component (J) is contained, the contained amount thereof is preferably 0.001 to 12 parts by mass, more preferably 0.01 to 8 parts by mass, relative to 80 parts by mass of the polymer (P). One kind of the nitrogen-containing quencher may be used, or two or more kinds thereof may be used in combination.

[(K) Surfactant Insoluble or Hardly Soluble in Water and Soluble in Alkaline Developer; and/or Surfactant Insoluble or Hardly Soluble in Water and Alkaline Developer]

The chemically amplified resist composition of the present invention may further contain (K) a surfactant insoluble or hardly soluble in water and soluble in an alkaline developer; and/or a surfactant insoluble or hardly soluble in water and an alkaline developer. As such a surfactant, surfactants described in JP 2010-215608 A and JP 2011-016746 A can be referred to.

Among the surfactants described in the above patent documents, the surfactant insoluble or hardly soluble in water and an alkaline developer is preferably FC-4430 (manufactured by 3M Company), SURFLON®S-381 (manufactured by AGC Seimi Chemical Co., Ltd.), OLFIN® E1004 (manufactured by Nissin Chemical Industry Co., Ltd.), KH-20 and KH-30 (manufactured by AGC Seimi Chemical Co., Ltd.), and oxetane ring-opening polymerized product represented by the following formula (surf-1).

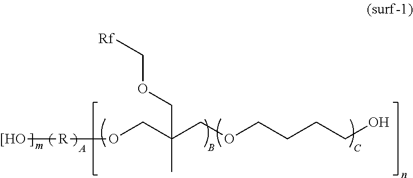

Here, R, Rf, A, B, C, “m”, and “n” in the formula (surf-1) are applied only in the formula (surf-1) regardless of the above description. R represents a divalent to tetravalent aliphatic group having 2 to 6 carbon atoms. Examples of the divalent aliphatic group include an ethylene group, a 1,4-butylene group, a 1,2-propylene group, a 2,2-dimethyl-1,3-propylene group, and a 1,5-pentylene group. Examples of the trivalent or tetravalent aliphatic group include the following groups.

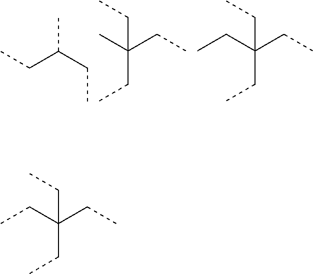

In the formula, a broken line represents an attachment point. The groups are partial structures derived from glycerol, trimethylolethane, trimethylolpropane, and pentaerythritol, respectively.

Among these, a 1,4-butylene group and a 2,2-dimethyl-1,3-propylene group are preferable.

Rf represents a trifluoromethyl group or a pentafluoroethyl group, and preferably represents a trifluoromethyl group. “m” represents an integer of 0 to 3. “n” represents an integer of 1 to 4. The sum of “n” and “m”, which represents a valency of R, is an integer of 2 to 4. “A” represents 1. “B” represents an integer of 2 to 25, and preferably represents an integer of 4 to 20. “C” represents an integer of 0 to 10, and preferably represents 0 or 1. As for each constituting unit in the formula (surf-1), the order is not stipulated, and may be block-bonded or random-bonded. Production of the surfactant of the partially fluorinated oxetane ring-opening polymerized product is described in detail in U.S. Pat. No. 5,650,483 B.

In the ArF immersion exposure without a resist protective film, the surfactant insoluble or hardly soluble in water and soluble in an alkaline developer has a function of reducing penetration of water or leaching by segregating at the surface of the resist film. Thus, such a surfactant is useful for inhibiting elution of a water-soluble component from the resist film to reduce damage of an exposure apparatus. Such a surfactant is also useful because such a surfactant becomes soluble during development with an aqueous alkaline solution after the exposure or after the PEB, and hardly forms a foreign matter causing a defect. Such a surfactant, which has a property of being insoluble or hardly soluble in water and soluble in an alkaline developer, is preferably a polymer surfactant, which is also referred to as a hydrophobic resin. In particular, such a surfactant preferably has high water repellency and improves water-slipping property.

Examples of such a polymer surfactant include a polymer having at least one selected from repeating units represented by the following formulae (6A) to (6E).

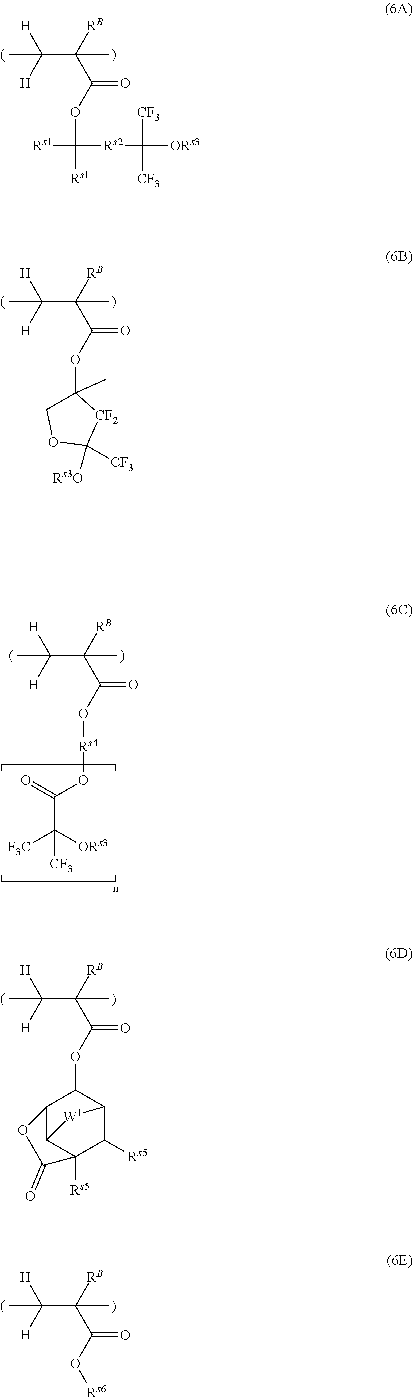

In the formulae (6A) to (6E), R^{B} represents a hydrogen atom, a fluorine atom, a methyl group, or a trifluoromethyl group. W¹ represents —CH₂—, —CH₂CH₂—, —O—, or two “—H”s which are separated from each other. R^{s1} each independently represents a hydrogen atom or a hydrocarbyl group having 1 to 10 carbon atoms. R^{s2} represents a single bond or a linear or branched hydrocarbylene group having 1 to 5 carbon atoms. R^{s3} each independently represents a hydrogen atom, a hydrocarbyl group or fluorinated hydrocarbyl group having 1 to 15 carbon atoms, or an acid-labile group. When R^{s3} represents a hydrocarbyl group or a fluorinated hydrocarbyl group, an ether bond (—O—) or a carbonyl group (—C(═O)—) is optionally interposed between a carbon-carbon bond. R^{s4} represents a (u+1)-valent hydrocarbon group or fluorinated hydrocarbon group having 1 to 20 carbon atoms. “u” represents an integer of 1 to 3. R^{s5} each independently represents a hydrogen atom or a group represented by the formula —C(═O)—O—R^{sa}. R^{sa} represents a fluorinated hydrocarbyl group having 1 to 20 carbon atoms. R^{s6} represents a hydrocarbyl group or fluorinated hydrocarbyl group having 1 to 15 carbon atoms, and an ether bond (—O—) or a carbonyl group (—C(═O)—) is optionally interposed between a carbon-carbon bond.

The hydrocarbyl group represented by R^{s1} is preferably a saturated hydrocarbyl group, and may be any of linear, branched, and cyclic groups. Specific examples thereof include: alkyl groups, such as a methyl group, an ethyl group, an n-propyl group, an isopropyl group, an n-butyl group, an isobutyl group, a sec-butyl group, a tert-butyl group, an n-pentyl group, an n-hexyl group, an n-heptyl group, an n-octyl group, an n-nonyl group, and an n-decyl group; and cyclic saturated hydrocarbyl groups, such as a cyclopropyl group, a cyclobutyl group, a cyclopentyl group, a cyclohexyl group, an adamantyl group, and a norbornyl group. Among these, groups having 1 to 6 carbon atoms are preferable.

The hydrocarbylene group represented by R^{s2} is preferably a saturated hydrocarbylene group, and may be any of linear, branched, and cyclic groups. Specific examples thereof include a methylene group, an ethylene group, a propylene group, a butylene group, and a pentylene group.

The hydrocarbyl group represented by R^{s3} or R^{s6} may be a saturated or unsaturated group, and may be any of linear, branched, and cyclic groups. Specific examples thereof include: saturated hydrocarbyl groups; and aliphatic unsaturated hydrocarbyl groups, such as alkenyl groups and alkynyl groups, and saturated hydrocarbyl groups are preferable. Examples of the saturated hydrocarbyl group include the groups exemplified as the hydrocarbyl group represented by R^{s1}, and in addition, an n-undecyl group, an n-dodecyl group, a tridecyl group, a tetradecyl group, and a pentadecyl group. Examples of the fluorinated hydrocarbyl group represented by R^{s3} or R^{s6} include groups in which a part or all of hydrogen atoms bonded to a carbon atom in the above hydrocarbyl group is substituted with a fluorine atom. As described above, an ether bond (—O—) or a carbonyl group (—C(═O)—) is optionally interposed between a carbon-carbon bond thereof.

Examples of the acid-labile group represented by R^{s3} include: the groups represented by the aforementioned formulae (AL-1) to (AL-3); trialkylsilyl groups in which each alkyl group has 1 to 6 carbon atoms; and oxo-group-containing alkyl groups having 4 to 20 carbon atoms.

The (u+1)-valent hydrocarbon group or fluorinated hydrocarbon group represented by R^{S4} may be any of linear, branched, and cyclic groups. Specific examples thereof include groups in which u hydrogen atoms are further removed from the above hydrocarbyl group, fluorinated hydrocarbyl group, etc.

The fluorinated hydrocarbyl group represented by R^{sa} is preferably a saturated group, and may be any of linear, branched, and cyclic groups. Specific examples thereof include groups in which a part or all of hydrogen atoms in the above hydrocarbyl group are substituted with a fluorine atom. Specific examples thereof include a trifluoromethyl group, a 2,2,2-trifluoroethyl group, a 3,3,3-trifluoro-1-propyl group, a 3,3,3-trifluoro-2-propyl group, a 2,2,3,3-tetrafluoropropyl group, a 1,1,1,3,3,3-hexafluoroisopropyl group, a 2,2,3,3,4,4,4-heptafluorobutyl group, a 2,2,3,3,4,4,5,5-octafluoropentyl group, a 2,2,3,3,4,4,5,5,6,6,7,7-dodecafluoroheptyl group, a 2-(perfluorobutyl)ethyl group, a 2-(perfluorohexyl)ethyl group, a 2-(perfluorooctyl)ethyl group, and a 2-(perfluorodecyl)ethyl group.

Examples of the repeating units represented by the formulae (6A) to (6E) include the following repeating units, but the repeating unit is not limited thereto. In the following formulae, R^{B} is as defined above.

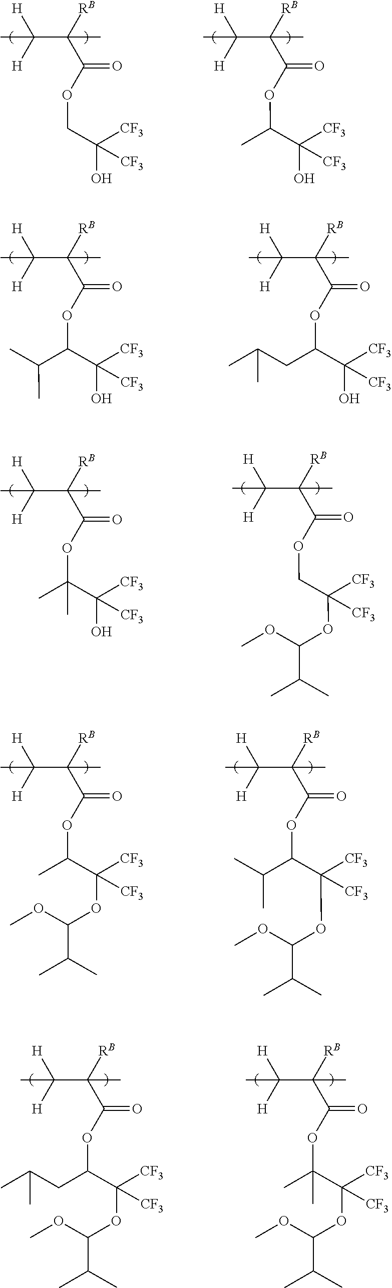

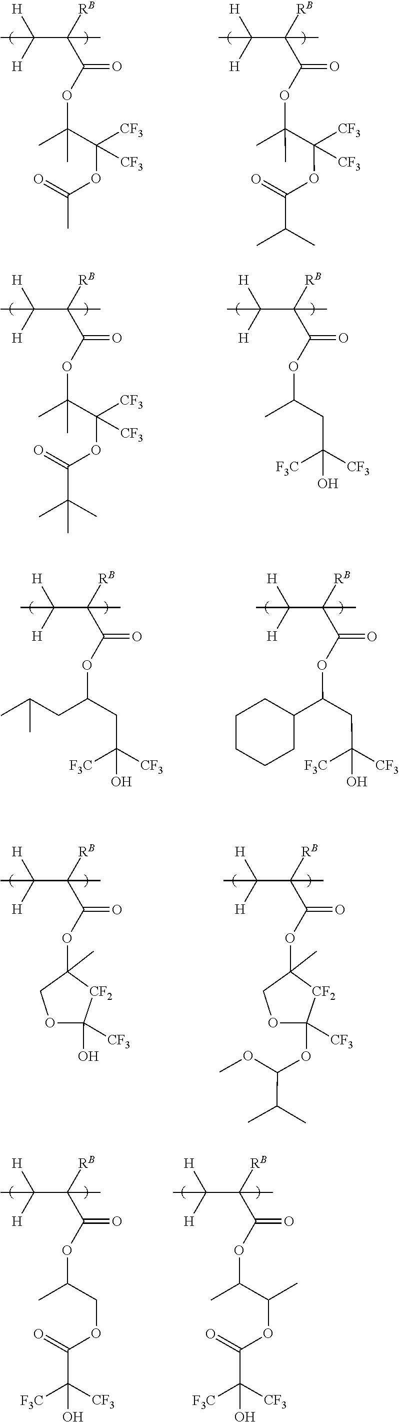

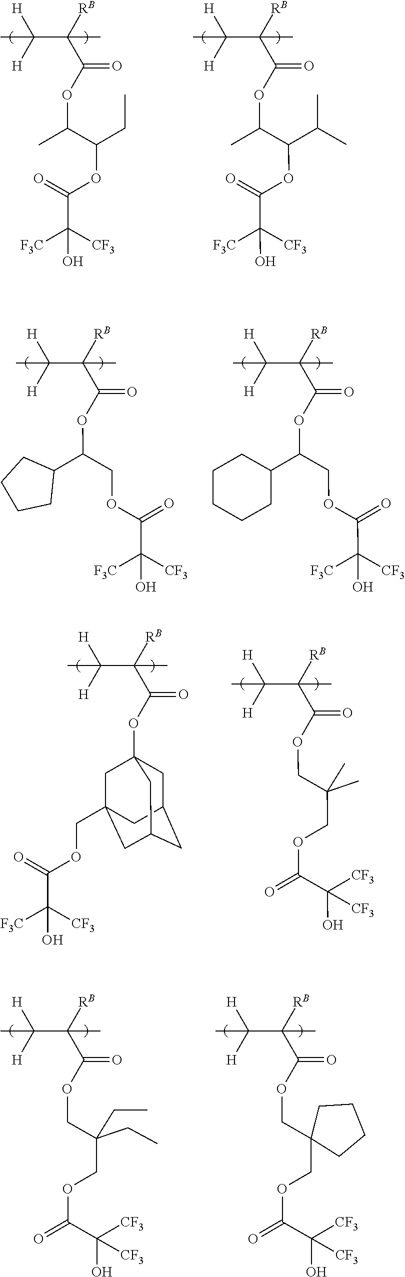

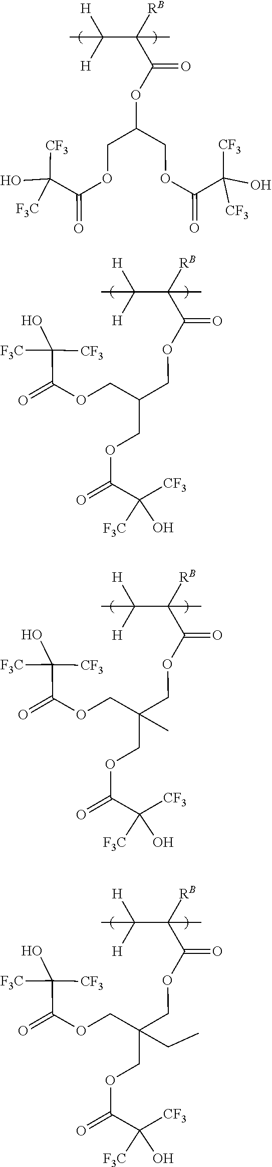

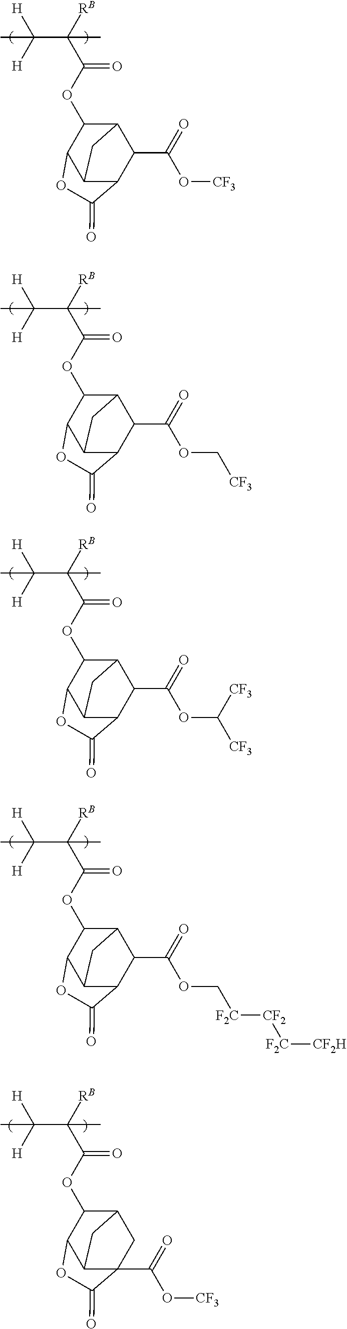

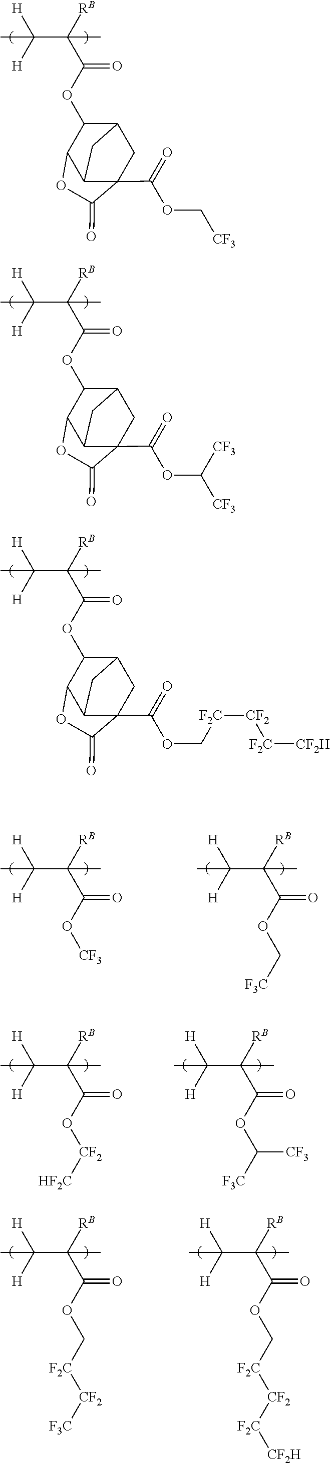

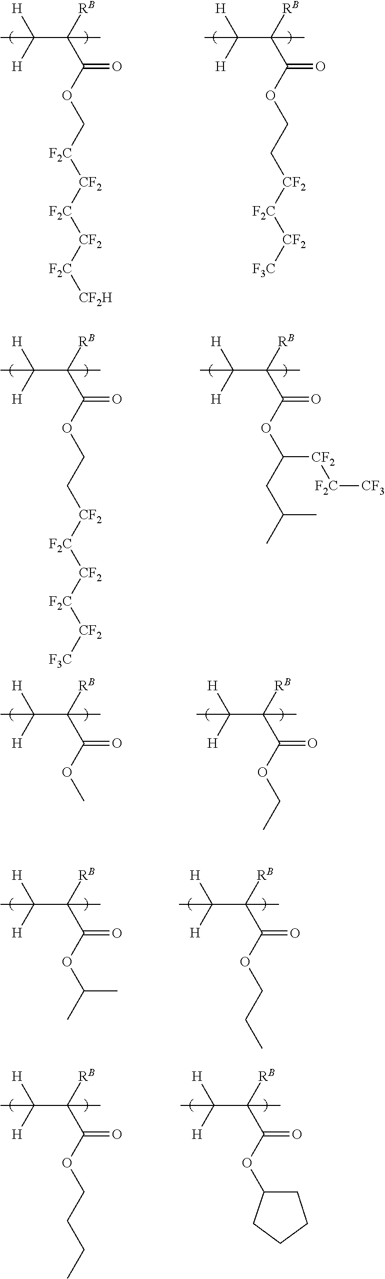

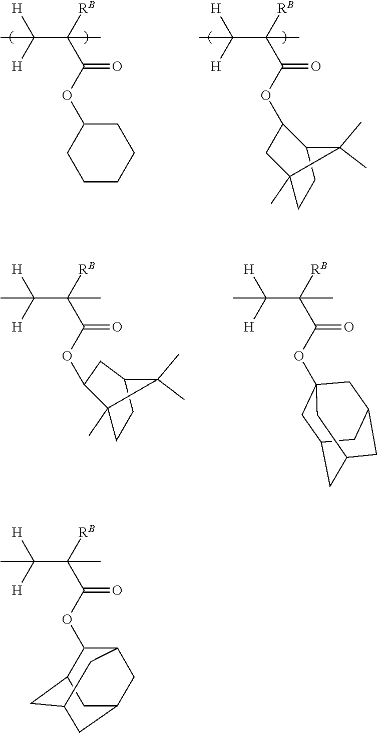

The polymer surfactant may further have a repeating unit other than the repeating unit represented by the formulae (6A) to (6E). Examples of the other repeating unit include repeating units obtained from methacrylic acid, an α-trifluoromethylacrylic acid derivative, etc. In the polymer surfactant, the contained amount of the repeating units represented by the formulae (6A) to (6E) is preferably 20 mol % or more, more preferably 60 mol % or more, and further preferably 100 mol % of all the repeating units.

Mw of the polymer surfactant is preferably 1,000 to 500,000, and more preferably 3,000 to 100,000. Mw/Mn is preferably 1.0 to 2.0, and more preferably 1.0 to 1.6.

Examples of a method for synthesizing the polymer surfactant include a method in which, in an organic solvent, monomers having an unsaturated bond to yield the repeating unit represented by the formulae (6A) to (6E) and, as necessary, other repeating units are added with a radical initiator and heated to be polymerized. Examples of the organic solvent used in the polymerization include toluene, benzene, THF, diethyl ether, and dioxane. Examples of the polymerization initiator include AIBN, 2,2′-azobis(2,4-dimethylvaleronitrile), dimethyl 2,2-azobis(2-methylpropionate), benzoyl peroxide, and lauroyl peroxide. The reaction temperature is preferably 50 to 100° C. The reaction time is preferably 4 to 24 hours. The acid-labile group may be introduced into the monomer to be used as it is, or may be protected or partially protected after the polymerization.

When the polymer surfactant is synthesized, known chain transfer agents, such as dodecyl mercaptan and 2-mercaptoethanol may be used to regulate the molecular weight. In this case, the addition amount of these chain transfer agents is preferably 0.01 to 10 mol % relative to the total number of moles of the monomers to be polymerized.

When the surfactant of the component (K) is contained, the contained amount thereof is preferably 0.1 to 50 parts by mass, and more preferably 0.5 to 10 parts by mass, relative to 80 parts by mass of the polymer (P). When the addition amount is 0.1 parts by mass or more, a sweepback contact angle between the resist film surface and water is sufficiently improved. When the addition amount is 50 parts by mass or less, the resist film surface has a low dissolution rate in the developing liquid to sufficiently maintain the height of the formed fine pattern.

### [(L) Other Components]

The chemically amplified resist composition of the present invention may contain: compounds to be decomposed by an acid to generate an acid (acid amplifying compounds); organic acid derivatives; fluorine-substituted alcohols; compounds to change in solubility in a developer by an action of an acid, the compound having Mw of 3,000 or less (dissolution inhibitors); etc. as another component (L). As the acid amplifying compound, compounds described in JP 2009-269953 A or JP 2010-215608 A can be referred to. When the acid amplifying compound is contained, the contained amount thereof is preferably 0 to 5 parts by mass, and more preferably 0 to 3 parts by mass, relative to 80 parts by mass of the polymer (P). Within the above range, the diffusion is easily controlled, and there is no degradation of resolution or degradation of the pattern profile. As the organic acid derivative, the fluorine-substituted alcohol, and the dissolution inhibitor, compounds described in JP 2009-269953 A or JP 2010-215608 A can be referred to.

### [Patterning Process]

The inventive patterning process includes the steps of:
(i) forming a resist film on a substrate by using the resist composition containing the above-described polymer;
(ii) exposing the resist film to a high-energy beam; and
(iii) developing the exposed resist film by using a developer.

As the substrate in the step (i), a substrate for producing an integrated circuit (such as Si, SiO₂, SiN, SiON, TiN, WSi, BPSG, SOG, and an organic anti-reflection film) or a substrate for producing a mask circuit (such as Cr, CrO, CrON, MoSi₂, and SiO₂) can be used, for example.

In the step (i), the resist film can be formed by, for example, applying the resist composition so as to have a film thickness of 0.05 to 2 μm by a method such as spin-coating, and prebaking this composition on a hot plate preferably at 60 to 150° C. for 1 to 10 minutes, more preferably at 80 to 140° C. for 1 to 5 minutes.

In the step (ii), examples of the high-energy beam used for exposing the resist film include i-line, KrF excimer laser light, ArF excimer laser light, electron beam (EB), and extreme ultraviolet ray (EUV). Extreme ultraviolet ray having a wavelength of 3 to 15 nm may be used. In particular, use of an electron beam and an extreme ultraviolet ray having a wavelength of 13.5 nm is effective. When the KrF excimer laser light, the ArF excimer laser light, or EUV is used for the exposure, the light-exposure can be performed by using a mask for forming a target pattern, and irradiating the resist film at an exposure dose of preferably 1 to 200 mJ/cm², more preferably 10 to 100 mJ/cm². When the EB is used, the light-exposure can be performed by irradiating the resist film at an exposure dose of preferably 1 to 300 μC/cm², more preferably 10 to 200 μC/cm², directly or using a mask for forming a target pattern.

The light-exposure can be performed by a common light-exposure method, or can be performed by using an immersion method in which a liquid having a refractive index of 1.0 or more is interposed between a resist film and a projection lens. In this case, a protective film insoluble in water can be used.

The protective film insoluble in water, which is used for preventing an eluted material from the resist film and for improving water-slipping property on the film surface, roughly includes two types. One type is an organic-solvent removal type, and the other type is an aqueous alkaline solution-soluble type. In the former type, the protective film is required to be removed by an organic solvent not dissolving the resist film before development with an aqueous alkaline solution. In the latter type, the protective film is soluble in an alkaline developer and removed together with a soluble portion in the resist film. The latter protective film is particularly preferably a material containing a base polymer having a 1,1,1,3,3,3-hexafluoro-2-propanol residue group, which is insoluble in water and soluble in the alkaline developer, and dissolved in a solvent. Examples of such a solvent include an alcoholic solvent having 4 or more carbon atoms, an ether solvent having 8 to 12 carbon atoms, and a mixed solvent thereof. The aforementioned surfactant insoluble in water and soluble in an alkaline developer can be dissolved in the alcoholic solvent having 4 or more carbon atoms, the ether solvent having 8 to 12 carbon atoms, or the mixed solvent thereof to form the above material.

PEB may be performed after the light exposure. PEB can be performed by heating, for example, on a hot plate preferably at 60 to 150° C. for 1 to 5 minutes, more preferably 80 to 140° C. for 1 to 3 minutes.

In the step (iii), a positive-tone development method can be used. This method uses an aqueous alkaline solution as the developer, and the exposed portion is dissolved and the unexposed portion is not dissolved to achieve the development. This method can yield a positive pattern.

In the step (iii), a developer of an aqueous alkaline solution, such as tetramethylammonium hydroxide (TMAH) at preferably 0.1 to 5 mass %, more preferably 2 to 3 mass %, can be used as the developer, for example. The development can be performed for preferably 0.1 to 3 minutes, more preferably 0.5 to 2 minutes, by a common method, such as a dip method, a puddle method, and a spray method, to form a target pattern on the substrate.

As a means for forming a pattern, after the resist film formation, the acid generator, etc. may be extracted from the film surface by performing a rinse with pure water (post soak), particles may be washed away, and rinsing (post soak) may be performed to remove water remaining on the film after the exposure.

Furthermore, a pattern may be formed by a double-patterning method. Examples of the double-patterning method include: a trench method in which a first exposure and etching process a foundation of 1:3 trenched pattern, and a position-shifted second exposure forms a 1:3 trenched pattern to form a 1:1 pattern; and a line method in which a first exposure and etching process a first foundation of 1:3 isolated left pattern, and a position-shifted second exposure processes a second foundation in which a 1:3 isolated left pattern is formed under the first foundation to form a 1:1 pattern with a half pitch.

Alternatively, in the step (iii) of the inventive patterning process, a negative-tone development method can be used. This method uses an organic solvent as a developer instead of the developer of the aqueous alkaline solution. The unexposed portion is dissolved and the exposed portion is not dissolved, and thus, the development is achieved. This method can yield a negative pattern.

As the developer for this organic solvent development, it is possible to use 2-octanone, 2-nonanone, 2-heptanone, 3-heptanone, 4-heptanone, 2-hexanone, 3-hexanone, diisobutyl ketone, methylcyclohexanone, acetophenone, methylacetophenone, propyl acetate, butyl acetate, isobutyl acetate, pentyl acetate, butenyl acetate, isopentyl acetate, propyl formate, butyl formate, isobutyl formate, pentyl formate, isopentyl formate, methyl valerate, methyl pentenoate, methyl crotonate, ethyl crotonate, methyl propionate, ethyl propionate, ethyl 3-ethoxypropionate, methyl lactate, ethyl lactate, propyl lactate, butyl lactate, isobutyl lactate, pentyl lactate, isopentyl lactate, methyl 2-hydroxyisobutyrate, ethyl 2-hydroxyisobutyrate, methyl benzoate, ethyl benzoate, phenyl acetate, benzyl acetate, methyl phenylacetate, benzyl formate, phenylethyl formate, methyl 3-phenylpropionate, benzyl propionate, ethyl phenylacetate, 2-phenylethyl acetate, etc. One kind of these organic solvents can be used, or two or more kinds thereof can be used in mixture.

### EXAMPLE

Hereinafter, the present invention will be described specifically with reference to Synthesis Examples, Comparative Synthesis Examples, Examples, and Comparative Examples. However, the present invention is not limited to the following Examples. Used apparatuses were as follows.
IR: NICOLET 6700, manufactured by Thermo Fisher Scientific K.K.
¹H-NMR: ECA-500, manufactured by JEOL Ltd.

### [1] Synthesis of Monomer

### [Synthesis Example 1-1] Synthesis of Monomer A1

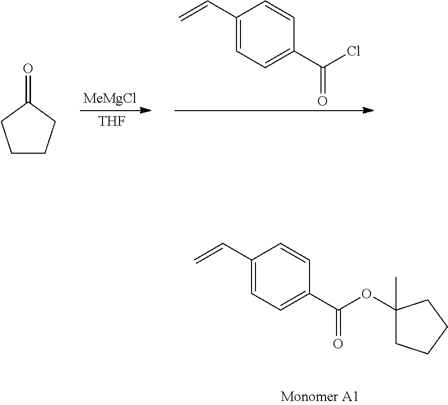 [SMILES: "MeMgCl" ; O=C1CCCC1 ; C=Cc1ccc(C(=O)Cl)cc1 ; C=Cc1ccc(C(=O)OC2(C)CCCC2)cc1 ; "THF"]

Under a nitrogen atmosphere, cyclopentanone (42.0 g) was dissolved in THF (200 g), methylmagnesium chloride (3.0 M-THF solution, 200 mL) was dropped into the solution in an ice bath, and the mixture was stirred for 1 hour. Subsequently, a solution of an acid chloride prepared from p-styrenecarboxylic acid (74.1 g) and THF (100 mL) was added dropwise with ice-bath cooling, and the mixture was stirred at room temperature for 3 hours. After that, the reaction liquid was cooled, and a saturated aqueous sodium bicarbonate solution (250 g) was added to terminate the reaction. A product was extracted with toluene (400 mL), a common aqueous work-up was performed, and after solvent removal, a product was purified by silica-gel column chromatography to obtain 74.9 g of monomer A1 as a colorless oil (65% yield).

IR spectrum data and results of 1H-NMR of monomer A1 are shown below.

IR (D-ATR): v=3089, 2966, 2973, 1710, 1630, 1608, 1567, 1507, 1464, 1444, 1403, 1374, 1314, 1283, 1201, 1175, 1118, 1107, 1016, 989, 915, 861, 783, 714, 453 cm⁻¹.

¹H-NMR (600 MHz in DMSO-d6): δ=7.86 (2H, d), 7.58 (2H, d), 6.79 (1H, dd), 5.96 (1H, d), 5.40 (1H, d), 2.17 (2H, m), 1.69 (6H, m), 1.61 (3H, s) ppm.

### [Synthesis Example 1-2] Synthesis of Monomer A2

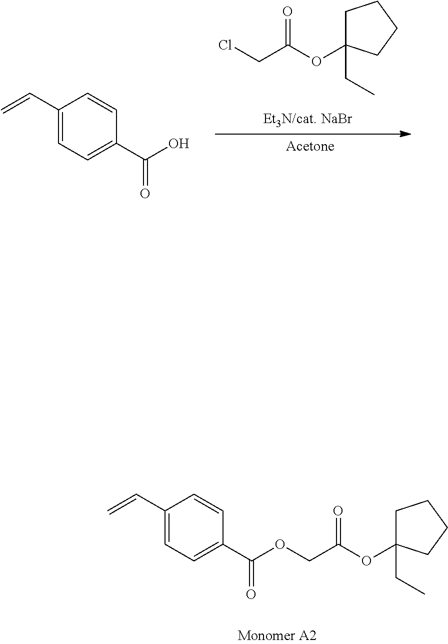 [SMILES: C=Cc1ccc(C(=O)O)cc1 ; CCC1(OC(=O)CCl)CCCC1 ; C=Cc1ccc(C(=O)OCC(=O)OC2(CC)CCCC2)cc1]

Under a nitrogen atmosphere, p-styrenecarboxylic acid (48.9 g), chloroacetic acid-1-ethylcyclopentyl (58.1 g), and sodium bromide (3.1 g) were dissolved in acetone (150 mL). Subsequently, triethylamine (36.4 g) was added dropwise at room temperature. After the dropwise addition, the mixture was stirred for 6 hours while maintaining the internal temperature to 50° C. The reaction liquid was then cooled, and water (75 g) was added to terminate the reaction. A product was extracted with toluene (300 mL), a common aqueous work-up was performed, and after solvent removal, a product was purified by silica-gel column chromatography to obtain 77.0 g of monomer A2 as a colorless oil (85% yield).

IR spectrum data and results of 1H-NMR of monomer A2 are shown below.

IR (D-ATR): v=2969, 2878, 1755, 1727, 1630, 1608, 1567, 1509, 1461, 1422, 1404, 1381, 1283, 1223, 1175, 1121, 1109, 1019, 990, 949, 919, 860, 830, 782, 735, 713, 450 cm⁻¹.

¹H-NMR (600 MHz in DMSO-d6): δ=7.96 (2H, d), 7.64 (2H, d), 6.82 (1H, dd), 6.01 (1H, d), 5.44 (1H, d), 4.81 (2H, s), 1.99 (2H, m), 1.92 (2H, q), 1.58 (6H, m), 0.84 (3H, t) ppm.

### [Synthesis Example 1-3] Synthesis of Monomers A3 to A10

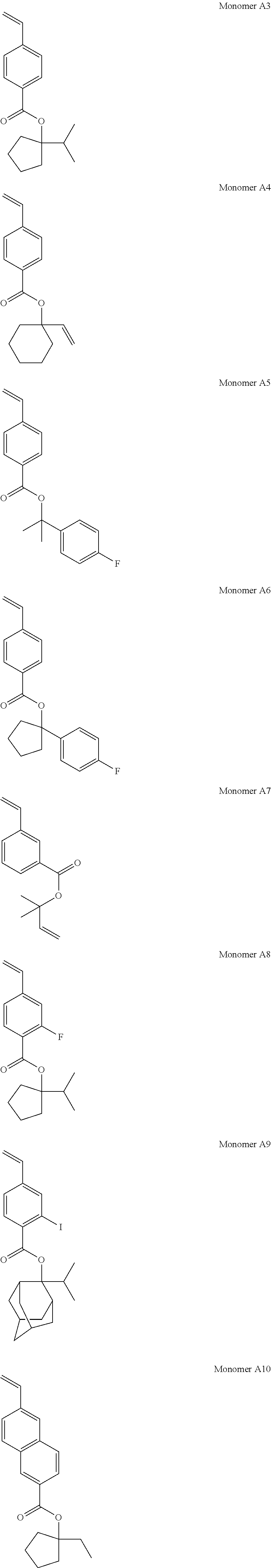

Monomers A3 to A10 were synthesized by using corresponding raw materials.

### [2] Synthesis of Polymer

Out of the monomers used for synthesizing a polymer, the monomers other than monomers A1 to A10 are as follows.

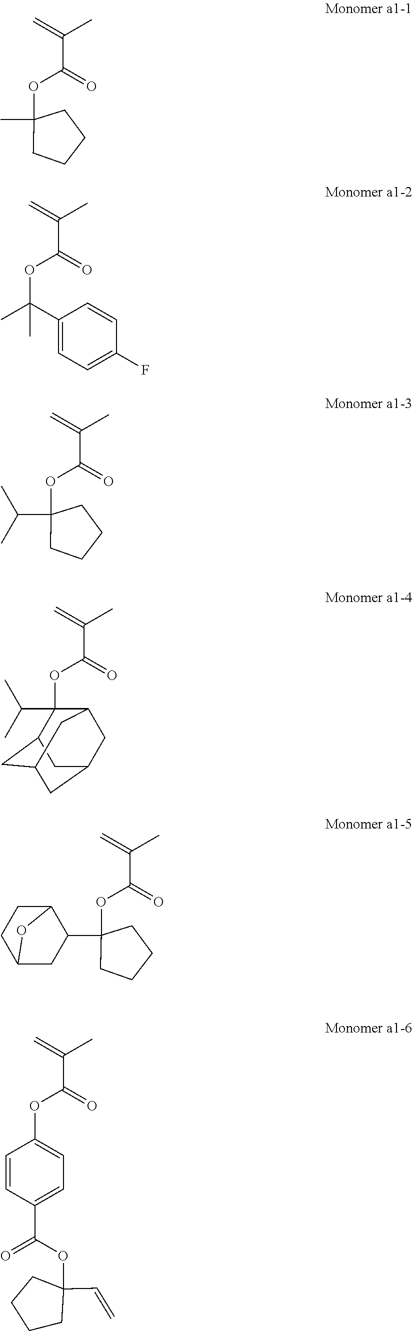

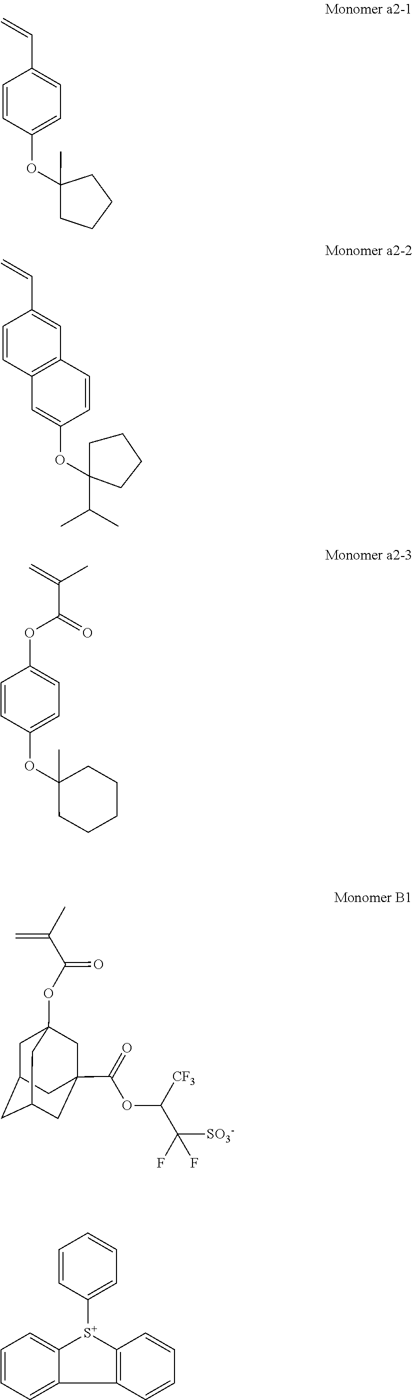

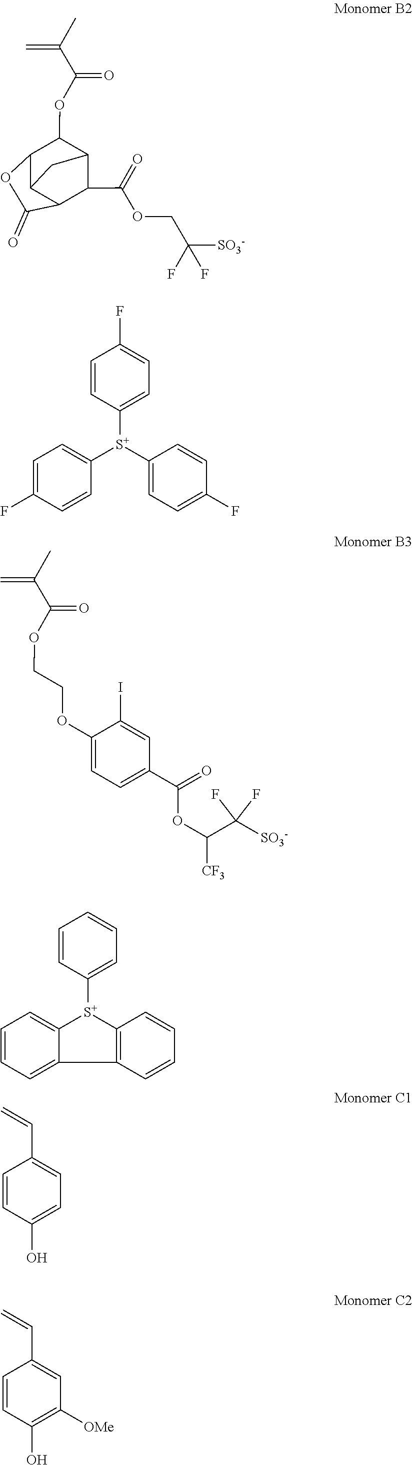

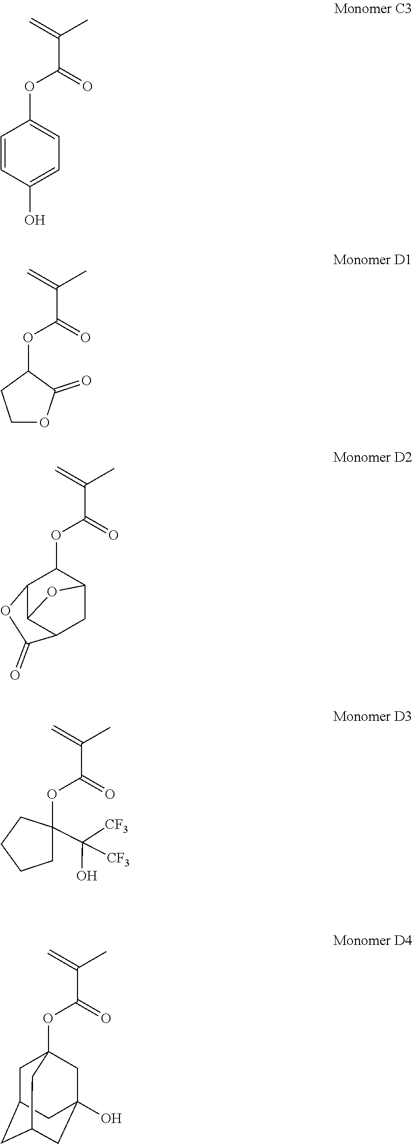 [SMILES: C=C(C)C(=O)Oc1ccc(O)cc1 ; C=C(C)C(=O)OC1CCOC1=O ; C=C(C)C(=O)OC1C2CC3C(=O)OC1C3O2 ; C=C(C)C(=O)OC1(C(O)(C(F)(F)F)C(F)(F)F)CCCC1 ; C=C(C)C(=O)OC12CC3CC(CC(O)(C3)C1)C2]

### [Synthesis Example 2-1] Synthesis of Polymer P-1

Under a nitrogen atmosphere, monomer A1 (32.1 g), monomer a1-1 (12.9 g), monomer B1 (42.4 g), monomer Ci (13.7 g), 3.80 g of V-601 (manufactured by Wako Pure Chemical Industries, Ltd.), and 126 g of MEK were added into a flask to prepare a monomer-polymerization initiator solution. Into another flask with a nitrogen atmosphere, 46 g of MEK was added and heated to 80° C. with stirring, and then the monomer-polymerization initiator solution was added dropwise over 4 hours. After the dropwise addition, the polymerization liquid was further stirred for 2 hours with maintaining the temperature at 80° C., and then cooled to room temperature. The obtained polymerization liquid was added dropwise to 2,000 g of vigorously stirred hexane, and a precipitated polymer was filtered. Thereafter, the obtained polymer was washed twice with 600 g of hexane, and then dried in vacuo at 50° C. for 20 hours to obtain a white powder polymer P-1 (98.1 g, 98% yield). The polymer P-1 had Mw of 9,400 and Mw/Mn of 1.83. The Mw is a polystyrene-converted measurement value by GPC using DMF as an eluent.

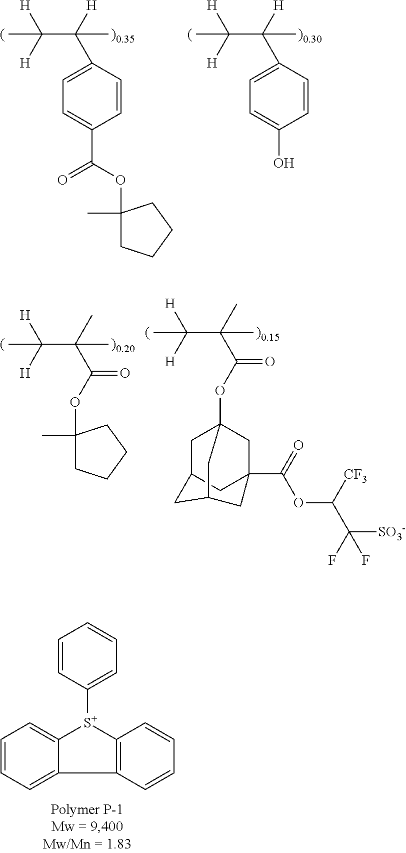

### [Synthesis Examples 2-2 to 2-10 and Comparative Synthesis Examples 1-1 to 1-20] Synthesis of Polymers P-2 to P-10 and Comparative Polymers CP-1 to CP-20

The polymers shown in Tables 1 and 2 were produced in the same manner as in Synthesis Example 2-1 except that the kinds and blending ratios of the monomers were changed.

TABLE 1

| | | Introduction | | Introduction | | Introduction | | Introduction | | Introduction | | |
|---|---|---|---|---|---|---|---|---|---|---|---|---|
| | | rate | | rate | | rate | | rate | | rate | | |
| Polymer | Unit A | (mol %) | Unit a | (mol %) | Unit B | (mol %) | Unit C | (mol %) | Unit D | (mol %) | Mw | Mw/Mn |
| P-1 | A1 | 35 | a1-1 | 20 | B1 | 15 | C1 | 30 | — | — | 9400 | 1.83 |
| P-2 | A2 | 40 | a1-2 | 20 | B2 | 15 | C2 | 25 | — | — | 9900 | 1.84 |
| P-3 | A3 | 25 | a1-3 | 25 | B2 | 15 | C1 | 35 | — | — | 9700 | 1.87 |
| P-4 | A4 | 30 | a1-4 | 15 | B1 | 10 | C2 | 25 | D1 | 20 | 9300 | 1.84 |
| P-5 | A5 | 35 | a1-5 | 15 | B3 | 15 | C1 | 35 | — | — | 9500 | 1.85 |
| P-6 | A6 | 35 | a1-1 | 15 | B1 | 20 | C2 | 30 | — | — | 9400 | 1.86 |
| P-7 | A7 | 30 | a1-3 | 15 | B2 | 10 | C3 | 25 | D2 | 20 | 9500 | 1.84 |
| P-8 | A8 | 30 | a1-2 | 20 | B3 | 15 | C1 | 35 | — | — | 9600 | 1.82 |
| P-9 | A9 | 35 | a1-1 | 15 | B1 | 15 | C2 | 35 | — | — | 9800 | 1.84 |
| P-10 | A10 | 30 | a1-2 | 20 | B1 | 15 | C1 | 30 | D3 | 5 | 9700 | 1.87 |

TABLE 2

| | | Introduction | | Introduction | | Introduction | | Introduction | | Introduction | | |
|---|---|---|---|---|---|---|---|---|---|---|---|---|
| | | rate | | rate | | rate | | rate | | rate | | |
| Polymer | Unit A | (mol %) | Unit a | (mol %) | Unit B | (mol %) | Unit C | (mol %) | Unit D | (mol %) | Mw | Mw/Mn |
| CP-1 | — | — | a1-1 | 55 | B1 | 15 | C1 | 30 | — | — | 9200 | 1.82 |
| CP-2 | — | — | a1-2 | 55 | B2 | 15 | C1 | 15 | — | — | 9400 | 1.83 |
| CP-3 | — | — | a1-1 | 25 | B1 | 15 | C1 | 35 | — | — | 9800 | 1.86 |
| | — | — | a1-2 | 25 | | | | | | | | |
| CP-4 | — | — | a1-2 | 30 | B2 | 15 | C1 | 30 | — | — | 9700 | 1.88 |
| | — | — | a1-3 | 25 | | | | | | | | |
| CP-5 | — | — | a1-3 | 30 | B1 | 15 | C3 | 35 | — | — | 9800 | 1.87 |
| | — | — | a1-5 | 20 | | | | | | | | |
| CP-6 | — | — | a1-4 | 10 | B1 | 15 | C3 | 25 | D2 | 20 | 9400 | 1.89 |
| | — | — | a2-1 | 30 | | | | | | | | |
| CP-7 | — | — | a1-6 | 50 | B3 | 10 | C2 | 30 | D1 | 10 | 9500 | 1.84 |
| CP-8 | — | — | a1-2 | 50 | B2 | 10 | C3 | 30 | D3 | 10 | 9400 | 1.83 |
| CP-9 | — | — | a1-3 | 35 | B2 | 15 | C2 | 30 | D1 | 10 | 9600 | 1.87 |
| | — | — | a2-2 | 15 | | | | | | | | |
| CP-10 | — | — | a1-2 | 25 | B1 | 15 | C1 | 35 | — | — | 9400 | 1.82 |
| | — | — | a2-3 | 25 | | | | | | | | |
| CP-11 | — | — | a1-1 | 50 | B3 | 15 | C1 | 35 | — | — | 9700 | 1.85 |
| CP-12 | A1 | 50 | — | — | — | — | C1 | 50 | — | — | 6500 | 1.67 |
| CP-13 | A3 | 50 | — | — | — | — | C3 | 50 | — | — | 6500 | 1.67 |
| CP-14 | A2 | 25 | a1-1 | 25 | — | — | C1 | 25 | D2 | 25 | 7100 | 1.54 |
| CP-15 | A3 | 30 | a1-3 | 20 | — | — | C3 | 40 | D3 | 10 | 6800 | 1.65 |
| CP-16 | — | — | a1-6 | 50 | — | — | C2 | 30 | D1 | 20 | 6500 | 1.64 |
| CP-17 | A5 | 35 | a1-4 | 15 | — | — | C3 | 40 | D3 | 10 | 7000 | 1.71 |
| CP-18 | A4 | 50 | — | — | — | — | — | — | D1 | 30 | 6700 | 1.64 |
| | | | | | | | | | D4 | 20 | | |
| CP-19 | A1 | 50 | — | — | — | — | C1 | 20 | D2 | 30 | 7800 | 1.51 |
| CP-20 | A10 | 30 | a1-4 | 30 | — | — | C3 | 30 | D2 | 10 | 8900 | 1.55 |

### [3] Preparation of Resist Composition

### Examples 1-1 to 1-10 and Comparative Examples 1-1 to 1-20

Prepared was a solution of each of the inventive polymers (P-1 to P-10), the comparative polymers (CP-1 to CP-20), photo-acid generators (PAG-1 and PAG-2), and quenchers (SQ-1 to SQ-3 and AQ-1) at the composition shown in the following Tables 3 and 4, 100 ppm of FC-4430, manufactured by 3M Company, being dissolved in the solution as a surfactant. The prepared solution was filtered with a filter made of Teflon® with 0.2 μm to prepare a resist composition.

In Tables 3 and 4, the components are as follows.
Organic solvent:PGMEA (propylene glycol monomethyl ether acetate) DAA (diacetone alcohol)
Photo-acid generator: PAG-1 and PAG-2

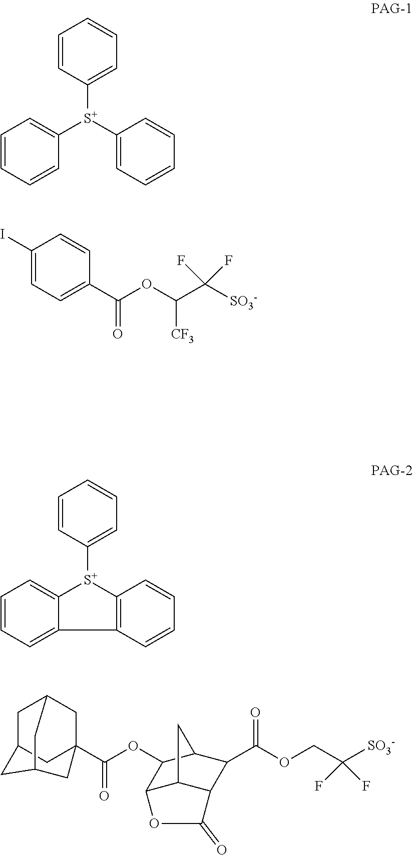

Quencher: SQ-1 to SQ-3 and AQ-1

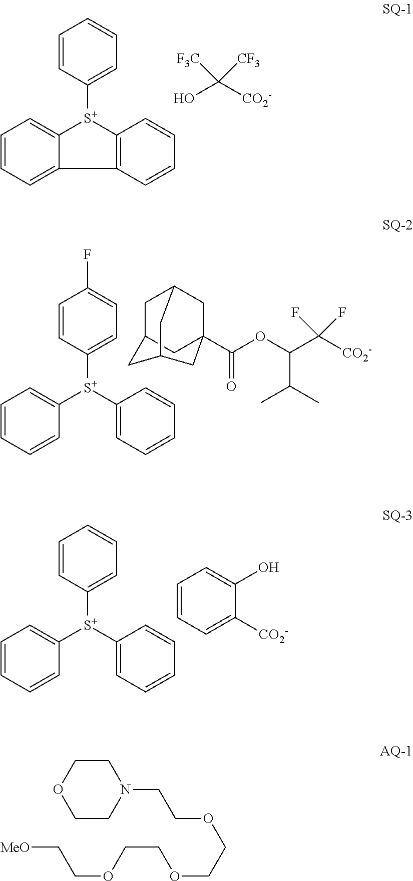

TABLE 3

| | | | Photoacid | | | |
|---|---|---|---|---|---|---|
| | | Polymer | generator | Quencher | Solvent 1 | Solvent 2 |
| | Resist | (parts by | (parts by | (parts by | (parts by | (parts by |
| | composition | mass) | mass) | mass) | mass) | mass) |
| Example 1-1 | R-1 | P-1 | — | SQ-1 | PGMEA | DAA |
| | | (80) | | (7.8) | (2,200) | (900) |
| Example 1-2 | R-2 | P-2 | — | SQ-2 | PGMEA | DAA |
| | | (80) | | (8.8) | (2,200) | (900) |
| Example 1-3 | R-3 | P-3 | — | SQ-3 | PGMEA | DAA |
| | | (80) | | (7.8) | (2,200) | (900) |
| Example 1-4 | R-4 | P-4 | PAG-1 | SQ-2 | PGMEA | DAA |
| | | (80) | (14.2) | (7.8) | (2,200) | (900) |
| Example 1-5 | R-5 | P-5 | — | SQ-1 | PGMEA | DAA |
| | | (80) | | (7.8) | (2,200) | (900) |
| Example 1-6 | R-6 | P-6 | — | SQ-3 | PGMEA | DAA |
| | | (80) | | (7.8) | (2,200) | (900) |
| Example 1-7 | R-7 | P-7 | PAG-2 | SQ-2 | PGMEA | DAA |
| | | (80) | (13.8) | (8.8) | (2,200) | (900) |
| Example 1-8 | R-8 | P-8 | — | SQ-1 | PGMEA | DAA |
| | | (80) | | (3.6) | (2,200) | (900) |
| | | | | AQ-1 | | |
| | | | | (3.6) | | |
| Example 1-9 | R-9 | P-9 | — | SQ-2 | PGMEA | DAA |
| | | (80) | | (7.8) | (2,200) | (900) |
| Example 1-10 | R-10 | P-10 | — | SQ-3 | PGMEA | DAA |
| | | (80) | | (7.4) | (2,200) | (900) |

TABLE 4

| | | Comparative | Photoacid | | | |
|---|---|---|---|---|---|---|
| | | polymer | generator | Quencher | Solvent 1 | Solvent 2 |
| | Resist | (parts by | (parts by | (parts by | (parts by | (parts by |
| | composition | mass) | mass) | mass) | mass) | mass) |
| Comparative | CR-1 | CP-1 | — | SQ-1 | PGMEA | DAA |
| Example 1-1 | | (80) | | (7.6) | (2,200) | (900) |
| Comparative | CR-2 | CP-2 | — | SQ-2 | PGMEA | DAA |
| Example 1-2 | | (80) | | (7.6) | (2,200) | (900) |
| Comparative | CR-3 | CP-3 | — | SQ-3 | PGMEA | DAA |
| Example 1-3 | | (80) | | (7.5) | (2,200) | (900) |
| Comparative | CR-4 | CP-4 | — | SQ-1 | PGMEA | DAA |
| Example 1-4 | | (80) | | (7.2) | (2,200) | (900) |
| Comparative | CR-5 | CP-5 | — | SQ-2 | PGMEA | DAA |
| Example 1-5 | | (80) | | (7.8) | (2,200) | (900) |
| Comparative | CR-6 | CP-6 | — | SQ-3 | PGMEA | DAA |
| Example 1-6 | | (80) | | (7.4) | (2,200) | (900) |
| Comparative | CR-7 | CP-7 | PAG-1 | SQ-3 | PGMEA | DAA |
| Example 1-7 | | (80) | (14.3) | (7.6) | (2,200) | (900) |
| Comparative | CR-8 | CP-8 | — | SQ-2 | PGMEA | DAA |
| Example 1-8 | | (80) | | (8.4) | (2,200) | (900) |
| Comparative | CR-9 | CP-9 | — | SQ-3 | PGMEA | DAA |
| Example 1-9 | | (80) | | (8.0) | (2,200) | (900) |
| Comparative | CR-10 | CP-10 | — | SQ-2 | PGMEA | DAA |
| Example 1-10 | | (80) | | (7.8) | (2,200) | (900) |
| Comparative | CR-11 | CP-11 | — | SQ-1 | PGMEA | DAA |
| Example 1-11 | | (80) | | (3.6) | (2,200) | (900) |
| | | | | AQ-1 | | |
| | | | | (3.6) | | |
| Comparative | CR-12 | CP-12 | PAG-1 | SQ-2 | PGMEA | DAA |
| Example 1-12 | | (80) | (28.5) | (7.8) | (2,200) | (900) |
| Comparative | CR-13 | CP-13 | PAG-2 | SQ-3 | PGMEA | DAA |
| Example 1-13 | | (80) | (27.6) | (7.8) | (2,200) | (900) |
| Comparative | CR-14 | CP-14 | PAG-1 | SQ-2 | PGMEA | DAA |
| Example 1-14 | | (80) | (27.7) | (7.8) | (2,200) | (900) |
| Comparative | CR-15 | CP-15 | PAG-1 | SQ-3 | PGMEA | DAA |
| Example 1-15 | | (80) | (28.9) | (7.2) | (2,200) | (900) |
| Comparative | CR-16 | CP-16 | PAG-2 | SQ-1 | PGMEA | DAA |
| Example 1-16 | | (80) | (26.6) | (7.6) | (2,200) | (900) |
| Comparative | CR-17 | CP-17 | PAG-2 | SQ-1 | PGMEA | DAA |
| Example 1-17 | | (80) | (27.3) | (7.6) | (2,200) | (900) |
| Comparative | CR-18 | CP-18 | PAG-1 | SQ-2 | PGMEA | DAA |
| Example 1-18 | | (80) | (29.5) | (7.8) | (2,200) | (900) |
| Comparative | CR-19 | CP-19 | PAG-2 | SQ-1 | PGMEA | DAA |
| Example 1-19 | | (80) | (27.2) | (7.4) | (2,200) | (900) |
| Comparative | CR-20 | CP-20 | PAG-1 | SQ-3 | PGMEA | DAA |
| Example 1-20 | | (80) | (27.8) | (7.6) | (2,200) | (900) |

### [4] EUV Lithography Evaluation (1)

### Examples 2-1 to 2-10 and Comparative Examples 2-1 to 2-20

Each of the resist compositions (R-1 to R-10 and CR-1 to CR-20) shown in Tables 3 and 4 was spin-applied on a Si substrate on which a silicon-containing spin-on hard mask SHB-A940, manufactured by Shin-Etsu Chemical Co., Ltd. (silicon content of 43 mass %), was formed with 20 nm in film thickness. Then, the substrate was prebaked at 100° C. for 60 seconds using a hot plate to produce a resist film having a film thickness of 50 nm. This resist film was exposed using an EUV scanner NXE3300 (NA 0.33, σ 0.9/0.6, dipole illumination), manufactured by ASML Holding N.V. The exposure was performed with an LS pattern with 18 nm on wafer size and 36 nm in pitch, and with changing an exposure dose and focus (exposure dose pitch: 1 mJ/cm², focus pitch: 0.020 μm). After the exposure, PEB was performed at a temperature shown in Tables 5 and 6 for 60 seconds. Thereafter, puddle development with a 2.38 mass % aqueous TMAH solution for 30 seconds, rinse with a surfactant-containing rinse material, and spin-drying were performed to obtain a positive pattern. The LS pattern after the development was observed with a length-measurement SEM (CG6300), manufactured by Hitachi High-Technologies Corporation, to evaluate sensitivity, EL, LWR, DOF, and collapse limit in accordance with the following methods. Tables 5 and 6 show the results.

### [Sensitivity Evaluation]

An optimum exposure dose Eₒₚ(mJ/cm²) to yield the LS pattern with 18 nm in line width and 36 nm in pitch was determined to specify this value as a sensitivity.

### [EL Evaluation]

From exposure doses to form the LS pattern within a range of ±10% of 18 nm space width (16.2 to 19.8 nm), EL (unit: %) was determined by the following equation. The larger the EL value, the better the performance.

EL(%)=(|E₁−E₂|/Eₒₚ)×100
E₁: An optimum exposure dose to yield an LS pattern with 16.2 nm in line width and 36 nm in pitch.
E₂: An optimum exposure dose to yield an LS pattern with 19.8 nm in line width and 36 nm in pitch.
Eₒₚ: An optimum exposure dose to yield the LS pattern with 18 nm in line width and 36 nm in pitch.

### [LWR Evaluation]

In the LS pattern obtained by irradiation at Eₒₚ, sizes at 10 positions in the longitudinal direction of the line were measured. From the results, a tripled value (3σ) of a standard variation (σ) was determined as LWR. A smaller LWR value can yield a pattern with smaller roughness and uniform line width.

### [DOF Evaluation]

As evaluation of depth of focus, determined was a focus range to form the LS pattern within a range of ±10% of 18 nm size (16.2 to 19.8 nm). A larger DOF value indicates wider depth of focus.

TABLE 5

| | | | Optimum | | | |
|---|---|---|---|---|---|---|
| | Resist | PEB | exposure | | | |
| | compo- | temperature | dose | EL | LWR | DOF |
| | sition | (° C.) | (mJ/cm²) | (%) | (nm) | (nm) |
| Example 2-1 | R-1 | 95 | 37 | 17 | 2.7 | 110 |
| Example 2-2 | R-2 | 95 | 36 | 18 | 2.8 | 120 |
| Example 2-3 | R-3 | 95 | 38 | 18 | 2.9 | 110 |
| Example 2-4 | R-4 | 95 | 37 | 19 | 2.8 | 120 |
| Example 2-5 | R-5 | 90 | 38 | 17 | 2.7 | 110 |
| Example 2-6 | R-6 | 95 | 37 | 18 | 2.6 | 100 |
| Example 2-7 | R-7 | 100 | 37 | 18 | 2.7 | 110 |
| Example 2-8 | R-8 | 90 | 38 | 17 | 2.7 | 120 |
| Example 2-9 | R-9 | 100 | 37 | 18 | 2.8 | 120 |
| Example 2-10 | R-10 | 95 | 37 | 19 | 2.9 | 120 |

TABLE 6

| | | | Optimum | | | |
|---|---|---|---|---|---|---|
| | Resist | PEB | exposure | | | |
| | compo- | temperature | dose | EL | LWR | DOF |
| | sition | (° C.) | (mJ/cm²) | (%) | (nm) | (nm) |
| Comparative | CR-1 | 100 | 41 | 16 | 3.2 | 80 |
| Example 2-1 | | | | | | |
| Comparative | CR-2 | 100 | 40 | 17 | 3.3 | 80 |
| Example 2-2 | | | | | | |
| Comparative | CR-3 | 95 | 40 | 16 | 3.2 | 90 |
| Example 2-3 | | | | | | |
| Comparative | CR-4 | 100 | 41 | 17 | 3.1 | 100 |
| Example 2-4 | | | | | | |
| Comparative | CR-5 | 100 | 41 | 15 | 3 | 70 |
| Example 2-5 | | | | | | |
| Comparative | CR-6 | 105 | 40 | 16 | 3.2 | 80 |
| Example 2-6 | | | | | | |
| Comparative | CR-7 | 100 | 39 | 16 | 3.2 | 70 |
| Example 2-7 | | | | | | |
| Comparative | CR-8 | 95 | 41 | 15 | 3.4 | 80 |
| Example 2-8 | | | | | | |
| Comparative | CR-9 | 95 | 40 | 15 | 3.1 | 90 |
| Example 2-9 | | | | | | |
| Comparative | CR-10 | 100 | 41 | 16 | 3.2 | 80 |
| Example 2-10 | | | | | | |
| Comparative | CR-11 | 95 | 40 | 15 | 3.3 | 90 |
| Example 2-11 | | | | | | |
| Comparative | CR-12 | 100 | 43 | 16 | 3.6 | 70 |
| Example 2-12 | | | | | | |
| Comparative | CR-13 | 100 | 42 | 15 | 3.7 | 90 |
| Example 2-13 | | | | | | |
| Comparative | CR-14 | 95 | 43 | 14 | 3.5 | 80 |
| Example 2-14 | | | | | | |
| Comparative | CR-15 | 100 | 42 | 16 | 3.5 | 70 |
| Example 2-15 | | | | | | |
| Comparative | CR-16 | 100 | 42 | 15 | 3.6 | 70 |
| Example 2-16 | | | | | | |
| Comparative | CR-17 | 95 | 41 | 14 | 3.7 | 80 |
| Example 2-17 | | | | | | |
| Comparative | CR-18 | 100 | 44 | 15 | 3.5 | 70 |
| Example 2-18 | | | | | | |
| Comparative | CR-19 | 100 | 43 | 15 | 3.7 | 80 |
| Example 2-19 | | | | | | |
| Comparative | CR-20 | 100 | 42 | 14 | 3.6 | 80 |
| Example 2-20 | | | | | | |

From the results shown in Tables 5 and 6, it was confirmed that the inventive resist compositions had good sensitivity and were excellent in various lithography properties.

### [5] EUV Lithography Evaluation (2)

### Examples 3-1 to 3-10 and Comparative Examples 3-1 to 3-20

Each of the resist compositions (R-1 to R-10 and CR-1 to CR-20) shown in Tables 3 and 4 was spin-applied on a Si substrate on which a silicon-containing spin-on hard mask SHB-A940, manufactured by Shin-Etsu Chemical Co., Ltd. (silicon content of 43 mass %), was formed with 20 nm in film thickness. Then, the substrate was prebaked at 105° C. for 60 seconds using a hot plate to produce a resist film with 50 nm in film thickness. This resist film was exposed using an EUV scanner NXE3400 (NA 0.33, σ 0.9/0.6, quadrupole illumination, 46 nm in pitch on wafer size, hole pattern mask with +20% bias), manufactured by ASML Holding N.V. Then, PEB was performed at a temperature shown in Tables 7 and 8 for 60 seconds using a hot plate. Thereafter, development was performed with a 2.38 mass % aqueous TMAH solution for 30 seconds to form a hole pattern with 23 nm in size.

Using a length-measurement SEM (CG6300), manufactured by Hitachi High-Technologies Corporation, an exposure dose when the hole size was formed with 23 nm was measured to specify this exposure dose as a sensitivity. Sizes of 50 holes were measured in this time, and a tripled value (36) of a standard variation (σ) calculated from the results was determined as size variation (CDU). Tables 7 and 8 show the results.

TABLE 7

| | | PEB | Optimum | |
|---|---|---|---|---|
| | Resist | temperature | exposure dose | CDU |
| | composition | (° C.) | (mJ/cm²) | (nm) |
| Example | R-1 | 100 | 25 | 2.6 |
| 3-1 | | | | |
| Example | R-2 | 90 | 24 | 2.6 |
| 3-2 | | | | |
| Example | R-3 | 95 | 26 | 2.5 |
| 3-3 | | | | |
| Example | R-4 | 100 | 26 | 2.4 |
| 3-4 | | | | |
| Example | R-5 | 95 | 25 | 2.4 |
| 3-5 | | | | |
| Example | R-6 | 95 | 24 | 2.5 |
| 3-6 | | | | |
| Example | R-7 | 100 | 25 | 2.5 |
| 3-7 | | | | |
| Example | R-8 | 100 | 25 | 2.4 |
| 3-8 | | | | |
| Example | R-9 | 105 | 26 | 2.6 |
| 3-9 | | | | |
| Example | R-10 | 95 | 24 | 2.6 |
| 3-10 | | | | |

TABLE 8

| | | PEB | Optimum | |
|---|---|---|---|---|
| | Resist | temperature | exposure dose | CDU |
| | composition | (° C.) | (mJ/cm²) | (nm) |
| Comparative | CR-1 | 100 | 28 | 2.8 |
| Example 3-1 | | | | |
| Comparative | CR-2 | 95 | 28 | 3 |
| Example 3-2 | | | | |
| Comparative | CR-3 | 95 | 29 | 2.9 |
| Example 3-3 | | | | |
| Comparative | CR-4 | 100 | 30 | 3.1 |
| Example 3-4 | | | | |
| Comparative | CR-5 | 100 | 29 | 3 |
| Example 3-5 | | | | |
| Comparative | CR-6 | 105 | 30 | 2.9 |
| Example 3-6 | | | | |
| Comparative | CR-7 | 100 | 29 | 3.2 |
| Example 3-7 | | | | |
| Comparative | CR-8 | 105 | 30 | 3.1 |
| Example 3-8 | | | | |
| Comparative | CR-9 | 100 | 28 | 3 |
| Example 3-9 | | | | |
| Comparative | CR-10 | 100 | 29 | 3.2 |
| Example 3-10 | | | | |
| Comparative | CR-11 | 95 | 30 | 2.9 |
| Example 3-11 | | | | |
| Comparative | CR-12 | 95 | 33 | 3.3 |
| Example 3-12 | | | | |
| Comparative | CR-13 | 100 | 34 | 3.2 |
| Example 3-13 | | | | |
| Comparative | CR-14 | 95 | 33 | 3.4 |
| Example 3-14 | | | | |
| Comparative | CR-15 | 95 | 32 | 3.5 |
| Example 3-15 | | | | |
| Comparative | CR-16 | 100 | 34 | 3.2 |
| Example 3-16 | | | | |
| Comparative | CR-17 | 95 | 34 | 3.4 |
| Example 3-17 | | | | |
| Comparative | CR-18 | 95 | 35 | 3.5 |
| Example 3-18 | | | | |
| Comparative | CR-19 | 100 | 32 | 3.4 |
| Example 3-19 | | | | |
| Comparative | CR-20 | 95 | 34 | 3.3 |
| Example 3-20 | | | | |

From the results shown in Tables 7 and 8, it was confirmed that the inventive resist compositions had good sensitivity and excellent CDU.

[6] Dry Etching Resistance Evaluation

### Examples 4-1 to 4-10 and Comparative Examples 4-1 to 4-20

Each of the polymers (P-1 to P-10) and comparative polymers (CP-1 to CP-20) shown in Tables 1 and 2 was respectively dissolved in 10 g of cyclohexanone in an amount of 2 g. Each polymer solution was filtered with a 0.2-μm filter and applied to a Si substrate by spin-coating to form a film. The film was formed to have a thickness of 300 nm, and evaluation was carried out under the following conditions.

Etching Test with CHF₃/CF₄-Based Gas:

The difference between the film thicknesses of the polymer film before and after etching was determined using a dry etching apparatus TE-8500P manufactured by Tokyo Electron Limited.

The etching conditions are as shown below.

| | | |
|---|---|---|
| Chamber pressure | 40.0 | Pa |
| RF power | 1,000 | W |
| Gap | 9 | mm |
| CHF₃ gas flow rate | 30 | mL/min |
| CF₄ gas flow rate | 30 | mL/min |
| Ar gas flow rate | 100 | mL/min |
| Time | 60 | sec |

In this evaluation, a smaller difference in film thickness, that is, a smaller amount reduced, indicates that the film has dry etching resistance.

Table 9 shows the results of the dry etching resistance.

TABLE 9

| | | CHF₃/CF₄ gas | | | CHF₃/CF₄ gas |
|---|---|---|---|---|---|
| | | etching rate | | Comparative | etching rate |
| | Polymer | (nm/min) | | polymer | (nm/min) |
| Example | P-1 | 97 | Comparative | CP-1 | 108 |
| 4-1 | | | Example 4-1 | | |
| Example | P-2 | 100 | Comparative | CP-2 | 110 |
| 4-2 | | | Example 4-2 | | |
| Example | P-3 | 97 | Comparative | CP-3 | 112 |
| 4-3 | | | Example 4-3 | | |
| Example | P-4 | 96 | Comparative | CP-4 | 111 |
| 4-4 | | | Example 4-4 | | |
| Example | P-5 | 98 | Comparative | CP-5 | 109 |
| 4-5 | | | Example 4-5 | | |
| Example | P-6 | 96 | Comparative | CP-6 | 107 |
| 4-6 | | | Example 4-6 | | |
| Example | P-7 | 98 | Comparative | CP-7 | 105 |
| 4-7 | | | Example 4-7 | | |
| Example | P-8 | 97 | Comparative | CP-8 | 108 |
| 4-8 | | | Example 4-8 | | |
| Example | P-9 | 96 | Comparative | CP-9 | 106 |
| 4-9 | | | Example 4-9 | | |
| Example | P-10 | 99 | Comparative | CP-10 | 104 |
| 4-10 | | | Example 4-10 | | |
| | | | Comparative | CP-11 | 107 |
| | | | Example 4-11 | | |
| | | | Comparative | CP-12 | 100 |
| | | | Example 4-12 | | |
| | | | Comparative | CP-13 | 99 |
| | | | Example 4-13 | | |
| | | | Comparative | CP-14 | 101 |
| | | | Example 4-14 | | |
| | | | Comparative | CP-15 | 99 |
| | | | Example 4-15 | | |
| | | | Comparative | CP-16 | 102 |
| | | | Example 4-16 | | |
| | | | Comparative | CP-17 | 103 |
| | | | Example 4-17 | | |
| | | | Comparative | CP-18 | 101 |
| | | | Example 4-18 | | |
| | | | Comparative | CP-19 | 103 |
| | | | Example 4-19 | | |
| | | | Comparative | CP-20 | 102 |
| | | | Example 4-20 | | |

From the results shown in Table 9, it was confirmed that the inventive polymer had excellent dry etching resistance to CHF₃/CF₄-based gas.

The present description includes the following embodiments.

[1]: A polymer (P) to generate an acid by light exposure and to change in solubility in a developer with an action of the acid, the polymer comprising:
a repeating unit represented by the following formula (A-1);
a repeating unit represented by any one or more selected from the following formulae (B-1), (B-2), (B-3), and (B-4) to generate an acid by light exposure; and
a repeating unit represented by the following formula (a-1) or (a-2) other than the repeating unit represented by the formula (A-1),

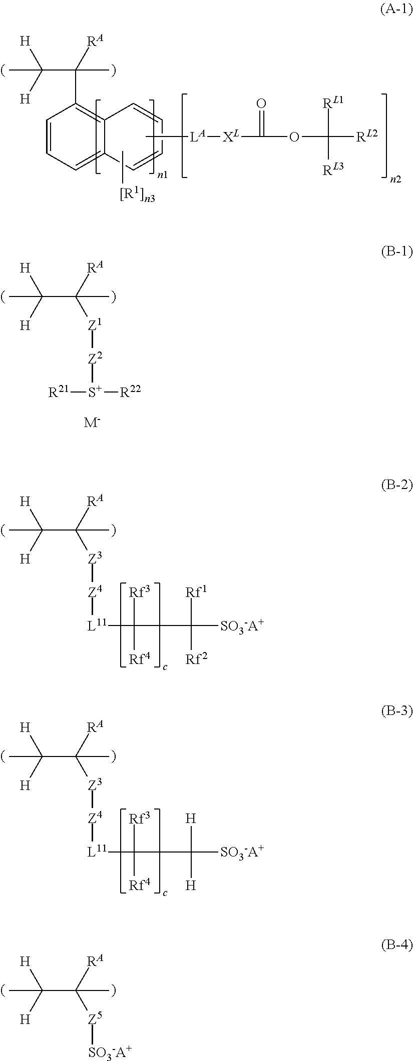

wherein in the formula (A-1), R^{A} represents a hydrogen atom, a fluorine atom, a methyl group, or a trifluoromethyl group, R^{L1}, R^{L2}, and R^{L3} each independently represent a hydrocarbyl group having 1 to 30 carbon atoms, any two of R^{L1}, R^{L2}, and R^{L3} optionally being bonded to each other to form a ring and when R^{L1}, R^{L2}, and R^{L3} are not bonded to each other to form a ring, at least one of R^{L1}, R^{L2}, and R^{L3} has one of a multiple bond, an aliphatic ring, and an aromatic ring structure, L^{A} represents a single bond, an ether bond, an ester bond, a sulfonic acid ester bond, a carbonate bond, or a carbamate bond, X^{L} represents a single bond or a hydrocarbylene group having 1 to 40 carbon atoms and optionally having a heteroatom, R¹ represents a halogen atom or a hydrocarbyl group having 1 to 20 carbon atoms and optionally having a heteroatom, n1 represents an integer of 0 or 1, n2 represents an integer of 1 or 2, n3 represents an integer of 0 to 6, provided that when n1 is 0, 1≤n2+n3≤5 and when n1 is 1, 1≤n2+n3≤7, in the formulae (B-1) to (B-4), R^{A} is as defined above, Z¹ represents a single bond or a phenylene group, Z² represents —C(═O)—O—Z²¹—, —C(═O)—NH—Z²¹—, or —O—Z²¹—, Z²¹ represents an aliphatic hydrocarbylene group having 1 to 6 carbon atoms, a phenylene group, or a divalent group obtained by combining these groups, Z²¹ optionally having a carbonyl group, an ester bond, an ether bond, or a hydroxy group, Z³ represents a single bond, a phenylene group, a naphthylene group, or (main chain) —C(═O)—O—Z³¹—, Z³¹ represents an aliphatic hydrocarbylene group having 1 to 10 carbon atoms, or a phenylene group or a naphthylene group optionally having a hydroxy group, an ether bond, an ester bond, or a lactone ring, Z⁴ represents a single bond or —Z⁴¹—C(═O)—O—, Z⁴¹ represents a hydrocarbylene group having 1 to 20 carbon atoms and optionally having a heteroatom, Z⁵ represents a single bond, a methylene group, an ethylene group, a phenylene group, a fluorinated phenylene group, a phenylene group substituted with a trifluoromethyl group, —C(═O)—O—Z⁵¹—, —C(═O)—NH—Z⁵¹—, or —O—Z⁵¹—, Z⁵¹ represents an aliphatic hydrocarbylene group having 1 to 6 carbon atoms, a phenylene group, a fluorinated phenylene group, or a phenylene group substituted with a trifluoromethyl group, Z⁵¹ optionally having a carbonyl group, an ester bond, an ether bond, or a hydroxy group, R²¹ and R²² each independently represent a hydrocarbyl group having 1 to 20 carbon atoms and optionally having a heteroatom, R²¹ and R²² are optionally bonded to each other to form a ring together with a sulfur atom to which R²¹ and R²² are bonded, L¹¹ represents a single bond, an ether bond, an ester bond, a carbonyl group, a sulfonic acid ester bond, a carbonate bond, or a carbamate bond, Rf¹ and Rf² each independently represent a fluorine atom or a fluorinated alkyl group having 1 to 6 carbon atoms, Rf³ and Rf⁴ each independently represent a hydrogen atom, a fluorine atom, or a fluorinated alkyl group having 1 to 6 carbon atoms, M⁻ represents a non-nucleophilic counterion, A⁺ represents an onium cation, and “c” represents an integer of 0 to 3,

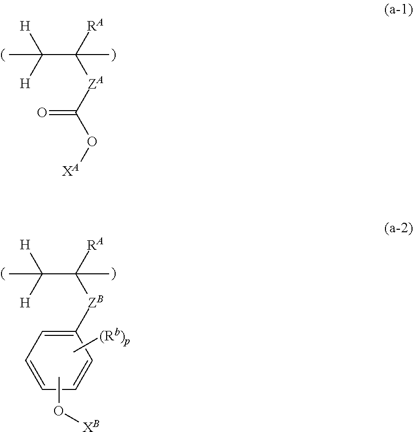

wherein R^{A} is as defined above, Z^{A} represents a single bond, a phenylene group, a naphthylene group, or (main chain) —C(═O)—O—Z^{A1}—, Z^{A1} represents a linear, branched, or cyclic alkanediyl group having 1 to 10 carbon atoms, or a phenylene group or a naphthylene group optionally having a hydroxy group, an ether bond, an ester bond, or a lactone ring, Z^{B} represents a single bond or (main chain) —C(═O)—O—, R^{b} represents a linear, branched, or cyclic hydrocarbyl group having 1 to 20 carbon atoms and optionally having a heteroatom, “p” represents an integer of 0 to 4, and X^{A} and X^{B} each independently represent an acid-labile group.

[2]: The polymer of the above [1], wherein the repeating unit represented by the formula (A-1) is a repeating unit represented by the following formula (A-2),

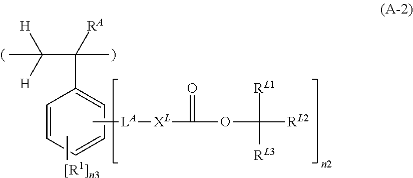

wherein R^{A}, R^{L1}, R^{L2}, R^{L3}, R¹, L^{A}, X^{L}, n2, and n3 are as defined above.

[3]: The polymer of the above [2], wherein the repeating unit represented by the formula (A-2) is a repeating unit represented by the following formula (A-3),

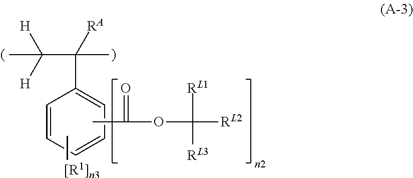

wherein R^{A}, R^{L1}, R^{L2}, R^{L3}, R¹, n2, and n3 are as defined above.

[4]: The polymer of any one of the above [1] to [3], wherein the repeating unit represented by the formulae (B-2), (B-3), and (B-4) to generate an acid by light exposure contains an onium cation represented by the following formula (cation-1) or (cation-2) as the onium cation A⁺,

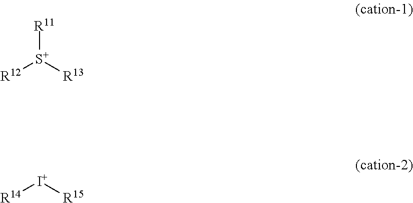

wherein R¹¹, R¹², and R¹³ each independently represent a linear, branched, or cyclic hydrocarbyl group having 1 to 30 carbon atoms and optionally having a heteroatom, any two of R¹¹, R¹², and R¹³ are optionally bonded to each other to form a ring together with a sulfur atom in the formula, and R¹⁴ and R¹⁵ each independently represent a linear, branched, or cyclic hydrocarbyl group having 1 to 30 carbon atoms and optionally having a heteroatom.

[5]: The polymer of any one of the above [1] to [4], further comprising a repeating unit represented by the following formula (C-1) in the polymer (P),

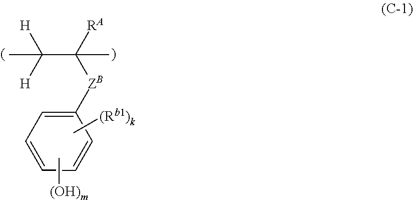

wherein R^{A} and Z^{B} are as defined above, R^{b1} represents a halogen atom, a cyano group, or a hydrocarbyl group having 1 to 20 carbon atoms, hydrocarbyloxy group having 1 to 20 carbon atoms, hydrocarbylcarbonyl group having 2 to 20 carbon atoms, hydrocarbylcarbonyloxy group having 2 to 20 carbon atoms, or hydrocarbyloxycarbonyl group having 2 to 20 carbon atoms optionally having a heteroatom, “m” represents an integer of 1 to 4, “k” represents an integer of 0 to 3, and “m+k” represents an integer of 1 to 4.

[6]: The polymer of any one of the above [1] to [5], further comprising a repeating unit represented by the following formula (D-1) in the polymer (P),

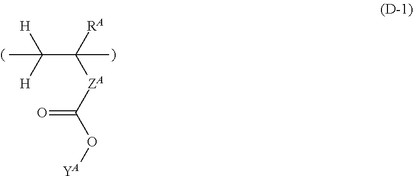

wherein R^{A} and Z^{A} are as defined above, Y^{A} represents a hydrogen atom or a polar group having at least one structure selected from a hydroxy group, a cyano group, a carbonyl group, a carboxy group, an ether bond, an ester bond, a sulfonic acid ester bond, a carbonate bond, a lactone ring, a sultone ring, and a carboxylic anhydride.

[7]: A resist composition comprising the polymer of any one of the above [1] to [6].

[8]: The resist composition of the above [7], further comprising an organic solvent.

[9]: The resist composition of the above [7] or [8], further comprising a photo-acid generator other than a structural unit of the polymer (P) to generate an acid by light exposure.

[10]: The resist composition of any one of the above [7] to [9], further comprising a quencher.

[11]: The resist composition of any one of the above [7] to [10], further comprising:
a surfactant insoluble or hardly soluble in water and soluble in an alkaline developer; and/or
a surfactant insoluble or hardly soluble in water and an alkaline developer.

[12]: A patterning process comprising the steps of:
forming a resist film on a substrate by using the resist composition of any one of the above [7] to [11];
exposing the resist film to a high-energy beam; and
developing the exposed resist film by using a developer.

[13]: The patterning process of the above [12], wherein an i-line beam, a KrF excimer laser beam, an ArF excimer laser beam, an electron beam, or an extreme ultraviolet ray having a wavelength of 3 to 15 nm is used as the high-energy beam.

[14]: The patterning process of the above [12] or [13], wherein an aqueous alkaline solution is used as the developer to obtain a positive pattern, where an exposed portion is dissolved and an unexposed portion is not dissolved.

[15]: The patterning process of the above [12] or [13], wherein an organic solvent is used as the developer to obtain a negative pattern, where an unexposed portion is dissolved and an exposed portion is not dissolved.

It should be noted that the present invention is not limited to the above-described embodiments. The embodiments are just examples, and any examples that have substantially the same feature and demonstrate the same functions and effects as those in the technical concept disclosed in claims of the present invention are included in the technical scope of the present invention.

1. A polymer (P) to generate an acid by light exposure and to change in solubility in a developer with an action of the acid, the polymer comprising:
a repeating unit represented by the following formula (A-1);
a repeating unit represented by any one or more selected from the following formulae (B-1), (B-2), (B-3), and (B-4) to generate an acid by light exposure; and
a repeating unit represented by the following formula (a-1) or (a-2) other than the repeating unit represented by the formula (A-1), 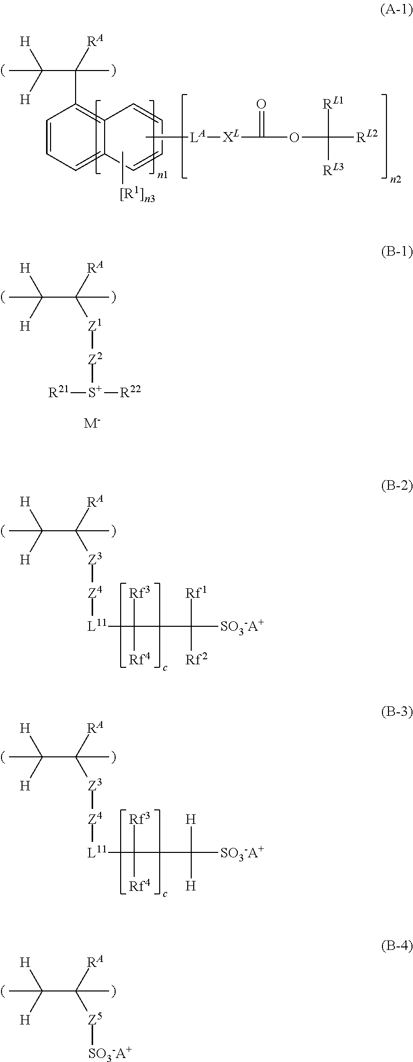
wherein in the formula (A-1), R^{A} represents a hydrogen atom, a fluorine atom, a methyl group, or a trifluoromethyl group, R^{L1}, R^{L2}, and R^{L3} each independently represent a hydrocarbyl group having 1 to 30 carbon atoms, any two of R^{L1}, R^{L2}, and R^{L3} optionally being bonded to each other to form a ring and when R^{L1}, R^{L2}, and R^{L3} are not bonded to each other to form a ring, at least one of R^{L1}, R^{L2}, and R^{L3} has one of a multiple bond, an aliphatic ring, and an aromatic ring structure, L^{A} represents a single bond, an ether bond, an ester bond, a sulfonic acid ester bond, a carbonate bond, or a carbamate bond, X^{L} represents a single bond or a hydrocarbylene group having 1 to 40 carbon atoms and optionally having a heteroatom, R¹ represents a halogen atom or a hydrocarbyl group having 1 to 20 carbon atoms and optionally having a heteroatom, n1 represents an integer of 0 or 1, n2 represents an integer of 1 or 2, n3 represents an integer of 0 to 6, provided that when n1 is 0, 1≤n2+n3≤5 and when n1 is 1, 1≤n2+n3≤7, in the formulae (B-1) to (B-4), R^{A} is as defined above, Z¹ represents a single bond or a phenylene group, Z² represents —C(═O)—O—Z²¹—, —C(═O)—NH—Z²¹—, or —O—Z²¹—, Z²¹ represents an aliphatic hydrocarbylene group having 1 to 6 carbon atoms, a phenylene group, or a divalent group obtained by combining these groups, Z²¹ optionally having a carbonyl group, an ester bond, an ether bond, or a hydroxy group, Z³ represents a single bond, a phenylene group, a naphthylene group, or (main chain) —C(═O)—O—Z³¹—, Z³¹ represents an aliphatic hydrocarbylene group having 1 to 10 carbon atoms, or a phenylene group or a naphthylene group optionally having a hydroxy group, an ether bond, an ester bond, or a lactone ring, Z⁴ represents a single bond or —Z⁴¹—C(═O)—O—, Z⁴¹ represents a hydrocarbylene group having 1 to 20 carbon atoms and optionally having a heteroatom, Z⁵ represents a single bond, a methylene group, an ethylene group, a phenylene group, a fluorinated phenylene group, a phenylene group substituted with a trifluoromethyl group, —C(═O)—O—Z⁵¹—, —C(═O)—NH—Z⁵¹—, or —O—Z⁵¹—, Z⁵¹ represents an aliphatic hydrocarbylene group having 1 to 6 carbon atoms, a phenylene group, a fluorinated phenylene group, or a phenylene group substituted with a trifluoromethyl group, Z⁵¹ optionally having a carbonyl group, an ester bond, an ether bond, or a hydroxy group, R²¹ and R²² each independently represent a hydrocarbyl group having 1 to 20 carbon atoms and optionally having a heteroatom, R²¹ and R²² are optionally bonded to each other to form a ring together with a sulfur atom to which R²¹ and R²² are bonded, L¹¹ represents a single bond, an ether bond, an ester bond, a carbonyl group, a sulfonic acid ester bond, a carbonate bond, or a carbamate bond, Rf¹ and Rf² each independently represent a fluorine atom or a fluorinated alkyl group having 1 to 6 carbon atoms, Rf³ and Rf⁴ each independently represent a hydrogen atom, a fluorine atom, or a fluorinated alkyl group having 1 to 6 carbon atoms, M⁻ represents a non-nucleophilic counterion, A⁺ represents an onium cation, and “c” represents an integer of 0 to 3, 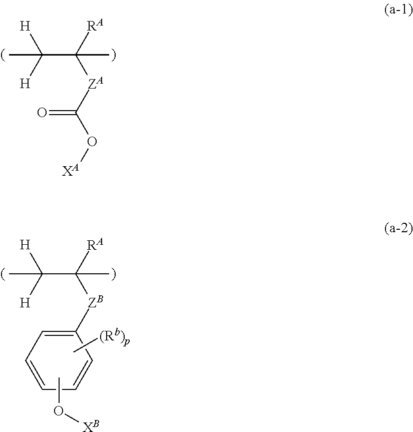
wherein R^{A} is as defined above, Z^{A} represents a single bond, a phenylene group, a naphthylene group, or (main chain) —C(═O)—O—Z^{A1}—, Z^{A1} represents a linear, branched, or cyclic alkanediyl group having 1 to 10 carbon atoms, or a phenylene group or a naphthylene group optionally having a hydroxy group, an ether bond, an ester bond, or a lactone ring, Z^{B} represents a single bond or (main chain) —C(═O)—O—, R^{b} represents a linear, branched, or cyclic hydrocarbyl group having 1 to 20 carbon atoms and optionally having a heteroatom, “p” represents an integer of 0 to 4, and X^{A} and X^{B} each independently represent an acid-labile group.

2. The polymer according to claim 1, wherein the repeating unit represented by the formula (A-1) is a repeating unit represented by the following formula (A-2), 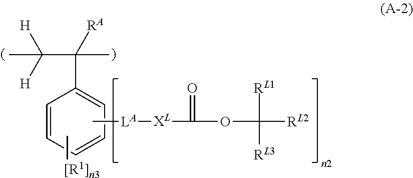
wherein R^{A}, R^{L1}, R^{L2}, R^{L3}, R¹, L^{A}, X^{L}, n2, and n3 are as defined above.

3. The polymer according to claim 2, wherein the repeating unit represented by the formula (A-2) is a repeating unit represented by the following formula (A-3), 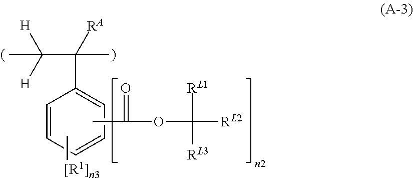
wherein R^{A}, R^{L1}, R^{L2}, R^{L3}, R¹, n2, and n3 are as defined above.

4. The polymer according to claim 1, wherein the repeating unit represented by the formulae (B-2), (B-3), and (B-4) to generate an acid by light exposure contains an onium cation represented by the following formula (cation-1) or (cation-2) as the onium cation A⁺, 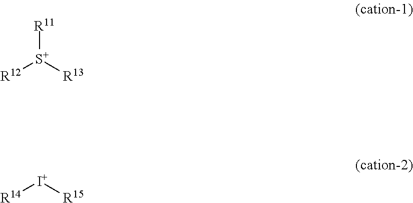
wherein R¹¹, R¹², and R¹³ each independently represent a linear, branched, or cyclic hydrocarbyl group having 1 to 30 carbon atoms and optionally having a heteroatom, any two of R¹¹, R¹², and R¹³ are optionally bonded to each other to form a ring together with a sulfur atom in the formula, and R¹⁴ and R¹⁵ each independently represent a linear, branched, or cyclic hydrocarbyl group having 1 to 30 carbon atoms and optionally having a heteroatom.

5. The polymer according to claim 1, further comprising a repeating unit represented by the following formula (C-1) in the polymer (P), 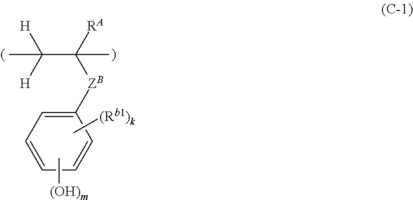
wherein R^{A} and Z^{B} are as defined above, R^{b1} represents a halogen atom, a cyano group, or a hydrocarbyl group having 1 to 20 carbon atoms, hydrocarbyloxy group having 1 to 20 carbon atoms, hydrocarbylcarbonyl group having 2 to 20 carbon atoms, hydrocarbylcarbonyloxy group having 2 to 20 carbon atoms, or hydrocarbyloxycarbonyl group having 2 to 20 carbon atoms optionally having a heteroatom, “m” represents an integer of 1 to 4, “k” represents an integer of 0 to 3, and “m+k” represents an integer of 1 to 4.

6. The polymer according to claim 1, further comprising a repeating unit represented by the following formula (D-1) in the polymer (P), 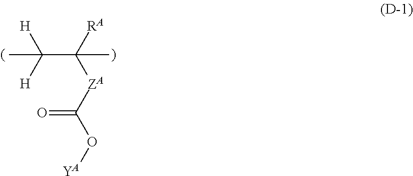
wherein R^{A} and Z^{A} are as defined above, Y^{A} represents a hydrogen atom or a polar group having at least one structure selected from a hydroxy group, a cyano group, a carbonyl group, a carboxy group, an ether bond, an ester bond, a sulfonic acid ester bond, a carbonate bond, a lactone ring, a sultone ring, and a carboxylic anhydride.

7. A resist composition comprising the polymer according to claim 1.

8. A resist composition comprising the polymer according to claim 2.

9. A resist composition comprising the polymer according to claim 3.

10. A resist composition comprising the polymer according to claim 4.

11. A resist composition comprising the polymer according to claim 5.

12. A resist composition comprising the polymer according to claim 6.

13. The resist composition according to claim 7, further comprising an organic solvent.

14. The resist composition according to claim 7, further comprising a photo-acid generator other than a structural unit of the polymer (P) to generate an acid by light exposure.

15. The resist composition according to claim 7, further comprising a quencher.

16. The resist composition according to claim 7, further comprising:
a surfactant insoluble or hardly soluble in water and soluble in an alkaline developer; and/or
a surfactant insoluble or hardly soluble in water and an alkaline developer.

17. A patterning process comprising the steps of:
forming a resist film on a substrate by using the resist composition according to claim 7;
exposing the resist film to a high-energy beam; and
developing the exposed resist film by using a developer.

18. The patterning process according to claim 17, wherein an i-line beam, a KrF excimer laser beam, an ArF excimer laser beam, an electron beam, or an extreme ultraviolet ray having a wavelength of 3 to 15 nm is used as the high-energy beam.

19. The patterning process according to claim 17, wherein an aqueous alkaline solution is used as the developer to obtain a positive pattern, where an exposed portion is dissolved and an unexposed portion is not dissolved.

20. The patterning process according to claim 17, wherein an organic solvent is used as the developer to obtain a negative pattern, where an unexposed portion is dissolved and an exposed portion is not dissolved.
